(19) United States
(12) Patent Application Publication
(10) Pub. No.: US 2022/0352105 A1
(43) Pub. Date: Nov. 3, 2022

(54) SEMICONDUCTOR DEVICE, ELECTRONIC COMPONENT, AND ELECTRONIC COMPONENT PRODUCTION METHOD

(71) Applicant: ROHM CO., LTD., Kyoto-shi, Kyoto (JP)

(72) Inventors: Isamu NISHIMURA, Kyoto-shi (JP); Hiroyuki SHINKAI, Kyoto-shi (JP); Yoshihisa TAKADA, Kyoto-shi (JP); Hideaki YANAGIDA, Kyoto-shi (JP); Hirofumi TAKEDA, Kyoto-shi (JP)

(21) Appl. No.: 17/765,265

(22) PCT Filed: Sep. 29, 2020
(86) PCT No.: PCT/JP2020/036908

§ 371 Date: Mar. 30, 2022

(30) Foreign Application Priority Data
Oct. 3, 2019 (JP) 2019-182886
Oct. 11, 2019 (JP) 2019-187336
Dec. 10, 2019 (JP) 2019-222901

(51) Int. Cl. H01L 23/00; H01L 23/498; H01L 23/31; H01L 21/48; H01L 25/16

(52) U.S. Cl. CPC H01L 24/16; H01L 23/49805; H01L 23/49838; H01L 23/3121; H01L 23/49894; H01L 21/4846; H01L 25/167; H01L 2224/16014; H01L 24/05; H01L 2224/05022; H01L 2224/05073; H01L 2224/05558; H01L 2224/05573; H01L 2224/05572; H01L 24/13; H01L 2224/13083; H01L 2224/16227; H01L 23/49827; H01L 2224/14155; H01L 24/06; H01L 2224/06155; H01L 24/14; H01L 2224/81192; H01L 2224/81815; H01L 2224/81191

(57) ABSTRACT

A semiconductor device includes a substrate, a wire portion, a bonding portion, a semiconductor element, and an encapsulation resin. The substrate includes substrate main and back surfaces facing in opposite directions. The wire portion includes a conductive layer formed on the substrate main surface. The bonding portion includes a first plated layer formed on an upper surface of the wire portion and a first solder layer formed on an upper surface of the first plated layer. The semiconductor element includes an element main surface facing the substrate main surface, an element electrode formed on the element main surface, and a second plated layer formed on a lower surface of the element electrode and bonded to the first solder layer. The encapsulation resin covers the semiconductor element. The bonding portion is larger than the element electrode as viewed in a thickness-wise direction that is perpendicular to the substrate main surface.

### TECHNICAL FIELD

The present disclosure relates to a semiconductor device, an electronic component, and a method for manufacturing an electronic component.

### BACKGROUND ART

In the prior art, an electronic component including an element such as a resistor or a semiconductor chip includes a substrate on which the element is mounted and an encapsulation resin that covers the element. Patent Literature 1 discloses an example of a semiconductor device that includes a wire element, external connection terminals disposed on a surface of the wire element, a semiconductor chip mounted on a further surface of the wire element, and an encapsulation resin formed on the further surface of the wire element to encapsulate the semiconductor chip.

In recent years, there is a demand for reduction in size of a semiconductor device used in an electronic apparatus as the size of the electronic apparatus is reduced. To meet such demands, Patent Literature 2 discloses an example of a semiconductor device that is reduced in size. The semiconductor device includes a semiconductor wafer, a semiconductor chip of a flip-chip-mounting type, and a sealing sheet including a thermosetting synthetic resin. The semiconductor wafer is used as a substrate on which the semiconductor chip is mounted. The semiconductor chip is flip-chip mounted on a wire disposed on the upper surface of the semiconductor wafer. The sealing sheet is formed on the semiconductor wafer to cover the semiconductor chip. Since the thickness of the semiconductor wafer is relatively small, the semiconductor device is reduced in size.

The semiconductor device has a larger linear expansion coefficient than the sealing sheet. Therefore, in the manufacturing of the semiconductor device described above, when the sealing sheet is heated and hardened, the semiconductor device may be bent. In this regard, Patent Literature 2 discloses that the sealing sheet of the semiconductor device has a two-layer structure including an embedding resin layer and a hard layer formed on the embedding resin layer that differ from each other in minimum melt viscosity. The embedding resin layer is in contact with the semiconductor wafer and covers the semiconductor chip. The hard layer and the semiconductor wafer are located at opposite sides of the embedding resin layer in a thickness-wise direction of the semiconductor device. The minimum melt viscosity of the hard layer is greater than the minimum melt viscosity of the embedding resin layer. Thus, the bending of the semiconductor device is reduced. However, in the semiconductor device disclosed in Patent Literature 2, the overall thickness of the sealing sheet is increased to reduce the bending of the sealing sheet. This hampers reduction in size of the semiconductor device.

One example of a known electronic component is an electronic component module that includes a circuit substrate, functional elements mounted on the upper surface of the circuit substrate, and an encapsulation resin that encapsulates the functional elements (for example, refer to Patent Literature 3).

### CITATION LIST

### Patent Literature

Patent Literature 1: Japanese Laid-Open Patent Publication No. 2013-197263

Patent Literature 2: Japanese Laid-Open Patent Publication No. 2015-32648

Patent Literature 3: Japanese Laid-Open Patent Publication No. 2011-124413

### SUMMARY OF INVENTION

### Technical Problem

A semiconductor chip is soldered to a conductive layer of a wire element by a reflow process. Copper (Cu) is used as the conductive layer. In the reflow process, the solder is heated and changed in phase to a liquid state. The liquid solder may flow outward along the conductive layer. Such an outflow of solder in unintended directions may form a short circuit.

A first objective of the present disclosure is to provide a semiconductor device that limits the outflow of solder.

A second objective of the present disclosure is to provide a semiconductor device that limits the bending of the device while being reduced in size.

In a conventional electronic component, functional elements are arranged on the same plane of a circuit substrate. There is room for improvement in reduction in size in the planar direction extending along the upper surface of the circuit substrate, that is, a direction orthogonal to the height-wise direction of the electronic component.

A third objective of the present disclosure to provide an electronic component that reduces the size in a direction orthogonal to the height-wise direction of the electronic component and a method for manufacturing an electronic component.

### Solution to Problem

A first aspect of the present disclosure is a semiconductor device that includes a substrate including a substrate main surface and a substrate back surface facing in opposite directions, a wire portion including a conductive layer formed on the substrate main surface, a bonding portion including a first plated layer formed on an upper surface of the wire portion and a first solder layer formed on an upper surface of the first plated layer, a semiconductor element including an element main surface facing the substrate main surface, an element electrode formed on the element main surface, and a second plated layer formed on a lower surface of the element electrode and bonded to the first solder layer, and an encapsulation resin covering the semiconductor element. The bonding portion is larger than the element electrode as viewed in a thickness-wise direction that is perpendicular to the substrate main surface.

In this configuration, the first solder layer is bonded to the second solder layer of the semiconductor element by a reflow process to form a solder layer. In the reflow process, the molten second solder layer is joined to the first solder layer and is less likely to flow outward from the plated layer. Thus, in the reflow process for mounting the semiconductor element, the outflow of solder is limited.

A second aspect of the present disclosure is a semiconductor device that includes an encapsulation resin including a first layer and a second layer, the first layer including a first main surface and a first back surface facing in opposite directions in a thickness-wise direction, the second layer including a second main surface and a second back surface facing in opposite directions in the thickness-wise direction, and the second back surface being in contact with the first main surface, a wire being in contact with the first main surface and partially covered by the second layer, and a semiconductor element including a lower surface facing the first main surface and pads disposed on the lower surface. At least one of the pads is bonded to the wire and covered by the second layer.

A third aspect of the present disclosure is an electronic component that includes an insulation member having an electrically insulating property and including an insulation main surface and an insulation back surface facing in opposite directions in a thickness-wise direction, a main surface wire formed on the insulation main surface and including a wire main surface facing in the same direction as the insulation main surface and a wire back surface facing the insulation main surface, a first functional element electrically connected to the main surface wire, the first functional element and the insulation member being disposed at opposite sides of the main surface wire in the thickness-wise direction, an encapsulation resin covering the main surface wire and the first functional element and including an element placement surface facing in the same direction as the insulation main surface, a connection conductor electrically connected to the main surface wire, extending from the wire main surface to the element placement surface in the thickness-wise direction, and exposed from the element placement surface, a through wire electrically connected to the main surface wire, extending from the wire back surface to the insulation back surface in the thickness-wise direction, and exposed from the insulation back surface, and a second functional element mounted on the element placement surface and electrically connected to the connection conductor.

In this configuration, the first functional element and the second functional element are disposed at different positions in the thickness-wise direction. Therefore, the first functional element and the second functional element may be disposed so as to overlap each other as viewed in the thickness-wise direction. Thus, as compared to a configuration in which the first functional element and the second functional element are arranged on the same plane in a direction orthogonal to the thickness-wise direction, the electronic component is reduced in size in the direction orthogonal to the thickness-wise direction.

A fourth aspect of the present disclosure is an electronic component that includes an insulation member having an electrically insulating property and including an insulation main surface and an insulation back surface facing in opposite directions in a thickness-wise direction, a main surface wire formed on the insulation main surface and including a wire main surface facing in the same direction as the insulation main surface and a wire back surface facing the insulation main surface, a through wire electrically connected to the main surface wire, extending from the wire back surface to the insulation back surface in the thickness-wise direction, and exposed from the insulation back surface, a first functional element electrically connected to the main surface wire, the first functional element and the insulation member being disposed at opposite sides of the main surface wire in the thickness-wise direction, an encapsulation resin covering the main surface wire and the first functional element and including an element placement surface facing in the same direction as the insulation main surface, and a connection conductor electrically connected to the main surface wire, extending from the wire main surface to the element placement surface in the thickness-wise direction, and exposed from the element placement surface. The connection conductor is configured to be electrically connected to a second functional element mounted on the element placement surface.

In this configuration, the first functional element and the second functional element are disposed at different positions in the thickness-wise direction. Therefore, the first functional element and the second functional element may be disposed so as to overlap each other as viewed in the thickness-wise direction. Thus, as compared to a configuration in which the first functional element and the second functional element are arranged on the same plane in a direction orthogonal to the thickness-wise direction, the electronic component is reduced in size in the direction orthogonal to the thickness-wise direction.

A fifth aspect of the present disclosure is a method for manufacturing an electronic component. The method includes a step of forming through wires on a support substrate having an electrically insulating property, an insulation layer forming step that forms an insulation layer including an insulation main surface and an insulation back surface facing in opposite directions in a thickness-wise direction so that the insulation layer fills a gap between the through wires on the support substrate and exposes the through wires from both the insulation main surface and the back surface, a main surface wire forming step that forms a main surface wire including a wire main surface and a wire back surface facing in opposite directions in the thickness-wise direction on the insulation main surface so that the wire back surface is electrically connected to the through wires, a conductor forming step that forms a connection conductor on the wire main surface, a first element mounting step that mounts a first functional element on the wire main surface, a resin layer forming step that forms a resin layer to cover the main surface wire, the connection conductor, and the first functional element, and a cutting step that cuts the insulation layer, the resin layer, the main surface wire, and the through wires in the thickness-wise direction to form an insulation member including the through wires and an encapsulation resin covering the main surface wire, the connection conductor, and the first functional element. In the resin layer forming step, the resin layer is formed so that the connection conductor is exposed from a surface of the resin layer located at a side opposite from the insulation member. The method further includes a second element mounting step that mounts a second functional element on a surface of the encapsulation resin located at a side opposite from the insulation member so as to be electrically connected to the connection conductor.

In this configuration, the first functional element and the second functional element are disposed at different positions in the thickness-wise direction. Therefore, the first functional element and the second functional element may be disposed so as to overlap each other as viewed in the thickness-wise direction. Thus, as compared to a configuration in which the first functional element and the second functional element are arranged on the same plane in a direction orthogonal to the thickness-wise direction, the electronic component is reduced in size in the direction orthogonal to the thickness-wise direction.

A sixth aspect of the present disclosure is a method for manufacturing an electronic component. The method includes an insulation layer forming step that forms an insulation layer including an insulation main surface and an insulation back surface facing in opposite directions in a thickness-wise direction, a first inner electrode forming step that forms a through wire exposed from the insulation back surface and a main surface wire including a wire main surface and a wire back surface facing in opposite directions in the thickness-wise direction and formed on the insulation main surface so as to be electrically connected to the through wire on the wire back surface, a second inner electrode forming step that forms a connection conductor formed on the wire main surface, a first element mounting step that mounts a first functional element on the wire main surface, a resin layer forming step that forms a resin layer that covers the main surface wire, the connection conductor, and the first functional element, and a cutting step that cuts the insulation layer, the through wire, the wire main surface, and the resin layer in the thickness-wise direction to form an insulation member including the through wire and an encapsulation resin covering the main surface wire, the connection conductor, and the first functional element. In the resin layer forming step, the resin layer is formed so that the connection conductor is exposed from a surface of the resin layer located at a side opposite from the insulation member. The method further includes a second element mounting step that mounts a second functional element on a surface of the encapsulation resin located a side opposite from the insulation member so as to be electrically connected to the connection conductor.

In this configuration, the first functional element and the second functional element are disposed at different positions in the thickness-wise direction. Therefore, the first functional element and the second functional element may be disposed so as to overlap each other as viewed in the thickness-wise direction. Thus, as compared to a configuration in which the first functional element and the second functional element are arranged on the same plane in a direction orthogonal to the thickness-wise direction, the electronic component is reduced in size in the direction orthogonal to the thickness-wise direction.

A seventh aspect of the present disclosure is a method for manufacturing an electronic component. The method includes a step of forming through wires on a support substrate, an insulation layer forming step that forms an insulation layer including an insulation main surface and an insulation back surface facing in opposite directions in a thickness-wise direction so that the insulation layer fills a gap between the through wires on the support substrate and exposes the through wires from both the insulation main surface and the back surface, a main surface wire forming step that forms a main surface wire including a wire main surface and a wire back surface facing in opposite directions in the thickness-wise direction on the insulation main surface so that the wire back surface is electrically connected to the through wires, a conductor forming step that forms a connection conductor on the wire main surface, a first element mounting step that mounts a first functional element on the wire main surface, a resin layer forming step that forms a resin layer to cover the main surface wire, the connection conductor, and the first functional element, and a cutting step that cuts the insulation layer, the resin layer, the main surface wire, and the through wires in the thickness-wise direction to form an insulation member including the through wires and an encapsulation resin covering the main surface wire, the connection conductor, and the first functional element. In the resin layer forming step, the resin layer is formed so that the connection conductor is exposed from a surface of the resin layer located at a side opposite from the insulation member. The encapsulation resin includes an element placement surface on which a second functional element is mounted. The second functional element is electrically connected to the connection conductor. The element placement surface and the insulation layer are formed on opposite surfaces of the encapsulation resin in the thickness-wise direction.

In this configuration, the first functional element and the second functional element are disposed at different positions in the thickness-wise direction. Therefore, the first functional element and the second functional element may be disposed so as to overlap each other as viewed in the thickness-wise direction. Thus, as compared to a configuration in which the first functional element and the second functional element are arranged on the same plane in a direction orthogonal to the thickness-wise direction, the electronic component is reduced in size in the direction orthogonal to the thickness-wise direction.

An eighth aspect of the present disclosure is a method for manufacturing an electronic component. The method includes an insulation layer forming step that forms an insulation layer including an insulation main surface and an insulation back surface facing in opposite directions in a thickness-wise direction, a first inner electrode forming step that forms a through wire exposed from the insulation back surface and a main surface wire including a wire main surface and a wire back surface facing in opposite directions in the thickness-wise direction and formed on the insulation main surface so as to be electrically connected to the through wire on the wire back surface, a second inner electrode forming step that forms a connection conductor formed on the wire main surface, a first element mounting step that mounts a first functional element on the wire main surface, a resin layer forming step that forms a resin layer that covers the main surface wire, the connection conductor, and the first functional element, and a cutting step that cuts the insulation layer, the through wire, the wire main surface, and the resin layer in the thickness-wise direction to form an insulation member including the through wire and an encapsulation resin covering the main surface wire, the connection conductor, and the first functional element. In the resin layer forming step, the resin layer is formed so that the connection conductor is exposed from a surface of the resin layer located at a side opposite from the insulation member. The encapsulation resin includes an element placement surface on which a second functional element is mounted. The second functional element is electrically connected to the connection conductor. The element placement surface and the insulation layer are formed on opposite surfaces of the encapsulation resin in the thickness-wise direction.

In this configuration, the first functional element and the second functional element are disposed at different positions in the thickness-wise direction. Therefore, the first functional element and the second functional element may be disposed so as to overlap each other as viewed in the thickness-wise direction. Thus, as compared to a configuration in which the first functional element and the second functional element are arranged on the same plane in a direction orthogonal to the thickness-wise direction, the electronic component is reduced in size in the direction orthogonal to the thickness-wise direction.

### BRIEF DESCRIPTION OF DRAWINGS

FIG. 1 is a schematic cross-sectional view of a semiconductor device in a first embodiment.

FIG. 2 is a schematic 25 back view of the semiconductor device in the first embodiment.

FIG. 3 is an enlarged partial plan view of the semiconductor device in the first embodiment.

FIG. 4 is an enlarged partial cross-sectional view of the semiconductor device in the first embodiment.

FIG. 5 is an enlarged partial cross-sectional view of a wire portion and a semiconductor element before the reflow process is performed.

FIG. 6 is a schematic cross-sectional view of a semiconductor device in a second embodiment.

FIG. 7 is a schematic plan view of the semiconductor device in the second embodiment.

FIG. 8 is an enlarged partial plan view of the semiconductor device in the second embodiment.

FIG. 9 is an enlarged partial plan view of a semiconductor device in a modified example.

FIG. 10 is a schematic cross-sectional view of a semiconductor device in a modified example.

FIG. 11 is a schematic cross-sectional view of a semiconductor device in a modified example.

FIG. 12 is a schematic cross-sectional view of a semiconductor device in a modified example.

FIG. 13 is a schematic cross-sectional view of a semiconductor device in a modified example.

FIG. 14 is a plan view of a semiconductor device in a third embodiment according to the present disclosure transparently showing a second layer of an encapsulation resin.

FIG. 15 is a plan view corresponding to FIG. 14 transparently showing the semiconductor element.

FIG. 16 is a bottom view of the semiconductor device shown in FIG. 14.

FIG. 17 is a front view of the semiconductor device shown in FIG. 14.

FIG. 18 is a cross-sectional view taken along line V-V in FIG. 14.

FIG. 19 is a cross-sectional view taken along line VI-VI in FIG. 14.

FIG. 20 is an enlarged partial view of FIG. 18.

FIG. 21 is a plan view of a modified example of the semiconductor device of the third embodiment according to the present disclosure transparently showing a second layer of an encapsulation resin.

FIG. 22 is a cross-sectional view taken along line IX-IX in FIG. 21.

FIG. 23 is a cross-sectional view showing a manufacturing step of the semiconductor device shown in FIG. 14.

FIG. 24 is a cross-sectional view showing a manufacturing step of the semiconductor device shown in FIG. 14.

FIG. 25 is a cross-sectional view showing a manufacturing step of the semiconductor device shown in FIG. 14.

FIG. 26 is a cross-sectional view showing a manufacturing step of the semiconductor device shown in FIG. 14.

FIG. 27 is a cross-sectional view showing a manufacturing step of the semiconductor device shown in FIG. 14.

FIG. 28 is a cross-sectional view showing a manufacturing step of the semiconductor device shown in FIG. 14.

FIG. 29 is a cross-sectional view showing a manufacturing step of the semiconductor device shown in FIG. 14.

FIG. 30 is a cross-sectional view showing a manufacturing step of the semiconductor device shown in FIG. 14.

FIG. 31 is a cross-sectional view showing a manufacturing step of the semiconductor device shown in FIG. 14.

FIG. 32 is a cross-sectional view showing a manufacturing step of the semiconductor device shown in FIG. 14.

FIG. 33 is a cross-sectional view showing a manufacturing step of the semiconductor device shown in FIG. 14.

FIG. 34 is a cross-sectional view showing a manufacturing step of the semiconductor device shown in FIG. 14.

FIG. 35 is a cross-sectional view showing a manufacturing step of the semiconductor device shown in FIG. 14.

FIG. 36 is a cross-sectional view showing a manufacturing step of the semiconductor device shown in FIG. 14.

FIG. 37 is a plan view of a semiconductor device in a fourth embodiment according to the present disclosure transparently showing a second layer of an encapsulation resin.

FIG. 38 is a front view of the semiconductor device shown in FIG. 37.

FIG. 39 is a cross-sectional view taken along line XXVI-XXVI in FIG. 37.

FIG. 40 is a plan view of a semiconductor device in a fifth embodiment according to the present disclosure transparently showing a second layer of an encapsulation resin.

FIG. 41 is a bottom view of the semiconductor device shown in FIG. 40.

FIG. 42 is a cross-sectional view taken along line XXIX-XXIX in FIG. 40.

FIG. 43 is a cross-sectional view taken along line XXX-XXX in FIG. 40.

FIG. 44 is an enlarged partial view of FIG. 42.

FIG. 45 is a plan view of a semiconductor device in a sixth embodiment according to the present disclosure.

FIG. 46 is a plan view corresponding to FIG. 45 transparently showing the second layer of the encapsulation resin.

FIG. 47 is a cross-sectional view taken along line XXXIV-XXXIV in FIG. 45.

FIG. 48 is a cross-sectional view taken along line XXXV-XXXV in FIG. 45.

FIG. 49 a perspective view of an electronic component in a seventh embodiment as viewed from a planar side.

FIG. 50 a perspective view of the electronic component shown in FIG. 49 as viewed from a back surface side.

FIG. 51 an exploded perspective view of the electronic component shown in FIG. 49.

FIG. 52 is a back view of the electronic component shown in FIG. 49.

FIG. 53 is a plan view of the electronic component shown in FIG. 49.

FIG. 54 is a side view of the electronic component shown in FIG. 49.

FIG. 55 is a cross-sectional view taken along line 7-7 in FIG. 53.

FIG. 56 is an enlarged view of a connection conductor shown in FIG. 55 and its surroundings.

FIG. 57 is an enlarged view of an electrode pad of a first functional element shown in FIG. 55 and its surroundings.

FIG. 58 is an enlarged view of the upper surface of the connection conductor shown in FIG. 56 and its surroundings.

FIG. 59 is a diagram showing an example of a step in a manufacturing method of the electronic component of the seventh embodiment.

FIG. 60 is a diagram showing an example of a step in the manufacturing method of the electronic component of the seventh embodiment.

FIG. 61 is a diagram showing an example of a step in the manufacturing method of the electronic component of the seventh embodiment.

FIG. 62 is a diagram showing an example of a step in the manufacturing method of the electronic component of the seventh embodiment.

FIG. 63 is an enlarged partial view of FIG. 62. FIG. 64 is a diagram showing an example of a step in the manufacturing method of the electronic component of the seventh embodiment.

FIG. 65 is a diagram showing an example of a step in the manufacturing method of the electronic component of the seventh embodiment.

FIG. 66 is an enlarged partial view of FIG. 65.

FIG. 67 is a diagram showing an example of a step in the manufacturing method of the electronic component of the seventh embodiment.

FIG. 68 is an enlarged partial view of FIG. 67.

FIG. 69 is a diagram showing an example of a step in the manufacturing method of the electronic component of the seventh embodiment.

FIG. 70 is a diagram showing an example of a step in the manufacturing method of the electronic component of the seventh embodiment.

FIG. 71 is a diagram showing an example of a step in the manufacturing method of the electronic component of the seventh embodiment.

FIG. 72 is a diagram showing an example of a step in the manufacturing method of the electronic component of the seventh embodiment.

FIG. 73 is a diagram showing an example of a step in the manufacturing method of the electronic component of the seventh embodiment.

FIG. 74 is a diagram showing an example of a step in the manufacturing method of the electronic component of the seventh embodiment.

FIG. 75 is a diagram showing an example of a step in the manufacturing method of the electronic component of the seventh embodiment.

FIG. 76 is a diagram showing an example of a step in the manufacturing method of the electronic component of the seventh embodiment.

FIG. 77 is a diagram showing an example of a step in the manufacturing method of the electronic component of the seventh embodiment.

FIG. 78 is a diagram showing an example of a step in the manufacturing method of the electronic component of the seventh embodiment.

FIG. 79 a cross-sectional view of an electronic component in an eighth embodiment.

FIG. 80 is an enlarged partial view of FIG. 79.

FIG. 81 is a diagram showing an example of a step in a manufacturing method of the electronic component of the eighth embodiment.

FIG. 82 is a diagram showing an example of a step in the manufacturing method of the electronic component of the eighth embodiment.

FIG. 83 is a diagram showing an example of a step in the manufacturing method of the electronic component of the eighth embodiment.

FIG. 84 is a diagram showing an example of a step in the manufacturing method of the electronic component of the eighth embodiment.

FIG. 85 is an enlarged partial view of FIG. 84.

FIG. 86 is a diagram showing an example of a step in the manufacturing method of the electronic component of the eighth embodiment.

FIG. 87 is a diagram showing an example of a step in the manufacturing method of the electronic component of the eighth embodiment.

FIG. 88 is an enlarged partial view of FIG. 87.

FIG. 89 is a diagram showing an example of a step in the manufacturing method of the electronic component of the eighth embodiment.

FIG. 90 is a diagram showing an example of a step in the manufacturing method of the electronic component of the eighth embodiment.

FIG. 91 is a diagram showing an example of a step in the manufacturing method of the electronic component of the eighth embodiment.

FIG. 92 is a diagram showing an example of a step in the manufacturing method of the electronic component of the eighth embodiment.

FIG. 93 is a diagram showing an example of a step in the manufacturing method of the electronic component of the eighth embodiment.

FIG. 94 is a diagram showing an example of a step in the manufacturing method of the electronic component of the eighth embodiment.

FIG. 95 is a diagram showing an example of a step in the manufacturing method of the electronic component of the eighth embodiment.

FIG. 96 is a diagram showing an example of a step in the manufacturing method of the electronic component of the eighth embodiment.

FIG. 97 is a diagram showing an example of a step in the manufacturing method of the electronic component of the eighth embodiment.

FIG. 98 is a diagram showing an example of a step in the manufacturing method of the electronic component of the eighth embodiment.

FIG. 99 is a diagram showing an example of a step in the manufacturing method of the electronic component of the eighth embodiment.

FIG. 100 is a diagram showing an example of a step in the manufacturing method of the electronic component of the eighth embodiment.

FIG. 101 a perspective view of an electronic component in a ninth embodiment as viewed from a planar side.

FIG. 102 is a plan view of the electronic component shown in FIG. 101.

FIG. 103 is a back view of the electronic component shown in FIG. 101.

FIG. 104 is a cross-sectional view taken along line 56-56 in FIG. 102.

FIG. 105 is a schematic circuit diagram of the electronic component shown in FIG. 101.

FIG. 106 is a schematic circuit diagram of an electronic component in a modified example.

FIG. 107 is a back view of an electronic component in a modified example.

FIG. 108 is an enlarged cross-sectional view of an electrode pad of a first functional element and its surroundings in a modified example of an electronic component.

FIG. 109 is a back view of an electronic component in a modified example.

FIG. 110 is a plan view of an electronic component in a modified example.

FIG. 111 is a cross-sectional view of an electronic component in a modified example.

FIG. 112 is a cross-sectional view of an electronic component in a modified example.

### DESCRIPTION OF EMBODIMENTS

Embodiments and modified examples will hereafter be described with reference to the drawings. The embodiments and modified examples described below exemplify configurations and methods for embodying a technical concept and are not intended to limit the material, shape, structure, arrangement, dimensions, and the like of each component to those described below. The embodiments and modified examples may undergo various modifications. The embodiments and modified examples may be combined as long as the combined modified examples remain technically consistent with each other.

First Embodiment

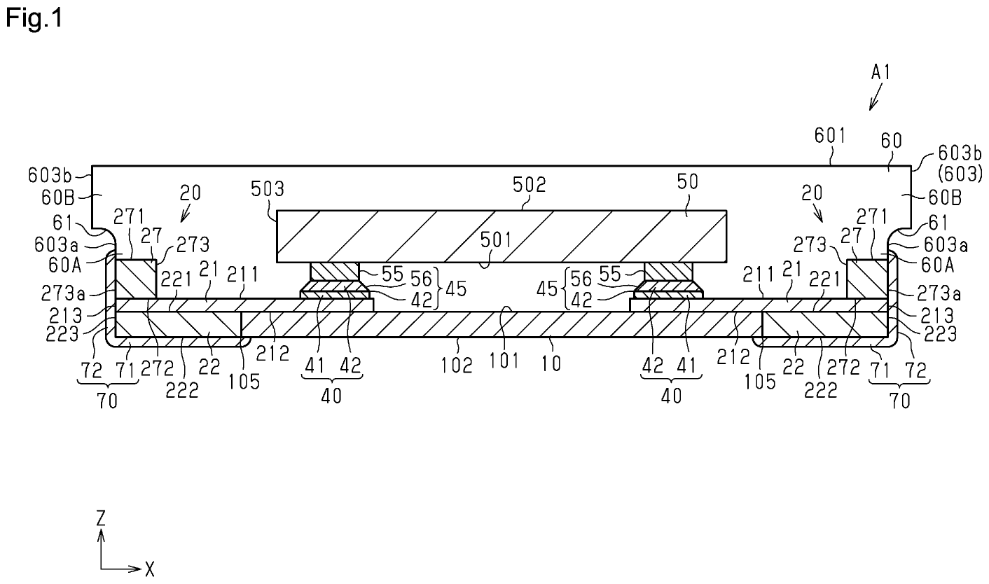

A first embodiment of a semiconductor device A1 will be described below with reference to FIGS. 1 to 5.

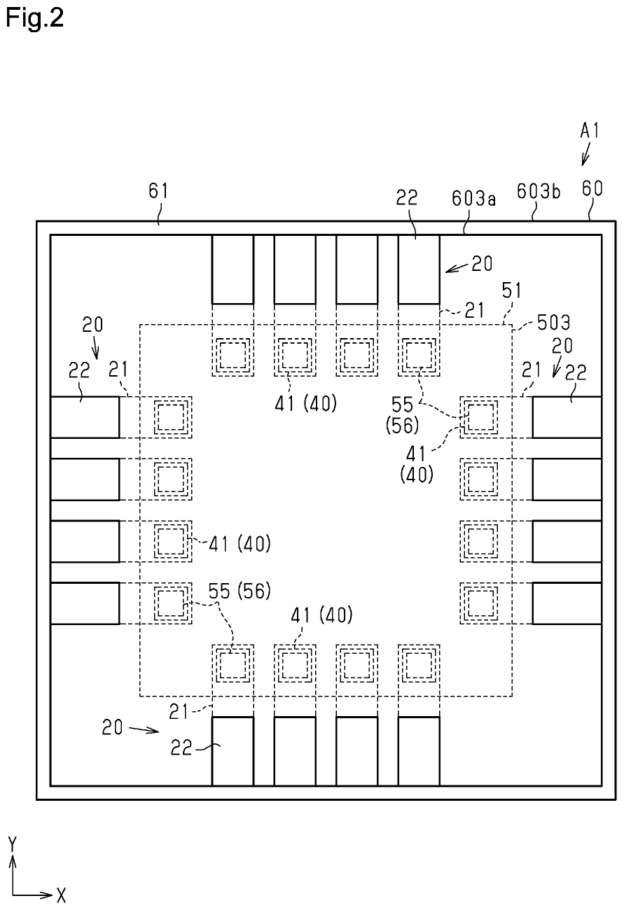

As shown in FIGS. 1 and 2, the semiconductor device A1 includes a substrate 10, a wire portion 20, bonding portions 40, a semiconductor element 50, an encapsulation resin 60, and external connection terminals 70. The wire portion 20 includes a main surface wire 21 and a through wire 22.

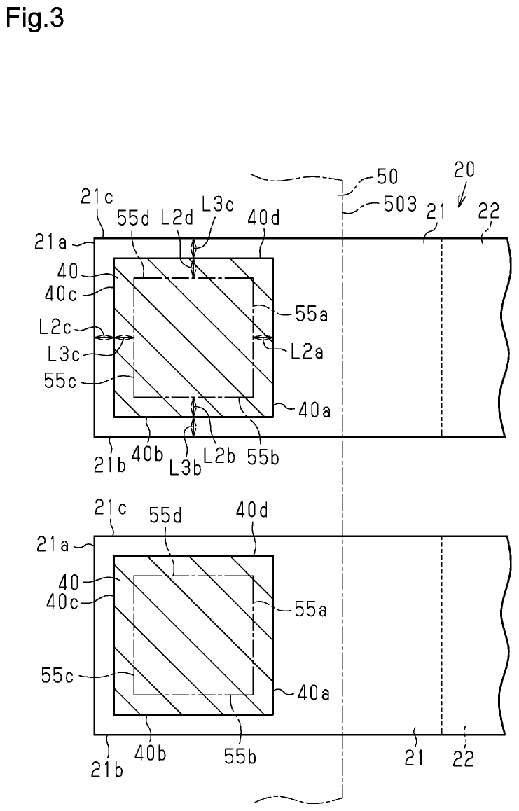

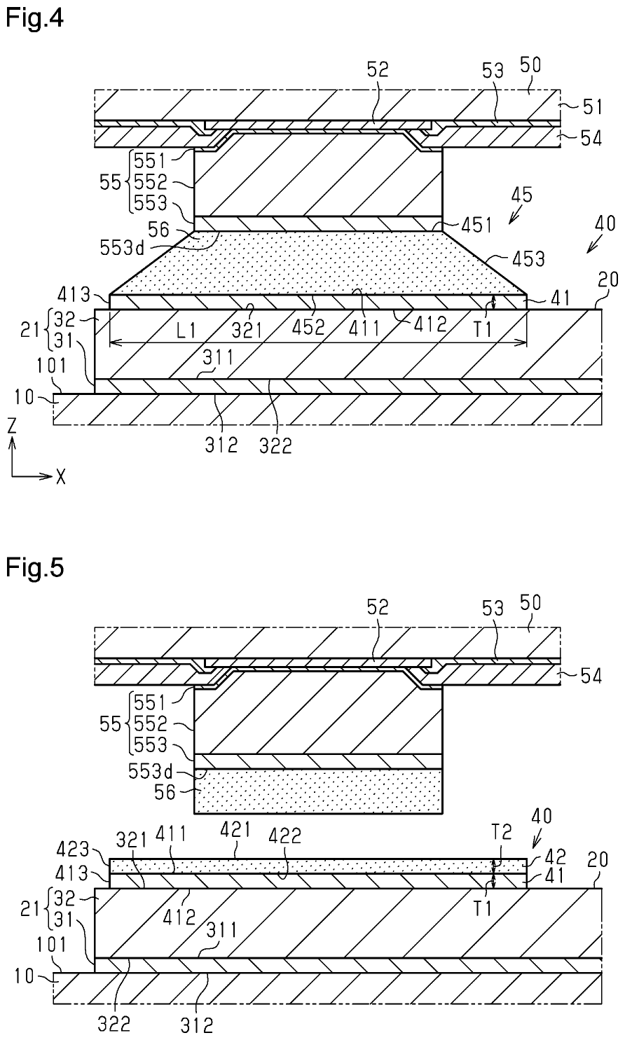

FIG. 1 is a cross-sectional view showing the semiconductor device A1 of the first embodiment. FIG. 2 is a schematic plan view of the semiconductor device A1. To facilitate understanding, in FIG. 2, the semiconductor element 50 is indicated by double-dashed lines excluding the encapsulation resin 60. FIG. 3 is an enlarged partial plan view of the semiconductor device A1 showing part of the wire portion 20. FIG. 4 is an enlarged partial cross-sectional view of the semiconductor device A1 showing part of the wire portion 20, the bonding portion 40, and the semiconductor element 50. FIG. 5 shows part of the wire portion 20, the bonding portion 40, and the semiconductor element 50 before being mounted.

The semiconductor device A1 shown in these drawings is configured to be surface-mounted on a circuit substrate of various electronic apparatuses. For the sake of brevity, the thickness-wise direction of the substrate 10 is referred to as the thickness-wise direction Z. A direction (sideward direction in plan drawing) orthogonal to the thickness-wise direction Z and extending along one side of the semiconductor device A1 is referred to as the first direction X. A direction (vertical direction in plan drawing) orthogonal to both the thickness-wise direction Z of the substrate 10 and the first direction X is referred to as the second direction Y.

As shown in FIG. 2, the semiconductor device A1 is rectangular as viewed in the thickness-wise direction Z.

As shown in FIG. 2, the semiconductor element 50 is rectangular as viewed in the thickness-wise direction Z. In the present embodiment, the semiconductor element 50 is square as viewed in the thickness-wise direction Z.

The semiconductor element 50 is, for example, an integrated circuit (IC) such as a large scale integration (LSI). The semiconductor element 50 may be a voltage-controlling element such as a low dropout (LDO) regulator, an amplifying element such as an operational amplifier, or a discrete semiconductor element such as a diode or various sensors. For example, in the case of an LSI, components for functions of the semiconductor element 50 are formed on an element main surface 501. The semiconductor element 50 is not limited to including multiple components and may be an element including a single component such as a chip capacitor or a chip inductor or an element including components formed on a base member other than a semiconductor. In the present embodiment, the semiconductor element 50 is an LSI.

As shown in FIG. 2, the semiconductor device A1 includes the external connection terminals 70. The external connection terminals 70 are located outward from the peripheral edges of the semiconductor element 50. The semiconductor device A1 has the form of a package referred to as a fan-out type.

As shown in FIGS. 1 and 2, the semiconductor element 50 includes the element main surface 501 and an element back surface 502 facing in opposite directions in the thickness-wise direction Z. The semiconductor element 50 includes element side surfaces 503, 504, 505, and 506 extending in the thickness-wise direction Z. The element side surface 503 intersects the element main surface 501 and the element back surface 502. The element main surface 501 faces a substrate main surface 101 of the substrate 10. The element back surface 502 faces in the same direction as the substrate main surface 101 of the substrate 10. The element side surfaces 503 and 504 face in opposite directions in the first direction X. The element side surfaces 505 and 506 face in opposite directions in the second direction Y.

A component for a function of the semiconductor element 50 is formed on the element main surface 501. The semiconductor element 50 includes element electrodes 55 used when mounting at the element main surface 501. The element electrodes 55 are mounted on the substrate 10 by a first solder layer 42 of the bonding portion 40 and a second solder layer 56 of the semiconductor element 50. That is, the semiconductor element 50 is mounted so that the element main surface 501 faces the substrate 10. Therefore, the element main surface 501 may be referred to as an element mount surface used to mount the semiconductor element 50.

As shown in FIG. 4, the semiconductor element 50 includes an element substrate 51, an electrode pad 52, an insulation film 53, a protection film 54, and the element electrode 55. The electrode pad 52 is formed from, for example, A1 (aluminum). The insulation film 53 covers the surface of the element substrate 51 and a peripheral portion of the electrode pad 52. The insulation film 53 is formed from, for example, SiN. The protection film 54 covers the surface of the insulation film 53 and part of the electrode pad 52 and exposes part of the surface of the electrode pad 52 as a connection terminal. The protection film 54 is formed from, for example, a polyimide resin.

The element electrode 55 is connected to the connection terminal, that is, the exposed part of the electrode pad 52. The element electrode 55 includes a metal layer 551, a conductive layer 552, and a barrier layer 553, which corresponds to a second plated layer. The metal layer 551 covers the exposed part of the electrode pad 52 and the edge of an opening exposing the electrode pad 52 in the protection film 54. The metal layer 551 is formed from, for example, titanium (Ti)/Cu as a seed layer that forms a conductive layer 32.

The conductive layer 552 covers the lower surface of the metal layer 551. The conductive layer 32 is formed from, for example, CU or an alloy of Cu. The barrier layer 553 covers the lower surface of the conductive layer 552. The barrier layer 553 is formed from Ni, an alloy including Ni, or multiple metal layers including Ni. For example, Ni, Pd, Au, or an alloy including two or more of these metals may be used as the barrier layer 553. The second solder layer 56 is formed on a lower surface 553d of the barrier layer 553. That is, the lower surface 553d of the barrier layer 553 is the lower surface of the element electrode 55.

As shown in FIG. 1, the semiconductor element 50 is mounted on the substrate 10, which is a support member used as a base of the semiconductor device A1. As shown in FIG. 2, as viewed in the thickness-wise direction Z, the substrate 10 is rectangular so that the sides along the first direction X are substantially equal in length to the sides along the second direction Y. The shape of the substrate 10 and the length of each side may be changed.

The substrate 10 includes the substrate main surface 101, a substrate back surface 102, and substrate side surfaces 103. The substrate main surface 101 and the substrate back surface 102 face in opposite directions in the thickness-wise direction Z. The substrate main surface 101 is flat. The substrate back surface 102 is flat. Each substrate side surface 103 intersects the substrate main surface 101 and the substrate back surface 102. The substrate side surface 103 faces in one of the first direction X or the second direction Y. The substrate side surface 103 is flat. The substrate side surface 103 intersects the substrate main surface 101 and the substrate back surface 102. In the first embodiment, the substrate side surface 103 is orthogonal to the substrate main surface 101 and the substrate back surface 102.

The substrate 10 is formed from, for example, an electrically insulating material. Such a material may be, for example, a synthetic resin, the main component of which is an epoxy resin or the like, ceramic, or glass. Through holes 105 extend through the substrate 10 from the substrate main surface 101 to the substrate back surface 102 in the thickness-wise direction Z. In the first embodiment, the substrate 10 has four through holes 105. The through holes 105 are separately arranged in the vicinity of four corners of the substrate 10. As viewed in the thickness-wise direction Z, each through hole 105 is, for example, rectangular. The shape of the through hole 105 may be a circle or a polygon.

The wire portion 20 includes multiple main surface wires 21, multiple through wires 22, and multiple columnar wires 27.

The through wires 22 are arranged in each through hole 105. Each through wire 22 includes an upper surface 221, a lower surface 222, and side surfaces 223. The upper surface 221 and the lower surface 222 face in opposite directions in the thickness-wise direction Z. Each side surface 223 intersects the upper surface 221 and the lower surface 222. In the first embodiment, the upper surface 221 of the through wire 22 is flush with the substrate main surface 101 of the substrate 10. In the first embodiment, the lower surface 222 of the through wire 22 is flush with the substrate back surface 102 of the substrate 10. The lower surface 222 is an exposed surface that is exposed from the substrate back surface 102 of the substrate 10. At least one of the upper surface 221 and the lower surface 222 of the through wire 22 may be configured not to be flush with the substrate main surface 101 and the substrate back surface 102 of the substrate 10. The side surface 223 of the through wire 22 is in contact with a wall surface 106 defining the through hole 105. The through wire 22 is formed from an electrically conductive material. For example, Cu or an alloy of Cu may be used as the material of the through wire 22.

The main surface wire 21 is formed on the substrate main surface 101 of the substrate 10. The main surface wire 21 is formed from an electrically conductive material and is electrically connected to the through wire 22. The main surface wire 21 includes an upper surface 211, a lower surface 212, and side surfaces 213. The upper surface 211 of the main surface wire 21 faces in the same direction as the substrate main surface 101 of the substrate 10. The lower surface 212 of the main surface wire 21 faces in the same direction as the substrate back surface 102 of the substrate 10 and faces the substrate main surface 101 of the substrate 10. The side surfaces 213 of the main surface wire 21 face in the same direction as the substrate side surfaces 103 of the substrate 10. The side surfaces 213 of the main surface wire 21 intersect the upper surface 211 and the lower surface 212 of the main surface wire 21.

The columnar wires 27 extend from the upper surface 211 of the main surface wire 21 in the thickness-wise direction Z. More specifically, the columnar wires 27 extend from the upper surface 211 of the main surface wire 21 in a direction away from the through wire 22 in the thickness-wise direction Z. As viewed in the thickness-wise direction Z, each columnar wire 27 is, for example, rectangular. That is, in the present embodiment, the columnar wire 27 is a prism. The shape of the columnar wire 27 is not limited to a prism and may be, for example, a cylinder or a polygonal rod.

The columnar wire 27 includes an upper surface 271, a lower surface 272, and side surfaces 273. The upper surface 271 and the lower surface 272 face in opposite directions in the thickness-wise direction Z. Each side surface 273 is located between the upper surface 271 and the lower surface 272. In the present embodiment, the upper surface 271 of the columnar wire 27 is, for example, flat. The shape of the upper surface 271 may be changed in any manner. The lower surface 272 of the columnar wire 27 is in contact with the upper surface 211 of the main surface wire 21. The lower surface 272 is, for example, flat. In the present embodiment, one of the side surfaces 273 is exposed from the encapsulation resin 60. In FIG. 1, side surfaces 273a facing in the first direction X are exposed side surfaces that are exposed from resin side surfaces 603 of the encapsulation resin 60.

As shown in FIGS. 4 and 5, the main surface wire 21 includes a metal layer 31 and the conductive layer 32. The metal layer 31 and the conductive layer 32 are stacked in this order on the substrate main surface 101 of the substrate 10.

The metal layer 31 includes, for example, a Ti layer, which is in contact with the substrate main surface 101 of the substrate 10 and the upper surface 221 of the through wire 22 shown in FIG. 1, and a Cu layer that is in contact with the Ti layer. The metal layer 31 is formed as a seed layer that forms the conductive layer 32. The metal layer 31 includes an upper surface 311 and a lower surface 312 facing in opposite directions in the thickness-wise direction Z.

The conductive layer 32 is formed on the upper surface 311 of the metal layer 31. The conductive layer 32 is formed from Cu or an alloy of Cu. The conductive layer 32 includes an upper surface 321 and a lower surface 322 facing in opposite directions in the thickness-wise direction Z. The thickness of the conductive layer 32 is, for example, greater than or equal to 15 μm and less than or equal to 20 μm.

As shown in FIGS. 1, 2, and 4, the bonding portions 40 are formed on the main surface wires 21. The bonding portions 40 are electrically connected to the wire portion 20. The bonding portions 40 are configured to bond the semiconductor element 50 to the wire portion 20.

The bonding portions 40 each include a plated layer 41 and the first solder layer 42 formed on the upper surface of the plated layer 41. The plated layer 41 corresponds to a first plated layer formed on the upper surface 321 of the conductive layer 32 of the main surface wire 21. The semiconductor element 50 includes the element electrode 55, which is formed on the element main surface 501, and the second solder layer 56, which is formed on the lower surface of the element electrode 55. As viewed in the thickness-wise direction Z, the bonding portion 40 is formed to be larger than the element electrode 55 of the semiconductor element 50. The first solder layer 42 and the second solder layer 56 are bonded to each other to integrally form a solder layer 45 by a reflow process performed in a step of mounting the semiconductor element 50 on the substrate 10. That is, the semiconductor element 50 is connected to the main surface wires 21 by the solder layer 45 and mounted on the substrate 10.

FIG. 5 shows the bonding portion 40 and the element electrode 55 and the second solder layer 56 of the semiconductor element 50 before undergoing the reflow process.

The bonding portion 40 includes the plated layer 41 and the first solder layer 42. The plated layer 41 and the first solder layer 42 are stacked in this order on the main surface wire 21 of the wire portion 20. The plated layer 41 is formed from a conductive metal material. For example, the plated layer 41 is formed from Ni (nickel). The first solder layer 42 is formed from Sn (tin) or an alloy including Sn. The alloy is, for example, an Sn—Ag (silver)-based alloy or an Sn—Sb (antimony)-based alloy.

As shown in FIGS. 3, 4, and 5, the plated layer 41 is formed on the upper surface 321 of the conductive layer 32 of the wire portion 20. The plated layer 41 includes an upper surface 411, a lower surface 412, and side surfaces 413. The upper surface 411 faces in the same direction as the upper surface 321 of the conductive layer 32. The lower surface 412 faces the upper surface 321 of the conductive layer 32. The lower surface 412 is in contact with the upper surface 321 of the conductive layer 32. The side surfaces 413 intersect the upper surface 411 and the lower surface 412. An oxide film may be formed on the side surfaces 413. The plated layer 41 has a thickness T1 that is, for example, greater than or equal to 3 μm and less than or equal to 5 μm.

As shown in FIG. 5, the first solder layer 42 includes an upper surface 421, a lower surface 422, and side surfaces 423. The upper surface 421 and the lower surface 422 face in opposite directions in the thickness-wise direction Z. The side surfaces 423 intersect the upper surface 421 and the lower surface 422. The lower surface 422 of the first solder layer 42 is in contact with the upper surface 411 of the plated layer 41. As viewed in the thickness-wise direction Z, the first solder layer 42 is formed to be the same size as the plated layer 41. The first solder layer 42 is formed to have a thickness that is less than or equal to the thickness T1 of the plated layer 41. Preferably, the thickness of the first solder layer 42 is, for example, greater than or equal to 1 μm and less than or equal to 5 μm. Preferably, in the first solder layer 42, the aspect ratio of a cross section that is perpendicular to the substrate main surface 101 of the substrate 10 is, for example, greater than or equal to 40 and less than or equal to 80. An example of the cross section extends in the first direction X. The aspect ratio of the first solder layer 42 is a ratio of a longer side to a shorter side of a rectangle including the first solder layer 42, that is, a ratio (L1/T2) of a length L1 of the first solder layer 42 in the first direction X to a thickness T2 of the first solder layer 42.

FIG. 4 shows the solder layer 45 that has undergone the reflow process.

The solder layer 45 includes an upper surface 451, a lower surface 452, and a side surface 453. The upper surface 451 and the lower surface 452 face in opposite directions in the thickness-wise direction Z. The side surface 453 intersects the upper surface 451 and the lower surface 452. The upper surface 451 of the solder layer 45 is in contact with the lower surface of the element electrode 55, that is, the lower surface 553d of the barrier layer 553.

The lower surface 452 of the solder layer 45 is in contact with the upper surface 411 of the plated layer 41. The solder layer 45 has a trapezoidal cross section perpendicular to the substrate main surface 101. More specifically, the side surfaces of the solder layer 45 extend from a peripheral end of the upper surface 411 of the plated layer 41 to a peripheral end of the element electrode 55, specifically, a peripheral end of the lower surface 553d of the barrier layer 553. The side surface 453 of the solder layer 45 is inclined so as to become wider in the first direction X and the second direction Y as the substrate 10 becomes closer.

As shown in FIG. 1, the encapsulation resin 60 is in contact with the substrate main surface 101 of the substrate 10 and covers the semiconductor element 50. More specifically, the encapsulation resin 60 covers the element main surface 501, the element back surface 502, and the element side surface 503 of the semiconductor element 50. In the first embodiment, the encapsulation resin 60 further covers the main surface wires 21 and the bonding portions 40.

The encapsulation resin 60 overlaps the substrate 10 as viewed in the thickness-wise direction Z. The encapsulation resin 60 includes a resin upper surface 601 facing in the same direction as the substrate main surface 101 of the substrate 10 and the resin side surfaces 603 facing in the same direction as the substrate side surfaces 103.

The encapsulation resin 60 includes a part located toward the substrate 10, defining a first resin part 60A, and a part located toward the resin upper surface 601, defining a second resin part 60B, in the thickness-wise direction Z. The first resin part 60A includes first resin side surfaces 603a, which partially form the resin side surfaces 603. The second resin part 60B includes second resin side surfaces 603b, which partially form the resin side surfaces 603. As viewed in the thickness-wise direction Z, the first resin part 60A is the same size as the substrate 10. As viewed in the thickness-wise direction Z, the second resin part 60B is formed to be larger than the first resin part 60A. The second resin side surfaces 603b are located outward from the first resin side surfaces 603a. Due to the difference in size between the first resin part 60A and the second resin part 60B, the encapsulation resin 60 includes a step 61 that is recessed in the encapsulation resin 60. As shown in FIG. 2, the step 61 extends along the entire perimeter of the encapsulation resin 60.

The encapsulation resin 60 is formed from, for example, an electrically insulating resin. An example of the resin may be a synthetic resin including an epoxy resin as the main component. The encapsulation resin 60 is, for example, colored black.

The external connection terminals 70 cover the wire portion 20 exposed from the substrate 10 and the encapsulation resin 60. Each external connection terminal 70 includes a first conductive film 71 covering the lower surface 222 of the through wire 22 and a second conductive film 72 covering the side surface 223 of the through wire 22, the side surface 213 of the main surface wire 21, and the side surface 273a of the columnar wire 27. The external connection terminal 70 including the first conductive film 71 and the second conductive film 72 is used as an external connection terminal of the semiconductor device A1. The external connection terminal 70 includes, for example, multiple metal layers stacked on one another. The metal layers are, for example, a Ni layer, a Pd (palladium) layer, and a Au (gold) layer. Although the material of the external connection terminal 70 is not limited, for example, the Ni layer and the Au layer may be stacked, or the material may be Sn.

When the semiconductor device A1 is mounted on a mount substrate, solder for connecting the external connection terminal 70 to a connection pad of the mount substrate is applied between the first conductive film 71 and the connection pad and is also adhered to the second conductive film 72. More specifically, in the reflow process, the solder changes the phase to a liquid state and flows upward on the second conductive film 72 to form a solder fillet between the second conductive film 72 and the connection pad. The semiconductor device A1 facilitates formation of a solder fillet. The solder fillet increases the area bonded by solder, thereby further increasing the connection strength. In addition, the solder fillet allows the soldering state of the semiconductor device A1 to be checked from outside.

FIG. 3 partially shows the semiconductor element 50 and the main surface wires 21 of the semiconductor device A1 in the present embodiment. In FIG. 3, the semiconductor element 50 and the element electrodes 55 are indicated by single-dashed lines. The main surface wires 21 are connected to the element electrodes 55 of the semiconductor element 50 and extend from the element electrodes 55 toward the outside of the semiconductor element 50.

Each bonding portion 40, which includes the plated layer 41 and the first solder layer 42, includes end sides 40a and 40c extending in the first direction X and end sides 40b and 40d extending in the second direction Y. As viewed in the thickness-wise direction Z, each element electrode 55 is rectangular and includes side surfaces 55a and 55c extending in the first direction X and side surfaces 55b and 55d extending in the second direction Y.

The side surface 55a of the element electrode 55 and the end side 40a of the bonding portion 40 are separated by a distance L2a that is, for example, greater than or equal to 4 μm and less than or equal to 10 μm. The side surface 55b of the element electrode 55 and the end side 40b of the bonding portion 40 are separated by a distance L2b that is, for example, greater than or equal to 4 μm and less than or equal to 10 μm. The side surface 55c of the element electrode 55 and the end side 40c of the bonding portion 40 are separated by a distance L2c that is, for example, greater than or equal to 4 μm and less than or equal to 10 μm. The side surface 55d of the element electrode 55 and the end side 40d of the bonding portion 40 are separated by a distance L2d that is, for example, greater than or equal to 4 μm and less than or equal to 10 μm.

The main surface wire 21 includes an end side 21a located at an inner side of the semiconductor element 50 and lateral sides 21b and 21c located at opposite sides of the end side 21a and intersecting the end side 21a. The end sides 40b to 40d of the bonding portion 40, that is, the end portions of the plated layer 41 and the first solder layer 42, are located at an inner side of the main surface wire 21 from the end side 21a and the lateral sides 21b and 21c. The end side 21a and the bonding portion 40 are separated by a distance L3a that is, for example, greater than or equal to 0.5 μm and less than or equal to 1.0 μm. The lateral side 21b and the bonding portion 40 are separated by a distance L3b that is, for example, greater than or equal to 0.5 μm and less than or equal to 1.0 μm. The lateral side 21c and the bonding portion 40 are separated by a distance L3c that is, for example, greater than or equal to 0.5 μm and less than or equal to 1.0 μm.

Manufacturing Steps

An example of steps for manufacturing the semiconductor device A1 will be described.

A support substrate is prepared. The support substrate is formed from, for example, a monocrystalline silicon material. Alternatively, a substrate formed from a synthetic resin material such as an epoxy resin may be used as the support substrate. Terminal pillars, which will be the through wires 22, are formed on the upper surface of the support substrate. The terminal pillars are formed of, for example, Cu or an alloy of Cu. The terminal pillars include, for example, a seed layer formed on the upper surface of the support substrate and a plated metal formed on the upper surface of the seed layer. Alternatively, the terminal pillars may be formed of columnar copper members.

Next, a base member is formed in contact with the upper surface of the support substrate to cover the terminal pillars. The base member covers the upper surface of the terminal pillars. The material of the base member may be the material forming the substrate 10 shown in FIG. 1. In the present embodiment, the material of the base member may be a synthetic resin, the main component of which is an epoxy resin or the like.

The base member and the terminal pillars are partially ground to form the through wires 220 exposed on the upper surface of the base member and the upper surface 221 of the through wires 22. The base member is configured to be the substrate 10 shown in FIG. 1. The base member is ground so that the base member and the substrate 10 have the same thickness.

The main surface wires 21 are formed on the upper surface of the base member and the upper surface 221 of the through wires 22. The main surface wires 21 include the metal layer 31 and the conductive layer 32. For example, the metal layer 31 is formed through, for example, sputtering. For example, when the metal layer 31 includes a Ti layer and a Cu layer, the Ti layer is formed on the upper surface of the base member and the upper surface 221 of the through wires 22, and the Cu layer is formed in contact with the Ti layer. Next, for example, an electrolytic plating process that uses the metal layer 31 as a conductive path is performed so that plated metal deposits on the surface of the metal layer 31 to form the conductive layer 32.

The bonding portions 40 are formed on the main surface wires 21. The bonding portions 40 include the plated layer 41 and the first solder layer 42. The plated layer 41 is formed on the main surface wires 21 through for example, an electrolytic plating process. The first solder layer 42 is formed on the plated layer 41 through, for example, an electrolytic plating process.

The columnar wires 27 are also formed on the main surface wires 21. The columnar wires 27 include, for example, a seed layer and a plated layer. The seed layer includes, for example, a first layer including Ti as a main component and a second layer including Cu as a main component. The main component of the plated layer is, for example, Cu. For example, sputtering is performed to form the seed layer on the main surface wires 21. Then, for example, an electrolytic plating process that uses the seed layer as a conductive path is performed to form the plated layer on the columnar wires 27.

The semiconductor element 50 is mounted. The semiconductor element 50 is mounted by flip chip bonding (FCB). The flip-chip-mounting is performed, for example, using a flip-chip bonder that applies a flux to the second solder layer 56 of the semiconductor element 50 through pin transfer. As a result, the semiconductor element 50 is temporarily attached to the bonding portions 40. Subsequently, the first solder layer 42 of the bonding portions 40 and the second solder layer 56 of the semiconductor element 50 undergo a phase change to a liquid state through reflow, and then the first solder layer 42 and the second solder layer 56 are cooled and solidified. This forms the solder layer 45. The semiconductor element 50 is mounted on the substrate 10 by the solder layer 45.

A resin layer is formed to cover the upper surface of the base member, the wire portion 20, and the semiconductor element 50. The resin layer is a member that will be the encapsulation resin 60 shown in FIG. 1. The resin layer is, for example, a synthetic resin, the main material of which is an epoxy resin. The resin layer is formed, for example, by transfer molding.

The support substrate is removed, for example, by grinding. Alternatively, a separation film may be formed between the support substrate and the base member in advance so that the support substrate is removed by separation.

For example, a dicing blade is used to form grooves from a base member side to an intermediate portion of the resin layer, so that the grooves expose the side surfaces 223 of the through wires 22, the side surfaces 213 of the main surface wires 21, and the side surfaces 273a of the columnar wires 27.

The external connection terminals 70 are formed on the surfaces of the through wires 22, the main surface wires 21, and the columnar wires 27 exposed from the base member and the resin layer. The external connection terminals 70 are formed of, for example, a plated metal. For example, an electroless plating process is performed so that plated metals of, for example, Ni, Pd, and Au are deposited in this order to form the external connection terminals 70. The structure and forming process of the external connection terminals 70 are not limited.

Dicing tape is applied to the resin layer. The base member and the resin layer are cut and separated into pieces singulated for each semiconductor element 50. In the separation process, for example, the base member and the resin layer are cut from the base member side to the dicing tape with the dicing blade. Each piece corresponds to the semiconductor device A1 including the substrate 10 and the encapsulation resin 60.

Operation

The operation of the semiconductor device A1 will be described.

The semiconductor device A1 includes the bonding portions 40 disposed on the upper surface 211 of the main surface wires 21. The bonding portions 40 include the plated layer 41 and the first solder layer 42 disposed on the plated layer 41. As viewed in the thickness-wise direction Z, the bonding portions 40 are formed to be larger than the element electrodes 55 of the semiconductor element 50. The first solder layer 42 is bonded to the second solder layer 56 of the semiconductor element 50 by a reflow process to form the solder layer 45. In the reflow process, the molten second solder layer 56 is joined to the first solder layer 42 and is less likely to flow outward from the plated layer 41. Thus, in the reflow process for mounting the semiconductor element 50, the outflow of solder is limited.

The bonding portions 40 include the plated layer 41 disposed on the upper surface of the main surface wires 21 and the first solder layer 42 disposed on the plated layer 41. The main surface wires 21 are formed from Cu or an alloy of Cu. The first solder layer 42 is formed from SnAg. The plated layer 41 is a barrier metal and inhibits the alloying of Cu of the main surface wires 21 with Sn of the first solder layer 42 and the second solder layer 56. This limits formation of a void between SnAg and Cu (Kirkendall void).

The bonding portions 40 include the plated layer 41 and the first solder layer 42 disposed on the plated layer 41. The first solder layer 42 is bonded to the second solder layer 56 of the semiconductor element 50 to form the solder layer 45. During formation of the main surface wires 21 and the plated layer 41, irregularities may be formed on the upper surface 411 of the plated layer 41. If the second solder layer 56 is directly bonded to the plated layer 41, the roughness of the upper surface 211 of the main surface wires 21 and the upper surface 411 of the plated layer 41 may result in formation of voids (holes) in the solder layer. In this regard, the first solder layer 42 formed on the plated layer 41 is molten by the reflow process performed prior to the mounting of the semiconductor element 50, so that the rough surface is smoothed. The smoothing limits formation of voids when the first solder layer 42 is bonded to the second solder layer 56. The thickness T2 of the first solder layer 42 is less than the size of the first solder layer 42 in a direction that is parallel to the upper surface 411 of the plated layer 41, on which the first solder layer 42 is formed. That is, the first solder layer 42 has a small aspect ratio and thus limits the flow of solder during the reflow process performed prior to the mounting of the semiconductor element 50.

As described above, the present embodiment has the advantages described below.

(1-1) The semiconductor device A1 includes the bonding portions 40 disposed on the upper surface 211 of the main surface wires 21. The bonding portions 40 include the plated layer 41 and the first solder layer 42 disposed on the plated layer 41. As viewed in the thickness-wise direction Z, the bonding portions 40 are formed to be larger than the element electrodes 55 of the semiconductor element 50. The first solder layer 42 is bonded to the second solder layer 56 of the semiconductor element 50 by a reflow process to form the solder layer 45. In the reflow process, the molten second solder layer 56 is joined to the first solder layer 42 and is less likely to flow outward from the plated layer 41. Thus, in the reflow process for mounting the semiconductor element 50, the outflow of solder is limited.

(1-2) The thickness T2 of the first solder layer 42 is less than the size of the first solder layer 42 in a direction that is parallel to the upper surface 411 of the plated layer 41, on which the first solder layer 42 is formed. That is, the first solder layer 42 has a small aspect ratio and thus limits the flow of solder during the reflow process performed prior to the mounting of the semiconductor element 50.

(1-4) The bonding portions 40 include the plated layer 41 disposed on the upper surface of the main surface wires 21 and the first solder layer 42 disposed on the plated layer 41. The main surface wires 21 are formed from Cu or an alloy of Cu. The first solder layer 42 is formed from SnAg. The plated layer 41 is a barrier metal and inhibits the alloying of Cu of the main surface wires 21 with Sn of the first solder layer 42 and the second solder layer 56. This limits formation of a void between SnAg and Cu (Kirkendall void).

(1-5) The bonding portions 40 include the plated layer 41 and the first solder layer 42 disposed on the plated layer 41. The first solder layer 42 is bonded to the second solder layer 56 of the semiconductor element 50 to form the solder layer 45. During formation of the main surface wires 21 and the plated layer 41, irregularities may be formed on the upper surface 411 of the plated layer 41. If the second solder layer 56 is directly bonded to the plated layer 41, the roughness of the upper surface 211 of the main surface wires 21 and the upper surface 411 of the plated layer 41 may result in formation of voids (holes) in the solder layer. In this regard, the first solder layer 42 formed on the plated layer 41 is molten by the reflow process performed prior to the mounting of the semiconductor element 50, so that the rough surface is smoothed. The smoothing limits formation of voids when the first solder layer 42 is bonded to the second solder layer 56.

(1-6) When the semiconductor device A1 is mounted on a mount substrate, solder for connecting the external connection terminal 70 to a connection pad of the mount substrate is applied between the first conductive film 71 and the connection pad and is also adhered to the second conductive film 72. More specifically, in the reflow process, the solder changes the phase to a liquid state and flows upward on the second conductive film 72 to form a solder fillet between the second conductive film 72 and the connection pad. The solder fillet increases the area bonded by solder, thereby further increasing the connection strength. In addition, the solder fillet allows the soldering state of the semiconductor device A1 to be checked from outside.

Second Embodiment

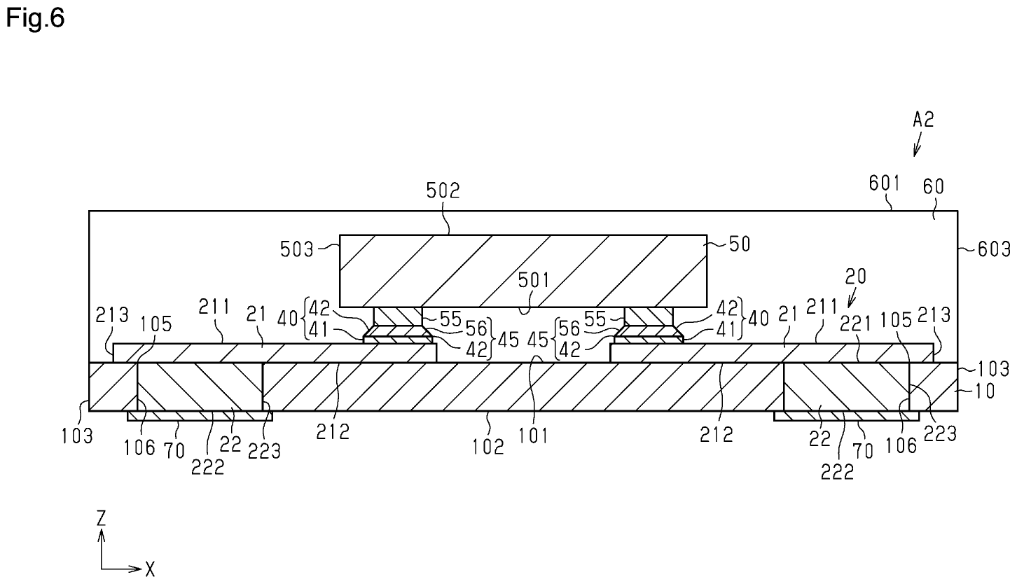

A second embodiment of a semiconductor device A2 will be described below with reference to FIGS. 6 to 8. In the second embodiment, same reference signs are given to those components that are the same as the corresponding components of the first embodiment.

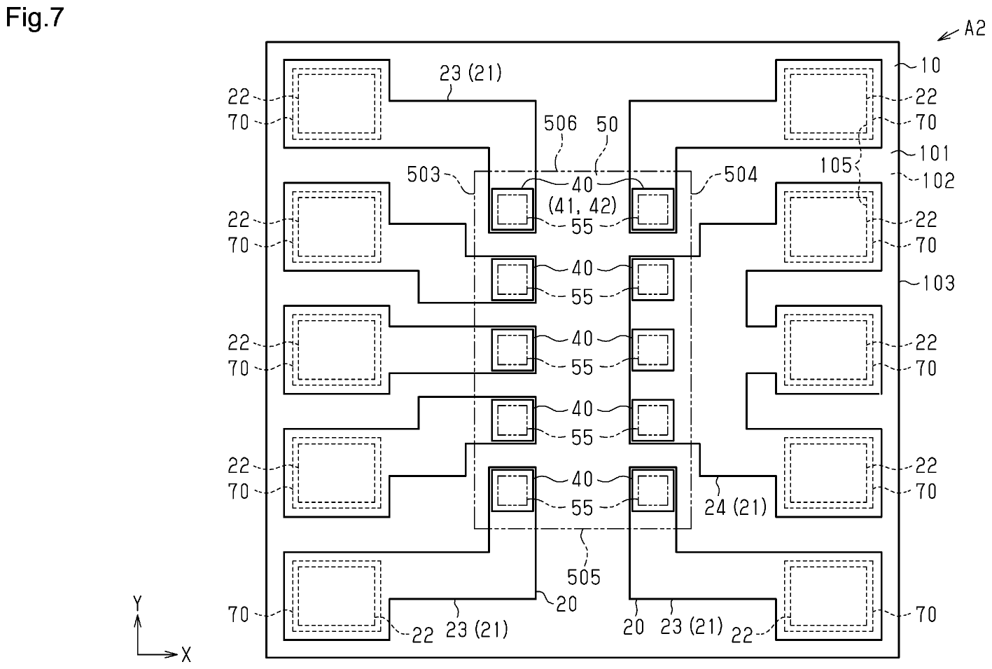

As shown in FIGS. 6 and 7, the semiconductor device A2 includes a substrate 10, a wire portion 20, bonding portions 40, a semiconductor element 50, an encapsulation resin 60, and external connection terminals 70. The wire portion 20 includes main surface wires 21 and through wires 22.

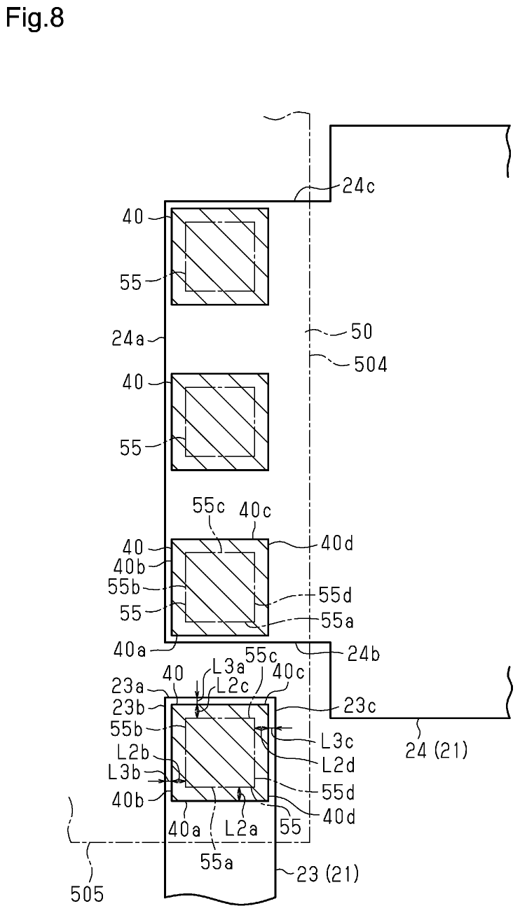

FIG. 6 is a cross-sectional view showing the semiconductor device A2 of the second embodiment. FIG. 7 is a schematic plan view of the semiconductor device A2. To facilitate understanding, in FIG. 7, the semiconductor element 50 is indicated by double-dashed lines excluding the encapsulation resin 60. FIG. 8 is an enlarged partial plan view of the semiconductor device A2 showing part of the wire portion 20.

The semiconductor device A2 shown in these drawings is a device configured to be surface-mounted on a circuit substrate of various electronic apparatuses. For the sake of brevity, the thickness-wise direction of the substrate 10 is referred to as the thickness-wise direction Z. A direction (sideward direction in plan drawing) orthogonal to the thickness-wise direction Z and extending along one side of the semiconductor device A2 is referred to as the first direction X. A direction (vertical direction in plan drawing) orthogonal to both the thickness-wise direction Z of the substrate 10 and the first direction X is referred to as the second direction Y.

As shown in FIG. 7, the semiconductor device A2 is rectangular as viewed in the thickness-wise direction Z.

As shown in FIG. 7, the semiconductor element 50 is rectangular as viewed in the thickness-wise direction Z. The rectangular shape of the semiconductor element 50 is longer in the second direction Y than in the first direction X.

The semiconductor element 50 is, for example, an integrated circuit (IC) such as a large scale integration (LSI). The semiconductor element 50 may be a voltage-controlling element such as a low dropout (LDO) regulator, an amplifying element such as an operational amplifier, or a discrete semiconductor element such as a diode or various sensors. For example, in the case of an LSI, components for functions of the semiconductor element 50 are formed on an element main surface 501. The semiconductor element 50 is not limited to including multiple components and may be an element including a single component such as a chip capacitor or a chip inductor or an element including components formed on a base member other than a semiconductor. In the present embodiment, the semiconductor element 50 is an LSI.

As shown in FIG. 7, the semiconductor device A2 includes the external connection terminals 70. The external connection terminals 70 are located outward from the peripheral edges of the semiconductor element 50. The semiconductor device A2 has the form of ap package referred to as a fan-out type.

As shown in FIGS. 6 and 7, the semiconductor element 50 includes an element main surface 501 and an element back surface 502 facing in opposite directions in the thickness-wise direction Z, and element side surfaces 503 extending in the thickness-wise direction Z. The element side surfaces 503 intersect the element main surface 501 and the element back surface 502. The element main surface 501 faces a substrate main surface 101 of the substrate 10. The element back surface 502 faces in the same direction as the substrate main surface 101 of the substrate 10.

A component for a function of the semiconductor element 50 is formed on the element main surface 501. The semiconductor element 50 includes element electrodes 55 used when mounting at the element main surface 501. The element electrodes 55 are mounted on the substrate 10 by a first solder layer 42 of the bonding portion 40 and a second solder layer 56 of the semiconductor element 50. That is, the semiconductor element 50 is mounted so that the element main surface 501 faces the substrate 10. Therefore, the element main surface 501 may be referred to as an element mount surface used to mount the semiconductor element 50.

As shown in FIG. 6, the semiconductor element 50 is mounted on the substrate 10, which is a support member used as a base of the semiconductor device A2. As shown in FIG. 7, as viewed in the thickness-wise direction Z, the substrate 10 is rectangular so that the sides along the first direction X are substantially equal in length to the sides along the second direction Y. The shape of the substrate 10 and the length of each side may be changed.

The substrate 10 includes the substrate main surface 101, a substrate back surface 102, and substrate side surfaces 103. The substrate main surface 101 and the substrate back surface 102 face in opposite directions in the thickness-wise direction Z. The substrate main surface 101 is flat. The substrate back surface 102 is flat. Each substrate side surface 103 is disposed between the substrate main surface 101 and the substrate back surface 102. The substrate side surface 103 faces in one of the first direction X or the second direction Y. The substrate side surface 103 is flat. The substrate side surface 103 intersects the substrate main surface 101 and the substrate back surface 102. In the present embodiment, the substrate side surface 103 is orthogonal to the substrate main surface 101 and the substrate back surface 102.

The substrate 10 is formed from, for example, an electrically insulating material. Such a material may be, for example, a synthetic resin, the main component of which is an epoxy resin or the like, ceramic, or glass. Through holes 105 extend through the substrate 10 from the substrate main surface 101 to the substrate back surface 102 in the thickness-wise direction Z. In the present embodiment, the substrate 10 has four through holes 105. The through holes 105 are separately arranged in the vicinity of four corners of the substrate 10. As viewed in the thickness-wise direction Z, each through hole 105 is, for example, rectangular. The shape of the through hole 105 may be a circle or a polygon.

The wire portion 20 includes multiple main surface wires 21 and multiple through wires 22.

The through wires 22 are arranged in each through hole 105. Each through wire 22 includes an upper surface 221, a lower surface 222, and side surfaces 223. The upper surface 221 and the lower surface 222 face in opposite directions in the thickness-wise direction Z. Each side surface 223 is located between the upper surface 221 and the lower surface 222. In the present embodiment, the upper surface 221 of the through wire 22 is flush with the substrate main surface 101 of the substrate 10. In the present embodiment, the lower surface 222 of the through wire 22 is flush with the substrate back surface 102 of the substrate 10. The lower surface 222 is an exposed surface that is exposed from the substrate back surface 102 of the substrate 10. At least one of the upper surface 221 and the lower surface 222 of the through wire 22 may be configured not to be flush with the substrate main surface 101 and the substrate back surface 102 of the substrate 10. The side surface 223 of the through wire 22 is in contact with a wall surface 106 defining the through hole 105. The through wire 22 is formed from an electrically conductive material. For example, Cu or an alloy of Cu may be used as the material of the through wire 22.

The external connection terminals 70 are formed on the substrate back surface 102 of the substrate 10. Each external connection terminal 70 is formed to cover the lower surface 222 of the through wire 22. Also, the external connection terminal 70 extends from the through wire 22 along the substrate back surface 102 and covers the substrate back surface 102 located around the through hole 105. The external connection terminal 70 includes, for example, multiple metal layers stacked on one another. The metal layers are, for example, a Ni layer, a Pd (palladium) layer, and a Au (gold) layer. Although the material of the external connection terminal 70 is not limited, for example, the Ni layer and the Au layer may be stacked, or the material may be Sn.

The main surface wire 21 is formed on the substrate main surface 101 of the substrate 10. The main surface wire 21 is formed from an electrically conductive material and is electrically connected to the through wire 22. The main surface wire 21 includes an upper surface 211, a lower surface 212, and side surfaces 213. The upper surface 211 of the main surface wire 21 faces in the same direction as the substrate main surface 101 of the substrate 10. The lower surface 212 of the main surface wire 21 faces in the same direction as the substrate back surface 102 of the substrate 10 and faces the substrate main surface 101 of the substrate 10. The side surfaces 213 of the main surface wire 21 face in the same direction as the substrate side surfaces 103 of the substrate 10. The side surfaces 213 of the main surface wire 21 intersect the upper surface 211 and the lower surface 212 of the main surface wire 21.

As shown in FIG. 7, the main surface wires 21 include separate first wire parts 23 respectively connected to the element electrodes 55 of the semiconductor element 50 and a plane second wire part 24 connected to multiple element electrodes 55.

As viewed in the thickness-wise direction Z, the first wire parts 23 and the second wire part 24 extend from locations overlapping the element electrodes 55 of the semiconductor element 50 to locations overlapping the respective through wires 22. That is, the first wire parts 23 and the second wire part 24 extend from the semiconductor element 50 toward the outside of the semiconductor element 50.

As shown in FIGS. 6 and 7, the bonding portions 40 are formed on the main surface wires 21. The bonding portions 40 are electrically connected to the wire portion 20. The bonding portions 40 are configured to bond the semiconductor element 50 to the wire portion 20.

The bonding portions 40 each include a plated layer 41 and the first solder layer 42 formed on the upper surface of the plated layer 41. The plated layer 41 corresponds to a first plated layer formed on the upper surface 321 of the conductive layer 32 of the main surface wire 21. The semiconductor element 50 includes the element electrode 55, which is formed on the element main surface 501, and the second solder layer 56, which is formed on the lower surface of the element electrode 55. As viewed in the thickness-wise direction Z, the bonding portion 40 is formed to be larger than the element electrode 55 of the semiconductor element 50. The first solder layer 42 and the second solder layer 56 are bonded to each other to integrally form a solder layer 45 by a reflow process performed in a step of mounting the semiconductor element 50 on the substrate 10. That is, the semiconductor element 50 is connected to the main surface wires 21 by the solder layer 45 and mounted on the substrate 10.

As shown in FIG. 8, the plated layer 41 is formed on the upper surface 321 of the conductive layer 32 of the wire portion 20. The plated layer 41 includes an upper surface 411, a lower surface 412, and side surfaces 413. The upper surface 411 faces in the same direction as the upper surface 321 of the conductive layer 32. The lower surface 412 faces the upper surface 321 of the conductive layer 32. The lower surface 412 is in contact with the upper surface 321 of the conductive layer 32. The side surfaces 413 intersect the upper surface 411 and the lower surface 412. An oxide film may be formed on the side surfaces 413. The plated layer 41 has a thickness Ti that is, for example, greater than or equal to 3 μm and less than or equal to 5 μm.

As shown in FIG. 6, the encapsulation resin 60 is in contact with the substrate main surface 101 of the substrate 10 and covers the semiconductor element 50. More specifically, the encapsulation resin 60 covers the element main surface 501, the element back surface 502, and the element side surface 503 of the semiconductor element 50. In the present embodiment, the encapsulation resin 60 further covers the main surface wires 21 and the bonding portions 40.

The encapsulation resin 60 overlaps the substrate 10 as viewed in the thickness-wise direction Z. The encapsulation resin 60 includes a resin upper surface 601 facing in the same direction as the substrate main surface 101 of the substrate 10 and the resin side surfaces 603 facing in the same direction as the substrate side surfaces 103.

The encapsulation resin 60 is formed from, for example, an electrically insulating resin. An example of the resin may be a synthetic resin including an epoxy resin as the main component. The encapsulation resin 60 is, for example, colored black.

FIG. 8 partially shows the semiconductor element 50 and the main surface wires 21 of the semiconductor device A2 in the present embodiment. In FIG. 8, the semiconductor element 50 and the element electrodes 55 are indicated by single-dashed lines. The main surface wires 21 are connected to the element electrodes 55 of the semiconductor element 50 and extend from the element electrodes 55 toward the outside of the semiconductor element 50.

Each bonding portion 40, which includes the plated layer 41 and the first solder layer 42, includes end sides 40a and 40c extending in the first direction X and end sides 40b and 40d extending in the second direction Y. As viewed in the thickness-wise direction Z, each element electrode 55 is rectangular and includes side surfaces 55a and 55c extending in the first direction X and side surfaces 55b and 55d extending in the second direction Y.

The side surface 55a of the element electrode 55 and the end side 40a of the bonding portion 40 are separated by a distance L2a that is, for example, greater than or equal to 4 μm and less than or equal to 10 μm. The side surface 55b of the element electrode 55 and the end side 40b of the bonding portion 40 are separated by a distance L2b that is, for example, greater than or equal to 4 μm and less than or equal to 10 μm. The side surface 55c of the element electrode 55 and the end side 40c of the bonding portion 40 are separated by a distance L2c that is, for example, greater than or equal to 4 μm and less than or equal to 10 μm. The side surface 55d of the element electrode 55 and the end side 40d of the bonding portion 40 are separated by a distance L2d that is, for example, greater than or equal to 4 μm and less than or equal to 10 μm.

Each first wire part 23 includes an end side 23a located an inner side of the semiconductor element 50 and lateral sides 23b and 23c located at opposite sides of the end side 23a and intersecting the end side 23a. The end sides 40b to 40d of the bonding portion 40, that is, the end portions of the plated layer 41 and the first solder layer 42, are located at an inner side of the main surface wire 21 from the end side 23a and the lateral sides 23b and 23c. The end side 23a and the bonding portion 40 are separated by a distance L3a that is, for example, greater than or equal to 0.5 μm and less than or equal to 1.0 μm. The lateral side 23b and the bonding portion 40 are separated by a distance L3b that is, for example, greater than or equal to 0.5 μm and less than or equal to 1.0 μm. The lateral side 23c and the bonding portion 40 are separated by a distance L3c that is, for example, greater than or equal to 0.5 μm and less than or equal to 1.0 μm.

The second wire part 24 includes the bonding portions 40 for each element electrode 55. That is, the bonding portions 40 are separately formed on the upper surface of the single second wire part 24. In the second wire part 24 including the bonding portions 40, the positional relationship between each bonding portion 40 and the element electrode 55 connected to the bonding portion 40 is the same as that of the first wire parts 23 described above. Also, the positional relationship of an end side 24a and lateral sides 24b and 24c of the second wire part 24 with the bonding portions 40 is the same as that of the first wire parts 23 described above. In the present embodiment, the bonding portions 40 are arranged along the end side 24a of the second wire part 24. However, the positions where the bonding portions 40 are arranged may be changed in accordance with a semiconductor element that is mounted.

Manufacturing Steps

An example of steps for manufacturing the semiconductor device A2 will be described.

A support substrate is prepared. The support substrate is formed from, for example, a monocrystalline silicon material. Alternatively, a substrate formed from a synthetic resin material such as an epoxy resin may be used as the support substrate. Terminal pillars, which will be the through wires 22, are formed on the upper surface of the support substrate. The terminal pillars are formed of, for example, Cu or an alloy of Cu. The terminal pillars include, for example, a seed layer formed on the upper surface of the support substrate and a plated metal formed on the upper surface of the seed layer. Alternatively, the terminal pillars may be formed of columnar copper members.

Next, a base member is formed in contact with the upper surface of the support substrate to cover the terminal pillars. The base member covers the upper surface of the terminal pillars. The material of the base member may be the material forming the substrate 10 shown in FIG. 6. In the present embodiment, the material of the base member may be a synthetic resin, the main component of which is an epoxy resin or the like.

The base member and the terminal pillars are partially ground to form the through wires 220 exposed on the upper surface of the base member and the upper surface 221 of the through wires 22. The base member is configured to be the substrate 10 shown in FIG. 6. The base member is ground so that the base member and the substrate 10 have the same thickness.

The main surface wires 21 are formed on the upper surface of the base member and the upper surface 221 of the through wires 22. The main surface wires 21 include the metal layer 31 and the conductive layer 32. For example, the metal layer 31 is formed through, for example, sputtering. For example, when the metal layer 31 includes a Ti layer and a Cu layer, the Ti layer is formed on the upper surface of the base member and the upper surface 221 of the through wires 22, and the Cu layer is formed in contact with the Ti layer. Next, for example, an electrolytic plating process that uses the metal layer 31 as a conductive path is performed so that plated metal deposits on the surface of the metal layer 31 to form the conductive layer 32.

The bonding portions 40 are formed on the main surface wires 21. The bonding portions 40 include the plated layer 41 and the first solder layer 42. The plated layer 41 is formed on the main surface wires 21 through for example, an electrolytic plating process. The first solder layer 42 is formed on the plated layer 41 through, for example, an electrolytic plating process.

The semiconductor element 50 is mounted. The semiconductor element 50 is mounted by flip chip bonding (FCB). The flip-chip-mounting is performed, for example, using a flip-chip bonder that applies a flux to the second solder layer 56 of the semiconductor element 50 through pin transfer. As a result, the semiconductor element 50 is temporarily attached to the bonding portions 40. Subsequently, the first solder layer 42 of the bonding portions 40 and the second solder layer 56 of the semiconductor element 50 undergo a phase change to a liquid state through reflow, and then the first solder layer 42 and the second solder layer 56 are cooled and solidified. This forms the solder layer 45. The semiconductor element 50 is mounted on the substrate 10 by the solder layer 45.

A resin layer is formed to cover the upper surface of the base member, the wire portion 20, and the semiconductor element 50. The resin layer is a member that will be the encapsulation resin 60 shown in FIG. 6. The resin layer is, for example, a synthetic resin, the main material of which is an epoxy resin. The resin layer is formed, for example, by transfer molding.

The support substrate is removed, for example, by grinding. Alternatively, a separation film may be formed between the support substrate and the base member in advance so that the support substrate is removed by separation.

The external connection terminals 70 are formed on a surface (lower surface 222 shown in FIG. 6) of the through wires 22 exposed from the base member. The external connection terminals 70 are formed of, for example, a plated metal. For example, an electroless plating process is performed so that plated metals of, for example, Ni, Pd, and Au are deposited in this order to form the external connection terminals 70. The structure and forming process of the external connection terminals 70 are not limited.

Dicing tape is applied to the resin layer. The base member and the resin layer are cut and separated into pieces singulated for each semiconductor element 50. In the separation process, for example, the base member and the resin layer are cut from the base member side to the dicing tape with the dicing blade. Each piece corresponds to the semiconductor device A2 including the substrate 10 and the encapsulation resin 60.

Operation

The operation of the semiconductor device A2 will be described.

The semiconductor device A2 includes the bonding portions 40 disposed on the upper surface 211 of the main surface wires 21. The bonding portions 40 include the plated layer 41 and the first solder layer 42 disposed on the plated layer 41. As viewed in the thickness-wise direction Z, the bonding portions 40 are formed to be larger than the element electrodes 55 of the semiconductor element 50. The first solder layer 42 is bonded to the second solder layer 56 of the semiconductor element 50 by a reflow process to form the solder layer 45. In the reflow process, the molten second solder layer 56 is joined to the first solder layer 42 and is less likely to flow outward from the plated layer 41. Thus, in the reflow process for mounting the semiconductor element 50, the outflow of solder is limited.

As shown in FIG. 8, the bonding portions 40 formed on the upper surface 211 of the single main surface wire 21 (second wire part 24) are formed separately from each other. The bonding portions 40 are respectively connected to the element electrodes 55 of the semiconductor element 50. The bonding portions 40 limit the outflow of solder. In the element electrodes 55 connected to the single main surface wire 21 (second wire part 24), the solder layer 45 is formed between each element electrode 55 and the bonding portion 40. This ensures a sufficient amount of solder for the element electrode 55. Accordingly, the electrical connection of the element electrodes 55 with the single main surface wire 21 (second wire part 24) is ensured.

For example, when a single bonding portion 40 is provided for multiple element electrodes 55, solder may concentrate on the vicinity of some element electrodes 55, and the solder may be insufficient for the other element electrodes 55. When the solder is insufficient, the element electrodes 55 may not be connected to the main surface wire 21. In this regard, in the present embodiment, the element electrodes 55 are separately connected to the single main surface wire 21.

The bonding portions 40 include the plated layer 41 disposed on the upper surface of the main surface wires 21 and the first solder layer 42 disposed on the plated layer 41. The main surface wires 21 are formed from Cu or an alloy of Cu. The first solder layer 42 is formed from SnAg. The plated layer 41 is a barrier metal and inhibits the alloying of Cu of the main surface wires 21 with Sn of the first solder layer 42 and the second solder layer 56. This limits formation of a void between SnAg and Cu (Kirkendall void).

The bonding portions 40 include the plated layer 41 and the first solder layer 42 disposed on the plated layer 41. The first solder layer 42 is bonded to the second solder layer 56 of the semiconductor element 50 to form the solder layer 45. During formation of the main surface wires 21 and the plated layer 41, irregularities may be formed on the upper surface 411 of the plated layer 41. If the second solder layer 56 is directly bonded to the plated layer 41, the roughness of the upper surface 211 of the main surface wires 21 and the upper surface 411 of the plated layer 41 may result in formation of voids (holes) in the solder layer. In this regard, the first solder layer 42 formed on the plated layer 41 is molten by the reflow process performed prior to the mounting of the semiconductor element 50, so that the rough surface is smoothed. The smoothing limits formation of voids when the first solder layer 42 is bonded to the second solder layer 56. The thickness T2 of the first solder layer 42 is less than the size of the first solder layer 42 in a direction that is parallel to the upper surface 411 of the plated layer 41, on which the first solder layer 42 is formed. That is, the first solder layer 42 has a small aspect ratio and thus limits the flow of solder during the reflow process performed prior to the mounting of the semiconductor element 50.

As described above, the second embodiment has the following advantages.

(2-1) The same advantages as (1-1) to (1-5) of the first embodiment are obtained.

(2-2) The bonding portions 40 formed on the upper surface 211 of the second wire part 24, that is, the single main surface wire 21, are formed separately from each other. The bonding portions 40 are respectively connected to the element electrodes 55 of the semiconductor element 50. The bonding portions 40 limit the outflow of solder. In the element electrodes 55 connected to the second wire part 24, that is, the single main surface wire 21, the solder layer 45 is formed between each element electrode 55 and the bonding portion 40. This ensures a sufficient amount of solder for the element electrode 55. Accordingly, the electrical connection of the element electrodes 55 with the second wire part 24, that is, the single main surface wire 21, is ensured.

Modified Examples

The embodiments may be modified as follows.

The size of the bonding portions 40 may be changed.

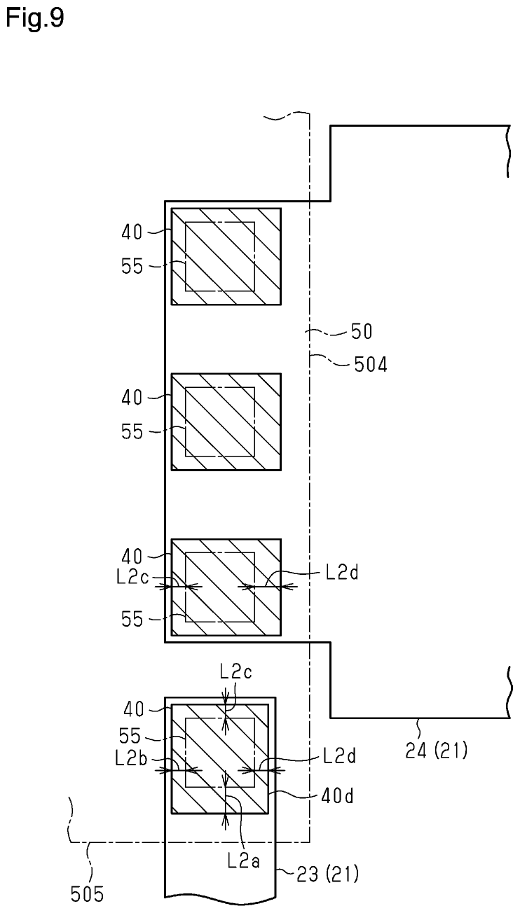

FIG. 9 shows a modified example of bonding portions 40. For example, in the first wire part 23, the element electrode 55 and the end side 40c of the bonding portion 40 are separated by a distance L2c at an inner side of the semiconductor element 50, and the element electrode 55 and the end side 40a of the bonding portion 40 are separated by a distance L2a at an outer side of the semiconductor element 50. It is preferred that the distance L2a is greater than the distance L2c. In the second wire part 24, at the element side surface 504 of the semiconductor element 50, the element electrode 55 and the end of the bonding portion 40 at an inner side of the semiconductor element 50 are separated by a distance L2c. The element electrode 55 and another end of the bonding portion 40 are separated by a distance L2d. It is preferred that the distance L2d is greater than the distance L2c. This further limits the outflow of solder to an inner side of the semiconductor element 50.

The configuration of the semiconductor device may be changed.

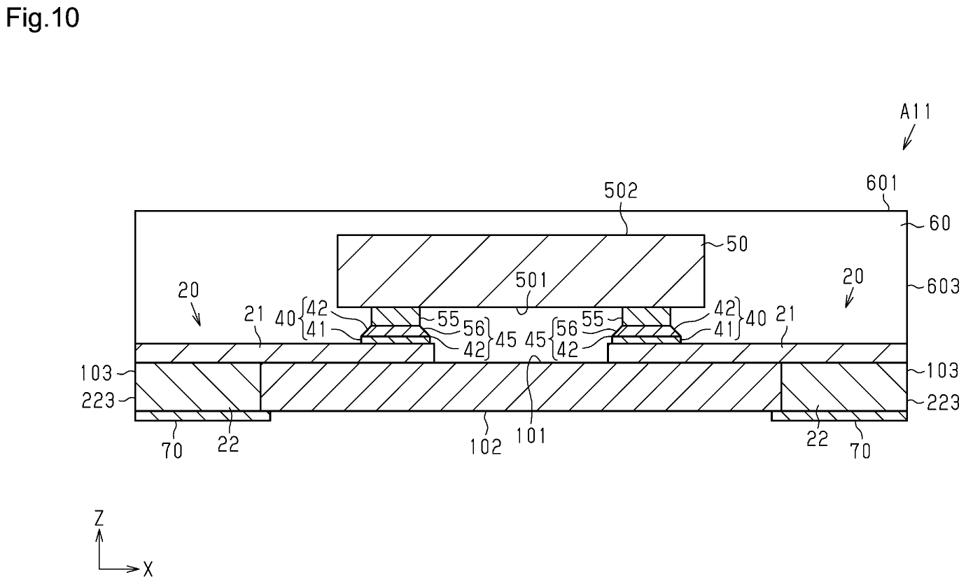

FIG. 10 shows a semiconductor device A11 that includes a substrate 10, a wire portion 20, bonding portions 40, a semiconductor element 50, an encapsulation resin 60, and external connection terminals 70. The wire portion 20 includes main surface wires 21 formed on a substrate main surface 101 of the substrate 10 and through wires 22 extending through the substrate 10.

Each through wire 22 extends to a substrate side surface 103 of the substrate 10. That is, the side surface 223 of the through wire 22 is flush with the substrate side surface 103 of the substrate 10. Also, each external connection terminal 70 extends to the substrate side surface 103 of the substrate 10. Thus, the lower surface 222 of the through wire 22 is exposed on the substrate back surface 102 of the substrate 10. The side surface 223 of the through wire 22 is exposed on the substrate side surface 103 of the substrate 10. Each external connection terminal 70 is formed to cover the lower surface 222 of the through wire 22. The semiconductor device A11 also obtains the same advantages as those of the embodiments described above.

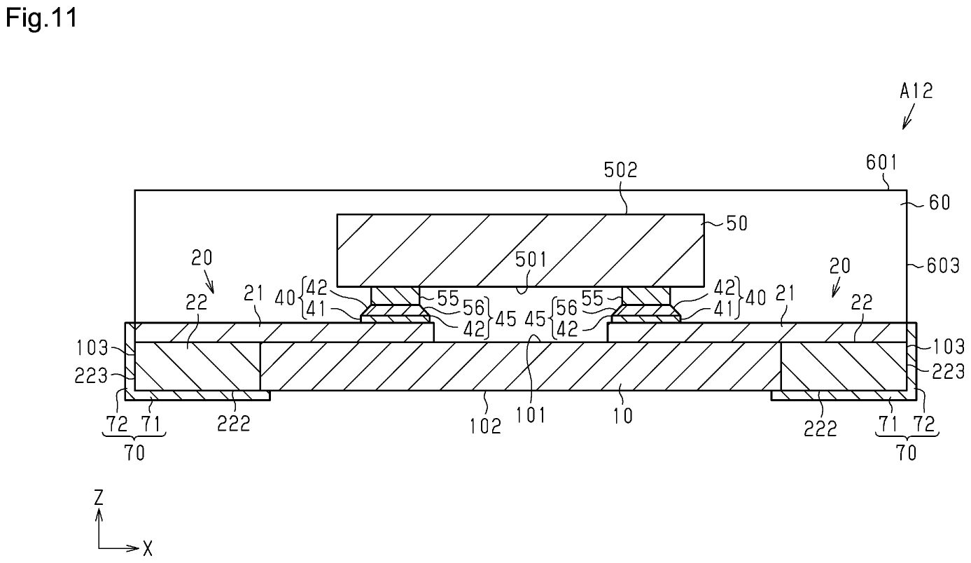

FIG. 11 shows a semiconductor device A12 that includes a substrate 10, a wire portion 20, bonding portions 40, a semiconductor element 50, an encapsulation resin 60, and external connection terminals 70. The wire portion 20 includes main surface wires 21 formed on a substrate main surface 101 of the substrate 10 and through wires 22 extending through the substrate 10.

Each through wire 22 extends to a substrate side surface 103 of the substrate 10. That is, the side surface 223 of the through wire 22 is flush with the substrate side surface 103 of the substrate 10. Thus, the lower surface 222 of the through wire 22 is exposed on the substrate back surface 102 of the substrate 10. The side surface 223 of the through wire 22 is exposed on the substrate side surface 103 of the substrate 10.

In the semiconductor device A12, the external connection terminal 70 is formed to cover the through wire 22 exposed from the substrate 10. The external connection terminal 70 includes a first conductive film 71 covering the lower surface 222 of the through wire 22 and a second conductive film 72 covering the side surface 223 of the through wire 22. The external connection terminal 70 including the first conductive film 71 and the second conductive film 72 is used as an external connection terminal of the semiconductor device A12 in the same manner as the external connection terminal 70 in the embodiments described above. The external connection terminal 70 includes, for example, multiple metal layers stacked on one another. The metal layers are, for example, a Ni layer, a Pd layer, and a Au layer. Although the material of the external connection terminal 70 is not limited, for example, the Ni layer and the Au layer may be stacked, or the material may be Sn.

When the semiconductor device A12 is mounted on a mount substrate, solder for connecting the external connection terminal 70 to a connection pad of the mount substrate is applied between the first conductive film 71 and the connection pad and is also adhered to the second conductive film 72. More specifically, in the reflow process, the solder changes the phase to a liquid state and flows upward on the second conductive film 72 to form a solder fillet between the second conductive film 72 and the connection pad. Although a solder fillet will also be formed in the semiconductor device A11 shown in FIG. 10, the solder fillet is more easily formed in the semiconductor device A12 of this modified example. The solder fillet increases the area bonded by solder, thereby further increasing the connection strength. In addition, the solder fillet allows the soldering state of the semiconductor device A12 to be checked from outside.

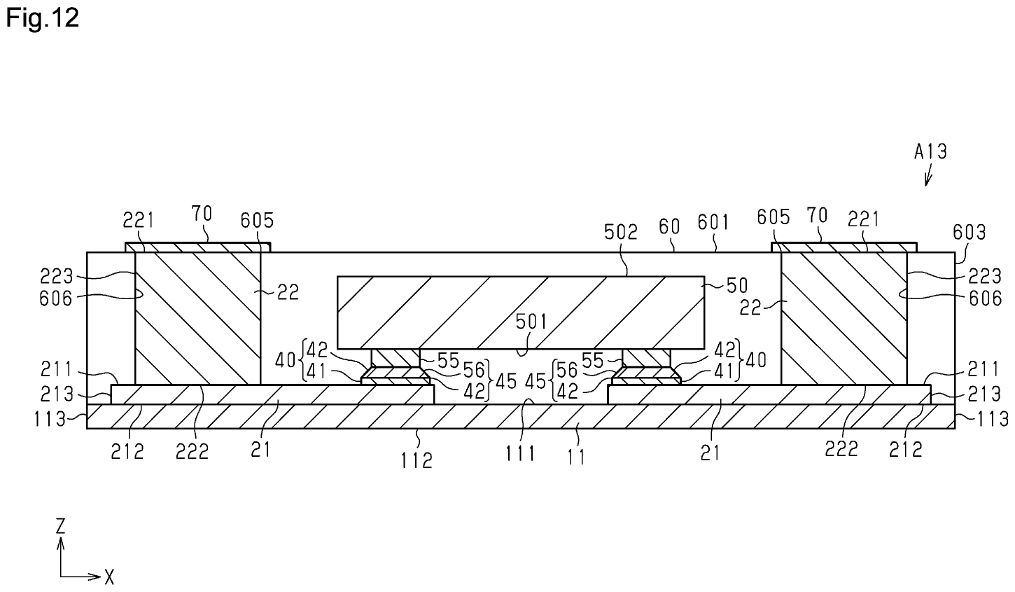

FIG. 12 shows a semiconductor device A13 that includes a substrate 11, a wire portion 20, bonding portions 40, a semiconductor element 50, an encapsulation resin 60, and external connection terminals 70.

The substrate 11 has the form of a thin plate and does not have through holes. The substrate 11 includes a substrate main surface 111, a substrate back surface 112, and substrate side surfaces 113. The substrate main surface 111 and the substrate back surface 112 face in opposite directions in the thickness-wise direction Z. The substrate main surface 111 and the substrate back surface 112 are flat. The material of the substrate 11 may be, for example, a synthetic resin, the main component of which is an epoxy resin or the like, ceramic, glass, or a semiconductor material such as Si. When the substrate 11 is formed from a semiconductor material such as Si, the substrate main surface 111 is covered by an insulation layer. The insulation layer is, for example, an oxide film such as SiO₂ or a resin film such as polyimide.

The wire portion 20 includes main surface wires 21 and through wires 22.

Each main surface wire 21 is formed on the substrate main surface 111 of the substrate 11. The upper surface 211 of the main surface wire 21 faces in the same direction as the substrate main surface 111 of the substrate 11. The lower surface 212 of the main surface wire 21 faces in the same direction as the substrate back surface 112 of the substrate 11 and faces the substrate main surface 111 of the substrate 11. The side surfaces 213 of the main surface wire 21 face in the same direction as the substrate side surfaces 113 of the substrate 11.

The encapsulation resin 60 is in contact with the substrate main surface 111 of the substrate 11 and covers the semiconductor element 50. Through holes 605 extend through the encapsulation resin 60 in the thickness-wise direction Z. Each through hole 605 extends from the resin upper surface 601 of the encapsulation resin 60 to the upper surface 211 of the main surface wire 21. The shape of the through hole 605 is, for example, a rectangle as viewed in the thickness-wise direction Z. The shape of the through hole 605 may be a circle or a polygon.

The through wires 22 are arranged in each through hole 605. Each through wire 22 includes an upper surface 221, a lower surface 222, and side surfaces 223. The upper surface 221 of the through wire 22 is flush with the resin upper surface 601 of the encapsulation resin 60. The upper surface 221 of the through wire 22 is exposed from the encapsulation resin 60. The lower surface 222 of the through wire 22 is in contact with the upper surface 211 of the main surface wire 21. The side surfaces 223 of the through wire 22 are in contact with wall surfaces 606 of the through hole 605 in the encapsulation resin 60.

Each external connection terminal 70 is formed on the resin upper surface 601 of the encapsulation resin 60. The external connection terminal 70 is formed to cover the upper surface 221 of the through wire 22 that is exposed. The external connection terminal 70 is used as an external connection terminal of the semiconductor device A13.

The semiconductor device A13 is mounted on a mount substrate so that the external connection terminals 70 face the mount substrate, that is, the element main surface 501 of the semiconductor element 50 and the mount substrate face in opposite directions. The semiconductor device A13 also obtains the same advantages as those of the embodiments described above. In addition, the semiconductor device A13 includes the substrate 11 that has a smaller thickness than the substrate 10 of the semiconductor device A2 in the embodiment. This allows for reduction in the thickness of the semiconductor device A13.

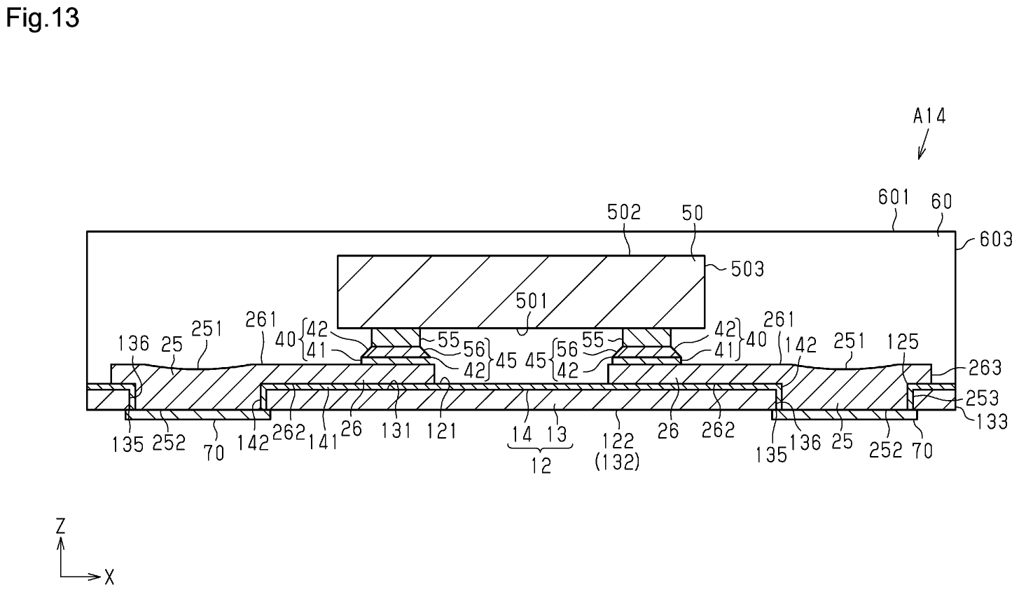

FIG. 13 shows a semiconductor device A14 that includes a substrate 12, a wire portion 20, external connection terminals 70, a semiconductor element 50, and an encapsulation resin 60. The wire portion 20 includes main surface wires 21 and columnar bodies 25 as a through wire.

FIG. 13 is a schematic cross-sectional view of the semiconductor device A14 in a modified example.

As viewed in the thickness-wise direction Z, the substrate 12 is rectangular. The substrate 12 includes a base member 13 and an insulation layer 14.

The base member 13 includes a main surface 131, a back surface 132, and side surfaces 133. The main surface 131 and the back surface 132 face in opposite directions in the thickness-wise direction Z. The main surface 131 and the back surface 132 are flat. The base member 13 is formed from, for example, an electrically insulating material. The material may be, for example, an intrinsic semiconductor material such as monocrystalline silicon or a synthetic resin, the main component of which is an epoxy resin or the like. The main surface 131 of the base member 13 may be, for example, a (100) plane with crystal orientation of (100).

The base member 13 includes through holes 135. The through holes 135 extend through the base member 13 from the main surface 131 to the back surface 132 in the thickness-wise direction Z. As viewed in the thickness-wise direction Z, each through hole 135 is, for example, rectangular. The shape of the through hole 135 may be a circle or a polygon. The through hole 135 is defined by a wall surface 136 that intersects the back surface 132. In the semiconductor device A14, the wall surface 136 is orthogonal to the back surface 132. The wall surface 136 may be inclined at a predetermined angle from the back surface 132. The inclination angle of the wall surface 136 is determined based on, for example, the configuration of the base member 13 formed from a semiconductor material such as the crystal orientation.

The insulation layer 14 is formed on the base member 13. The insulation layer 14 covers the main surface 131 of the base member 13 and the wall surfaces 136 of the through holes 135. The insulation layer 14 includes a first insulation layer 141 covering the main surface 131 of the base member 13 and a second insulation layer 142 covering the wall surfaces 136 of the through holes 135. The insulation layer 14 is an electrically insulating film. In this modified example, the insulation layer 14 is formed from SiO₂. The insulation layer 14 is formed by, for example, thermally oxidizing the base member 13. The thickness of the insulation layer 14 is, for example, greater than or equal to 0.7 μm and less than or equal to 2.0 μm. The material properties, thickness, and forming process of the insulation layer 14 is not limited. For example, the insulation layer 14 may include SiO₂ and a resin layer. Alternatively, the insulation layer 14 may be formed of a resin layer.

Thus, the substrate 12 includes the base member 13 and the insulation layer 14. The base member 13 is formed from an intrinsic semiconductor material of monocrystalline and has the through holes 135 extending through the base member 13 from the main surface 131 to the back surface 132. The insulation layer 14 covers the main surface 131 of the base member 13 and the wall surfaces 136 of the base member 13 defining the through holes 135. The upper surface of the insulation layer 14 (first insulation layer 141) defines a substrate main surface 121 of the substrate 12. The back surface 132 of the base member 13 defines a substrate back surface 122 of the substrate 12. The substrate 12 includes through holes 125 defined by wall surfaces covered with the insulation layer 14 (second insulation layer 142).

An insulation layer may be formed on the back surface 132 of the base member 13. The insulation layer is an electrically insulating film. The insulation layer formed on the back surface 132 may be the same as the insulation layer 14.

The wire portion 20 of the semiconductor device A14 includes multiple main surface wires 26 and multiple columnar bodies 25.

The main surface wires 26 are part of the wire portion 20 formed at the substrate main surface 121 of the substrate 12. Each main surface wire 26 includes an upper surface 261, a lower surface 262, and side surfaces 263. In this modified example, the main surface wire 26 includes a metal layer and a conductive layer.

The bonding portions 40 are formed on the main surface wires 26. The bonding portions 40 include the plated layer 41 and the first solder layer 42. The second solder layer 56 of the semiconductor element 50 is connected to the first solder layer 42.

The columnar bodies 25 extend through the substrate 12. Each columnar body 25 fills a space in the through hole 125 surrounded by the insulation layer 14.

The columnar body 25 is exposed from the substrate main surface 121 and the substrate back surface 122 of the substrate 12. The columnar body 25 includes an upper surface 251, a back surface 252, and side surfaces 253. The upper surface 251 and the back surface 252 face in opposite directions in the thickness-wise direction Z. The upper surface 251 is curved so as to be recessed toward the inside of the columnar body 25, that is, toward the back surface 252 of the columnar body 25. The back surface 252 is exposed from the substrate back surface 122. The back surface 252 of the columnar body 25 is flush with the substrate back surface 122. The side surfaces 253 are in contact with the second insulation layer 142 of the insulation layer 14.

The shape of the columnar body 25 is not limited and may be, for example, a cylinder. In the semiconductor device A14 of the modified example, the main surface wires 26 and the columnar bodies 25 are integrally formed from the same material. However, the main surface wires 26 and the columnar bodies 25 may be separately formed from different materials.

The encapsulation resin 60 is disposed at the substrate main surface 121 of the substrate 12 and covers the semiconductor element 50. The encapsulation resin 60 is in contact with the substrate main surface 121 of the substrate 12 and covers the semiconductor element 50 and the wire portion 20 (the main surface wires 25 and upper surface 152 of the columnar bodies 25). The encapsulation resin 60 overlaps the substrate 12 as viewed in the thickness-wise direction Z. As viewed in the thickness-wise direction Z, the encapsulation resin 60 rectangular.

The encapsulation resin 60 is electrically insulative. The encapsulation resin 60 is formed from, for example, a resin material that is colored black. The resin material is, for example, a synthetic resin such as an epoxy resin. The material properties and shape of the encapsulation resin 60 are not limited.

The external connection terminals 70 are formed on the substrate back surface 122 of the substrate 12. Each external connection terminal 70 covers the upper surface 251 of the columnar body 25. The external connection terminal 70 is used as an external connection terminal of the semiconductor device A14. The external connection terminal 70 includes, for example, multiple metal layers stacked on one another. The metal layers are, for example, a Ni layer, a Pd layer, and a Au layer. Although the material of the external connection terminal 70 is not limited, for example, the Ni layer and the Au layer may be stacked, or the material may be Sn.

In the semiconductor device A14, the base member 13 is formed from a monocrystalline semiconductor material to limit the outflow of solder in the reflow process for mounting the semiconductor element 50.

Third Embodiment

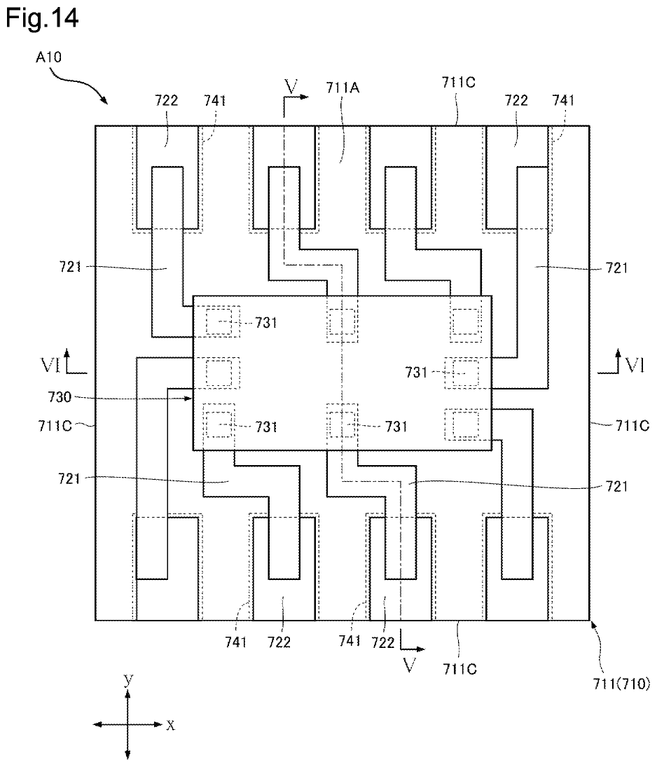

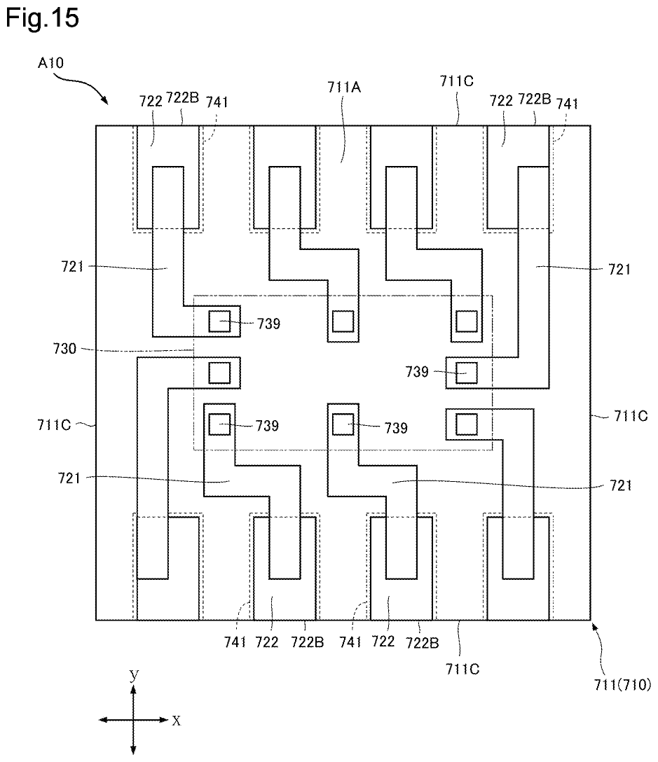

A third embodiment of a semiconductor device A10 according to the present disclosure will now be described with reference to FIGS. 14 to 20. The semiconductor device A10 includes an encapsulation resin 710, a wire 721, joint wires 722, a semiconductor element 730, and terminals 741. The semiconductor device A10 is in the form of a resin package that is surface-mounted on a wiring substrate. To facilitate understanding, FIG. 14 transparently shows a second layer 712 (will be described later in detail) of the encapsulation resin 710. In FIG. 14, line V-V is indicated by a single-dashed line. To facilitate understanding, the semiconductor element 730 shown in FIG. 15 is more transparent than that shown in FIG. 14. In FIG. 15, the semiconductor element 730 is transparently indicated by an imaginary line (double-dashed line).

In the description of the semiconductor device A10, for the sake of convenience, the thickness-wise direction of the semiconductor device A10 is referred to as “the thickness-wise direction z.” A direction orthogonal to the thickness-wise direction z is referred to as “the first direction x.” A direction orthogonal to the thickness-wise direction z and the first direction x is referred to as “the second direction y.” As shown in FIG. 14, the semiconductor device A10 is rectangular as viewed in the thickness-wise direction z.

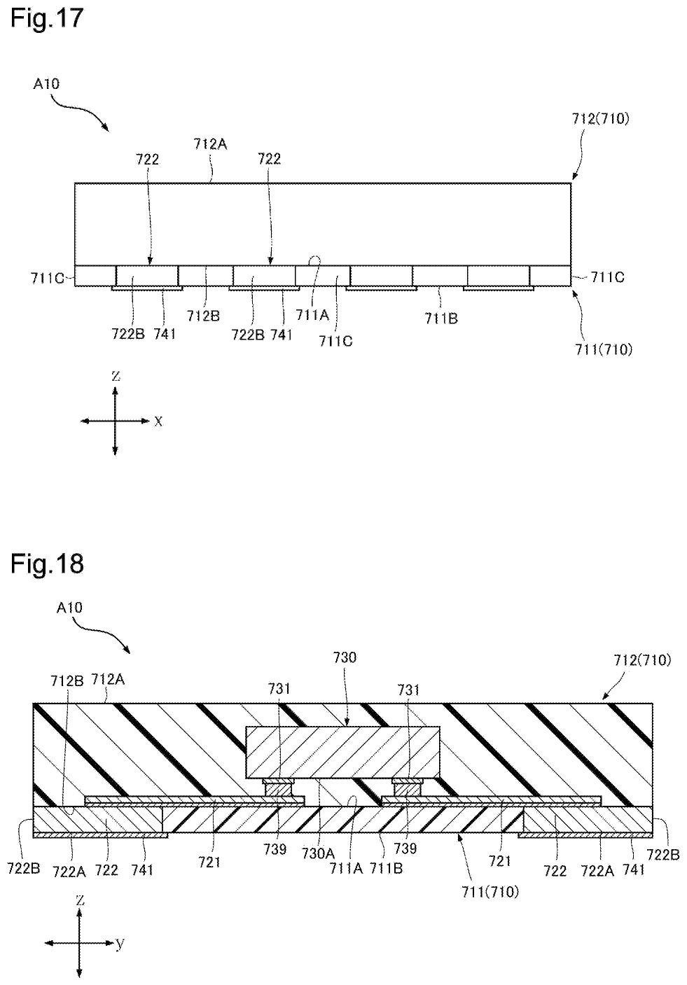

As shown in FIGS. 17 to 19, the encapsulation resin 710 includes a first layer 711 and the second layer 712. Each of the first layer 711 and the second layer 712 is formed from a material including a synthetic resin. An example of the synthetic resin is an epoxy resin. To minimize the difference in linear expansion coefficient between the linear the first layer 711 and the second layer 712, it is preferred that the first layer 711 and the second layer 712 include the same synthetic resin. The first layer 711 includes a first main surface 711A, a first back surface 711B, and a side surface 711C. The first main surface 711A and the first back surface 711B face in opposite directions in the thickness-wise direction z. When the semiconductor device A10 is mounted on a wiring substrate, the first back surface 711B faces the wiring substrate. The side surface 711C faces in a direction orthogonal to the thickness-wise direction z and is joined to the first main surface 711A and the first back surface 711B. In the semiconductor device A10, the side surface 711C includes two regions separated from each other and facing in the first direction x and two regions separated from each other and facing in the second direction y. The second layer 712 is stacked on the first main surface 711A in the thickness-wise direction z. The second layer 712 includes a second main surface 712A and a second back surface 712B. The second main surface 712A and the second back surface 712B face in opposite directions in the thickness-wise direction z. The second back surface 712B is in contact with the first main surface 711A. As viewed in the thickness-wise direction z, the peripheral edge of the second layer 712 coincides with the peripheral edge of the first layer 711. The distance between the first main surface 711A and the first back surface 711B is smaller than the distance between the second main surface 712A and the second back surface 712B. That is, the thickness of the first layer 711 is less than the thickness of the second layer 712.

As shown in FIG. 20, a filler 788 is mixed in the first layer 711. The filler 788 is fine powder. The filler 788 includes an inorganic compound. The inorganic compound is, for example, glass or ceramic. An example of the ceramic is alumina (A1203).

As shown in FIGS. 14, 15, 18, and 19, the wire 721 is in contact with the first main surface 711A of the first layer 711. The wire 721 forms part of a conductive path extending between the semiconductor element 730 and a wiring substrate on which the semiconductor device A10 is mounted. The wire 721 includes multiple regions. Each of the multiple regions is belt-shaped as viewed in the thickness-wise direction z. In the semiconductor device A10, the semiconductor device A10 includes eight regions. The wire 721 is partially covered by the second layer 712. As viewed in the thickness-wise direction z, the wire 721 is located at an inner side of the peripheral edges of the encapsulation resin 710 (the first layer 711 and the second layer 712). Thus, the wire 721 is not exposed to the exterior of the semiconductor device A10 from the encapsulation resin 710.

As shown in FIG. 20, each region of the wire 721 includes a base layer 789 and a body layer 790. The base layer 789 is in contact with the first main surface 711A of the first layer 711 and one of the joint wires 722. The base layer 789 includes a barrier layer contacting the first main surface 711A of the first layer 711 and the joint wire 722 and a seed layer stacked on the barrier layer in the thickness-wise direction z. The composition of the barrier layer includes titanium (Ti). The composition of the seed layer includes copper (Cu). The body layer 790 is stacked on the base layer 789 in the thickness-wise direction z. The thickness of the body layer 790 is greater than the thickness of the base layer 789. Thus, in each region of the wire 721, the conductive path is mainly the body layer 790. The composition of the body layer 790 is the same as that of the seed layer of the base layer 789. Thus, the composition of the body layer 790 includes copper.

As shown in FIGS. 14, 15, and 18, each joint wire 722 is joined to one of the regions of the wire 721. The joint wire 722 extends from the wire 721 to the first back surface 711B of the first layer 711 and is partially covered by the first layer 711. The joint wires 722 and the wire 721 form part of the conductive path extending between the semiconductor element 730 and the wiring substrate on which the semiconductor device A10 is mounted. The composition of the joint wires 722 includes copper.

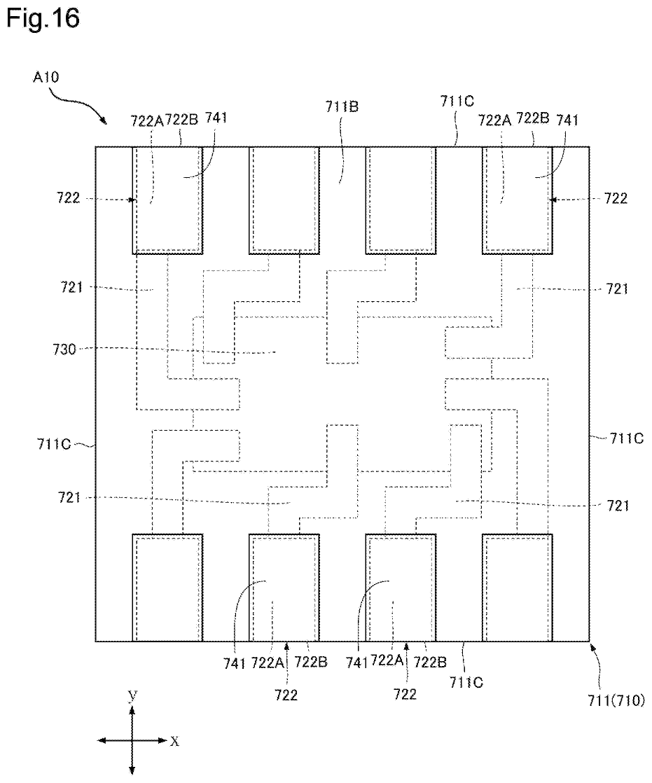

As shown in FIGS. 16, 18, and 19, the joint wires 722 each include a bottom surface 722A and an end surface 722B. The bottom surface 722A is exposed on the first back surface 711B of the first layer 711. The end surface 722B is joined to the bottom surface 722A and faces in a direction orthogonal to the thickness-wise direction z. In the semiconductor device A10, the end surface 722B faces in the second direction y. As shown in FIG. 17, the end surface 722B is exposed in one region of the side surface 711C of the first layer 711. In the semiconductor device A10, the end surface 722B is exposed in one of the two regions of the side surface 711C separated from each other in the second direction y. Each joint wire 722 includes a surface facing in a direction opposite from the bottom surface 722A in the thickness-wise direction z, and the surface is flush with the first main surface 711A of the first layer 711 and is in contact with the second back surface 712B of the second layer 712.

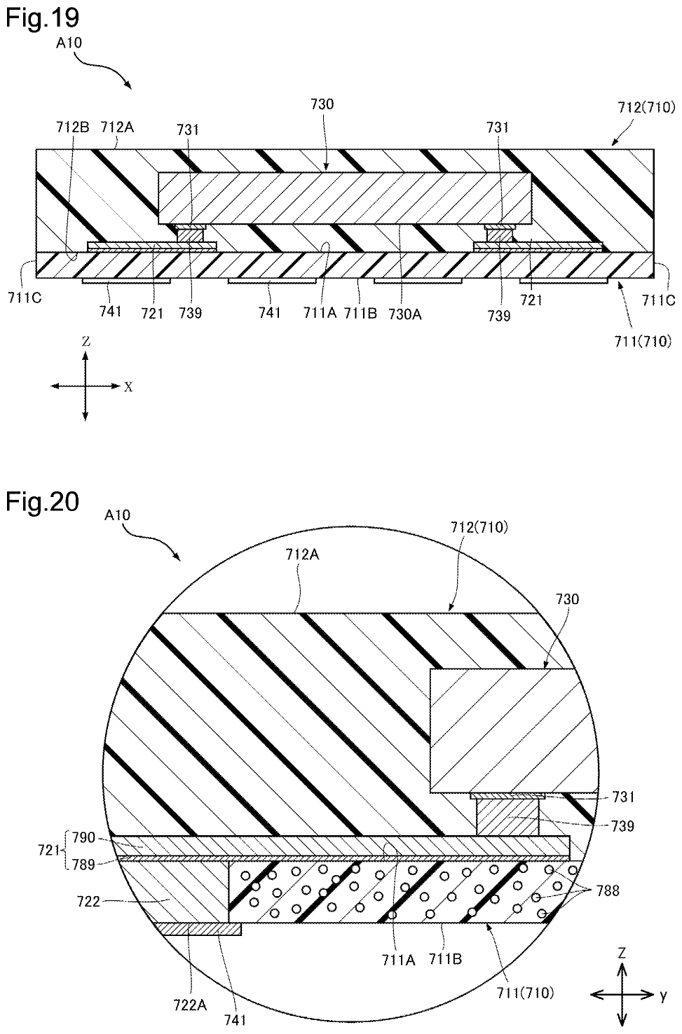

As shown in FIGS. 18 and 19, the semiconductor element 730 is bonded to the wire 721 by bonding layers 739. The bonding layers 739 are electrically conductive. Each bonding layer 739 includes a nickel (Ni) layer stacked on the wire 721 in the thickness-wise direction z and an alloy layer stacked on the nickel layer. The composition of the alloy layer includes tin (Sn). The semiconductor element 730 is a flip-mount-type element. In the semiconductor device A10, the semiconductor element 730 is an LSI. The semiconductor element 730 is covered by the second layer 712.

As shown in FIGS. 18 to 20, the semiconductor element 730 includes a lower surface 730A and pads 731. The lower surface 730A faces the first main surface 711A of the first layer 711 and the wire 721. The pads 731 are disposed on the lower surface 730A. In the semiconductor device A10, the pads 731 are electrically connected to a circuit (not shown) formed in the semiconductor element 730. Each pad 731 is bonded to the wire 721 by one of the bonding layers 739. Thus, the semiconductor element 730 is electrically connected to the wire 721.

As shown in FIGS. 16 and 18, the terminals 741 separately cover the bottom surface 722A of the joint wires 722. The terminals 741 are exposed to the exterior of the semiconductor device A10. When the terminals 741 are bonded to a wiring substrate with solder, the semiconductor device A10 is mounted on the wiring substrate. In the semiconductor device A10, each terminal 741 includes multiple metal layers stacked on the bottom surface 722A in the thickness-wise direction z. The metal layers are obtained by stacking a nickel layer and a gold (Au) layer in order from a position closer to the bottom surface 722A. Thus, the composition of the metal layers include nickel and gold. In another example of the configuration of the metal layers, a nickel layer, palladium (Pd) layer, and a gold layer may be stacked in order from a position closer to the bottom surface 722A.

Modified Examples of Third Embodiment

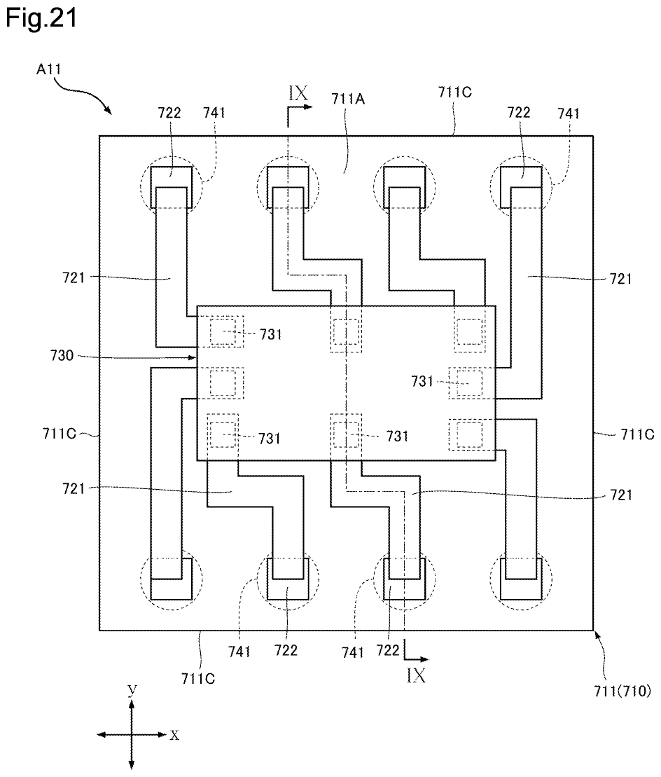

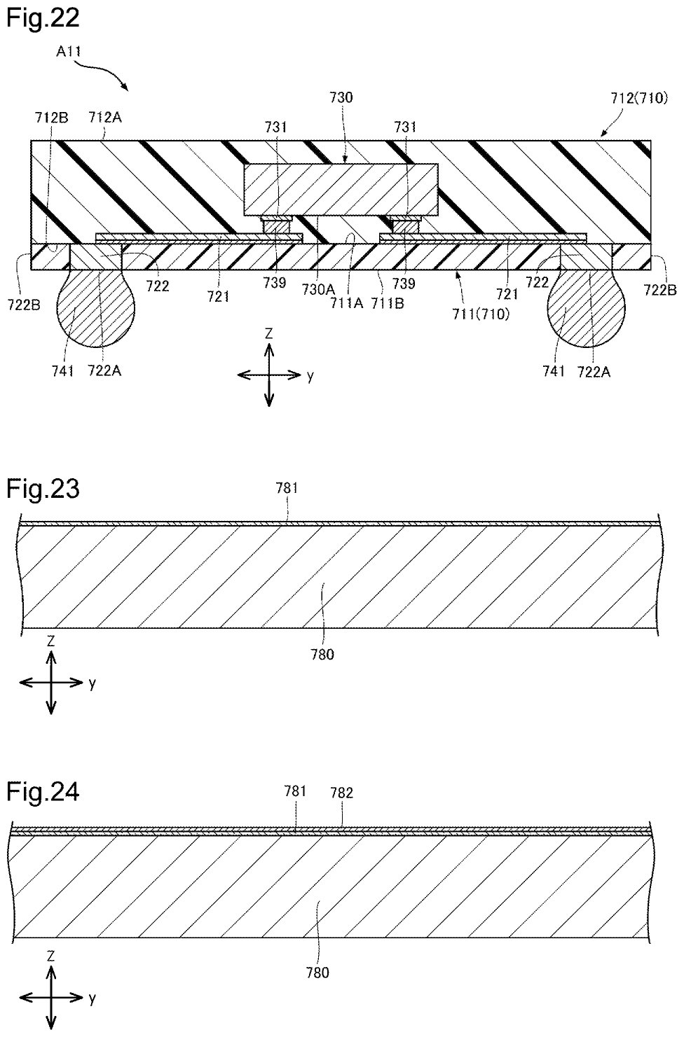

A modified example of the semiconductor device A11 in the third embodiment of according to the present disclosure will now be described with reference to FIGS. 21 and 22. To facilitate understanding, FIG. 21 transparently shows the second layer 712 of the encapsulation resin 710. In FIG. 21, line IX-IX is indicated by a single-dashed line.

The semiconductor device A11 differs in the configuration of the terminals 741 from the semiconductor device A10, which has been described. As shown in FIG. 22, each terminal 741 includes a solder ball. The terminal 741 projects from the bottom surface 722A of one of the joint wires 722 in the thickness-wise direction z. As shown in FIGS. 21 and 22, the terminal 741 is spherical.

An example of a method for manufacturing the semiconductor device A10 will now be described with reference to FIGS. 23 to 36. The position of the cross sections shown in FIGS. 23 to 36 is the same as the position of the cross section shown in FIG. 18.

As shown in FIG. 23, a base member 780 has surfaces located in the thickness-wise direction z, and an insulation film 781 is formed on one of the surfaces of the base member 780. The base member 780 is a semiconductor wafer (silicon wafer). The insulation film 781 is an oxide film (SiO₂) or a nitride film (Si₃N₄). When the insulation film 781 is an oxide film, the insulation film 781 is formed by thermal oxidation. When the insulation film 781 is a nitride film, the insulation film 781 is formed by plasma chemical vapor deposition (CVD).

As shown in FIG. 24, a separation layer 782 is formed to cover the upper surface of the insulation film 781. The separation layer 782 includes a titanium metal thin film that is in contact with the insulation film 781 and a copper metal thin film that is stacked on the titanium metal thin film in the thickness-wise direction z. The separation layer 782 is formed of these metal thin films that are formed through sputtering.

As shown in FIG. 25, columnar bodies 783 are formed to project from the upper surface of the separation layer 782 in the thickness-wise direction z. The columnar bodies 783 are formed from copper. The columnar bodies 783 are formed through lithography patterning that is performed on the upper surface of the separation layer 782 and then electrolytic plating that uses the separation layer 782 as a conductive path. The columnar bodies 783 are formed to have a height that is greater than or equal to 100

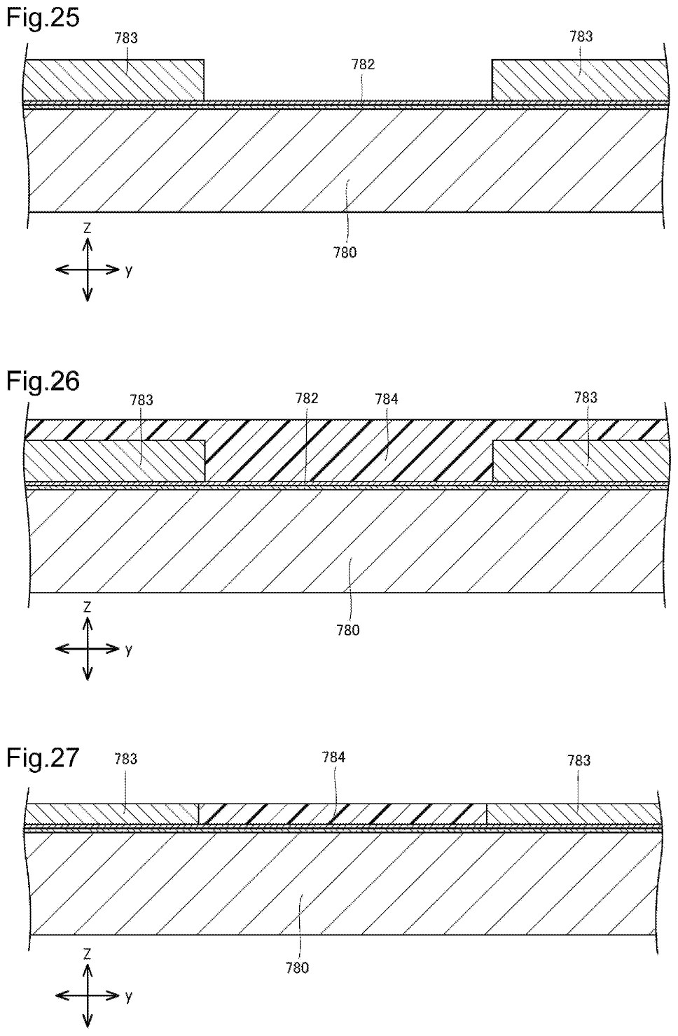

As shown in FIG. 26, a first resin layer 784 is formed to contact the separation layer 782 and cover the columnar bodies 783. The first resin layer 784 is formed from a material including a black epoxy resin and an inorganic compound filler mixed into the epoxy resin.

The first resin layer 784 is formed by compression molding. In this step, the first resin layer 784 is formed to have a thickness that is greater than or equal to 150 μm and greater than the height of the columnar bodies 783.

As shown in FIG. 27, the first resin layer 784 and the columnar bodies 783 are partially removed by grinding. The removal subject is a portion located at a side opposite from the base member 780 in the thickness-wise direction z. In this step, the height of the columnar bodies 783 becomes equal to the thickness of the first resin layer 784. In addition, the upper surface of the columnar bodies 783 is exposed on the upper surface of the first resin layer 784.

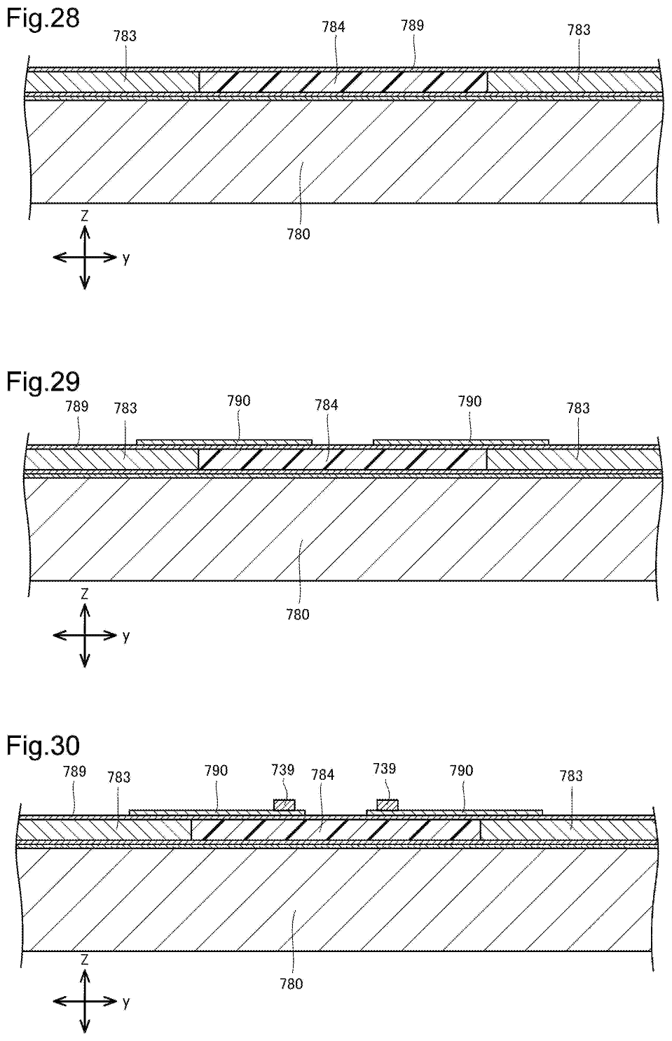

As shown in FIGS. 28 to 31, the wire 721 is formed to contact the upper surface of the first resin layer 784 and the upper surface of the columnar bodies 783, and the bonding layers 739 are formed on the upper surface of the wire 721.

As shown in FIG. 28, the base layer 789 is formed to cover the upper surface of the first resin layer 784 and the upper surface of the columnar bodies 783. The base layer 789 is formed through sputtering that forms a barrier layer covering the upper surfaces described above and then sputtering that forms a seed layer on the upper surface of the barrier layer. The barrier layer is formed of titanium having a thickness of 100 nm to 300 nm. The seed layer is formed of copper having a thickness of 200 nm to 600 nm.

As shown in FIG. 29, the body layers 790 are formed on the upper surface of the base layer 789. The body layers 790 are formed through lithography patterning that is performed on the upper surface of the base layer 789 and then electrolytic plating that uses the base layer 789 as a conductive path.

As shown in FIG. 30, the bonding layers 739 are formed on the upper surface of the body layers 790. The bonding layers 739 are formed through lithography patterning that is performed on the upper surface of the base layer 789 and the upper surface of the body layers 790 and then electrolytic plating that uses the base layer 789 and the body layers 790 as a conductive path.

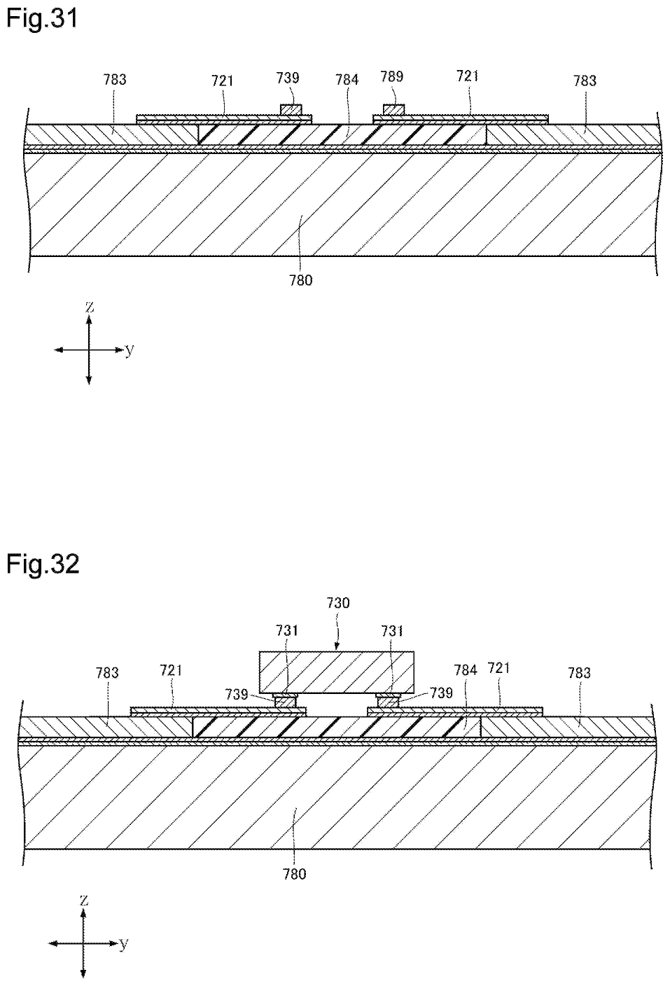

As shown in FIG. 31, the base layer 789 is partially removed. The removal subject of the base layer 789 is a portion where the body layers 790 are not formed. The base layer 789 is removed by wet etching that uses a mixture solution of sulfuric acid (H₂SO₄) and hydrogen peroxide (H₂O₂). In this step, the wire 721 is formed.

As shown in FIG. 32, the semiconductor element 730 is bonded to the wire 721 by the bonding layers 739. The pads 731 of the semiconductor element 730 are separately and temporarily attached to the bonding layers 739 using a collet. The bonding layers 739 are melted by a reflow process. The molten bonding layers 739 are cooled and solidified. This completes the bonding of the semiconductor element 730 to the wire 721.

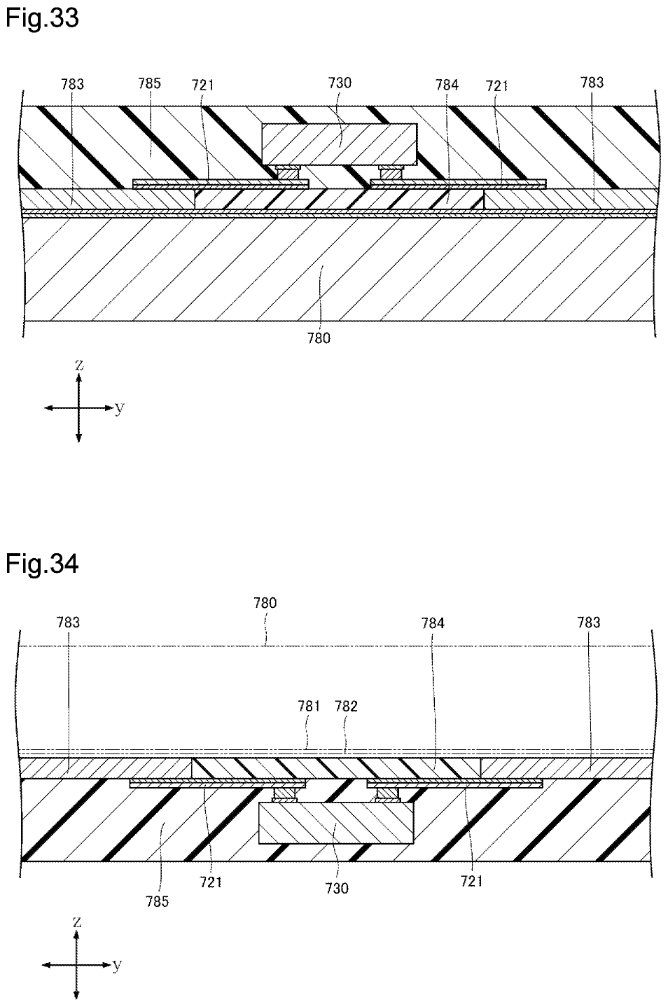

As shown in FIG. 33, a second resin layer 785 is formed to contact the first resin layer 784. The second resin layer 785 is formed from a material including a black epoxy resin. The second resin layer 785 is formed by compression molding. In this step, part of the wire 721 and the semiconductor element 730 are covered by the second resin layer 785.

As shown in FIG. 34, the base member 780, the insulation film 781, and the separation layer 782 are removed. The base member 780 and the insulation film 781 are removed by grinding. The separation layer 782 is removed by wet etching that uses a mixture solution of sulfuric acid and hydrogen peroxide. In this step, each columnar body 783 is partially exposed from the first resin layer 784.

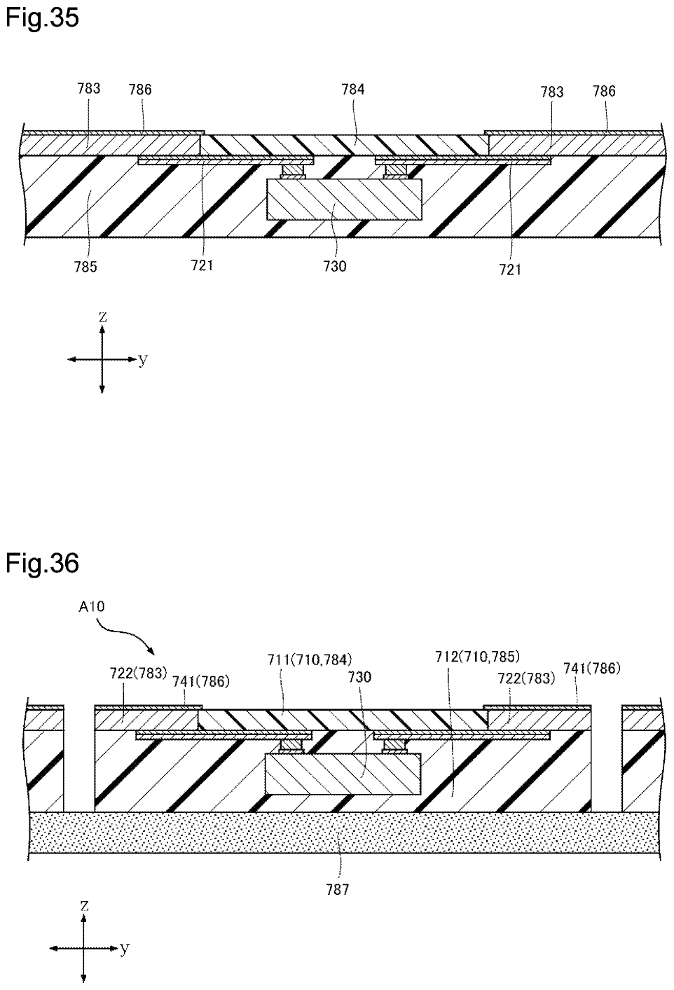

As shown in FIG. 35, metal layers 786 are formed to separately cover each of the columnar bodies 783 exposed from the first resin layer 784. The metal layers 786 are formed by depositing a nickel layer in contact with one of the columnar bodies 783 through electroless plating and then depositing a gold layer on the nickel layer through electroless plating.

After a tape 787 is applied to a surface of the second resin layer 785 facing in the thickness-wise direction z, the columnar bodies 783, the first resin layer 784, the second resin layer 785, and the metal layers 786 are cut in a lattice pattern extending in both the first direction x and the second direction y to be separated into pieces. A dicing blade or the like is used for cutting. In this step, the first resin layer 784 and the second resin layer 785 in each piece define the first layer 711 of the encapsulation resin 710 of the semiconductor device A10 and the second layer 712 of the encapsulation resin 710 of the semiconductor device A10. Also, the columnar bodies 783 in each piece and the metal layers 786 separately covering the columnar bodies 783 define the joint wires 722 of the semiconductor device A10 and the terminals 741 of the semiconductor device A10. The semiconductor device A10 is manufactured through the steps described above.

The operation and advantages of the semiconductor device A10 will now be described.

The semiconductor device A10 includes the encapsulation resin 710, the wire 721, and the semiconductor element 730. The encapsulation resin 710 includes the first layer 711 including the first main surface 711A and the first back surface 711B and the second layer 712 including the second main surface 712A and the second back surface 712B. The second back surface 712B is in contact with the first main surface 711A. The wire 721 is in contact with the first main surface 711A. The wire 721 is partially covered by the second layer 712. The semiconductor element 730 is joined to the wire 721 and is covered by the second layer 712. This reduces the difference in linear expansion coefficient between the first layer 711, on which the semiconductor element 730 is mounted, and the second layer 712, which covers the semiconductor element 730, as compared to when the first layer 711 is a semiconductor wafer. In addition, the thickness of the second layer 712 is minimized under a condition in which the second layer 712 covers the semiconductor element 730. Therefore, the semiconductor device A10 reduces the bending of the semiconductor device A10 while reducing the size of the semiconductor device A10.

The distance between the first main surface 711A and the first back surface 711B of the first layer 711 is smaller than the distance between the second main surface 712A and the second back surface 712B of the second layer 712. That is, the thickness of the first layer 711 is less than the thickness of the second layer 712. Thus, the semiconductor device A10 is reduced in size.

The filler 788 including an inorganic compound is mixed into the first layer 711. The filler 788 is used as a reinforcement material of the first layer 711. Thus, the mechanical strength of the first layer 711 is ensured even when the thickness of the first layer 711 is minimized.

The semiconductor device A10 further includes the joint wires 722 joined to the wire 721. The joint wires 722 extend from the wire 721 to the first back surface 711B of the first layer 711 and are partially covered by the first layer 711. Each joint wire 722 includes the bottom surface 722A exposed on the first back surface 711B. Thus, in the semiconductor device A10, as viewed in the thickness-wise direction z, a conductive member joined to the wire 721 does not project from the encapsulation resin 710. This structure is suitable for reducing the size of the semiconductor device A10. When the first layer 711 is a semiconductor wafer, holes for arranging the joint wires 722 need to be formed in the semiconductor wafer. The holes may be formed by reactive ion etching (ME) or the like. The formation of the holes takes time and increases the cost. Since the first layer 711 of the semiconductor device A10 eliminates the need for forming the holes, the time and cost for manufacturing the semiconductor device A10 are reduced.

The semiconductor device A10 further includes the multiple terminals 741 separately covering the bottom surface 722A of the joint wires 722. When the semiconductor device A10 is mounted on a wiring substrate, solder adheres to the terminals 741. The terminals 741 reduce a thermal shock acting on the joint wires 722 caused by the solder.

Each terminal 741 includes the metal layers stacked in the thickness-wise direction z. The composition of the metal layers include nickel and gold. This further effectively reduces the thermal shock acting on the joint wires 722 caused by the solder. In addition, the solder wettability is satisfactory and improves the strength of mounting the semiconductor device A10 on the wiring substrate.

As viewed in the thickness-wise direction z, the wire 721 is located at an inner side of the peripheral edges of the encapsulation resin 710. Thus, the wire 721 is entirely covered by the encapsulation resin 710. This limits decreases in the dielectric strength of the semiconductor device A10 caused by the wire 721.

Fourth Embodiment

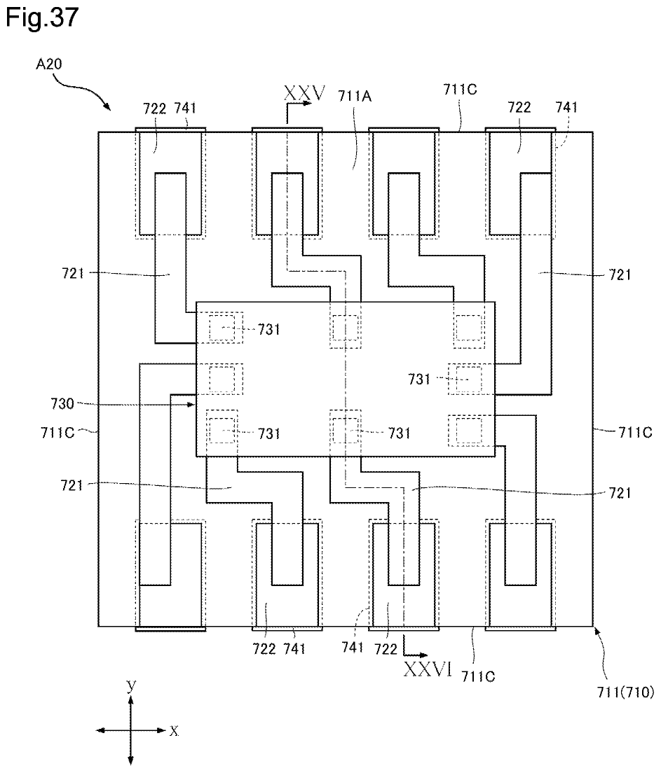

A fourth embodiment of a semiconductor device A20 according to the present disclosure will now be described with reference to FIGS. 37 to 39. In the drawings, the same reference signs are given to those elements that are the same as or similar to the corresponding elements of the semiconductor device A10. Such elements will not be described in detail. To facilitate understanding, FIG. 37 transparently shows the second layer 712 of the encapsulation resin 710. In FIG. 37, line XXVI-XXVI is indicated by a single-dashed line.

The semiconductor device A20 differs in the configuration of the terminals 741 from the semiconductor device A10, which has been described.

As shown in FIG. 39, the semiconductor device A20 includes terminals 741, each of which includes a bottom portion 791 and a lateral portion 792. The bottom portion 791 covers the bottom surface 722A of one of the joint wires 722. The bottom portion 791 includes metal layers stacked on the bottom surface 722A in the thickness-wise direction z.

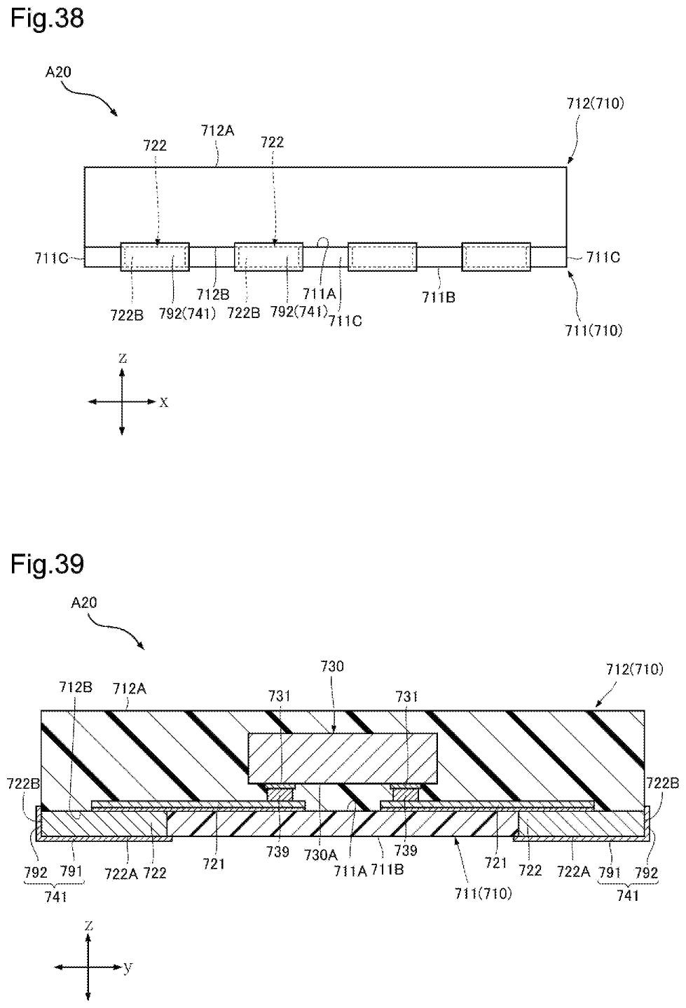

The metal layers have the same configuration as the metal layers included in the terminals 741 of the semiconductor device A10. The lateral portion 792 is joined to the bottom portion 791 of one of the terminals 741. The lateral portion 792 extends from the bottom portion 791 in the thickness-wise direction z. The lateral portion 792 covers the end surface 722B of one of the joint wires 722. Thus, as shown in FIG. 38, in the semiconductor device A20, the joint wires 722 are configured not to be exposed to the exterior of the semiconductor device A10. The lateral portion 792 includes metal layers stacked in a direction orthogonal to the thickness-wise direction z (the second direction y in the semiconductor device A20). The metal layers have the same configuration as the metal layers included in the bottom portion 791.

The operation and advantages of the semiconductor device A20 will now be described.

The semiconductor device A20 includes the encapsulation resin 710, the wire 721, and the semiconductor element 730. The encapsulation resin 710 includes the first layer 711 including the first main surface 711A and the first back surface 711B and the second layer 712 including the second main surface 712A and the second back surface 712B. The second back surface 712B is in contact with the first main surface 711A. The wire 721 is in contact with the first main surface 711A. The wire 721 is partially covered by the second layer 712. The semiconductor element 730 is joined to the wire 721 and is covered by the second layer 712. Thus, the semiconductor device A20 reduces the bending of the semiconductor device A20 while reducing the size of the semiconductor device A20.

In the semiconductor device A20, the terminals 741 each include the bottom portion 791 and the lateral portion 792 joined to the bottom portion 791. The bottom portion 791 covers the bottom surface 722A of one of the joint wires 722. The lateral portion 792 covers the end surface 722B of one of the joint wires 722. Thus, when the semiconductor device A10 is mounted on a wiring substrate, solder adheres to the lateral portion 792 as well as the bottom portion 791 of each terminal 741. This increases the area of the terminal 741 to which the solder is adhered, thereby improving the strength of mounting the semiconductor device A20 on the wiring substrate. In addition, the solder adhered to the lateral portion 792 is readily seen. This allows for visual inspection of the mount state of the semiconductor device A20 on the wiring substrate.

Fifth Embodiment

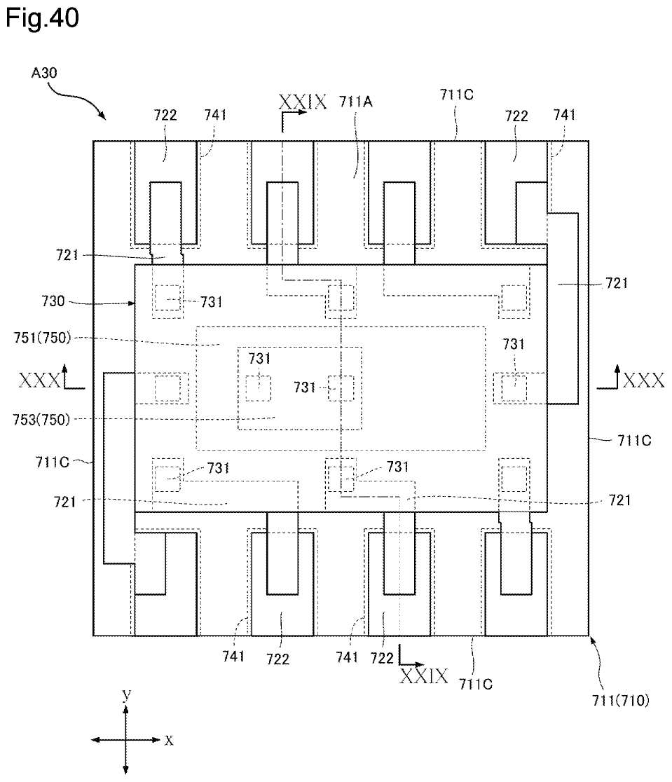

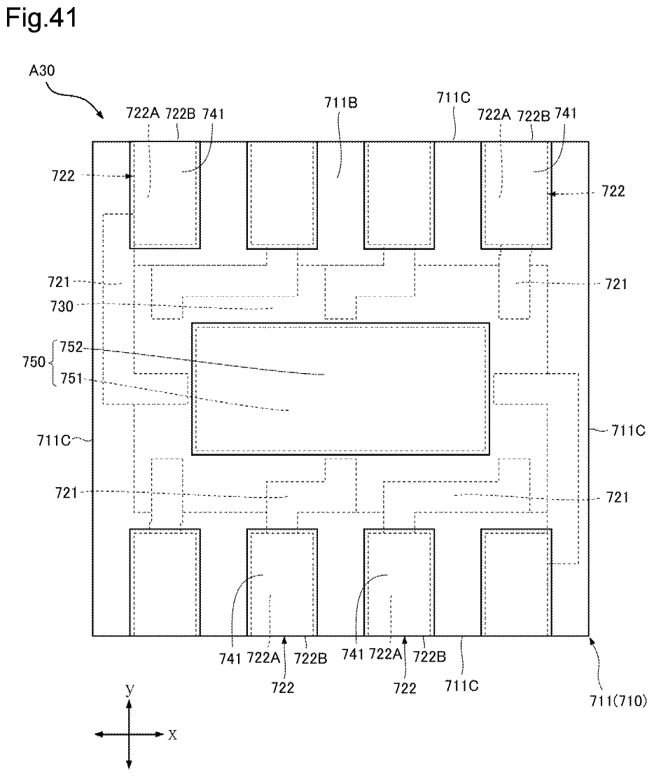

A fifth embodiment of a semiconductor device A30 according to the present disclosure will now be described with reference to FIGS. 40 to 44. In the drawings, the same reference signs are given to those elements that are the same as or similar to the corresponding elements of the semiconductor device A10. Such elements will not be described in detail. To facilitate understanding, FIG. 40 transparently shows the second layer 712 of the encapsulation resin 710. In FIG. 40, line XXIX-XXIX is indicated by a single-dashed line.

The semiconductor device A30 differs from the semiconductor device A10, which has been described, in that the semiconductor device A30 includes a heat dissipating body 750.

As shown in FIGS. 40 to 43, the semiconductor device A30 includes the heat dissipating body 750. As viewed in the thickness-wise direction z, at least part of the heat dissipating body 750 overlaps the semiconductor element 730. The heat dissipating body 750 includes a base 751, a cover 752, and a bump 753. The base 751 is embedded in the first layer 711 of the encapsulation resin 710 and is in contact with the second layer 712 of the encapsulation resin 710. The thickness of the base 751 equals the distance between the first main surface 711A of the first layer 711 and the first back surface 711B of the first layer 711, that is, the thickness of the first layer 711. The composition of the base 751 includes pcopper. The cover 752 includes metal layers stacked on the base 751 in the thickness-wise direction z and is exposed on the first back surface 711B. Thus, the cover 752 is exposed to the exterior of the semiconductor device A30. The metal layers have the same configuration as the metal layers included in the terminals 741 of the semiconductor device A10.

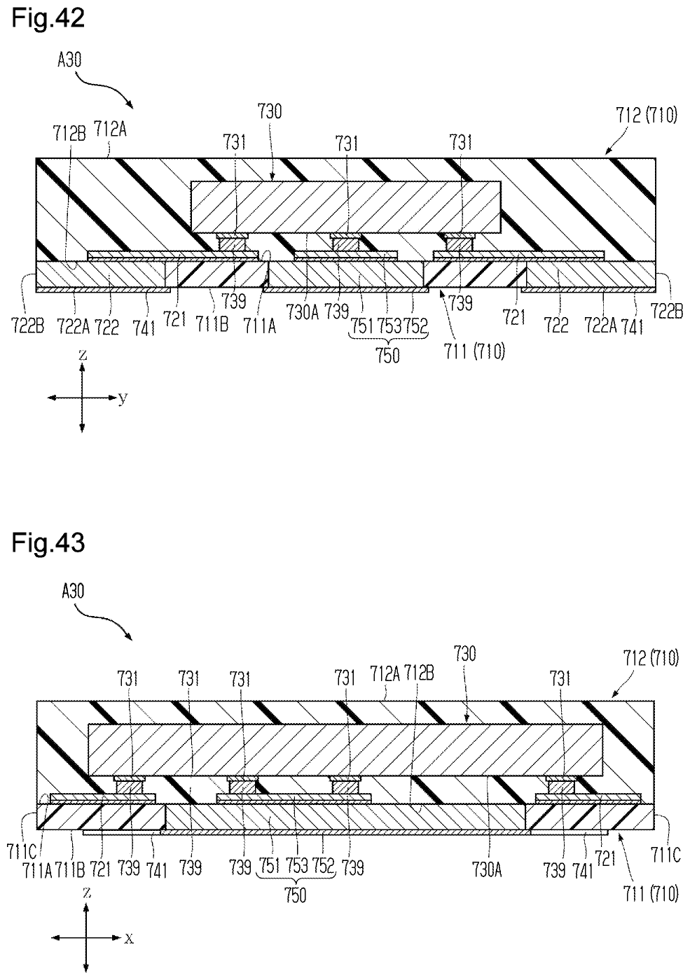

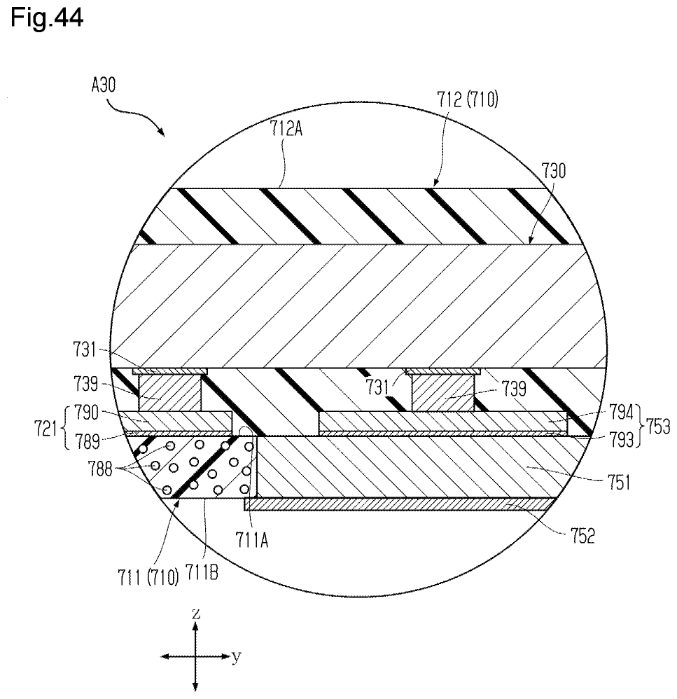

As shown in FIGS. 42 and 43, the bump 753 and the cover 752 are located at opposite sides of the base 751 in the thickness-wise direction z. The bump 753 projects from the base 751 toward the lower surface 730A of the semiconductor element 730 in the thickness-wise direction z. As shown in FIG. 44, the bump 753 includes a base layer 793 and a body layer 794. The base layer 793 is in contact with the base 751. The base layer 793 includes a barrier layer contacting the base 751 and a seed layer stacked on the barrier layer in the thickness-wise direction z. The composition of the barrier layer includes titanium. The composition of the seed layer includes copper. The thickness of the base layer 793 is equal to the thickness of the base layer 789 of the wire 721. The body layer 794 is stacked on the base layer 793 in the thickness-wise direction z. The composition of the body layer 790 is the same as that of the seed layer of the base layer 789. Thus, the composition of the body layer 790 includes copper. The thickness of the body layer 794 is greater than the thickness of the base layer 793 and is equal to the thickness of the body layer 790 of the wire 721. Thus, the thickness of the bump 753 is equal to the thickness of the wire 721.

As shown in FIGS. 42 and 43, some of the pads 731 of the semiconductor element 730 are bonded to the bump 753 by the bonding layer 739. The pads 731 bonded to the bump 753 are not electrically connected to the circuit formed in the semiconductor element 730 and are so-called dummy pads. Otherwise, the pads 731 bonded to the bump 753 are connected to ground of the semiconductor element 730.

The operation and advantages of the semiconductor device A30 will now be described.

The semiconductor device A30 includes the encapsulation resin 710, the wire 721, and the semiconductor element 730. The encapsulation resin 710 includes the first layer 711 including the first main surface 711A and the first back surface 711B and the second layer 712 including the second main surface 712A and the second back surface 712B. The second back surface 712B is in contact with the first main surface 711A. The wire 721 is in contact with the first main surface 711A. The wire 721 is partially covered by the second layer 712. The semiconductor element 730 is joined to the wire 721 and is covered by the second layer 712. Thus, the semiconductor device A30 reduces the bending of the semiconductor device A30 while reducing the size of the semiconductor device A30.

The semiconductor device A30 further includes the heat dissipating body 750. The heat dissipating body 750 includes the base 751. The base 751 is embedded into the first layer 711 and is in contact with the second back surface 712B of the second layer 712. As viewed in the thickness-wise direction z, at least part of the heat dissipating body 750 overlaps the semiconductor element 730. When the semiconductor device A30 is used, heat generated from the semiconductor element 730 is efficiently dissipated to the outside of the semiconductor device A30. The thickness of the base 751 is equal to the distance between the first main surface 711A and the first back surface 711B of the first layer 711. Thus, when manufacturing the semiconductor device A30, the base 751 may be formed in the same process as the process for forming the joint wires 722 (refer to FIGS. 25 to 27).

The heat dissipating body 750 includes the cover 752. The cover 752 is formed on the base 751 and is exposed on the first back surface 711B of the first layer 711. The cover 752 includes the metal layers forming the terminals 741. In this configuration, when the semiconductor device A30 is mounted on a wiring substrate, the heat dissipating body 750 is bonded to the wiring substrate with solder, so that heat conducted from the semiconductor element 730 to the heat dissipating body 750 is further efficiently transferred to the wiring substrate. In addition, when manufacturing the semiconductor device A30, the process for forming the cover 752 may be the same as the process for forming the terminals 741 (refer to FIG. 35).

The heat dissipating body 750 includes the bump 753. The bump 753 projects from the base 751 toward the lower surface 730A of the semiconductor element 730 in the thickness-wise direction z. Some of the pads 731 of the semiconductor element 730 are bonded to the bump 753. With this configuration, heat generated from the semiconductor element 730 is further effectively transferred to the heat dissipating body 750. In addition, all of the bonding layers 739, which are separately arranged for the pads 731, have the same height. In addition, when manufacturing the semiconductor device A30, the process for forming the bump 753 may be the same as the process for forming the wire 721 (refer to FIGS. 28, 29, and 31).

Sixth Embodiment

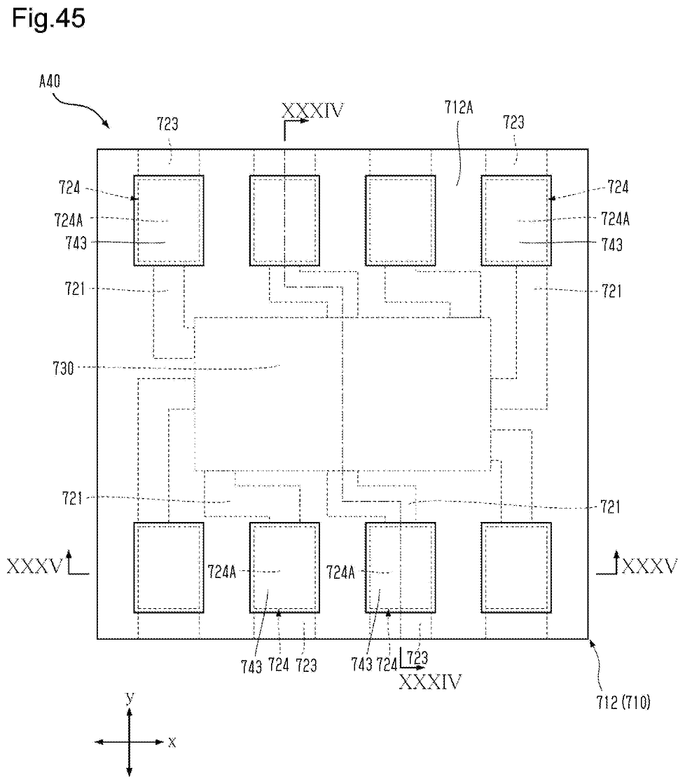

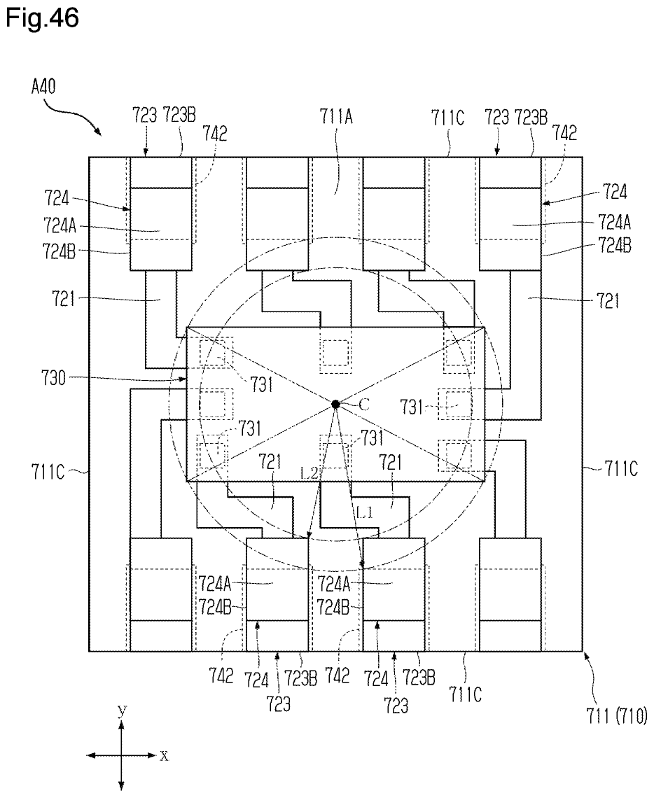

A sixth embodiment of a semiconductor device A40 according to the present disclosure will now be described with reference to FIGS. 45 to 48. In the drawings, the same reference signs are given to those elements that are the same as or similar to the corresponding elements of the semiconductor device A10. Such elements will not be described in detail. To facilitate understanding, FIG. 46 transparently shows the second layer 712 of the encapsulation resin 710. In FIG. 45, line XXXIV-XXXIV is indicated by a single-dashed line.

The semiconductor device A40 differs from the semiconductor device A10, which has been described, in that the semiconductor device A40 includes first joint wires 723, second joint wires 724, first terminals 742, and second terminals 743 instead of the joint wires 722 and the terminals 741.

As shown in FIGS. 46 to 48, the semiconductor device A40 includes the first joint wires 723. Each first joint wire 723 is joined to one of the regions of the wire 721. The first joint wire 723 extends from the wire 721 to the first back surface 711B of the first layer 711 and is partially covered by the first layer 711. The first joint wires 723 and the wire 721 form part of the conductive path extending between the semiconductor element 730 and a wiring substrate on which the semiconductor device A40 is mounted. The composition of the first joint wires 723 includes copper.

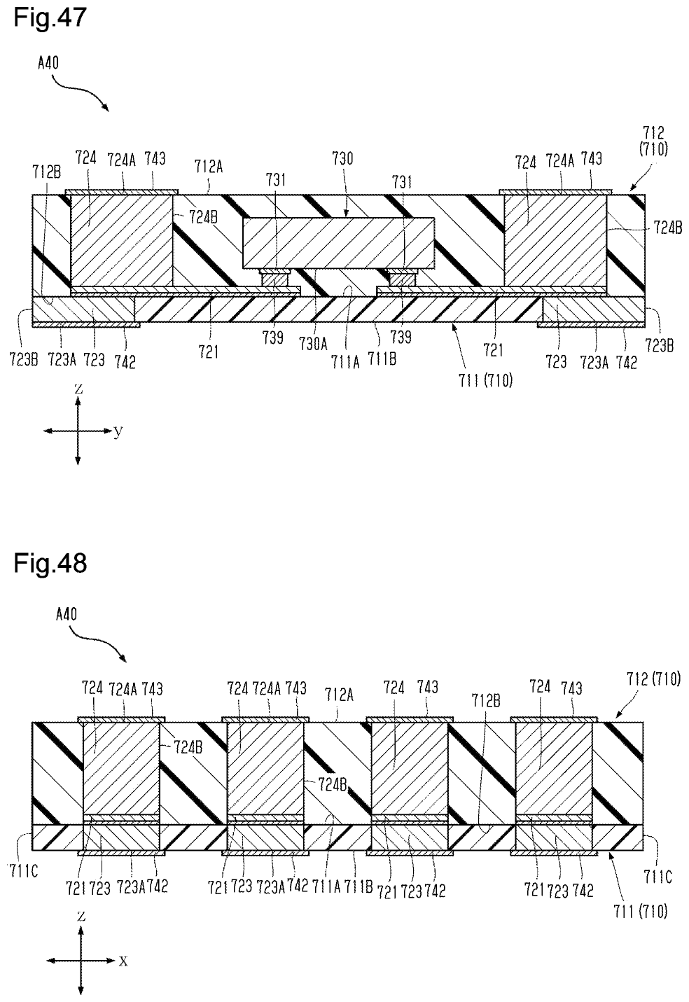

As shown in FIG. 47, the first joint wires 723 each include a bottom surface 723A and an end surface 723B. The bottom surface 723A is exposed on the first back surface 711B of the first layer 711. The end surface 723B is joined to the bottom surface 723A and faces in a direction orthogonal to the thickness-wise direction z. In the semiconductor device A40, the end surface 723B faces in the second direction y. As shown in FIGS. 46 and 47, the end surface 723B is exposed in one region of the side surface 711C of the first layer 711. In the semiconductor device A40, the end surface 723B is exposed in one of the two regions of the side surface 711C separated from each other in the second direction y. Each first joint wire 723 includes a surface facing in a direction opposite from the bottom surface 723A in the thickness-wise direction z, and the surface is flush with the first main surface 711A of the first layer 711 and is in contact with the second back surface 712B of the second layer 712.

As shown in FIGS. 45 to 48, the semiconductor device A40 includes the second joint wires 724. Each second joint wire 724 is joined to one of the regions of the wire 721. The second joint wire 724 extends from the wire 721 to the second main surface 712A of the second layer 712 and is partially covered by the second layer 712. The second joint wires 724 and the wire 721 form part of the conductive path extending between the semiconductor element 730 and a wiring substrate on which the semiconductor device A40 is mounted. The composition of the second joint wires 724 includes copper.

As shown in FIGS. 46 to 48, the second joint wires 724 each include a top surface 724A and a side surface 724B. The top surface 724A is exposed on the second main surface 712A of the second layer 712. The side surface 724B is joined to the top surface 724A and faces in a direction orthogonal to the thickness-wise direction z. The side surface 724B is covered by the second layer 712.

As shown in FIG. 47, as viewed in the thickness-wise direction z, the shortest distance L2 from a center C of the semiconductor element 730 to one of the second joint wires 724 is less than the shortest distance L1 from the center C of the semiconductor element 730 to one of the first joint wires 723. The center C of the semiconductor element 730 refers to the intersection point of diagonals of the semiconductor element 730 as viewed in the thickness-wise direction z.

As shown in FIGS. 47 and 48, the semiconductor device A40 includes the first terminals 742. The first terminals 742 separately cover the bottom surface 723A of the first joint wires 723. The first terminals 742 are exposed to the exterior of the semiconductor device A40. When the first terminals 742 are bonded to a wiring substrate with solder, the semiconductor device A40 is mounted on the wiring substrate. The first terminals 742 each include metal layers stacked on the bottom surface 723A in the thickness-wise direction z. The metal layers have the same configuration as the metal layers included in the terminals 741 of the semiconductor device A10.

As shown in FIGS. 45, 47, and 48, the semiconductor device A40 includes the second terminals 743. The second terminals 743 separately cover the top surface 724A of the second joint wires 724. The second terminals 743 are exposed to the exterior of the semiconductor device A40. When the second terminals 743 are bonded to a wiring substrate with solder, the semiconductor device A40 is mounted on the wiring substrate. The second terminals 743 each include metal layers stacked on the top surface 724A in the thickness-wise direction z. The metal layers have the same configuration as the metal layers included in the terminals 741 of the semiconductor device A10.

The operation and advantages of the semiconductor device A40 will now be described.

The semiconductor device A40 includes the encapsulation resin 710, the wire 721, and the semiconductor element 730. The encapsulation resin 710 includes the first layer 711 including the first main surface 711A and the first back surface 711B and the second layer 712 including the second main surface 712A and the second back surface 712B. The second back surface 712B is in contact with the first main surface 711A. The wire 721 is in contact with the first main surface 711A. The wire 721 is partially covered by the second layer 712. The semiconductor element 730 is joined to the wire 721 and is covered by the second layer 712. Thus, the semiconductor device A40 reduces the bending of the semiconductor device A40 while reducing the size of the semiconductor device A40.

The semiconductor device A40 includes the first joint wires 723 and the second joint wires 724 instead of the joint wires 722. Each first joint wire 723 extends from the wire 721 to the first back surface 711B of the first layer 711 and is partially covered by the first layer 711. The first joint wire 723 includes the bottom surface 723A exposed on the first back surface 711B. Each second joint wire 724 extends from the wire 721 to the second main surface 712A of the second layer 712 and is partially covered by the second layer 712. The second joint wire 724 includes the top surface 724A exposed on the second main surface 712A. With this configuration, when the semiconductor device A40 is mounted on a wiring substrate, either one of the first back surface 711B and the second main surface 712A may face the wiring substrate. Since the semiconductor device A40 is mounted on the wiring substrate regardless of the direction of the semiconductor device A40, the efficiency of the mounting task is improved.

As viewed in the thickness-wise direction z, the shortest distance L2 from the center C of the semiconductor element 730 to one of the second joint wires 724 is less than the shortest distance L1 from the center C of the semiconductor element 730 to one of the first joint wires 723. In this configuration, the second layer 712 covers the side surface 724B of each second joint wire 724. In this configuration, the thickness of the second layer 712 is greater than the thickness of the first layer 711. Hence, the height of each second joint wire 724 is greater than the height of each first joint wire 723. Accordingly, the second joint wire 724 is likely to have a larger volume than the first joint wire 723. With this configuration, decreases in the dielectric strength of the semiconductor device A40 caused by the second joint wires 724 are limited.

The semiconductor device A40 includes the first terminals 742 and the second terminals 743 instead of the terminals 741. The first terminals 742 separately cover the bottom surface 723A of the first joint wires 723. The second terminals 743 separately cover the top surface 724A of the second joint wires 724. When the semiconductor device A40 is mounted on a wiring substrate, solder adheres to any one of the first terminals 742 and the second terminals 743. The first terminals 742 and the second terminals 743 reduce a thermal shock acting on the first joint wires 723 and the second joint wires 724 caused by the solder.

The present disclosure is not limited to the semiconductor devices A10 to A40, which have been described. Each component of the present disclosure may have a specific configuration that is variously designed and changed in any manner.

Embodiments of an electronic component and a method for manufacturing an electronic component will now be described with reference to the drawings. The embodiments described below exemplify configurations and methods for embodying a technical concept and are not intended to limit the material, shape, structure, layout, dimensions, and the like of each component to those described below. The embodiments described below may undergo various modifications.

Seventh Embodiment

Structure of Electronic Component

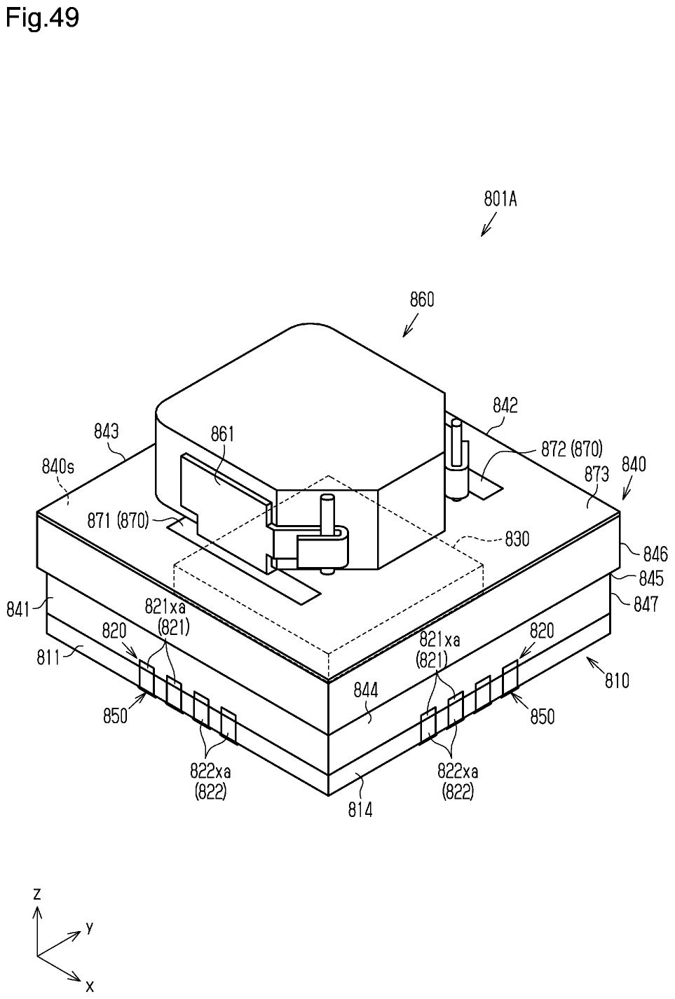

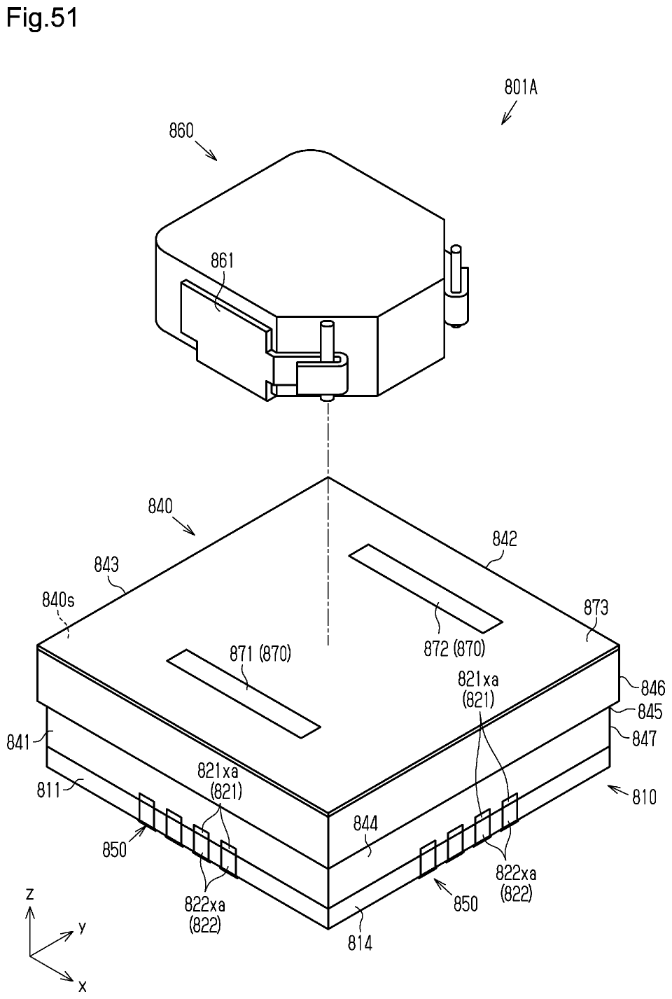

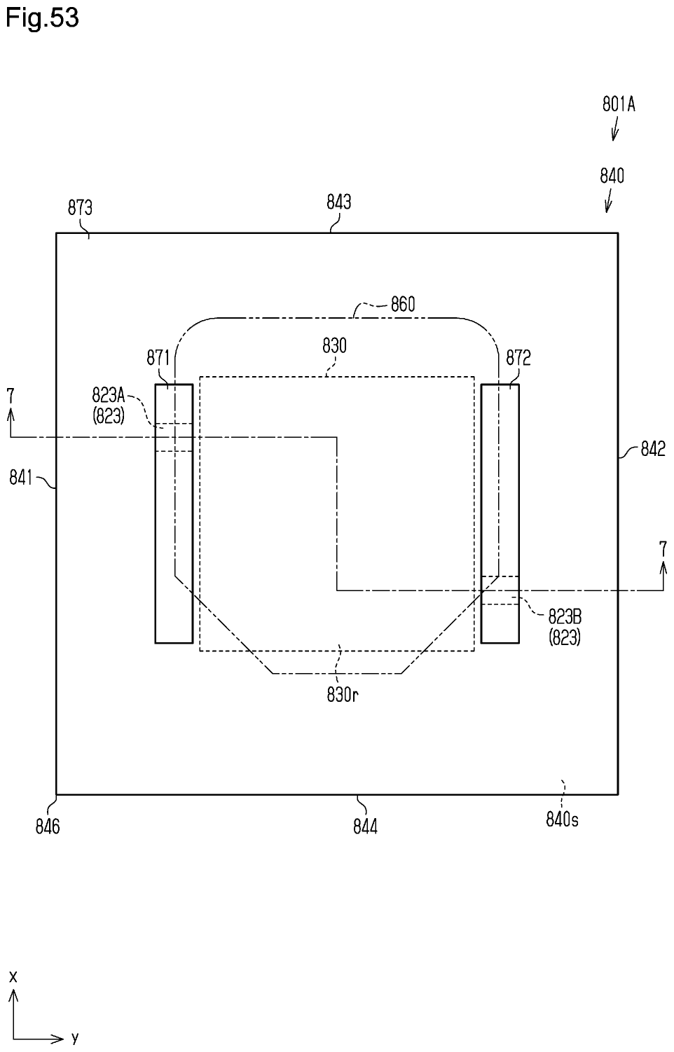

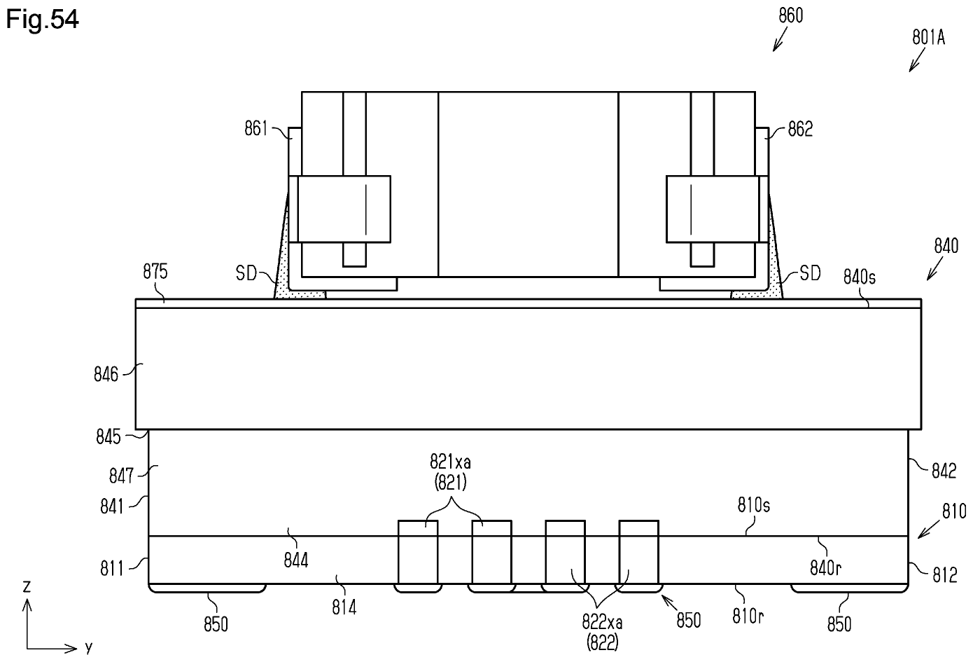

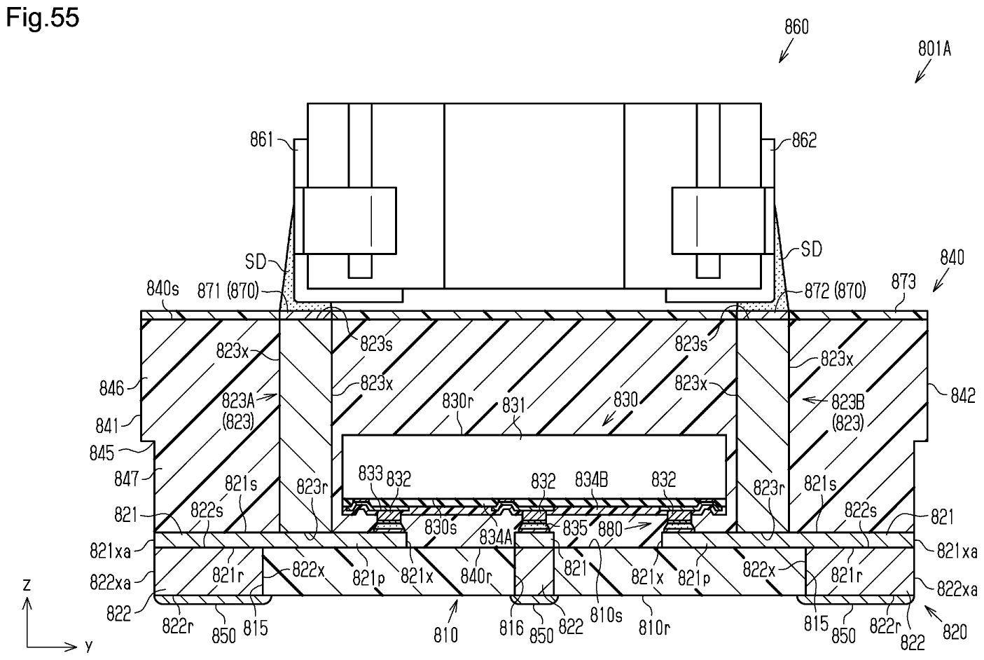

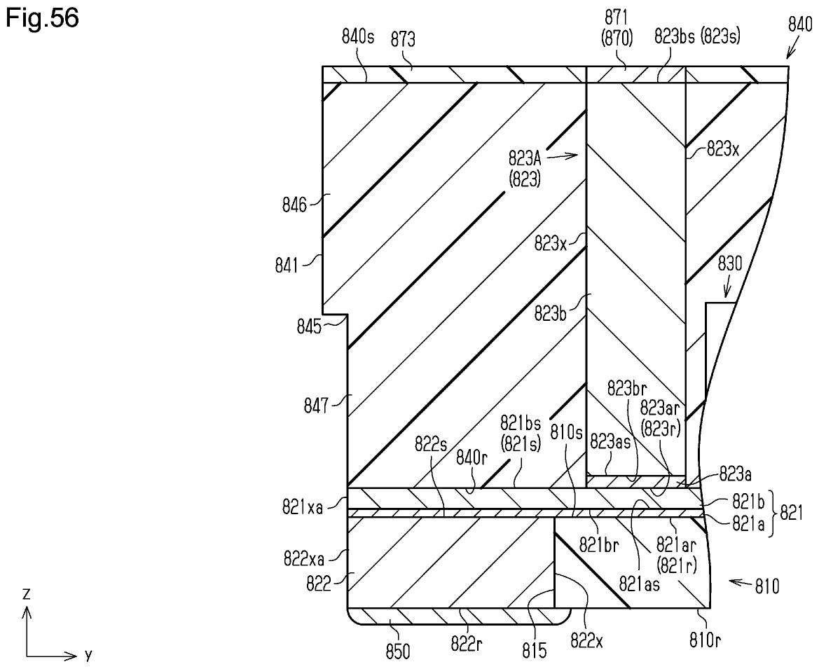

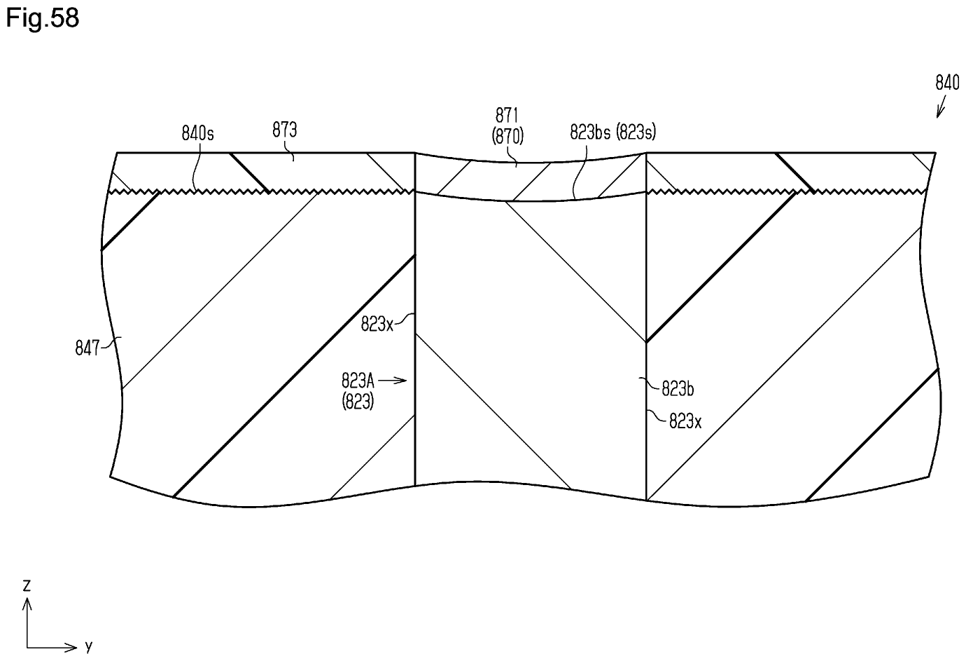

A seventh embodiment of an electronic component 801A according to the present disclosure will now be described with reference to FIGS. 49 to 58. For the sake of convenience, FIGS. 49 and 51 do not show solder SD that bonds a second functional element 860 to an encapsulation resin 840. In FIG. 53, the second functional element 860 is indicated by double-dashed lines for the sake of convenience. FIG. 55 shows a side structure instead of a cross-sectional structure of the second functional element 860 for the sake of convenience. FIGS. 56 and 58 do not show the second functional element 860 and the solder SD for the sake of convenience. In side views, the solder SD is given dots so as to be easily distinguished from other components.

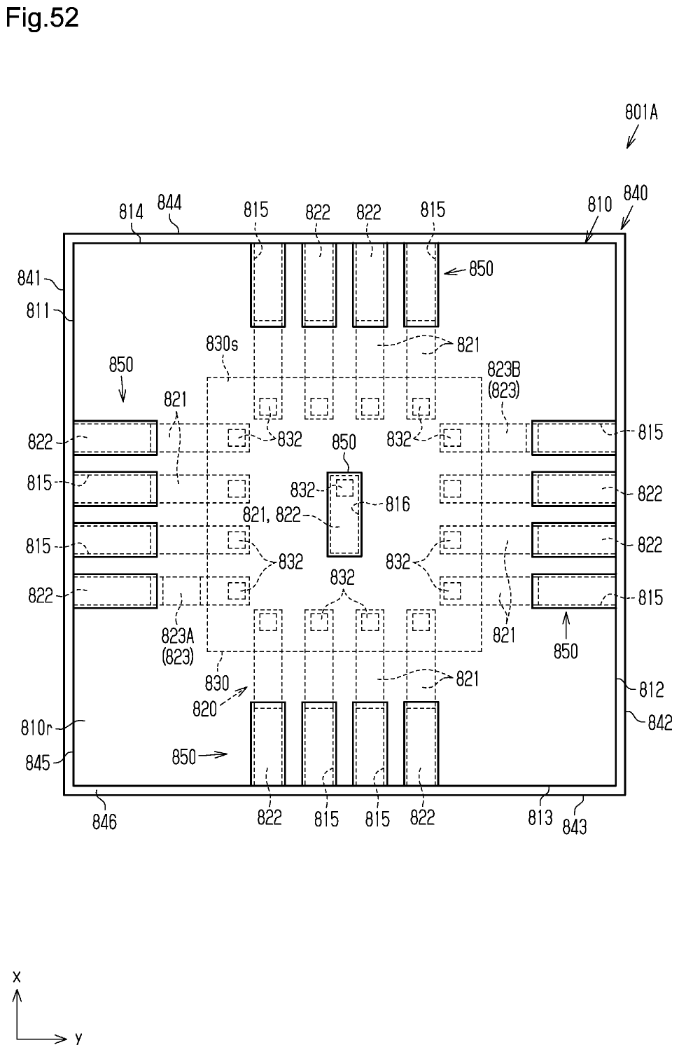

As shown in FIGS. 49 to 52, the electronic component 801A includes a substrate 810, inner electrodes 820, a first functional element 830, an encapsulation resin 840, outer electrodes 850, and a second functional element 860. The substrate 810 is an example of an insulation member. The electronic component 801A is configured to be surface-mounted on a wiring substrate (not shown) of various electronic apparatuses. As shown in FIGS. 49 and 52, the first functional element 830 is disposed in the encapsulation resin 840. As shown in FIGS. 49 to 51, the second functional element 860 is disposed on the encapsulation resin 840 outside the encapsulation resin 840. The encapsulation resin 840 is formed on the substrate 810. The second functional element 860 is formed on the encapsulation resin 840. As shown in FIG. 52, in the electronic component 801A of the present embodiment, the inner electrodes 820 extend outward from the first functional element 830, so that the outer electrodes 850 are disposed at an outer side of the first functional element 830.

In the description hereafter, for the sake of convenience, the thickness-wise direction of the substrate 810 is referred to as the thickness-wise direction z. Also, two directions orthogonal to each other and orthogonal to the thickness-wise direction z are referred to as the first direction x and the second direction y.

As shown in FIGS. 49 and 52, the substrate 810, on which the first functional element 830 is mounted, is a support member used as a base of the electronic component 801A. As shown in FIG. 52, in the present embodiment, as viewed in the thickness-wise direction z, the substrate 810 is generally square so that two sides extend in the first direction x and two sides extend in the second direction y.

The shape of the substrate 810 as viewed in the thickness-wise direction z is not limited to a square and may be changed in any manner. In an example, as viewed in the thickness-wise direction z, the substrate 810 is rectangular so that long sides extend in one of the first direction x or the second direction y and short sides extend in the other one of the first direction x or the second direction y.

As shown in FIGS. 52 and 55, the substrate 810 includes a substrate main surface 810s, which is an example of an insulation main surface, a substrate back surface 810r, which is an example of an insulation back surface, and multiple (four in the present embodiment) substrate side surfaces 811 to 814, which are an example of an insulation side surface. As shown in FIG. 55, the substrate main surface 810s and the substrate back surface 810r face in opposite directions in the thickness-wise direction z. The substrate main surface 810s and the substrate back surface 810r are flat. As shown in FIG. 52, the substrate side surfaces 811 to 814 are disposed between the substrate main surface 810s and the substrate back surface 810r in the thickness-wise direction z and face in the first direction x or the second direction y. The substrate side surfaces 811 and 812 face in opposite directions in the second direction y and extend in the first direction x as viewed in the thickness-wise direction z. The substrate side surfaces 813 and 814 face in opposite directions in the first direction x and extend in the second direction y as viewed in the thickness-wise direction z.

In the description hereafter, for the sake of convenience, in the thickness-wise direction z, a direction extending from the substrate back surface 810r toward the substrate main surface 810s is referred to as “upward,” and a direction extending from the substrate main surface 810s toward the substrate back surface 810r is referred to as “downward.” Hence, the substrate main surface 810s may be referred to as the upper surface of the substrate 810, and the substrate back surface 810r is referred to as the lower surface of the substrate 810.

As shown in FIG. 52, the substrate 810 is formed from, for example, an electrically insulating material. Such a material may be, for example, a synthetic resin, the main component of which is an epoxy resin or the like, ceramic, or glass. In the present embodiment, the synthetic resin, the main component of which is an epoxy resin, is used as the substrate 810. The substrate 810 includes recesses 815 that are recessed inward from each of the substrate side surfaces 811 to 814 so as to extend through the substrate 810 in the thickness-wise direction z. In the present embodiment, four recesses 815 are arranged in each side of the substrate 810. As viewed in the thickness-wise direction z, each recess 815 is rectangular. The four recesses 815 arranged near the substrate side surface 811 and the four recesses 815 arranged near the substrate side surface 812 each have the form of a rectangular recess so that the short sides extend in the first direction x and the long sides extend in the second direction y as viewed in the thickness-wise direction z. The four recesses 815 arranged near the substrate side surface 813 and the four recesses 815 arranged near the substrate side surface 814 each have the form of a rectangular recess so that the long sides extend in the first direction x and the short sides extend in the second direction y as viewed in the thickness-wise direction z.

The four recesses 815 arranged in the substrate side surface 811 are formed outward from the first functional element 830 in the second direction y. The four recesses 815 arranged in the substrate side surface 812 are formed outward from the first functional element 830 in the second direction y. The four recesses 815 arranged in the substrate side surface 813 are formed outward from the first functional element 830 in the first direction x. The four recesses 815 arranged in the substrate side surface 814 are formed outward from the first functional element 830 in the first direction x. Thus, the recesses 815 do not overlap the first functional element 830 as viewed in the thickness-wise direction z.

A through hole 816 extends through the substrate 810 in the thickness-wise direction z. The through hole 816 is disposed at a center of the substrate 810 in the first direction x and the second direction y. As viewed in the thickness-wise direction z, the through hole 816 overlaps the first functional element 830. As viewed in the thickness-wise direction z, the through hole 816 is rectangular. In the present embodiment, as viewed in the thickness-wise direction z, the through hole 816 is rectangular so that the long sides extend in the first direction x and the short sides extend in the second direction y.

The shape of each recess 815 as viewed in the thickness-wise direction z may be changed in any manner. As viewed in the thickness-wise direction z, the recess 815 may be square, arc-shaped, or polygonal other than tetragonal. The shape of the through hole 816 as viewed in the thickness-wise direction z may be changed in any manner. As viewed in the thickness-wise direction z, the through hole 816 may be square, circular, elliptical, or polygonal other than tetragonal.

As shown in FIGS. 52, 54, and 55, the encapsulation resin 840 covers the entire substrate main surface 810s of the substrate 810. In other words, the encapsulation resin 840 overlaps the entire substrate 810 as viewed in the thickness-wise direction z. As shown in FIG. 55, the encapsulation resin 840 covers the inner electrodes 820 and the first functional element 830.

As shown in FIGS. 49 to 53, the encapsulation resin 840 includes a resin main surface 840s, a resin back surface 840r, and multiple (four in the present embodiment) resin side surfaces 841 to 844. The resin main surface 840s is an example of an element placement surface. The resin main surface 840s and the resin back surface 840r face in opposite directions in the thickness-wise direction z. The resin main surface 840s and the resin back surface 840r are flat. The resin main surface 840s and the substrate main surface 810s face in the same direction. The resin back surface 840r and the substrate back surface 810r face in the same direction. The resin side surfaces 841 to 844 are disposed between the resin main surface 840s and the resin back surface 840r in the thickness-wise direction z and face in the first direction x or the second direction y. The resin side surfaces 841 and 842 face in opposite directions in the second direction y and extend in the first direction x as viewed in the thickness-wise direction z. The resin side surface 841 faces in the same direction as the substrate side surface 811 in the second direction y. The resin side surface 842 faces in the same direction as the substrate side surface 812 in the second direction y. The resin side surfaces 843 and 844 face in opposite directions in the first direction x and extend in the second direction y as viewed in the thickness-wise direction z. The resin side surface 843 faces in the same direction as the substrate side surface 813 in the first direction x. The resin side surface 844 faces in the same direction as the substrate side surface 814 in the first direction x. In the present embodiment, part of the resin side surface 841 in the thickness-wise direction z is flush with the substrate side surface 811. Part of the resin side surface 842 in the thickness-wise direction z is flush with the substrate side surface 812. Part of the resin side surface 843 in the thickness-wise direction z is flush with the substrate side surface 813. Part of the resin side surface 844 in the thickness-wise direction z is flush with the substrate side surface 814.

As shown in FIGS. 49 to 52, each of the resin side surfaces 841 to 844 of the encapsulation resin 840 includes a step 845 that is recessed inward from the resin side surfaces 841 to 844. The steps 845 divide the encapsulation resin 840 into a first resin part 846 and a second resin part 847 in the thickness-wise direction z. The first resin part 846 extends from the steps 845 to the resin main surface 840s. The second resin part 847 extends from the steps 845 to the resin back surface 840r. As shown in FIGS. 49 to 52, the second resin part 847 is recessed inward from the first resin part 846.

The encapsulation resin 840 is formed from, for example, an electrically insulating resin material. An example of the resin material may be, for example, a synthetic resin including an epoxy resin as the main component. In the present embodiment, the substrate 810 and the encapsulation resin 840 are formed from the same material. The encapsulation resin 840 is, for example, colored black. The encapsulation resin 840 is formed on the substrate main surface 810s so as to cover the substrate main surface 810s of the substrate 810 by molding. Thus, the resin back surface 840r is in contact with the substrate main surface 810s. More specifically, the resin back surface 840r and the substrate main surface 810s are melted and tightly attached to each other. The resin back surface 840r and the substrate main surface 810s become an interface between the substrate 810 and the encapsulation resin 840.

As shown in FIGS. 51 and 53, an upper surface wire 870 and an insulation film 873 are disposed on the resin main surface 840s. The upper surface wire 870 is configured to be electrically connected to the second functional element 860 and forms part of a conductive path that electrically connects the second functional element 860 and the inner electrodes 820. The upper surface wire 870 is, for example, formed from Cu and formed on the resin main surface 840s. The insulation film 873 is formed from an electrically insulating material, for example, a polyimide resin.

The upper surface wire 870 includes a first upper surface electrode 871 and a second upper surface electrode 872. The first upper surface electrode 871 and the second upper surface electrode 872 are separated from each other in the first direction x. The first upper surface electrode 871 and the second upper surface electrode 872 extend in the first direction x. As viewed in the thickness-wise direction z, the first upper surface electrode 871 and the second upper surface electrode 872 are rectangular so that the long sides extend in the first direction x and the short sides extend in the second direction y.

The first upper surface electrode 871 and the second upper surface electrode 872 are exposed from the insulation film 873. In other words, the insulation film 873 covers the resin main surface 840s and part of the upper surface wire 870 excluding the first upper surface electrode 871 and the second upper surface electrode 872.

As shown in FIGS. 52 and 55, the inner electrodes 820 include multiple (sixteen in the present embodiment) main surface wires 821, multiple (sixteen in the present embodiment) through wires 822, and multiple (two in the present embodiment) connection conductors 823. The main surface wires 821 are electrically connected to the through wires 822 and the connection conductors 823. Thus, the main surface wires 821, the through wires 822, and the connection conductors 823 are electrically connected to each other. In the description hereafter, for the sake of convenience, to distinguish between the two connection conductors 823, one of the connection conductors 823 is referred to as the first connection conductor 823A, and the other one of the connection conductors 823 is referred to as the second connection conductor 823B.

The through wires 822 connect the outer electrodes 850 to the main surface wires 821 and are disposed in the recesses 815 and the through hole 816. As shown in FIG. 52, the through wires 822 arranged in the four recesses 815 of the substrate side surface 811 are formed outward from the first functional element 830 in the second direction y. The through wires 822 arranged in the four recesses 815 of the substrate side surface 812 are formed outward from the first functional element 830 in the second direction y. The through wires 822 arranged in the four recesses 815 of the substrate side surface 813 are formed outward from the first functional element 830 in the first direction x. The through wires 822 arranged in the four recesses 815 of the substrate side surface 814 are formed outward from the first functional element 830 in the first direction x. Thus, the through wires 822 do not overlap the first functional element 830 as viewed in the thickness-wise direction z.

For each through wire 822 arranged in the recesses 815 of the substrate 810, the positional relationship between the through wire 822 and the first functional element 830 as viewed in the thickness-wise direction z may be changed in any manner. In an example, as viewed in the thickness-wise direction z, part of the through wire 822 may overlap the first functional element 830. It is preferred that the through wire 822 extends to an outer side of the first functional element 830 in a direction orthogonal to the thickness-wise direction z.

In the present embodiment, the through wires 822 are provided separately from the main surface wires 821. The shapes of the through wires 822 as viewed in the thickness-wise direction z are determined in accordance with the shapes of the recesses 815 and the through hole 816 as viewed in the thickness-wise direction z. In the present embodiment, as viewed in the thickness-wise direction z, the through wires 822 are rectangular. The through wires 822 are formed from an electrically conductive material. For example, Cu or an alloy of Cu may be used as the material of the through wires 822. In the present embodiment, the through wires 822 each include a plated layer.

As shown in FIG. 55, each through wire 822 includes a main surface 822s, a back surface 822r, and multiple (four in the present embodiment) side surfaces 822x. The through wire 822 extends through the substrate 810 in the thickness-wise direction z.

The main surface 822s and the back surface 822r face in opposite directions in the thickness-wise direction z. The main surface 822s faces in the same direction as the substrate main surface 810s. In the present embodiment, the main surface 822s is flush with the substrate main surface 810s. The back surface 822r faces in the same direction as the substrate back surface 810r. In the present embodiment, the back surface 822r is flush with the substrate back surface 810r. The main surface 822s is exposed from the substrate main surface 810s. The back surface 822r is exposed from the substrate back surface 810r.

The side surfaces 822x are disposed between the main surface 822s and the back surface 822r in the thickness-wise direction z and face in the first direction x or the second direction y. One of the four side surfaces 822x of the through wire 822 arranged in each recess 815 is exposed from the substrate side surfaces 811 to 814 of the substrate 810 and defines an exposed side surface 822xa. The four side surfaces 822x of the through wire 822 arranged in the through hole 816 are surrounded by the substrate 810. That is, the four side surfaces 822x of the through wire 822 arranged in the through hole 816 are not exposed.

The main surface wires 821 are formed on the substrate main surface 810s of the substrate 810. In other words, the main surface wires 821 are disposed on the second resin part 847 of the encapsulation resin 840. The main surface wires 821 are formed from an electrically conductive material. For example, Cu or an alloy of Cu may be used as the material of the main surface wires 821. In the present embodiment, the main surface wires 821 each include a plated layer.

The main surface wires 821 include main surface wires 821 that extend in the first direction x and main surface wires 821 that extend in the second direction y. The main surface wires 821 extending in the first direction x are separated from each other in the second direction y. The main surface wires 821 extending in the second direction y are separated from each other in the first direction x. The thickness of the main surface wires 821 (dimension of the main surface wires 821 in the thickness-wise direction z) is less than the thickness of the through wires 822 (dimension of the through wires 822 in the thickness-wise direction z). In other words, the thickness of the through wires 822 is greater than the thickness of the main surface wires 821.

The main surface wires 821 each include a wire main surface 821s, a wire back surface 821r, and wire side surfaces 821x. The wire main surface 821s and the substrate main surface 810s face in the same direction. The wire back surface 821r faces in the same direction as the substrate back surface 810r and faces the substrate main surface 810s. The wire side surfaces 821x are disposed between the wire main surface 821s and the wire back surface 821r in the thickness-wise direction z and face in the same direction as the substrate side surfaces 811 to 814. The wire side surfaces 821x include a wire side surface 821xa that faces in the same direction as the exposed side surface 822xa of the through wire 822. The wire side surface 821xa is exposed from one of the resin side surfaces 841 to 844. The wire side surface 821xa is flush with the exposed side surface 822xa.

As shown in FIG. 55, the main surface wire 821 is disposed to cover the through wire 822 from above. Thus, the wire back surface 821r is in contact with the main surface 822s of the through wire 822. This electrically connects the main surface wire 821 and the through wire 822. As described above, the through wire 822 extends from the wire back surface 821r to the substrate back surface 810r in the thickness-wise direction z and is exposed from the substrate back surface 810r.

The main surface wires 821 extending in the first direction x each include an inward part 821p. The inward part 821p extends in the first direction x to an inner side of the substrate 810 from the through wire 822 disposed in the recess 815 of the substrate 810. The main surface wires 821 extending in the second direction y each include an inward part 821p. The inward part 821p extends in the second direction y to an inner side of the substrate 810 from the through wire 822 disposed in the recess 815. The distal end of each inward part 821p overlaps the peripheral part of the first functional element 830 as viewed in the thickness-wise direction z.

Each main surface wire 821 includes a main surface wire 821 that is electrically connected to the through wire 822 disposed in the through hole 816 of the substrate 810. The main surface wire 821 covers the main surface 822s of the through wire 822. The dimensions of the main surface wire 821 in the first direction x and the second direction y are the same as the dimensions of the through wire 822 in the first direction x and the second direction y.

As shown in FIG. 56, the main surface wire 821 includes a metal layer 821a and a conductive layer 821b. The metal layer 821a and the conductive layer 821b are stacked in this order on the substrate main surface 810s.

The metal layer 821a includes, for example, a titanium (Ti) layer that is in contact with the substrate main surface 810s and the main surface 822s of the through wire 822 and a Cu layer that is in contact with the Ti layer. The metal layer 821a is formed as a seed layer that forms the conductive layer 821b. The metal layer 821a includes an upper surface 821as and a lower surface 821ar facing in opposite directions in the thickness-wise direction z. The lower surface 821ar defines the wire back surface 821r of the main surface wire 821.

The conductive layer 821b is formed on the upper surface 821as of the metal layer 821a. The conductive layer 821b is formed from Cu or an alloy of Cu. The conductive layer 821b includes an upper surface 821bs and a lower surface 821br facing in opposite directions in the thickness-wise direction z. In the present embodiment, the lower surface 821br of the conductive layer 821b is in contact with the upper surface 821as of the metal layer 821a. The upper surface 821bs of the conductive layer 821b is covered by the second resin part 847 of the encapsulation resin 840. The upper surface 821bs of the conductive layer 821b defines the wire main surface 821s of the main surface wire 821.

As shown in FIG. 55, the first connection conductor 823A extends in the thickness-wise direction z from the wire main surface 821s of one of the main surface wires 821 located toward the substrate side surface 811 in the first direction x. As shown in FIG. 52, the first connection conductor 823A is connected to one of the main surface wires 821 located closest to the substrate side surface 814 in the second direction y among the main surface wires 821 located toward the substrate side surface 811 in the first direction x. As shown in FIG. 55, the second connection conductor 823B extends in the thickness-wise direction z from the wire main surface 821s of one of the main surface wires 821 located toward the substrate side surface 812. As shown in FIG. 52, the second connection conductor 823B is connected to one of the main surface wires 821 located closest to the substrate side surface 813 in the second direction y among the main surface wires 821 located toward the substrate side surface 812 in the first direction x.

Each of the connection conductors 823A and 823B is located on the inward part 821p of the main surface wire 821 at a position closer to the through wire 822 than the first functional element 830. Each of the connection conductors 823A and 823B is located inward from the through wire 822 as viewed in the thickness-wise direction z. More specifically, as shown in FIG. 55, each of the connection conductors 823A and 823B is located on the inward part 821p of the main surface wire 821 at a position between the through wire 822 and the first functional element 830 as viewed in the thickness-wise direction z.

As shown in FIGS. 52 and 53, as viewed in the thickness-wise direction z, each of the connection conductors 823A and 823B is rectangular. That is, each of the connection conductors 823A and 823B is a prism. The shape of the connection conductors 823A and 823B is not limited to a prism and may be, for example, a cylinder or a polygonal rod. The connection conductors 823A and 823B are formed from an electrically conductive material. For example, Cu or an alloy of Cu may be used as the material of the connection conductors 823A and 823B. In the present embodiment, the connection conductors 823A and 823B each include a plated layer.

As shown in FIG. 55, the connection conductors 823A and 823B each include an upper surface 823s, a lower surface 823r, and side surfaces 823x. The upper surfaces 823s of the connection conductors 823A and 823B face in the same direction as the substrate main surface 810s. The lower surfaces 823r of the connection conductors 823A and 823B face in the same direction as the substrate back surface 810r. The side surfaces 823x of the connection conductors 823A and 823B are disposed between the upper surface 823s and the lower surface 823r in the thickness-wise direction z and face in the first direction x or the second direction y. The side surfaces 823x of the connection conductors 823A and 823B are entirely covered by the encapsulation resin 840.

The lower surfaces 823r of the connection conductors 823A and 823B are in contact with the wire main surface 821s of the main surface wires 821. The lower surfaces 823r are flat.

The connection conductors 823A and 823B extend from the wire main surface 821s to the resin main surface 840s in the thickness-wise direction z. Thus, the upper surfaces 823s of the connection conductors 823A and 823B are exposed from the resin main surface 840s. In the present embodiment, as shown in FIG. 58, the upper surface 823s of the first connection conductor 823A is curvedly recessed. Although not shown in the drawings, the upper surface 823s of the second connection conductor 823B is curvedly recessed in the same manner.

As shown in FIG. 53, the first connection conductor 823A is electrically connected to the first upper surface electrode 871 of the upper surface wire 870. More specifically, the upper surface 823s of the first connection conductor 823A overlaps the first upper surface electrode 871 of the upper surface wire 870 as viewed in the thickness-wise direction z and is in contact with the first upper surface electrode 871. The second connection conductor 823B is electrically connected to the second upper surface electrode 872 of the upper surface wire 870. More specifically, the upper surface 823s of the second connection conductor 823B overlaps the second upper surface electrode 872 of the upper surface wire 870 as viewed in the thickness-wise direction z and is in contact with the second upper surface electrode 872. Thus, the upper surface wire 870 is electrically connected to the connection conductors 823.

As shown in FIG. 56, the first connection conductor 823A includes a seed layer 823a and a plated layer 823b stacked on each other. The seed layer 823a includes a first layer that is in contact with the upper surface 821bs of the conductive layer 821b (the wire main surface 821s of the main surface wire 821) and a second layer that is in contact with the first layer. The main component of the first layer is, for example, Ti. The main component of the second layer is, for example, Cu. The thickness of the seed layer 823a (dimension of the seed layer 823a in the thickness-wise direction z) is approximately greater than or equal to 200 nm and less than or equal to 8800 nm. The main component of the plated layer 823b is Cu.

The seed layer 823a includes an upper surface 823as and a lower surface 823ar facing in opposite directions in the thickness-wise direction z. The upper surface 823as faces in the same direction as the substrate main surface 810s. The lower surface 823ar faces in the same direction as the substrate back surface 810r. The lower surface 823ar of the seed layer 823a defines the lower surface 823r of the connection conductor 823.

The plated layer 823b includes an upper surface 823bs and a lower surface 823br facing in opposite directions in the thickness-wise direction z. The upper surface 823bs faces in the same direction as the substrate main surface 810s. The lower surface 823br faces in the same direction as the substrate back surface 810r. The lower surface 823br of the plated layer 823b is in contact with the upper surface 823as of the seed layer 823a. The upper surface 823bs of the plated layer 823b defines the upper surface 823s of the connection conductor 823. The second connection conductor 823B has the same structure as the first connection conductor 823A shown in FIG. 56.

As shown in FIGS. 49 and 52, the first functional element 830 is a flat chip component. The first functional element 830 includes a semiconductor element. In the present embodiment, the first functional element 830 is, for example, an integrated circuit (IC) such as a large scale integration (LSI). More specifically, the first functional element 830 is a switched-mode power supply LSI. The first functional element 830 may be a voltage-controlling element such as a low dropout (LDO) regulator, an amplifying element such as an operational amplifier, or a discrete semiconductor element such as a diode or various sensors.

As shown in FIGS. 49 and 55, the first functional element 830 is smaller in size than the second functional element 860. More specifically, the dimension of the first functional element 830 in the thickness-wise direction z is smaller than the dimension of the second functional element 860 in the thickness-wise direction z. The dimension of the first functional element 830 in the thickness-wise direction z is greater than or equal to 100 μm and less than or equal to 300 μm. When the first functional element 830 is an LSI, the dimension of the LSI in the thickness-wise direction z is, for example, approximately 100 μm. The dimension of the first functional element 830 in the first direction x is smaller than the dimension of the second functional element 860 in the first direction x. The dimension of the first functional element 830 in the second direction y is smaller than the dimension of the second functional element 860 in the second direction y.

As viewed in the thickness-wise direction z, the first functional element 830 is substantially square. As shown in FIG. 55, the first functional element 830 includes an element main surface 830s and an element back surface 830r facing in opposite directions in the thickness-wise direction z. A component for the function of the first functional element 830 is formed on the element main surface 830s. The element main surface 830s faces in the same direction as the substrate back surface 810r of the substrate 810. The element back surface 830r faces in the same direction as the substrate main surface 810s of the substrate 810.

The first functional element 830 includes an element substrate 831, electrode pads 832, a wire 833, an insulation film 834A, and a protective film 834B.

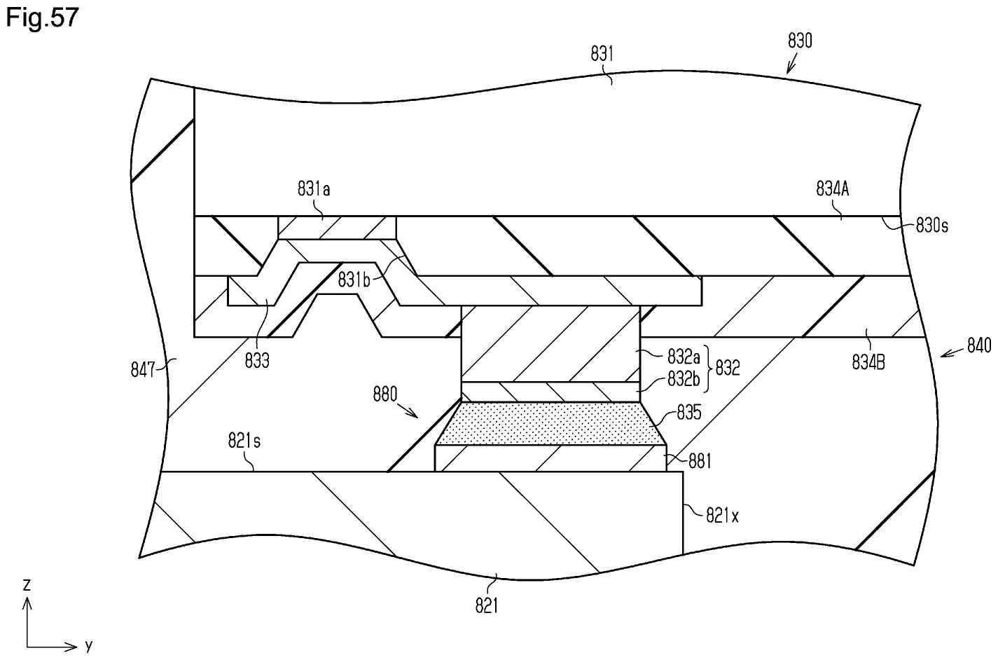

As shown in FIG. 57, the element substrate 831 includes an electrode 831a and a recess 831b in which the electrode 831a is exposed. The element substrate 831 includes multiple electrodes 831a and multiple recesses 831b.

The insulation film 834A covers a surface (element main surface 830s) of the element substrate 831. The recess 831b is formed by a hole extending through the insulation film 834A in the thickness-wise direction z. In the present embodiment, the insulation film 834A is formed from an electrically insulating material, for example, SiO₂ (silicon oxide). The insulation film 834A covers part of the electrode pad 832 and exposes part of the surface of the electrode pad 832 as a connection terminal. The insulation film 834A may be formed from SiN (silicon nitride).

Multiple wires 833 are formed on the element main surface 830s and separately connected to the electrodes 831a. Each wire 833 is formed on the insulation film 834A. The wire 833 is also formed in the recess 831b and connected to the electrode 831a. The wire 833 is formed from, for example, Cu.

The protective film 834B covers a surface of the insulation film 834A and a surface of each wire 833. The protective film 834B also covers a peripheral portion of each electrode pad 832. That is, the electrode pad 832 projects downward from the protective film 834B. The protective film 834B is formed from an electrically insulating material, for example, a polyimide resin.

Each electrode pad 832, which is a terminal configured to be electrically connected to the main surface wire 821, is connected to the wire 833. Thus, the electrodes 831a of the element substrate 831 are electrically connected to the main surface wires 821 by the electrode pads 832 and the wires 833.

The electrode pads 832 and the recesses 831b are located at different positions in a direction orthogonal to the thickness-wise direction z (planar direction of the element main surface 830s). The electrode pads 832 each include a conductive portion 832a and a barrier layer 832b stacked on each other in the thickness-wise direction z. The conductive portion 832a is formed from, for example, Cu. The barrier layer 832b is formed of a Ni layer. The barrier layer 832b is formed so as to cover a distal surface of the conductive portion 832a. A solder layer 835 is formed on an end surface of the barrier layer 832b that is opposite in the thickness-wise direction z from the end surface of the barrier layer 832b on which the conductive portion 832a is formed. In the electrode pads 832, the barrier layer 832b hinders the conductive portion 832a, which is formed from Cu, from permeating through the solder layer 835. The barrier layer 832b may be formed by stacking a Ni layer, a Pd (palladium) layer, and a Au (gold) layer. The barrier layer 832b may be omitted.

As shown in FIG. 57, a barrier layer 881 is formed on a portion of the wire main surface 821s of the main surface wire 821 that faces the solder layer 835 in the thickness-wise direction z. The barrier layer 881 is formed of a Ni layer. The barrier layer 881 limits the wetting and spreading of the solder layer 835. The barrier layer 881 may be formed by stacking a Ni layer, a Pd layer, and a Au layer. Thus, the solder layer 835 and the barrier layer 881 form a bonding portion 880 that bonds the main surface wire 821 to the electrode pad 832 of the first functional element 830.

As shown in FIG. 55, the first functional element 830 is connected to the main surface wire 821 by the solder layer 835. The solder layer 835 is formed from Su (tin) or an alloy including Sn. The alloy is, for example, a Sn—Ag-based alloy or a Sn—Sb (antimony)-based alloy. As described above, when the electrode pads 832 are bonded to the main surface wires 821 by the solder layer 835, the first functional element 830 is mounted on the main surface wires 821.

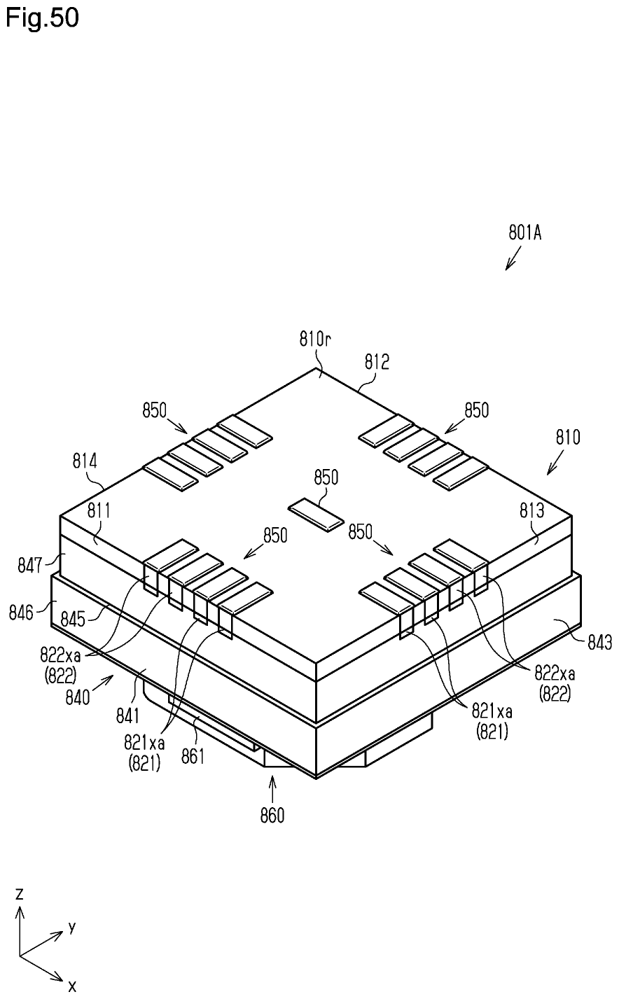

As shown in FIGS. 50, 52, and 54, the outer electrodes 850 are used as external connection terminals of the electronic component 801A that are connected to a wiring substrate. The outer electrodes 850 each includes, for example, metal layers stacked on one another. The metal layers are, for example, an Ni layer, a Pd layer, and a Au layer.

The outer electrodes 850 are arranged in accordance with the through wires 822. More specifically, as shown in FIG. 52, outer electrodes 850 are respectively arranged on the four through wires 822 arranged close to the substrate side surface 811 and separated from each other in the first direction x. In this case, the four outer electrodes 850 are separated from each other in the first direction x. Outer electrodes 850 are respectively arranged on the four through wires 822 arranged close to the substrate side surface 812 and separated from each other in the first direction x. In this case, the four outer electrodes 850 are separated from each other in the first direction x. Outer electrodes 850 are respectively arranged on the four through wires 822 arranged close to the substrate side surface 813 and separated from each other in the second direction y. In this case, the four outer electrodes 850 are separated from each other in the second direction y. Outer electrodes 850 are respectively arranged on the four through wires 822 arranged close to the substrate side surface 814 and separated from each other in the second direction y. In this case, the four outer electrodes 850 are separated from each other in the second direction y. Outer electrodes 850 are arranged on the through wires 822 arranged on the center of the substrate back surface 810r in the first direction x and the second direction y. The outer electrodes 850 respectively cover the back surface 822r of the through wires 822.

As shown in FIG. 55, the second functional element 860 has a relatively large dimension in the thickness-wise direction z and is, for example, a resistor, a capacitor, an inductor, or a diode. In the present embodiment, the second functional element 860 is an inductor used for a power supply circuit, that is, a power supply inductor. In the illustrated example, the second functional element 860 includes a winding metal alloy capable of being used with high current and encapsulated by an encapsulation resin. The second functional element 860 includes a first electrode 861 and a second electrode 862. In the illustrated example, the second functional element 860 is a surface-mount-type package. The dimension of the second functional element 860 in the first direction x is approximately 6.6 mm. The dimension of the second functional element 860 in the second direction y is approximately 7.0 mm. The dimension of the second functional element 860 in the thickness-wise direction z is approximately 3.0 mm.

When the second functional element 860 is an inductor, the configuration of the inductor is not limited to that described above. For example, a winding ferrite inductor or a multilayer ferrite inductor may be used. The shape of the inductor is not limited to that of the illustrated example and may be flat and rectangular or box-shaped and square as viewed in the thickness-wise direction z.

As shown in FIGS. 51 and 55, the second functional element 860 is connected to the upper surface wire 870. More specifically, the first electrode 861 of the second functional element 860 is bonded to the first upper surface electrode 871 of the upper surface wire 870 by the solder SD. The second electrode 862 of the second functional element 860 is bonded to the second upper surface electrode 872 of the upper surface wire 870 by the solder SD. Thus, the second functional element 860 is electrically connected to the first functional element 830. As shown in FIG. 55, the inner electrodes 820 and the upper surface wire 870 form a conductive path that electrically connects the first functional element 830 and the second functional element 860. Also, the inner electrodes 820 and the upper surface wire 870 electrically connect the second functional element 860 to the outer electrodes 850.

In the present embodiment, the electronic component 801A is a power supply module in which the second functional element 860, or an inductor, is electrically connected to the first functional element 830, or a switched-mode power supply LSI. The electronic component 801A is used for a power supply circuit. Since the switched-mode power supply LSI and the inductor are modularized in the electronic component 801A, the power supply circuit is reduced in size.

Manufacturing Method of Electronic Component

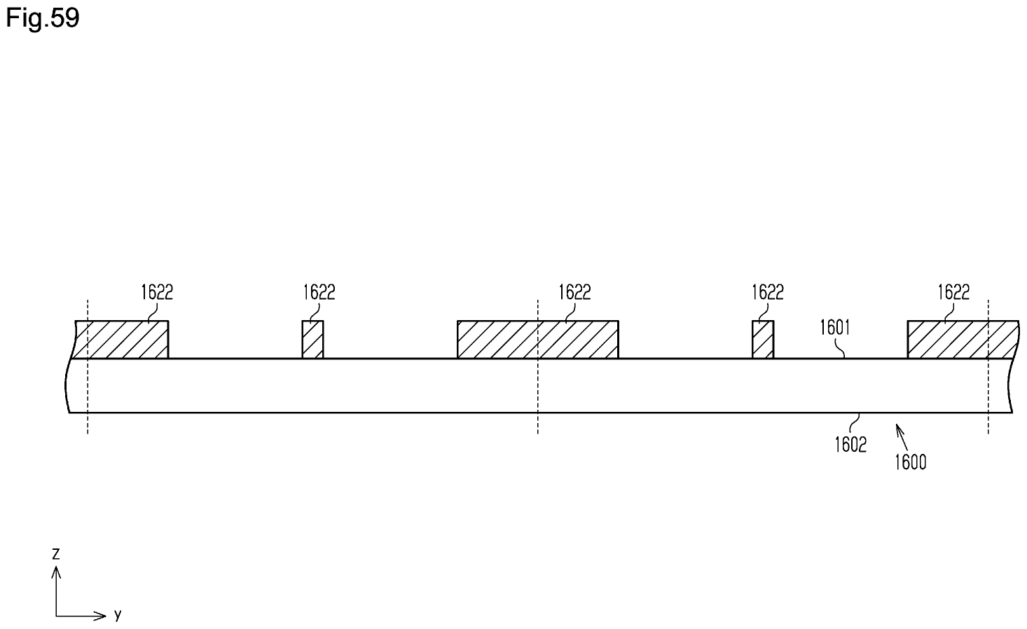

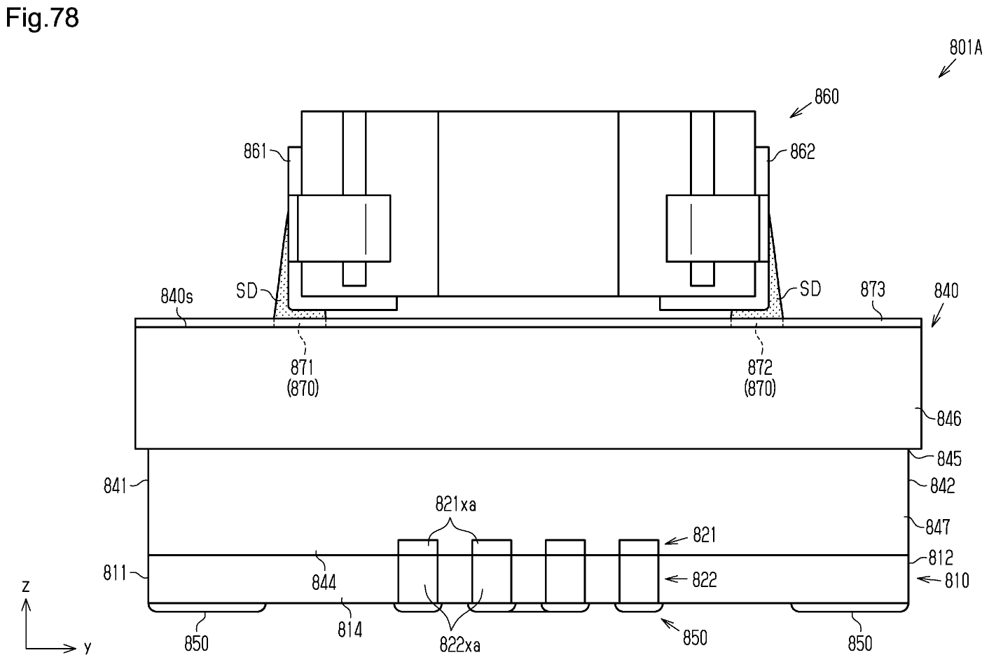

A method for manufacturing the electronic component 801A of the seventh embodiment according to the present disclosure will now be described with reference to FIGS. 59 to 78. In FIGS. 59 to 62, 64, 65, 67, and 69 to 73, two adjacent broken lines define a range in which one electronic component 801A is formed. The definition of directions shown in FIGS. 59 to 78 is the same as the definition of directions shown in FIGS. 49 to 58.

As shown in FIG. 59, a method for manufacturing the electronic component 801A includes a step of preparing a support substrate 1600. The support substrate 1600 is formed from, for example, a monocrystalline intrinsic semiconductor. The support substrate 1600 is formed from, for example, a monocrystalline silicon material. The support substrate 1600 includes an upper surface 1601 and a lower surface 1602 facing in opposite directions in the thickness-wise direction z. Alternatively, a substrate formed from a composite resin material such as an epoxy resin may be used as the support substrate 1600.

The method for manufacturing the electronic component 801A includes a step of forming terminal pillars 1622 on the upper surface 1601 of the support substrate 1600. The terminal pillars 1622 are formed from, for example, Cu or an alloy of Cu through an electrolytic plating process.

More specifically, the terminal pillars 1622 are formed by performing, for example, a step of forming a seed layer, a step of forming a mask on the seed layer through photolithography, and a step of forming the terminal pillars 1622 that contact the seed layer. More specifically, the seed layer is formed on the upper surface 1601 of the support substrate 1600 through, for example, sputtering. Next, for example, the seed layer is covered by a photosensitive resist layer, and the resist layer undergoes reaction with light and development to form a mask having openings. An electrolytic plating process that uses the seed layer as a conductive path is performed so that plated metal deposits on the surface of the seed layer exposed from the mask. This forms the terminal pillars 1622. After the terminal pillars 1622 are formed, the mask is removed. Alternatively, the terminal pillars 1622 may be formed of copper columnar members.

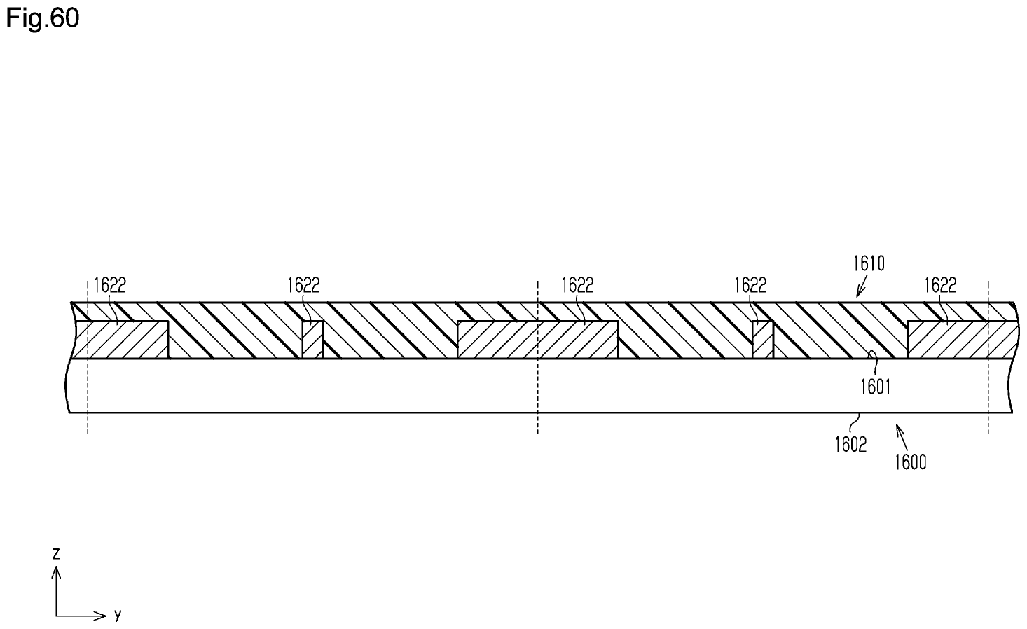

The method for manufacturing the electronic component 801A includes a step of forming a base member 1610, which is an example of an insulation layer. More specifically, as shown in FIG. 60, the base member 1610 is in contact with the upper surface 1601 of the support substrate 1600 and covers the terminal pillars 1622. The base member 1610 covers the upper surface of the terminal pillars 1622. The material of the base member 1610 may be the material forming the substrate 810 shown in FIG. 49. In the present embodiment, the material of the base member 1610 may be a synthetic resin, the main component of which is an epoxy resin or the like. That is, the method for manufacturing the electronic component 801A includes an insulation layer forming step.

The method for manufacturing the electronic component 801A includes a step of grinding the base member 1610 and the terminal pillars 1622. More specifically, the base member 1610 and the terminal pillars 1622 are partially ground so that the terminal pillars 1622 are exposed on an upper surface 1611 of the base member 1610. In this step, the main surface 822s of the through wires 822 is defined by an upper surface 1622s of the terminal pillars 1622. Also, in this step, the base member 1610 includes the upper surface 1611 defining an insulation main surface and a lower surface 1612 defining an insulation back surface. The base member 1610 is configured to be the substrate 810 shown in FIG. 55. The base member 1610 is ground so that the base member 1610 has the same thickness as the substrate 810. The terminal pillars 1622 have the same thickness as the through wires 822. As shown in FIG. 60, some of the terminal pillars 1622 (the terminal pillars 1622 located between broken lines adjacent to each other in the second direction y) form the through wires 822. That is, the method for manufacturing the electronic component 801A includes a step of forming the multiple through wires 822.

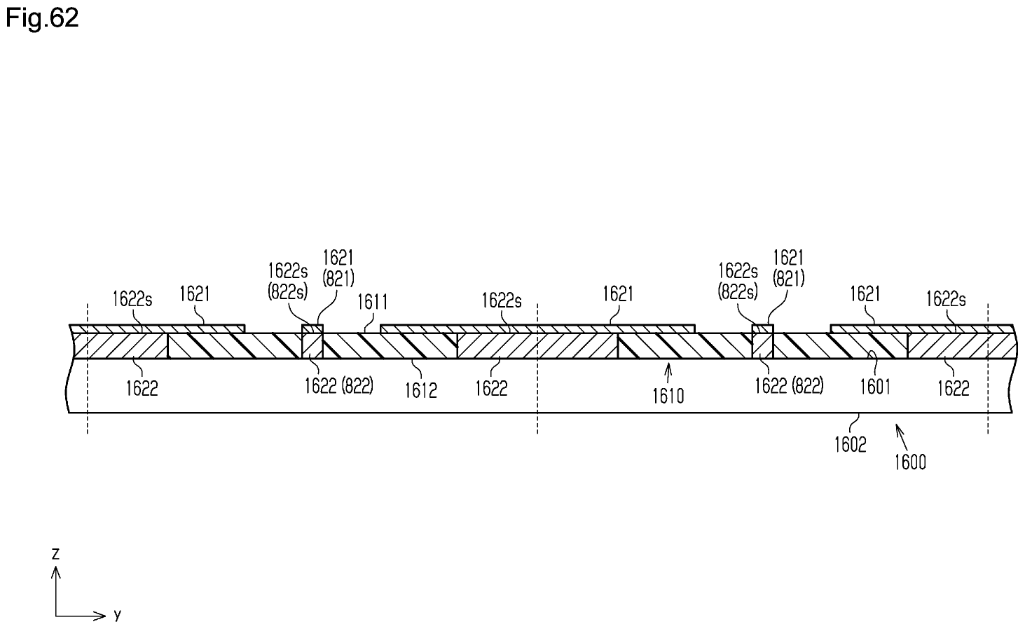

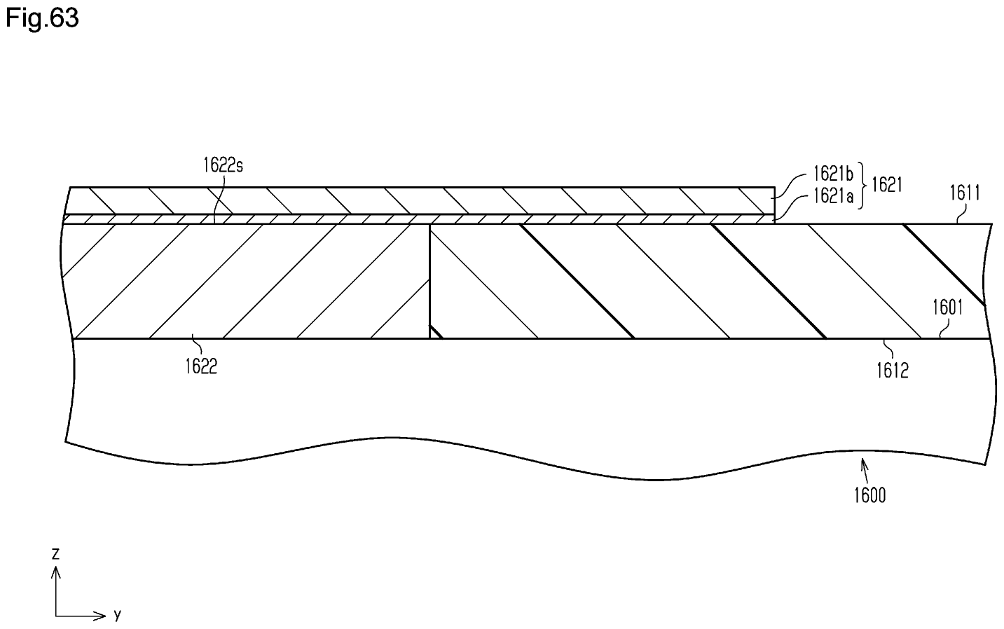

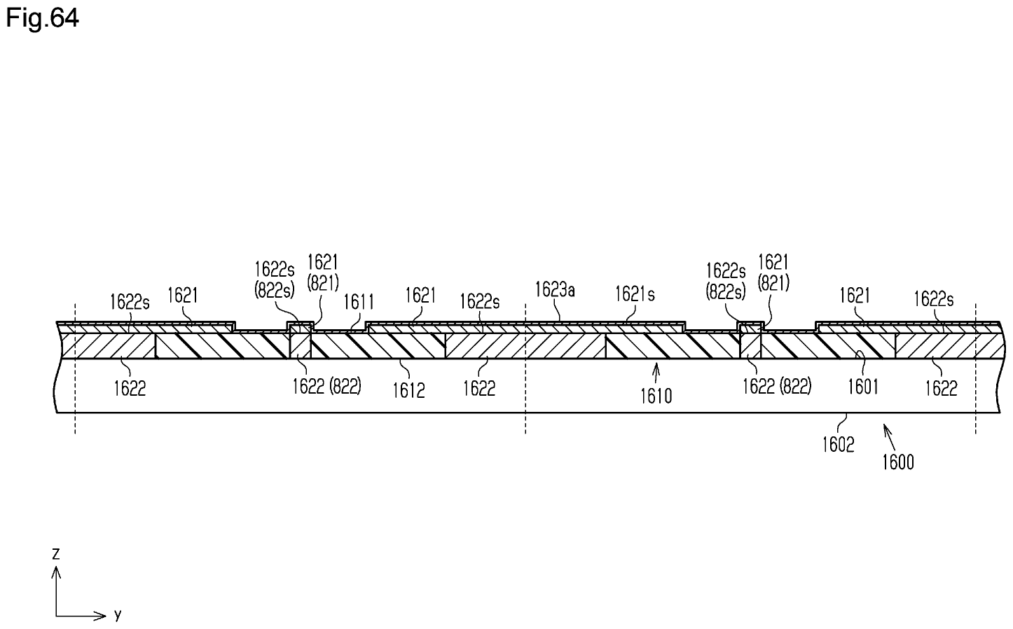

The method for manufacturing the electronic component 801A includes a step of forming a main surface wire 1621. More specifically, as shown in FIG. 62, the main surface wire 1621 is formed on the upper surface 1611 of the base member 1610 and the upper surface 1622s of the terminal pillars 1622 (the main surface 822s of the through wires 822). As shown in FIG. 63, the main surface wire 1621 includes a metal layer 1621a and a conductive layer 1621b. The main surface wire 1621 is formed by performing a step of forming the metal layer 1621a, a step of forming a mask on the metal layer 1621a through photolithography, and a step of forming the conductive layer 1621b that contacts the metal layer 1621a.

More specifically, the metal layer 1621a is formed through, for example, sputtering. For example, when the metal layer 1621a includes a Ti layer and a Cu layer, the Ti layer is formed on the upper surface 1611 of the base member 1610 and the main surface 822s of the through wires 822, and the Cu layer is formed on the Ti layer. Next, for example, the metal layer 1621a is covered by a photosensitive resist layer, and the resist layer undergoes light exposure and development to form a mask having openings. For example, an electrolytic plating process that uses the metal layer 1621a as a conductive path is performed so that plated metal deposits on the surface of the metal layer 1621a exposed from the mask to form the conductive layer 162lb. The steps described above form the main surface wire 1621. After the main surface wire 1621 is formed, the mask is removed. That is, the method for manufacturing the electronic component 801A includes a main surface wire forming step.

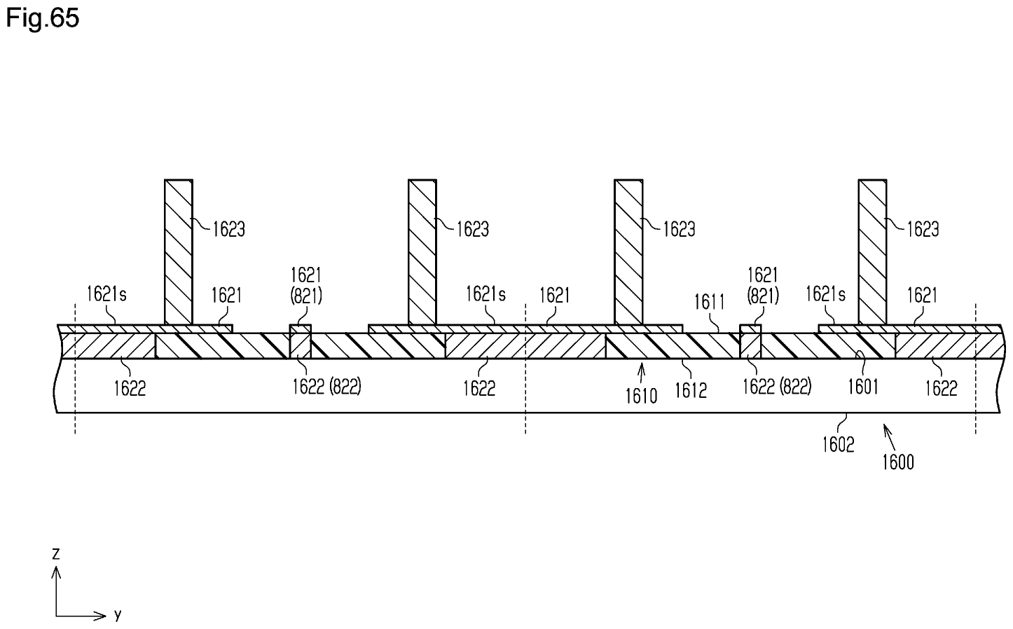

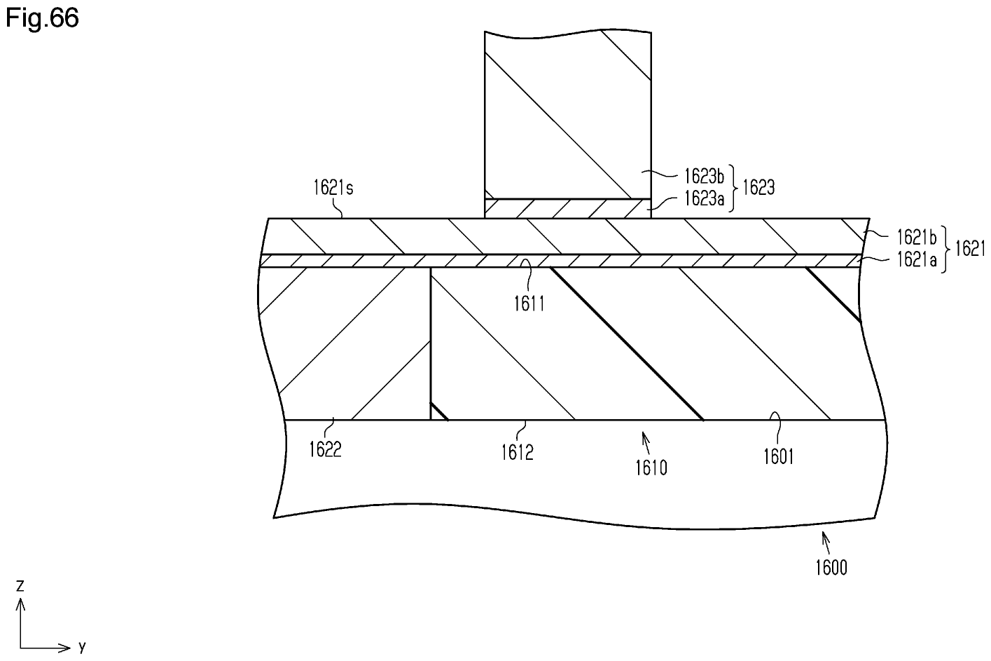

As shown in FIGS. 64 to 66, the method for manufacturing the electronic component 801A includes a step of forming connection conductors 1623. More specifically, as shown in FIGS. 65 and 66, the connection conductors 1623 are formed on an upper surface 1621s of the main surface wire 1621.

The connection conductors 1623 are formed by performing, for example, a step of forming a seed layer, a step of forming a mask on the seed layer through photolithography, and a step of forming a plated layer that contacts the seed layer.

More specifically, as shown in FIG. 64, a seed layer 1623a is formed on the upper surface 1621s of the main surface wire 1621 and the upper surface 1611 of the base member 1610 through, for example, sputtering. Next, for example, the seed layer 1623a is covered by a photosensitive resist layer, and the resist layer undergoes reaction with light and development to form a mask having openings.

As shown in FIG. 66, an electrolytic plating process that uses the seed layer 1623a as a conductive layer is performed so that plated metal deposits on the surface of the seed layer 1623a exposed from the mask. This forms a plated layer 1623b. As a result, the connection conductors 1623 including the stack of the seed layer 1623a and the plated layer 1623b are formed. After the connection conductors 1623 are formed, the mask is removed. Alternatively, the connection conductors 1623 may be formed of copper columnar members.

As shown in FIG. 66, unwanted portions of the seed layer 1623a are removed. More specifically, portions of the seed layer 1623a that are not covered by the plated layer 1623b are removed. The removal of the unwanted seed layer 1623a is performed, for example, by wet-etching using a mixture solution of H₂SO₄. That is, the method for manufacturing the electronic component 801A includes a conductor forming step.

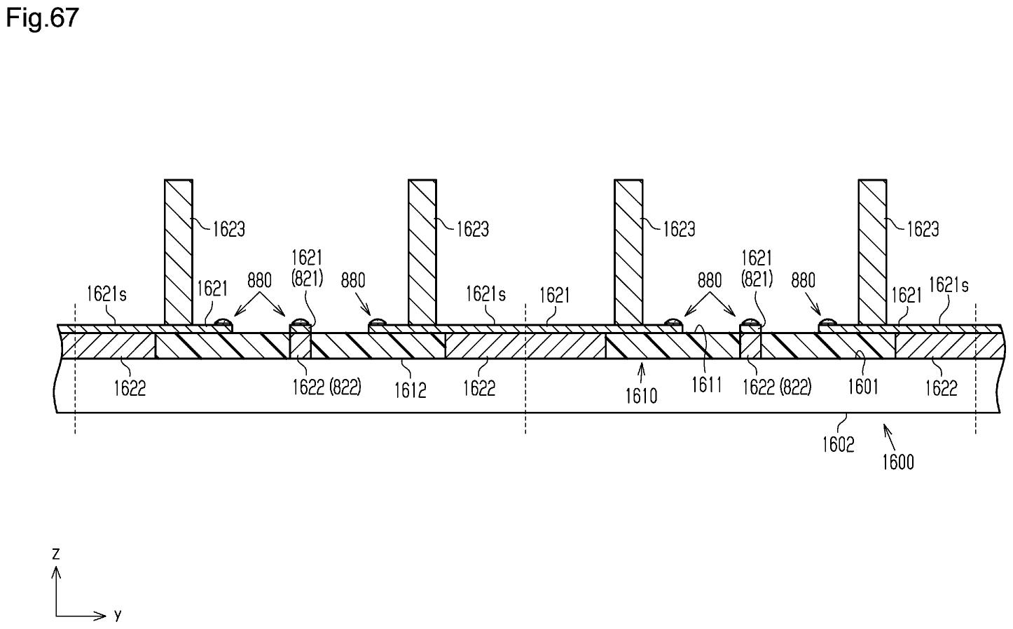

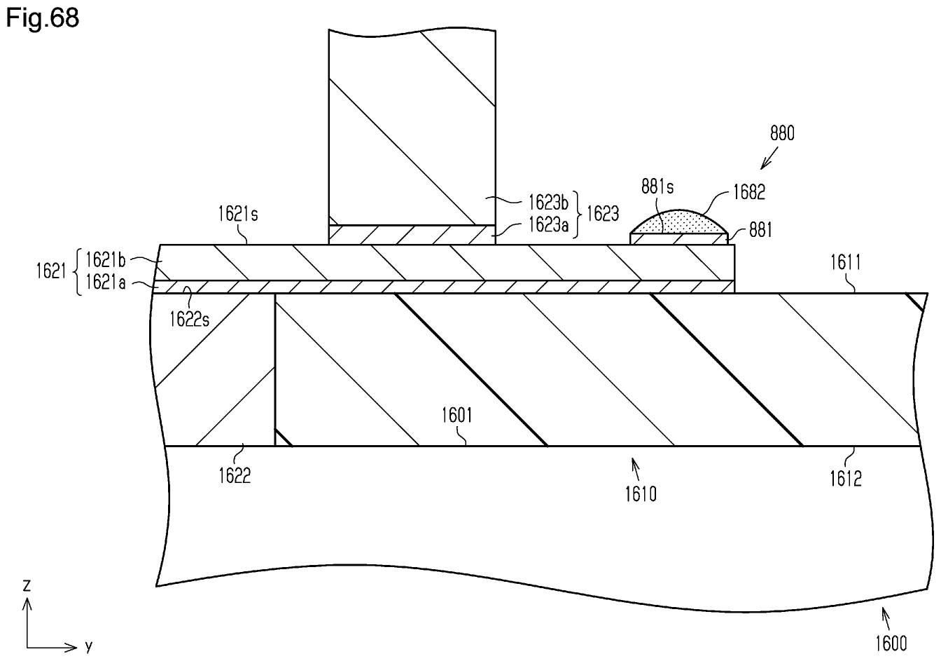

As shown in FIGS. 67 and 68, the method for manufacturing the electronic component 801A includes a step of forming bonding portions 880. More specifically, as shown in FIG. 67, the bonding portions 880 are formed on the upper surface 1621s of the main surface wire 1621. As shown in FIG. 68, the bonding portion 880 includes the barrier layer 881 and a solder layer 1682. The barrier layer 881 is formed on the upper surface 1621s of the main surface wire 1621. The barrier layer 881 may be formed through, for example, an electrolytic plating process that uses the main surface wire 1621 as a conductive path. Next, the electrolytic plating process is performed so that an alloy including Sn deposits as plated metal on an upper surface 881s of the barrier layer 881 to form the solder layer 1682. Subsequently, in the reflow process, the solder layer 1682 is melted to smooth the rough surface of the solder layer 1682. The smoothing limits formation of voids when the solder layer 1682 and the first functional element 830 are bonded by the solder layers (not shown). FIGS. 67 and 68 show the solder layer 1682 that has undergone the reflow process.

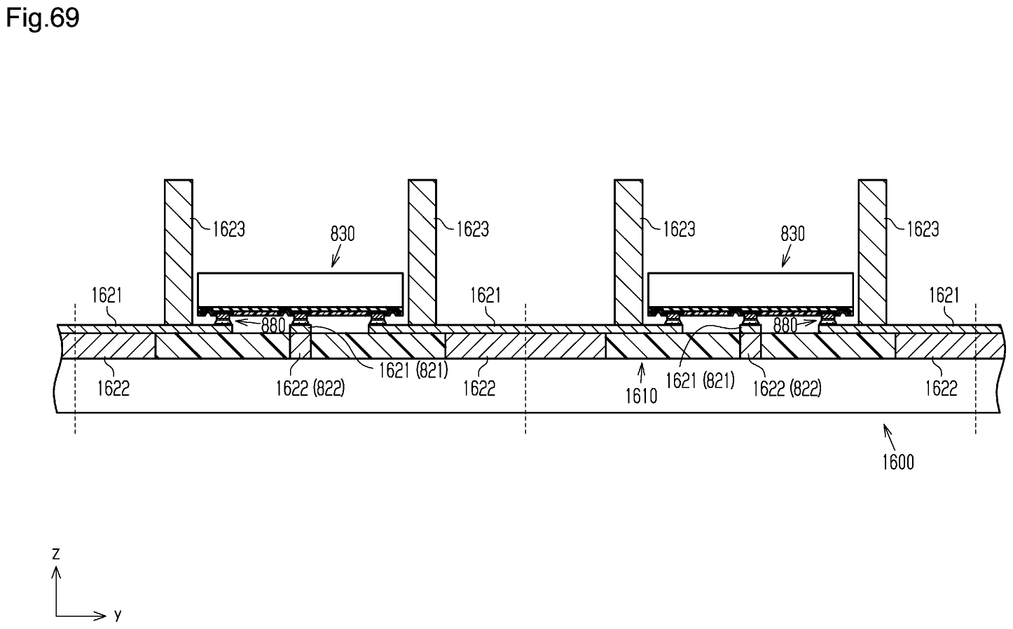

The method for manufacturing the electronic component 801A includes a step of mounting the first functional element 830. More specifically, as shown in FIG. 69, the first functional elements 830 are mounted on the main surface wire 1621. Each first functional element 830 is mounted by flip chip bonding (FCB).

More specifically, for example, an electrolytic plating process is performed so that an alloy including Sn deposits as plated metal on the barrier layer 832b of the electrode pads 832 of the first functional element 830 to form a solder layer (not shown). The solder layer is formed from the same material as that forming the solder layer 1682 (refer to FIG. 68) of the bonding portion 880. In the same manner as the solder layer 1682, the reflow process is performed to smooth the surface of the solder layer of the first functional element 830.

Next, for example, after a flux is applied to the bonding portions 880, the first functional element 830 is mounted on the bonding portions 880 using a flip-chip bonder. This temporarily attaches the first functional element 830 to the bonding portions 880. Subsequently, the solder layer 1682 of the bonding portions 880 and the solder layer of the first functional element 830 undergo a phase change to a liquid state in the reflow process, and then the solder layer 1682 of the bonding portions 880 and the solder layer of the first functional element 830 are cooled and solidified. As a result, the first functional element 830 is connected to the bonding portions 880. Thus, the solder layer 835 shown in FIG. 57 includes the solder layer 1682 of the bonding portions 880 and the solder layer of the first functional element 830. That is, the method for manufacturing the electronic component 801A includes a first element mounting step.

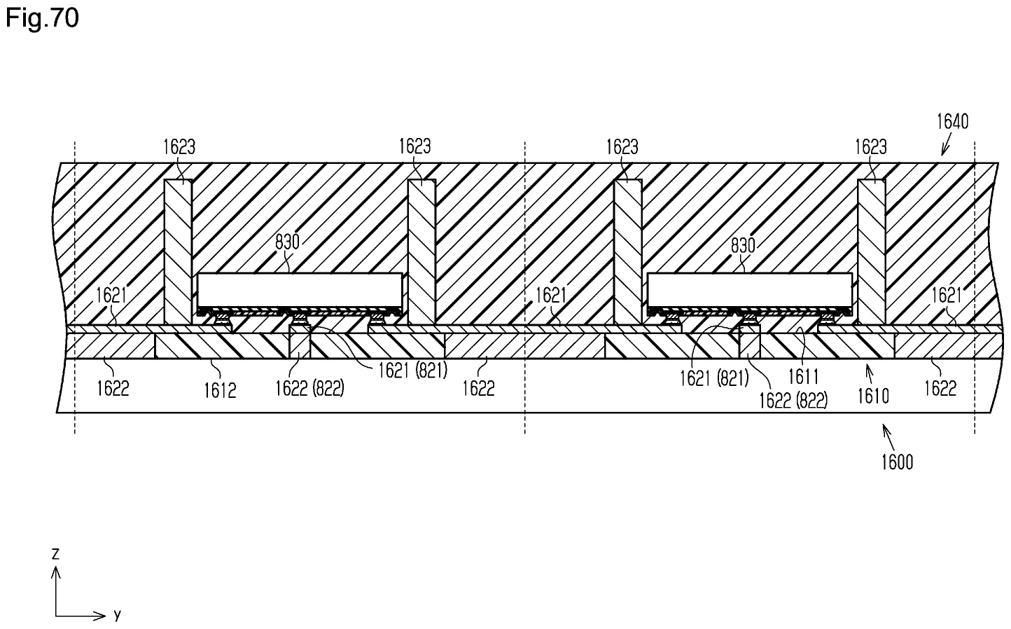

The method for manufacturing the electronic component 801A includes a step of forming a resin layer 1640. More specifically, as shown in FIG. 70, the resin layer 1640 is formed to cover the upper surface 1611 of the base member 1610, the main surface wire 1621, the connection conductors 1623, and the first functional elements 830. The resin layer 1640 is a member that will be the encapsulation resin 840 shown in FIG. 49. The resin layer 1640 is, for example, a synthetic resin, the main material of which is an epoxy resin. The resin layer 1640 is formed, for example, by transfer molding. That is, the method for manufacturing the electronic component 801A includes a resin layer forming step.

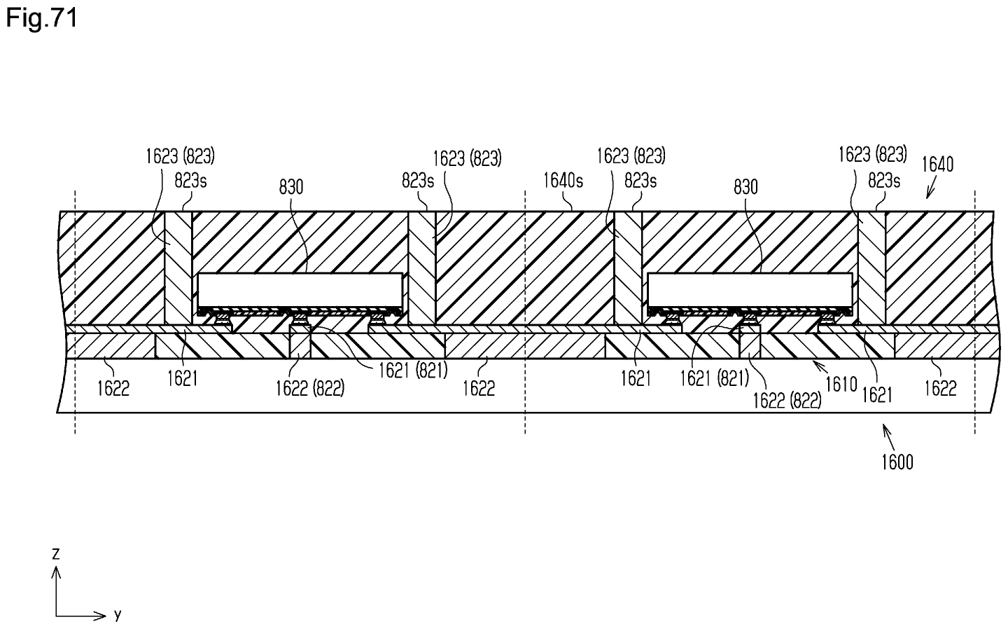

The method for manufacturing the electronic component 801A includes a step of grinding the resin layer 1640 and the connection conductors 1623 to reduce the thickness of the resin layer 1640 and the connection conductors 1623. More specifically, as shown in FIG. 71, for example, a resin main surface 1640s of the resin layer 1640 is ground by chemical mechanical polishing (CMP) using an abrasive (abrasive grains) until the connection conductors 1623 are exposed from the resin layer 1640. In this step, the resin main surface 1640s of the resin layer 1640 and the upper surface of the connection conductors 1623 are ground until the dimension of the connection conductors 1623 in the thickness-wise direction z reaches a predetermined dimension. As a result, the connection conductors 823 are formed. FIG. 71 shows a ground state. As shown in FIG. 71, the upper surface 823s of the connection conductors 823 is exposed from the resin main surface 1640s of the resin layer 1640. In this step, the upper surface 823s of the connection conductors 823 has the same shape as the upper surface 823s of the connection conductors 823 shown in FIG. 58. Also, the resin main surface 1640s of the resin layer 1640 has the same shape as the resin main surface 40s of the encapsulation resin 840 shown in FIG. 58. That is, ground marks are formed in the resin main surface 1640s by grinding. The resin main surface 1640s corresponds to a ground surface of the resin layer 1640. That is, the method for manufacturing the electronic component 801A includes a resin layer grinding step.

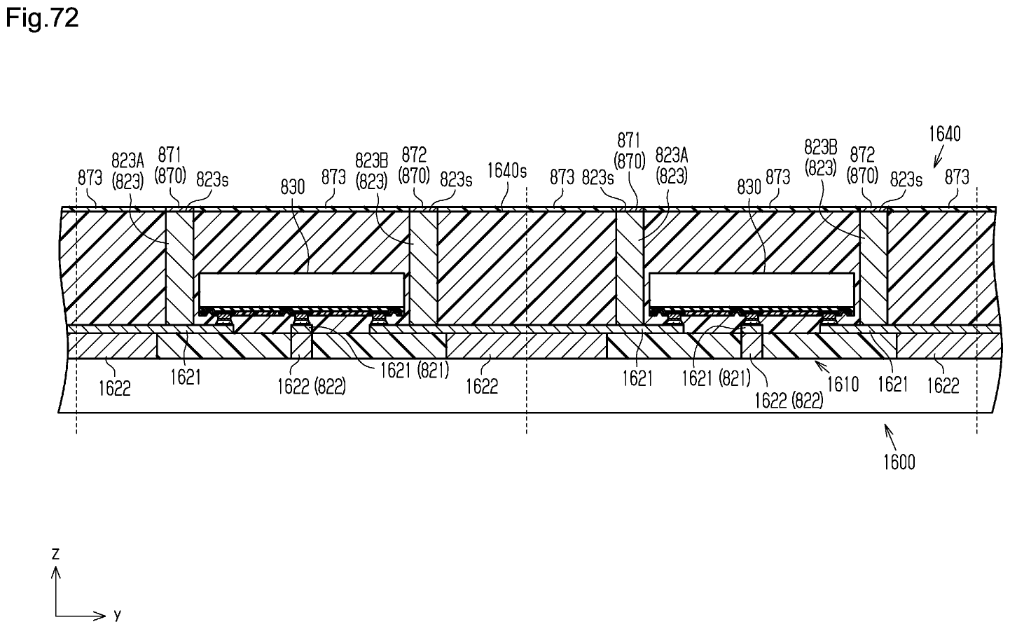

The method for manufacturing the electronic component 801A includes a step of forming the upper surface wire 870 and the insulation film 873. More specifically, as shown in FIG. 72, the upper surface wire 870 is formed on the resin main surface 1640s of the resin layer 1640 and the upper surface 823s of the connection conductors 823. In other words, this step forms the upper surface wire 870 on the ground surface of the resin layer 1640. The process for forming the upper surface wire 870 is, for example, similar to the process for forming the main surface wire 1621. The insulation film 873 is formed on the resin main surface 1640s of the resin layer 1640 excluding the first upper surface electrode 871 and the second upper surface electrode 872 of the upper surface wire 870. In the step of forming the insulation film 873, for example, a spin coater (rotary coating device) is used to apply the insulation film 873 to the resin main surface 1640s of the resin layer 1640. Alternatively, a film of a photosensitive resin material may be applied. The photosensitive resin material undergoes patterning through exposure and development. As a result, the first upper surface electrode 871 and the second upper surface electrode 872 of the upper surface wire 870 are exposed from the insulation film 873. That is, the method for manufacturing the electronic component 801A includes an upper surface wire forming step and an insulation film forming step.

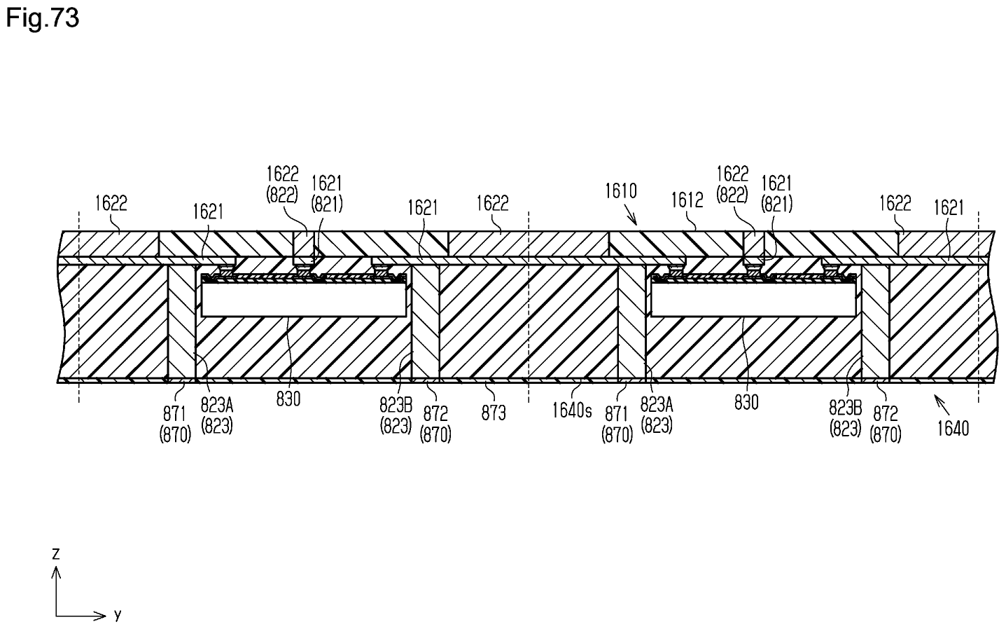

The method for manufacturing the electronic component 801A includes a step of removing the support substrate 1600. In the present embodiment, as shown in FIG. 73, the support substrate 1600 is removed by grinding. FIG. 73 is an upside-down view of FIG. 72. In an alternative process performing this step, the base member 1610 having a larger thickness than the substrate 810 shown in FIG. 55 may be used. In the step of grinding the support substrate 1600, the support substrate 1600 is ground and then the base member 1610 and the terminal pillars 1622 are ground so that the base member 1610 and the substrate 810 have the same thickness. Alternatively, a separation film may be formed in advance so that the support substrate 1600 is removed by separation.

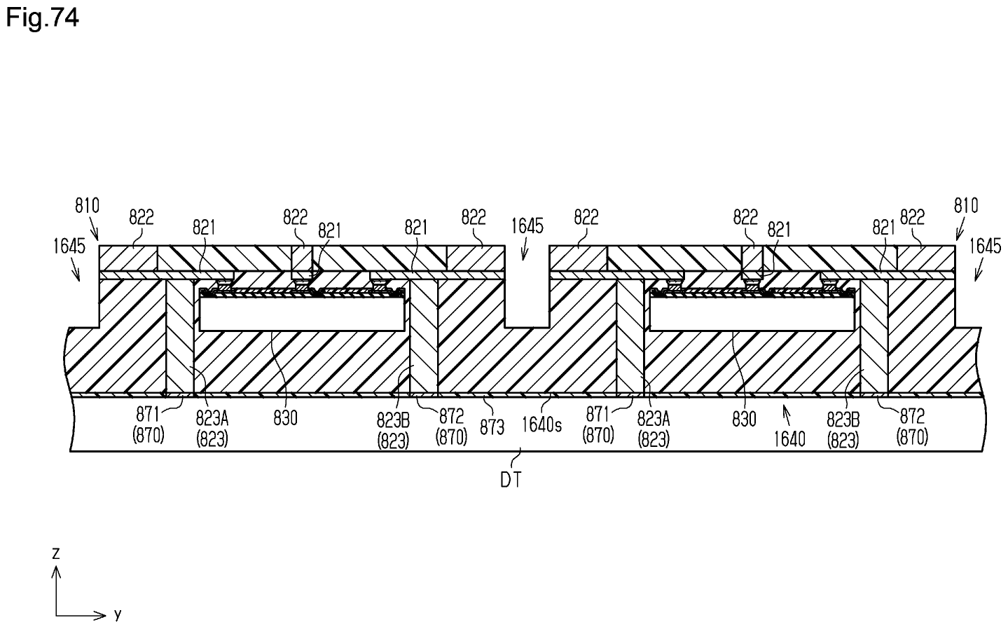

The method for manufacturing the electronic component 801A includes a step of cutting the base member 1610 and half-cutting the resin layer 1640. More specifically, as shown in FIG. 74, dicing tape DT is applied to the lower surface of the resin layer 1640. The base member 1610 is cut. Also, the resin layer 1640 is partially cut in the thickness-wise direction z (half cutting). The cutting of the base member 1610 and the half cutting of the resin layer 1640 are performed, for example, from the base member 1610 toward the dicing tape DT along the cutting lines (broken lines) shown in FIG. 73 with a dicing blade. The half cutting of the resin layer 1640 forms a separation groove 1645 in the resin layer 1640 as shown in FIG. 74. In this step, when the base member 1610 is cut, the substrate 810, the through wires 822, and the main surface wires 821 are formed. That is, the method for manufacturing the electronic component 801A includes a cutting step. Moreover, the method for manufacturing the electronic component 801A includes a first cutting step.

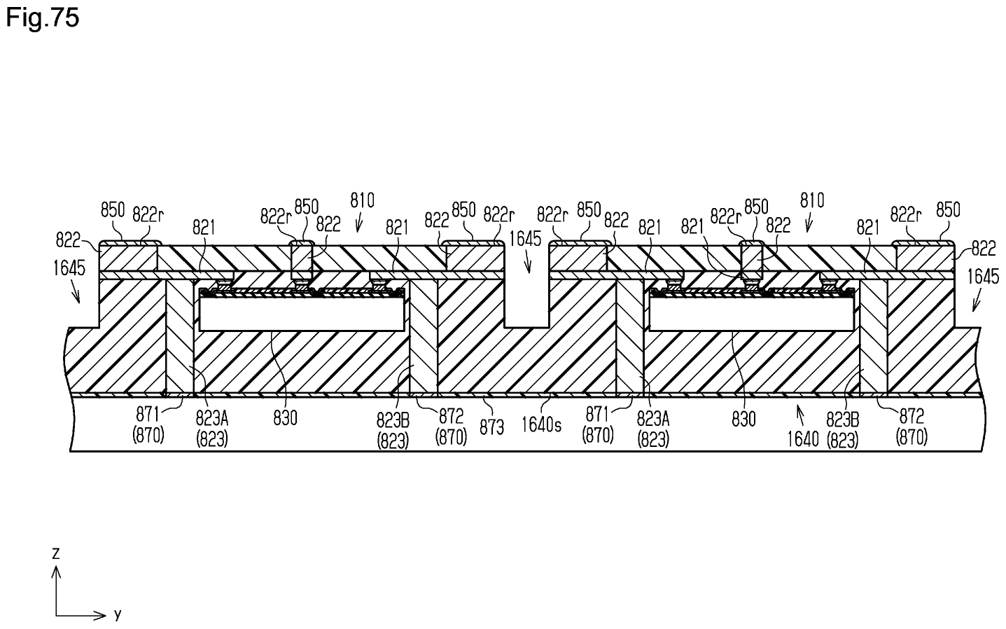

The method for manufacturing the electronic component 801A includes a step of forming the outer electrodes 850. More specifically, as shown in FIG. 75, the outer electrodes 850 are formed on the back surface 822r of each through wire 822 exposed from the base member 1610. The outer electrodes 850 are formed of plated metal. For example, electroless plating is performed so that the plated metal, for example, Ni, Pd, and Au are deposited in this order to form the outer electrodes 850.

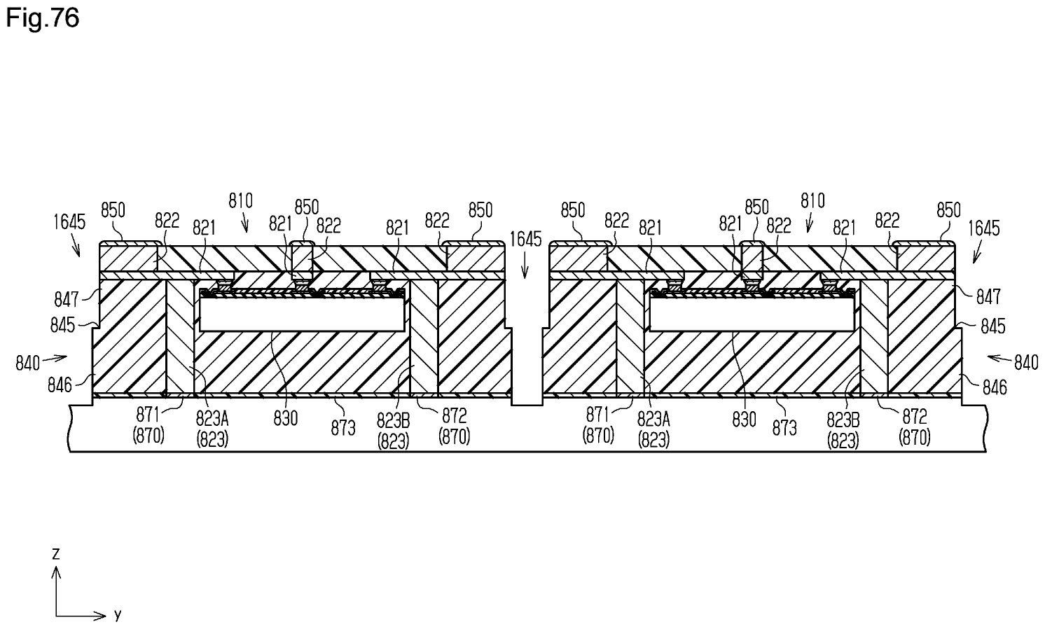

The method for manufacturing the electronic component 801A includes a step of separating into pieces singulated for each first functional element 830. More specifically, as shown in FIG. 76, the resin layer 1640 is cut from the separation groove 1645 of the resin layer 1640 to the dicing tape DT using a dicing blade that has a smaller thickness than the dicing blade used to half-cut the resin layer 1640. In this case, the resin layer 1640 is cut along the cutting lines (broken lines) shown in FIG. 73. As a result, the encapsulation resin 840 including the steps 845 is formed. The piece is an electronic component that includes the substrate 810, the encapsulation resin 840, and the first functional element 830. That is, the method for manufacturing the electronic component 801A includes a cutting step. Moreover, the method for manufacturing the electronic component 801A includes a second cutting step.

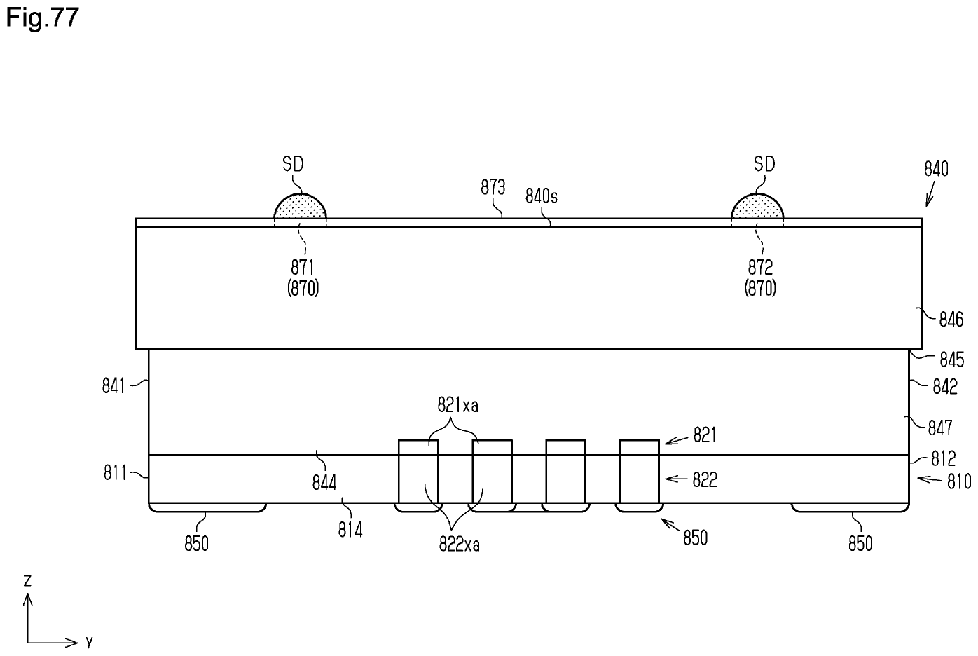

The method for manufacturing the electronic component 801A includes a step of mounting the second functional element 860. More specifically, as shown in FIG. 77, the solder SD is applied to the first upper surface electrode 871 and the second upper surface electrode 872 of the upper surface wire 870. In the process for forming the solder SD, the solder SD may be formed by depositing an alloy including Sn as plated metal on the first upper surface electrode 871 and the second upper surface electrode 872.

The second functional element 860 is mounted on the solder SD formed on the first upper surface electrode 871 and the second upper surface electrode 872. This temporarily attaches the second functional element 860 to the first upper surface electrode 871 and the second upper surface electrode 872. Subsequently, the solder SD is melted in the reflow process and then cooled so that the solder SD is solidified. As a result, the second functional element 860 is connected to the solder SD. That is, the method for manufacturing the electronic component 801A includes a second element mounting step. The steps described above manufacture the electronic component 801A.

Operation

The operation of the present embodiment will now be described.

The connection conductors 823, which are electrically connected to the main surface wires 821, are electrically connected to the upper surface wire 870, which is formed on the resin main surface 840s of the encapsulation resin 840. That is, the main surface wires 821 and the upper surface wire 870 are electrically connected by the connection conductors 823.

The first functional element 830 is disposed in the encapsulation resin 840 so as to be electrically connected to the main surface wires 821. The second functional element 860 is disposed on the resin main surface 840s of the encapsulation resin 840 so as to be electrically connected to the upper surface wire 870. Thus, the first functional element 830 and the second functional element 860 are disposed so that the first functional element 830 and the second functional element 860 are located at different positions in the thickness-wise direction z and that the first functional element 830 overlaps the second functional element 860 as viewed in the thickness-wise direction z. In the electronic component 801A of the present embodiment, the first functional element 830 and the second functional element 860 that are electrically connected to each other are mounted three-dimensionally (3D mounting) instead of two-dimensionally (2D mounting). Thus, the space for arranging the first functional element 830 and the second functional element 860 in a direction orthogonal to the thickness-wise direction z is decreased as compared to a configuration in which the first functional element 830 and the second functional element 860 are arranged on the same plane in the direction orthogonal to the thickness-wise direction z.

Advantages

The present embodiment has the following advantages.

(1-1) The electronic component 801A includes the first functional element 830 disposed so as to be electrically connected to the main surface wires 821 formed on the substrate 810, the encapsulation resin 840 encapsulating the main surface wires 821 and the first functional element 830, the second functional element 860 mounted on the resin main surface 840s of the encapsulation resin 840, and the connection conductors 823 electrically connecting the main surface wires 821 and the second functional element 860. The connection conductors 823 are exposed from the resin main surface 840s of the encapsulation resin 840. In this configuration, the first functional element 830 and the second functional element 860 overlap as viewed in the thickness-wise direction z. Thus, as compared to a configuration in which the first functional element 830 and the second functional element 860 are arranged on the same plane in a direction orthogonal to the thickness-wise direction z, the electronic component 801A is reduced in size in the direction orthogonal to the thickness-wise direction z.

(1-2) The dimension of the second functional element 860 in the thickness-wise direction z is greater than the dimension of the first functional element 830 in the thickness-wise direction z. In this configuration, even when the second functional element 860, which is disposed outside the encapsulation resin 840, has a great dimension in the thickness-wise direction z, there is no need to increase the dimension of the encapsulation resin 840 in the thickness-wise direction z. In other words, since the first functional element 830, which is encapsulated by the encapsulation resin 840, has a smaller dimension in the thickness-wise direction z, the dimension of the encapsulation resin 840 in the thickness-wise direction z is decreased. In the process for manufacturing the electronic component 801A, since the dimension of the resin layer 1640 in the thickness-wise direction z is reduced, the bending of the base member 1610 caused by thermal contraction of the resin layer 1640 is limited.

(1-3) The upper surface wire 870 is formed on the resin main surface 840s of the encapsulation resin 840. The upper surface wire 870 is electrically connected to the connection conductors 823. In this configuration, the upper surface wire 870 is formed suitably for mounting the second functional element 860. Thus, the second functional element 860 is appropriately mounted on the resin main surface 840s.

(1-4) The dimension of the second functional element 860 in the second direction y is greater than the dimension of the first functional element 830 in the second direction y. In this configuration, a functional element that is greater than the first functional element 830 in the dimension in the second direction y may be mounted on the resin main surface 840s. This increases the number of types of second functional element 860 that are mountable on the resin main surface 840s.

(1-5) The main surface wires 821 each include the inward part 821p extending to an inner side of the substrate main surface 810s from the through wire 822. The first functional element 830 is mounted on the inward parts 821p. In this configuration, the through wires 822 are disposed at an outer side of the substrate main surface 810s from the first functional element 830. This ensures space for changing the pitch between the through wires 822 in the arrangement direction. For example, the pitch between the through wires 822 in the arrangement direction may be larger than the pitch between the inward parts 821p in the arrangement direction of the main surface wires 821.

(1-6) The connection conductor 823 is disposed on the inward part 821p of the main surface wire 821 between the first functional element 830 and the through wire 822 in a direction in which the inward part 821p extends. In this configuration, the connection conductor 823 is less likely to receive effects of deformation of the through wires 822.

(1-7) The first connection conductor 823A and the second connection conductor 823B are separately disposed at opposite sides of the first functional element 830 as viewed in the thickness-wise direction z. This configuration shortens the distance between the first upper surface electrode 871 of the upper surface wire 870 and the first connection conductor 823A and the distance between the second upper surface electrode 872 of the upper surface wire 870 and the second connection conductor 823B. Accordingly, the upper surface wire 870 is shortened.

(1-8) The through wires 822 are exposed from each of the substrate side surfaces 811 to 814 of the substrate 810. In this configuration, for example, when the electronic component 801A is mounted on a wiring substrate with solder, the solder contacts surfaces of the through wires 822 exposed from the substrate side surfaces 811 to 814 and forms fillets. This allows for visual inspection of the bonding state of the electronic component 801A with the solder when the electronic component 801A is mounted on the wiring substrate.

(1-9) The main surface wires 821 are exposed from each of the resin side surfaces 841 to 844 of the encapsulation resin 840. In this configuration, for example, when the electronic component 801A is mounted on a wiring substrate with solder, the solder contacts surfaces of the main surface wires 821 exposed from the resin side surfaces 841 to 844 and forms fillets. This allows for visual inspection of the bonding state of the electronic component 801A with the solder when the electronic component 801A is mounted on the wiring substrate.

(1-10) The main surface wires 821, the through wires 822, and the connection conductors 823 are formed through electrolytic plating. In other words, the inner electrodes 820 are formed through electrolytic plating. The outer electrodes 850 are formed through electroless plating. Thus, the wires of the electronic component 801A are formed through plating processes and are not formed of a lead frame of a metal plate. The wires formed through plating processes have a smaller thickness than those having a lead frame structure. Thus, the thickness of the electronic component 801A is reduced. In addition, when an LSI is used in the first functional element 830, a highly-integrated LSI uses a larger number of terminals so that internal electrodes and the like need to be miniaturized. When a lead frame is used, the processing of a metal plate imposes limitations on miniaturization. In the electronic component 801A of the present embodiment, the inner electrodes 820 are formed through a plating process and thus can be miniaturized. This allows for the manufacturing of an electronic component including a further larger number of terminals.

Eighth Embodiment

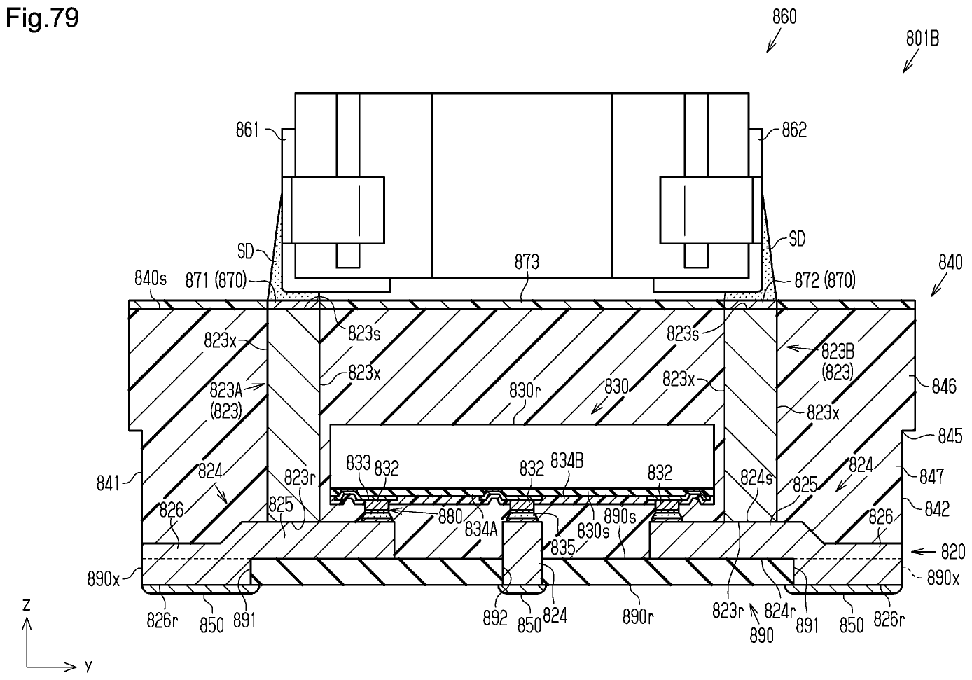

An eighth embodiment of an electronic component 801B according to the present disclosure will now be described with reference to FIGS. 79 to 100. The electronic component 801B of the present embodiment differs from the electronic component 801A of the seventh embodiment in the structure of the inner electrodes 820 and in that the electronic component 801B includes an insulation member 890 instead of the substrate 810. In the description below, the same reference signs are given to those elements that are the same as the electronic component 801A of the seventh embodiment. Such elements may not be described in detail.

Structure of Electronic Component

As shown in FIG. 79, the insulation member 890 is formed from an electrically insulating material, for example, a polyimide resin or a phenol resin. The insulation member 890 is disposed at a lower surface (back surface) of the electronic component 801B. In the present embodiment, the insulation member 890 is located at a lower position than the encapsulation resin 840 in the thickness-wise direction z. In the present embodiment, the shape of the insulation member 890 viewed in the thickness-wise direction z is identical to the shape of the substrate 810 viewed in the thickness-wise direction z (refer to FIGS. 50 and 52). The insulation member 890 includes an insulation main surface 890s and an insulation back surface 890r facing in opposite directions in the thickness-wise direction z and four insulation side surfaces 890x disposed between the insulation main surface 890s and the insulation back surface 890r in the thickness-wise direction z. The insulation side surfaces 890x face in the first direction x or the second direction y.

The insulation main surface 890s of the insulation member 890 faces in the same direction as the element back surface 830r of the first functional element 830 in the thickness-wise direction z and faces the element main surface 830s of the first functional element 830. The insulation back surface 890r of the insulation member 890 faces in the same direction as the element main surface 830s of the first functional element 830 in the thickness-wise direction z. The insulation member 890 includes recesses 891 and a through hole 892. In the present embodiment, the recesses 891 are arranged in the same manner as the recesses 815 (refer to FIG. 52) of the seventh embodiment. That is, four recesses 891 are arranged in each side of the insulation member 890. As viewed in the thickness-wise direction z, each recess 891 is rectangular. The shape of the recess 891 as viewed in the thickness-wise direction z is identical to the shape of the recess 815 of the seventh embodiment as viewed in the thickness-wise direction z.

The through hole 892 extends through the substrate 810 in the thickness-wise direction z. The through hole 892 is disposed at a center of the insulation member 890 in the first direction x and the second direction y. As viewed in the thickness-wise direction z, the through hole 892 is rectangular.

The shape of each recess 891 as viewed in the thickness-wise direction z may be changed in any manner. The recess 891 may be square, arc-shaped, or polygonal other than tetragonal as viewed in the thickness-wise direction z. The shape of the through hole 892 as viewed in the thickness-wise direction z may be changed in any manner. The through hole 892 may be square, circular, elliptical, or polygonal other than tetragonal as viewed in the thickness-wise direction z.

The inner electrodes 820 include multiple (sixteen in the present embodiment) wiring layers 824, and multiple (two in the present embodiment) connection conductors 823. The wiring layers 824 are arranged in the same manner as the main surface wires 821 and the through wires 822 (refer to FIG. 52) of the seventh embodiment. In the same manner as the seventh embodiment, in the present embodiment, two connection conductors 823 are referred to as the first connection conductor 823A and the second connection conductor 823B. The first connection conductor 823A is electrically connected to one of the wiring layers 824. The second connection conductor 823B is electrically connected to another one of the wiring layers 824. The connection conductors 823A and 823B are arranged in the same manner as the connection conductors 823A and 823B of the seventh embodiment.

As shown in FIG. 79, the wiring layers 824 each include a wire main surface 824s and a wire back surface 824r facing in opposite directions in the thickness-wise direction z. The wire main surface 824s and the insulation main surface 890s of the insulation member 890 face in the same direction. The wire back surface 824r and the insulation back surface 890r of the insulation member 890 face in the same direction. The wiring layers 824 are formed from an electrically conductive material. For example, Cu or an alloy of Cu may be used as the material of the wiring layers 824. In the present embodiment, the wiring layers 824 each include a plated layer.

Each wiring layer 824 includes a main surface wire 825 and a through wire 826. In the present embodiment, in the wiring layer 824, the main surface wire 825 is formed integrally with the through wire 826. Thus, the wire main surface 824s defines the wire main surface of the main surface wire 825. The wire back surface 824r defines the back surface of the main surface wire 825 and the back surface of the through wire 826. The back surface of the through wire 826 is exposed from the insulation member 890 in the thickness-wise direction z. In other words, the wire back surface 824r defines an exposed back surface of the through wire 826 exposed from the insulation back surface 890r.

The main surface wire 825 is formed on the insulation main surface 890s of the insulation member 890. The through wires 826 are formed in the recesses 891 and the through hole 892 of the insulation member 890. The shapes of the through wires 826 as viewed in the thickness-wise direction z are determined in accordance with the shapes of the recesses 891 and the through hole 892 as viewed in the thickness-wise direction z. In the present embodiment, as viewed in the thickness-wise direction z, the through wires 826 are rectangular.

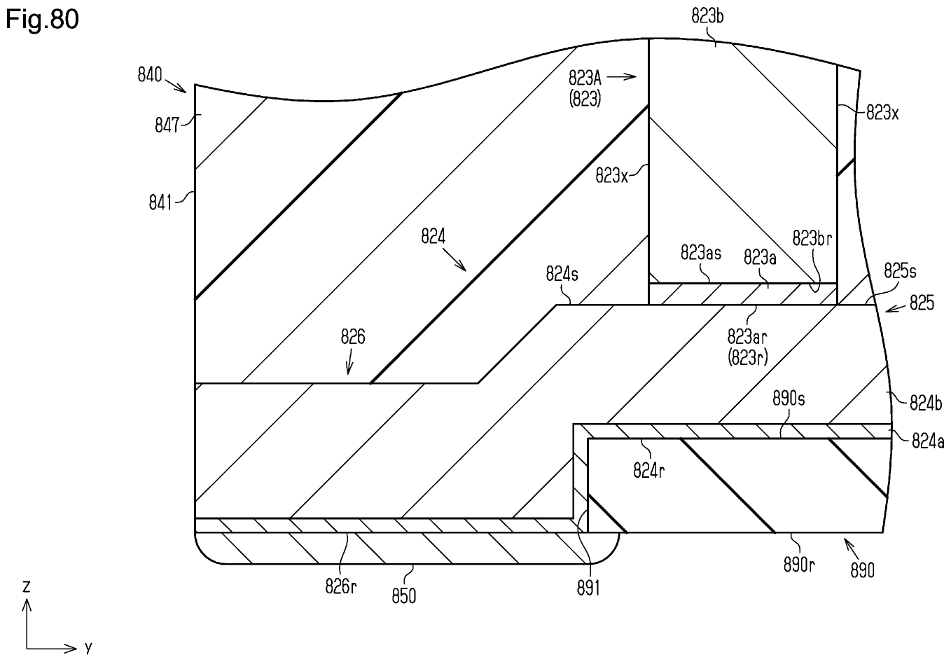

As shown in FIG. 80, each wiring layer 824 includes a seed layer 824a and a plated layer 824b that are stacked on each other. The seed layer 824a includes, for example, a first layer including Ti as a main component and a second layer including Cu as a main component. The thickness of the seed layer 824a is approximately greater than or equal to 200 nm and less than or equal to 8800 nm. The main component of the plated layer 824b is Cu. The thickness of the plated layer 824b is approximately greater than or equal to 20 μm and less than or equal to 50 μm. The thickness of the seed layer 824a and the thickness of the plated layer 824b are not limited to those described above.

The connection conductors 823A and 823B extend upward from the wire main surface 824s of the wiring layers 824 in the thickness-wise direction z. More specifically, the main surface wire 825 includes an upper surface 825s, and the connection conductors 823A and 823B extend upward from the upper surface 825s in the thickness-wise direction z. The connection conductors 823A and 823B are arranged in the same manner as the connection conductors 823A and 823B of the seventh embodiment. The upper surface 823s of the connection conductors 823A and 823B is exposed from the resin main surface 840s of the encapsulation resin 840 in the same manner as the seventh embodiment.

The upper surface wire 870 and the insulation film 873 are formed on the resin main surface 840s of the encapsulation resin 840 in the same manner as the seventh embodiment. The second functional element 860 is connected to the upper surface wire 870 in the same manner as the seventh embodiment. The mount position of the second functional element 860 with respect to the resin main surface 840s is the same as the mount position of the second functional element 860 with respect to the resin main surface 840s in the seventh embodiment. Therefore, the positional relationship between the first functional element 830 and the second functional element 860 is the same as the positional relationship between the first functional element 830 and the second functional element 860 in the seventh embodiment.

Manufacturing Method of Electronic Component

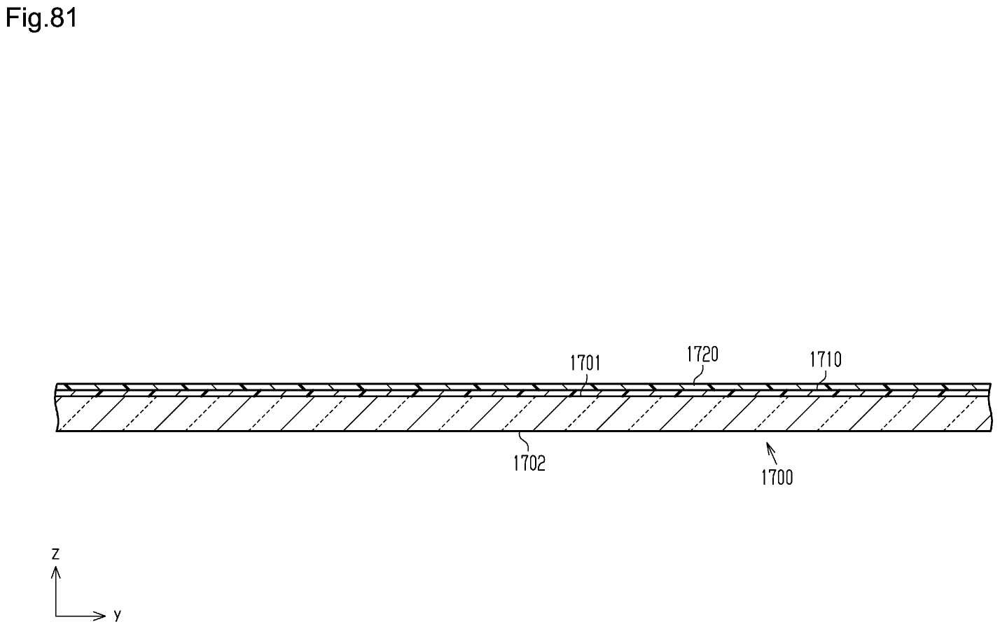

A method for manufacturing the electronic component 801B of the eighth embodiment according to the present disclosure will now be described with reference to FIGS. 81 to 100. The definition of directions shown in the drawings is the same as the definition of directions shown in FIGS. 49 to 58.

The method for manufacturing the electronic component 801B includes a step of preparing a support substrate 1700. As shown in FIG. 81, the support substrate 1700 including an upper surface 1701 and a lower surface 1702 facing in opposite directions in the thickness-wise direction z is prepared. The support substrate 1700 is formed of, for example, a glass substrate or a Si substrate. In the present embodiment, a transparent glass substrate is used as the support substrate 1700. The thickness of the support substrate 1700 is approximately 0.5 μm.

The method for manufacturing the electronic component 801B includes a step of forming a temporary fixing material 1710 on the upper surface 1701 of the support substrate 1700. More specifically, as shown in FIG. 81, the temporary fixing material 1710 is formed to cover the entire upper surface 1701 of the support substrate 1700.

The method for manufacturing the electronic component 801B includes a step of forming a sputtered film 1720 on the temporary fixing material 1710. More specifically, as shown in FIG. 81, the sputtered film 1720 is formed to cover the entire temporary fixing material 1710. The sputtered film 1720 is a metal film including Ti as a main component.

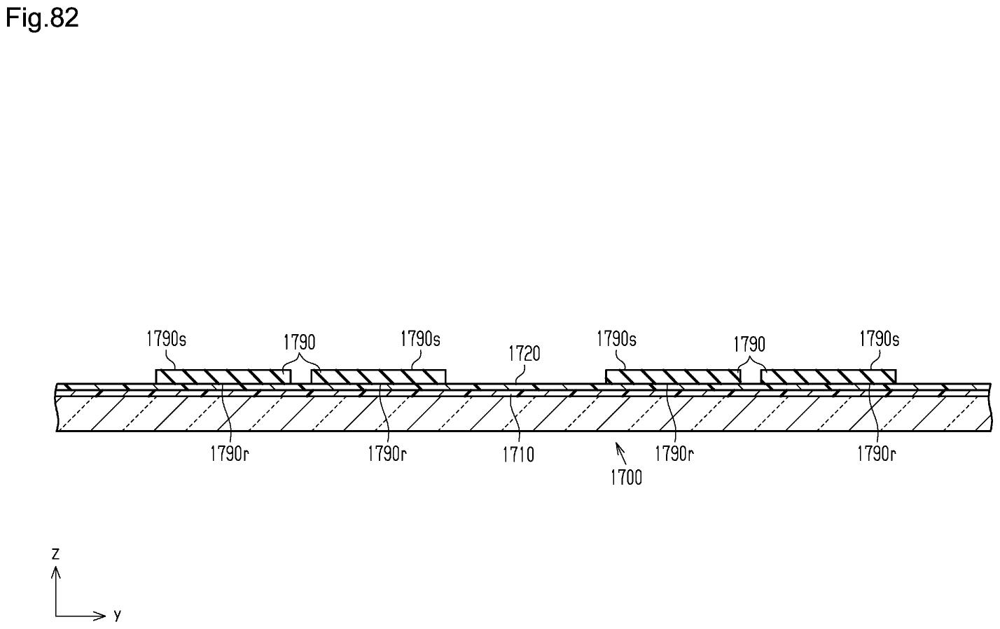

The method for manufacturing the electronic component 801B includes a step of forming an insulation layer 1790 shown in FIG. 82. The insulation layer 1790 corresponds to the insulation member 890 (refer to FIG. 79) of the electronic component 801B. More specifically, the insulation layer 1790 is, for example, an insulation film formed from a photosensitive resin material such as a polyimide resin or a phenol resin. The insulation layer 1790 includes an insulation main surface 1790s and an insulation back surface 1790r facing in opposite directions in the thickness-wise direction z. In this step, for example, a spin coater (rotary coating device) is used to apply the insulation layer 1790 to the sputtered film 1720. Alternatively, a film of a photosensitive resin material may be applied. The photosensitive resin material undergoes patterning through exposure and development. As a result, the insulation layer 1790 is formed. That is, the method for manufacturing the electronic component 801B includes an insulation layer forming step.

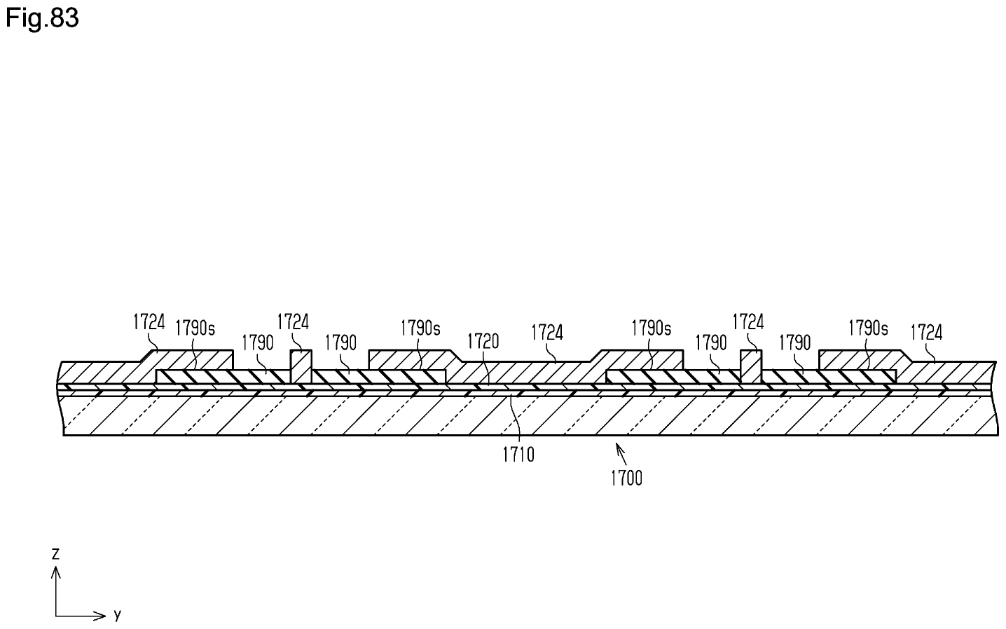

The method for manufacturing the electronic component 801B includes a step of forming a wiring layer 1724 shown in FIG. 83.

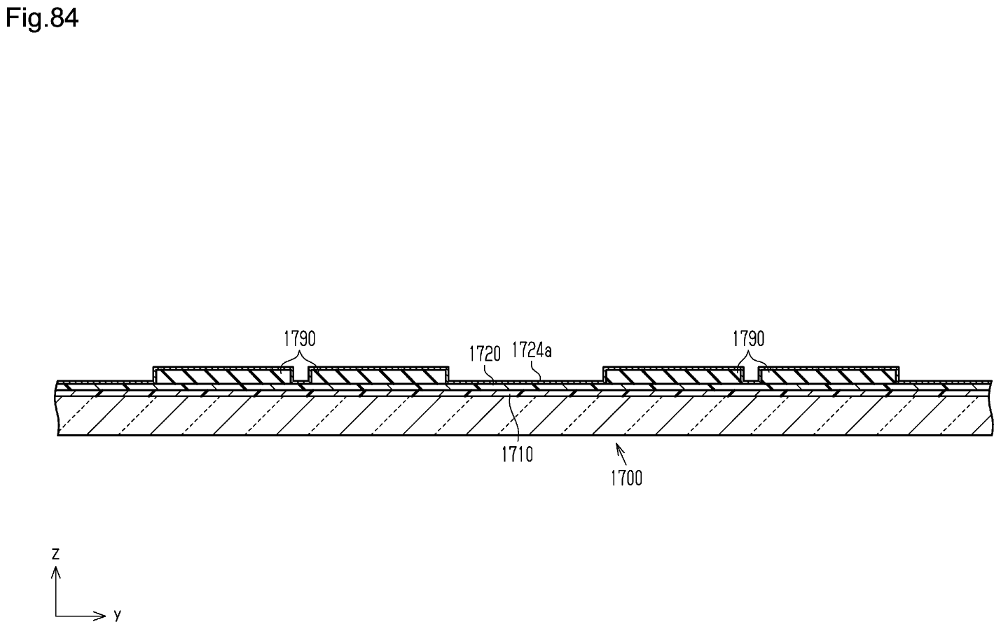

More specifically, as shown in FIG. 84, a seed layer 1724a is formed. Part of the seed layer 1724a subsequently corresponds to part of the inner electrodes 820 of the electronic component 801B (specifically, the seed layer 824a of the wiring layers 824). The seed layer 1724a is formed through sputtering. The seed layer 1724a is formed on the entire surface of the insulation layer 1790 and the entire surface of the sputtered film 1720 exposed from the insulation layer 1790. In the present embodiment, the seed layer 1724a includes a Ti layer and a Cu layer that are stacked on each other. In the step of forming the seed layer 1724a, a Ti layer is formed in contact with the insulation layer 1790 and the sputtered film 1720 exposed from the insulation layer 1790, and then a Cu layer is formed in contact with the Ti layer.

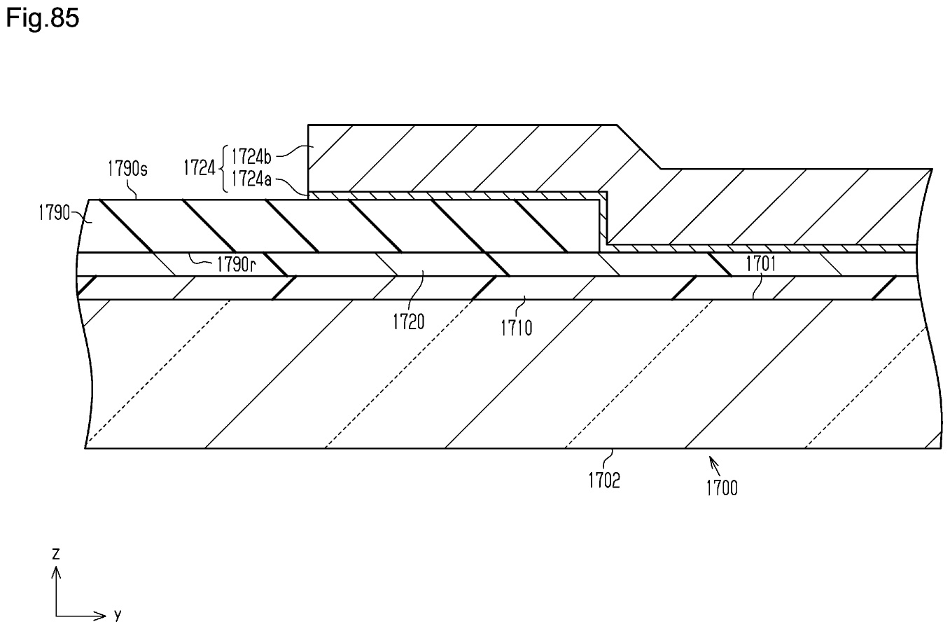

As shown in FIG. 85, a plated layer 1724b is formed. FIG. 85 shows the plated layer 1724b formed on a portion of the seed layer 1724a. The wiring layer 1724 shown in FIG. 85 includes the seed layer 1724a and the plated layer 1724b that are stacked.

As shown in FIG. 85, the plated layer 1724b corresponds to part of the inner electrode 820 of the electronic component 801B (specifically, the plated layer 824b of the wiring layer 824). The plated layer 824b is formed by forming a pattern through photolithography and performing electrolytic plating. In the step of forming the plated layer 1724b, a resist layer (not shown) for forming the plated layer 1724b is formed through photolithography. When forming the resist layer, a photosensitive resist is applied to cover the entire surface of the seed layer 1724a, and the photosensitive resist undergoes patterning through light exposure and development. The patterning partially exposes the seed layer 1724a (portion on which the plated layer 1724b is formed). The plated layer 1724b is formed on the exposed portion of the seed layer 1724a through electrolytic plating that uses the seed layer 1724a as a conductive path. Subsequently, the resist layer is removed to form the plated layer 1724b shown in FIG. 85.

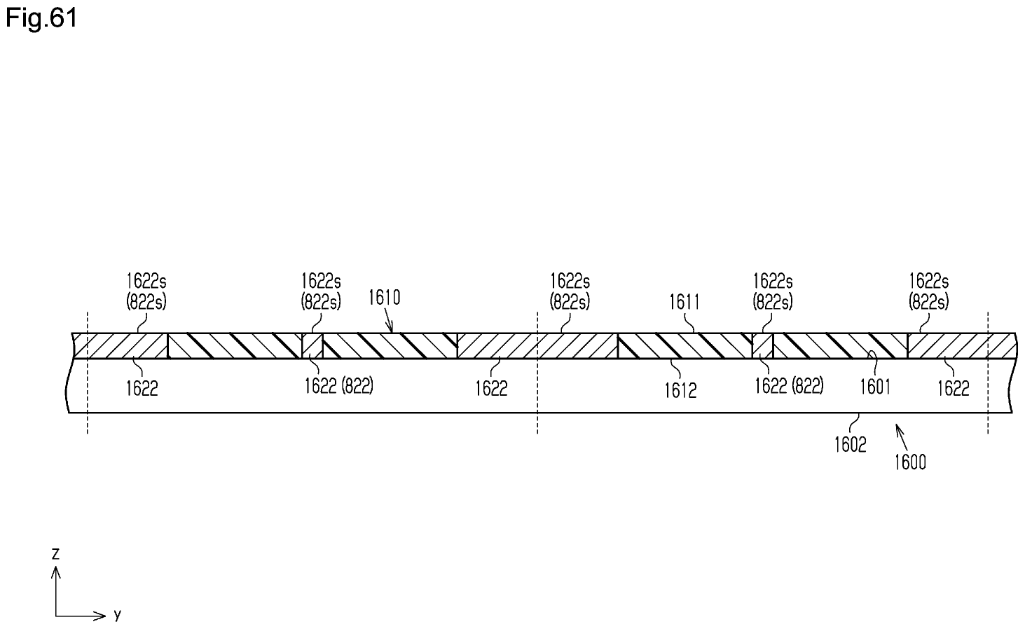

As shown in FIG. 85, the unwanted portion of the seed layer 1724a, which is not covered by the plated layer 1724b, is completely removed. The unwanted seed layer 1724a is removed by wet-etching. The wet-etching uses, for example, a mixture solution of H₂SO₄ and H₂O₂ (hydrogen peroxide). In the step of removing the unwanted seed layer 1724a, the insulation layer 1790 is exposed from where the seed layer 1724a has been removed. In addition, the removal of the unwanted seed layer 1724a forms the wiring layer 1724, which includes the seed layer 1724a and the plated layer 1724b. The wiring layer 1724 corresponds to the wiring layer 824 (refer to FIG. 61) of the inner electrode 820 in the electronic component 801B. That is, the method for manufacturing the electronic component 801B includes a first inner electrode forming step.

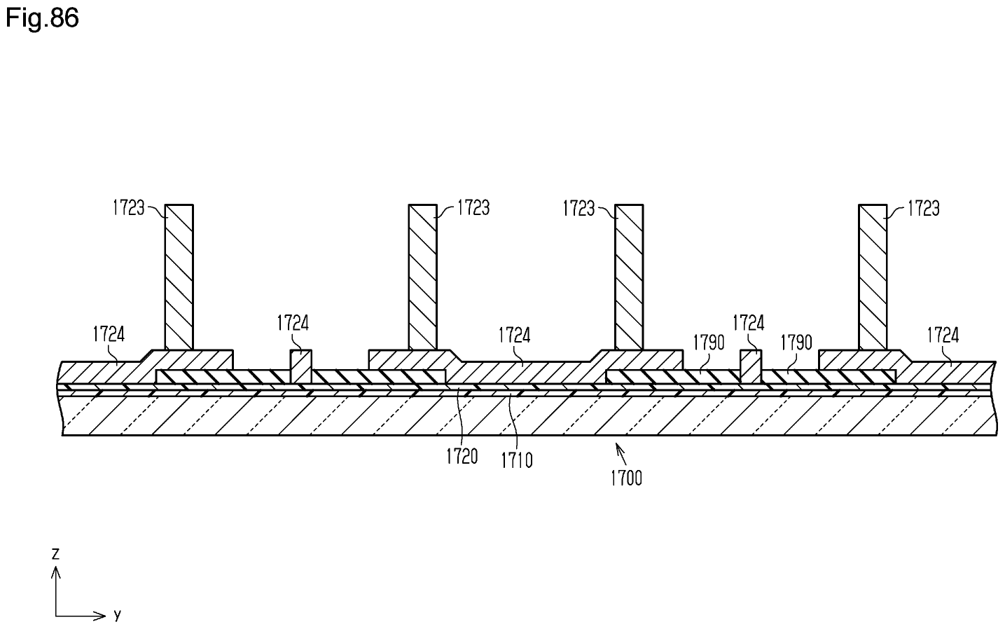

The method for manufacturing the electronic component 801B includes a step of forming multiple (in the present embodiment, two) connection conductors 1723 shown in FIG. 86.

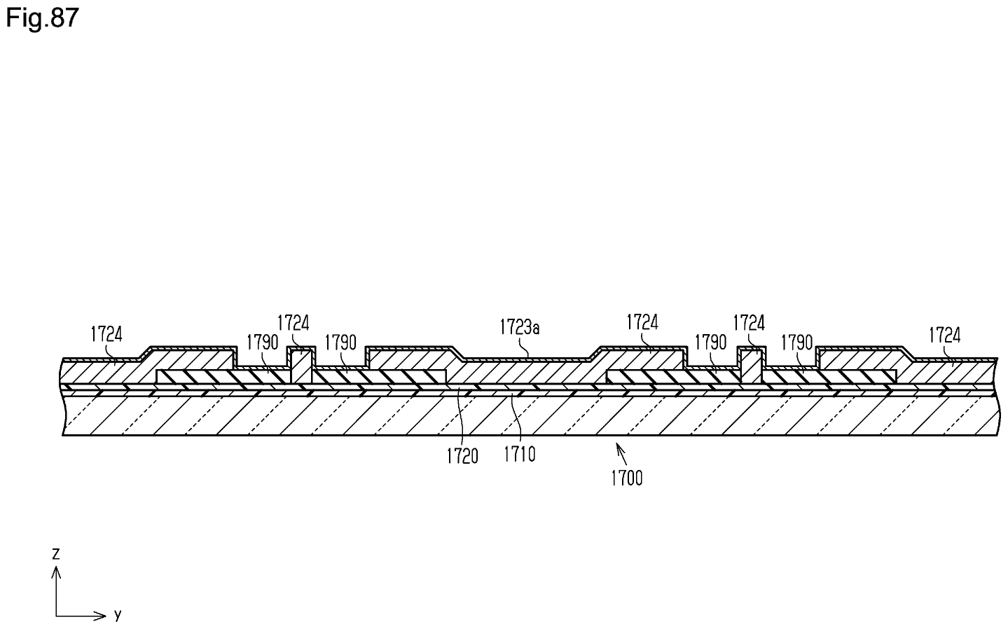

More specifically, as shown in FIG. 87, a seed layer 1723a is formed. Part of the seed layer 1723a subsequently corresponds to part of the inner electrode 820 of the electronic component 801B (specifically, the seed layer 823a of the connection conductors 823). The seed layer 1723a is formed through sputtering. The seed layer 1723a is formed on the entire wiring layer 1724 and the entire insulation layer 1790 exposed from the wiring layer 1724. In the present embodiment, the seed layer 1723a includes a Ti layer and a Cu layer that are stacked on each other. In the step of forming the seed layer 1723a, a Ti layer is formed in contact with the wiring layer 1724 and the portion of the insulation layer 1790 exposed from the wiring layer 1724, and then a Cu layer is formed in contact with the Ti layer.

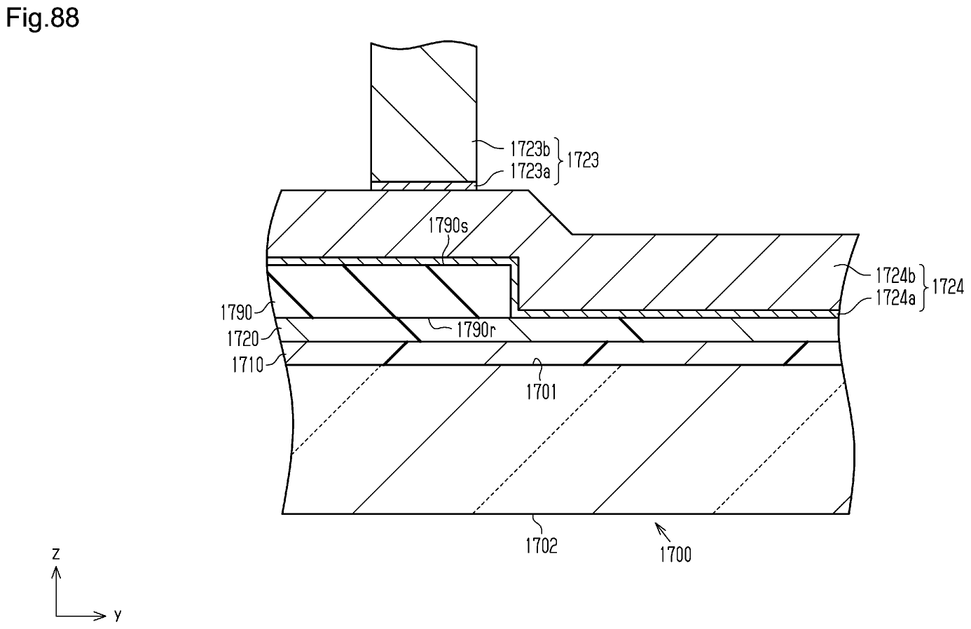

As shown in FIG. 88, a plated layer 1723b is formed. FIG. 88 shows the plated layer 1723b formed on a portion of the seed layer 1723a. The connection conductor 1723 shown in FIG. 88 includes the seed layer 1723a and the plated layer 1723b that are stacked.

As shown in FIG. 88, the plated layer 1723b corresponds to part of the inner electrode 820 of the electronic component 801B (specifically, the plated layer 823b of the connection conductor 1723). The plated layer 1723b is formed by forming a pattern through photolithography and performing electrolytic plating. In the step of forming the plated layer 1723b, a resist layer (not shown) for forming the plated layer 1723b is formed through photolithography. When forming the resist layer, a photosensitive resist is applied to cover the entire surface of the seed layer 1723a, and the photosensitive resist undergoes patterning through light exposure and development. The patterning partially exposes the seed layer 1723a (portion on which the plated layer 1723b is formed). Then, the plated layer 1723b is formed on the exposed portion of the seed layer 1723a through electrolytic plating that uses the seed layer 1723a as a conductive path.

The method for manufacturing the electronic component 801B includes a step of removing an unwanted portion of the seed layer 1723a. More specifically, the unwanted portion of the seed layer 1723a, which is not covered by the plated layer 1723b and the bonding portion 880, is completely removed. The unwanted seed layer 1723a is removed in the same manner as the removal of the unwanted seed layer 1724a described above. More specifically, for example, wet-etching is performed using a mixture solution of H₂SO₄ and H₂O₂. As a result, the wiring layer 1724, the insulation layer 1790, and the sputtered film 1720 are exposed from where the seed layer 1723a has been removed. In addition, the removal of the unwanted seed layer 1723a forms the connection conductor 1723, which includes the seed layer 1723a and the plated layer 1723b. The connection conductor 1723 corresponds to the connection conductor 823 (refer to FIG. 79) of the inner electrode 820 in the electronic component 801B. That is, the method for manufacturing the electronic component 801B includes a second inner electrode forming step.

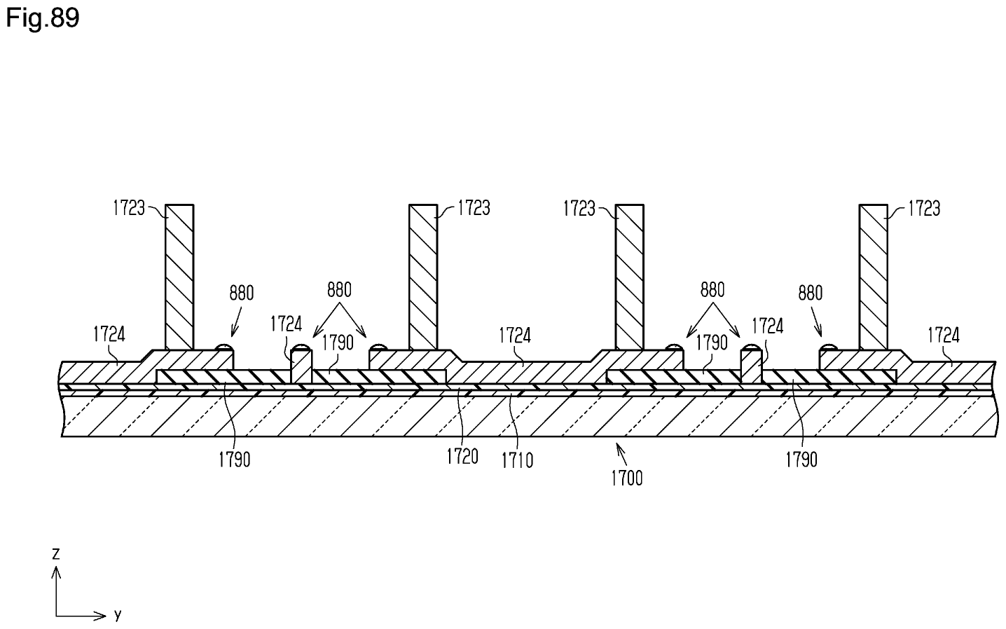

The method for manufacturing the electronic component 801B includes a step of forming the bonding portions 880 shown in FIG. 89. The step of forming the bonding portions 880 of the present embodiment is the same as the step of forming the bonding portions 880 of the seventh embodiment.

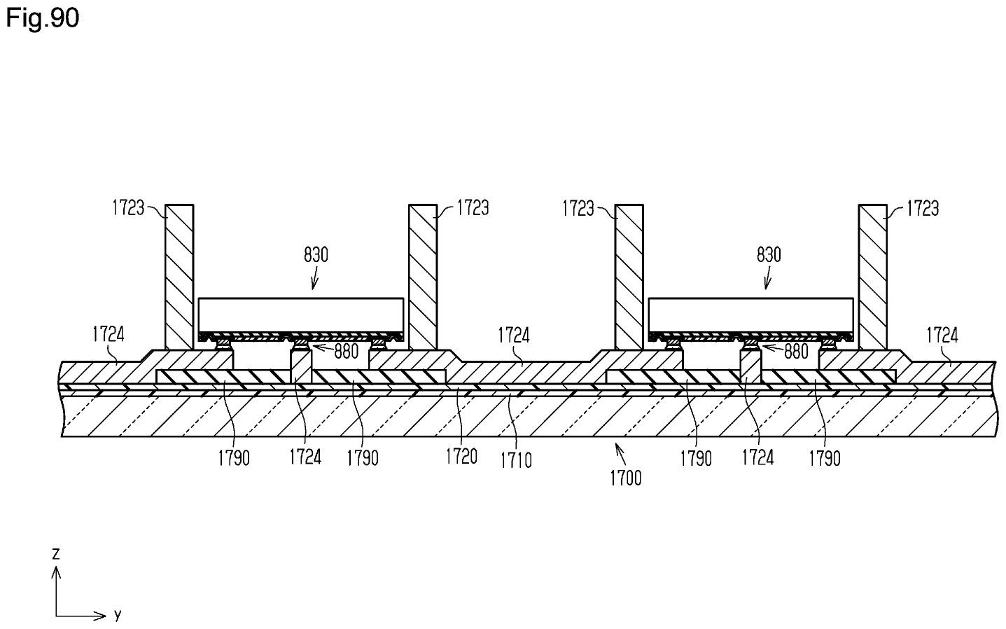

The method for manufacturing the electronic component 801B includes a step of mounting the first functional elements 830 shown in FIG. 90. The mounting process of the first functional elements 830 in the present embodiment is the same as the mounting process of the first functional elements 830 in the seventh embodiment. That is, the method for manufacturing the electronic component 801B includes a first element mounting step.

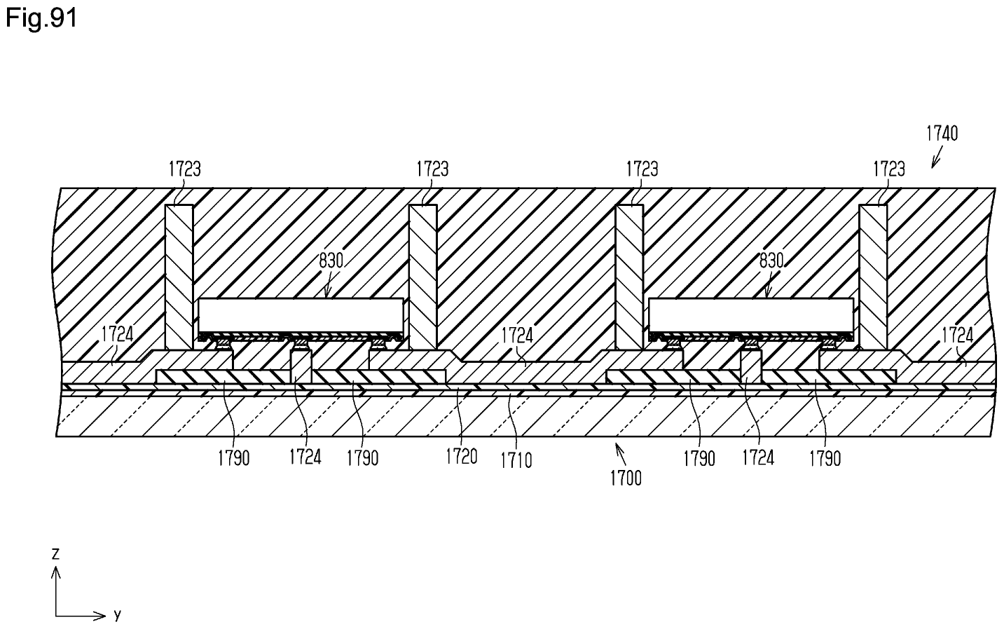

As shown in FIG. 91, the method for manufacturing the electronic component 801B includes a step of forming a resin layer 1740 that covers the first functional element 830. The resin layer 1740 corresponds to the encapsulation resin 840 (refer to FIG. 79) of the electronic component 801B. In the step of forming the resin layer 1740 of the present embodiment, the resin layer 1740 is formed to simultaneously encapsulate all of the first functional elements 830. The resin layer 1740 is, for example, a synthetic resin, the main material of which is an epoxy resin. The resin layer 1740 is formed, for example, by transfer molding. That is, the method for manufacturing the electronic component 801B includes a resin layer forming step.

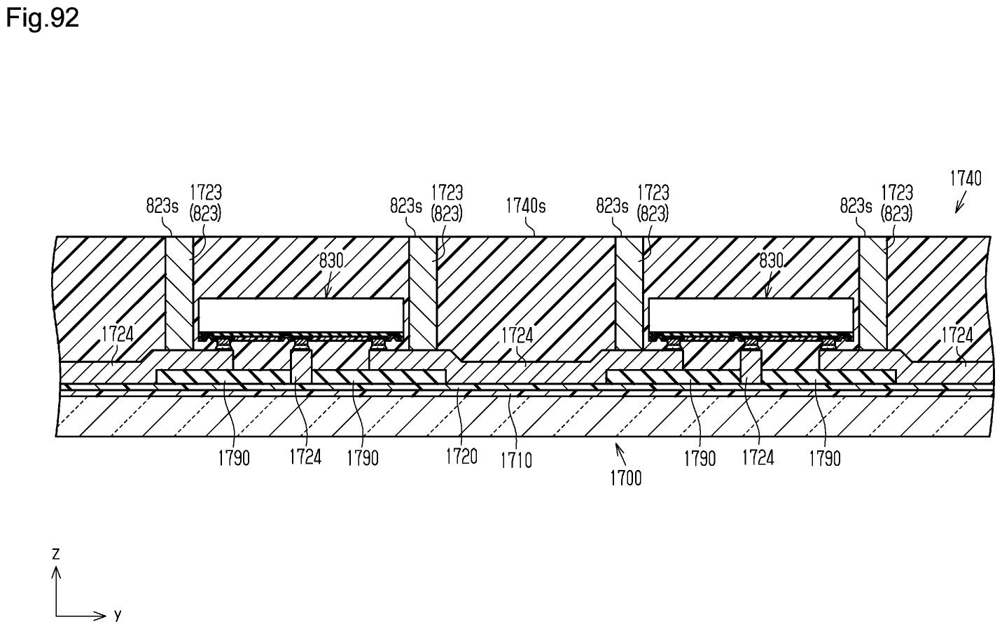

The method for manufacturing the electronic component 801B includes a step of grinding the resin layer 1740 and the connection conductors 1723 to reduce the thickness of the resin layer 1740 and the connection conductors 1723 shown in FIG. 92. The step of grinding the resin layer 1740 and the connection conductors 1723 to reduce the thickness in the present embodiment is the same as the step of grinding the resin layer 1640 and the connection conductors 1623 to reduce the thickness of the resin layer 1640 and the connection conductors 1623 (refer to FIG. 71) in the seventh embodiment. As a result, the connection conductors 823 are formed. The resin layer 1740 includes a resin main surface 1740s located at a side opposite from the support substrate 1700 in the thickness-wise direction z. The upper surface 823s of the connection conductor 823 is exposed from the resin main surface 1740s. That is, the method for manufacturing the electronic component 801B includes a resin layer grinding step.

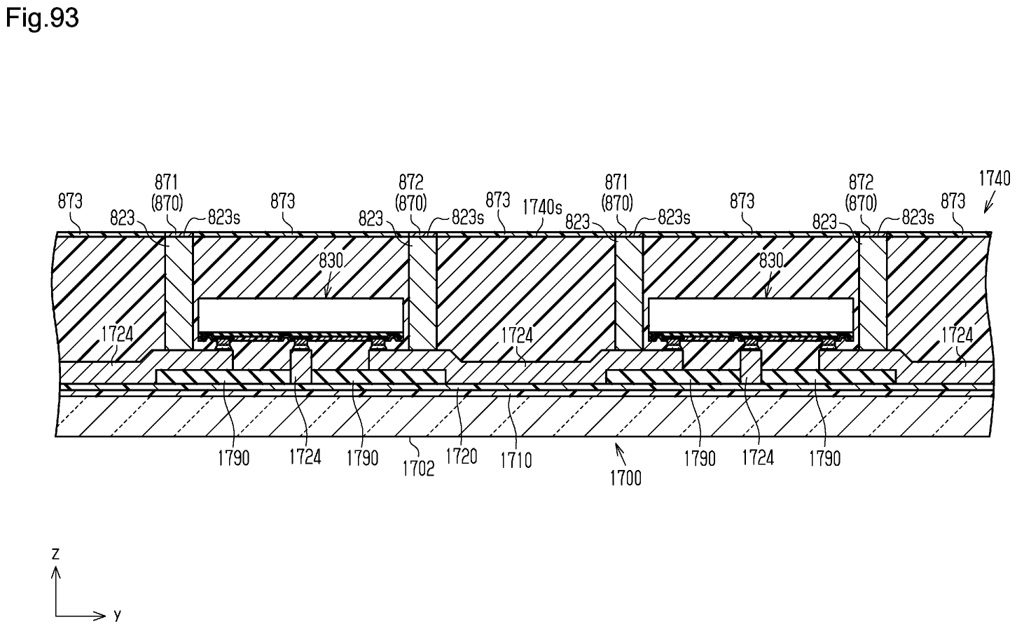

The method for manufacturing the electronic component 801B includes a step of forming the upper surface wire 870 and the insulation film 873 shown in FIG. 93. The step of forming the upper surface wire 870 and the insulation film 873 in the present embodiment is the same as the step of forming the upper surface wire 870 and the insulation film 873 of the seventh embodiment. That is, the method for manufacturing the electronic component 801B includes an upper surface wire forming step and an insulation film forming step.

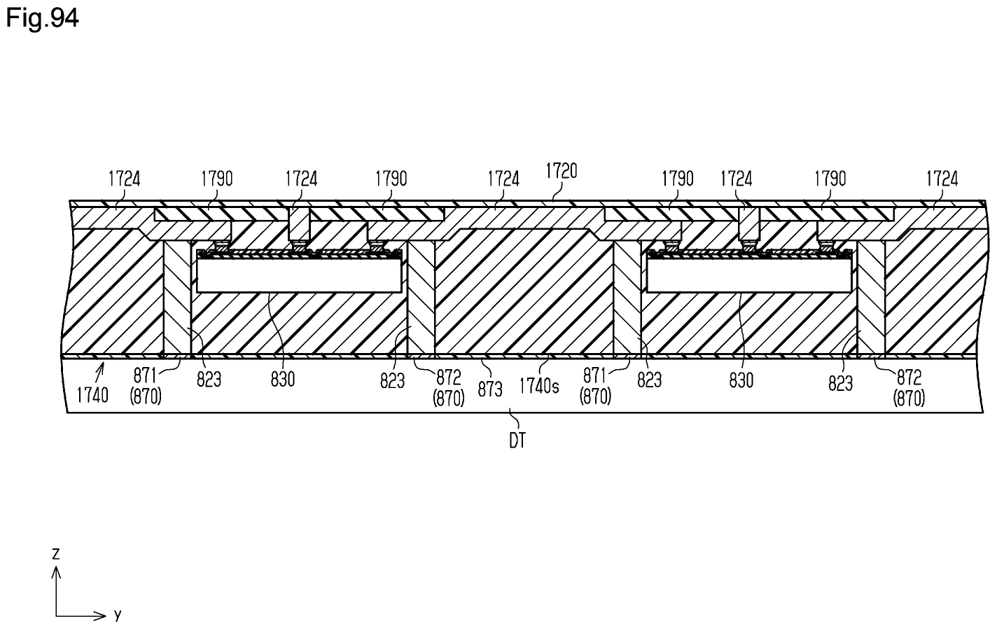

As shown in FIG. 94, the method for manufacturing the electronic component 801B includes a step of separating the support substrate 1700 (refer to FIG. 93) from the sputtered film 1720. In the step of separating the support substrate 1700, the dicing tape DT is applied to the resin main surface 1740s (insulation film 873) of the resin layer 1740. Subsequently, for example, the lower surface 1702 (refer to FIG. 93) of the support substrate 1700 is irradiated with a laser beam. In this process, the laser beam transmits through the support substrate 1700, and the temporary fixing material 1710 (refer to FIG. 93) is irradiated with the laser beam. This decreases the adhesion strength of the temporary fixing material 1710 and allows the support substrate 1700 to be separated from the sputtered film 1720. After the support substrate 1700 is separated from the sputtered film 1720, when the temporary fixing material 1710 partially remains (for example, as soot), the remaining portion of the temporary fixing material 1710 is removed by, for example, plasma. The support substrate 1700 and the temporary fixing material 1710 are removed by the above-described process.

The process for separating the support substrate 1700 is not limited to laser beam irradiation. For example, the support substrate 1700 may be separated from the sputtered film 1720 by forcing air in a direction (the first direction x or the second direction y) orthogonal to the thickness-wise direction z. The temporary fixing material 1710 may be heated and softened, and then the support substrate 1700 may be removed from the sputtered film 1720. When the laser beam irradiation is used for the separation, the support substrate 1700 needs to be formed of a material having a transparency appropriate for transmitting a laser beam. When the forced air or heating is used for the separation, the support substrate 1700 may be formed of, for example, a Si substrate instead of a glass substrate.

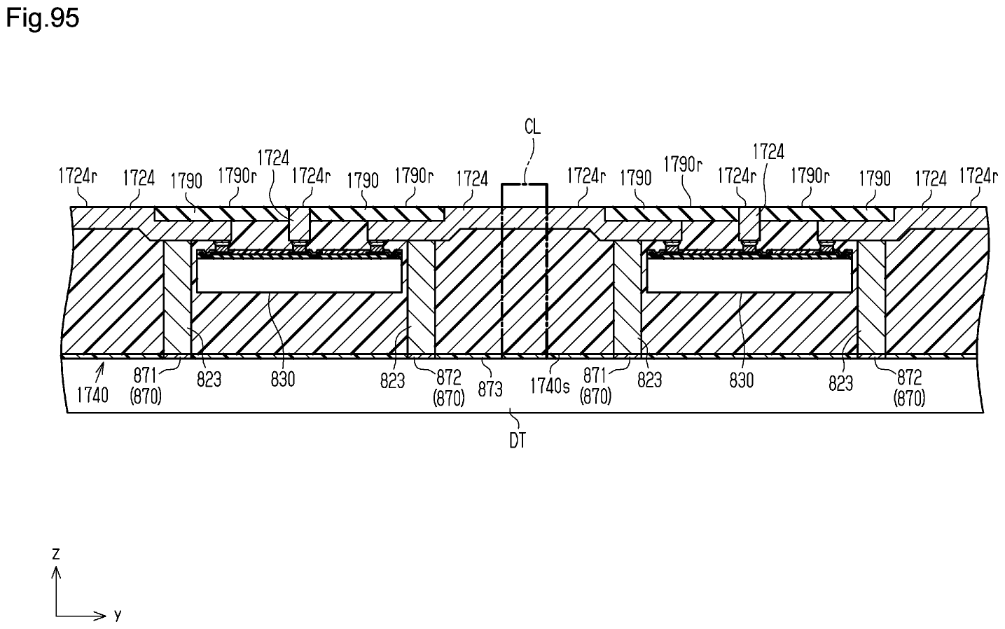

As shown in FIG. 95, the method for manufacturing the electronic component 801B includes a step of removing the sputtered film 1720 (refer to FIG. 94). When the sputtered film 1720 is removed, the insulation back surface 1790r of the insulation layer 1790 and a back surface 1724r of the wiring layer 1724 are exposed.

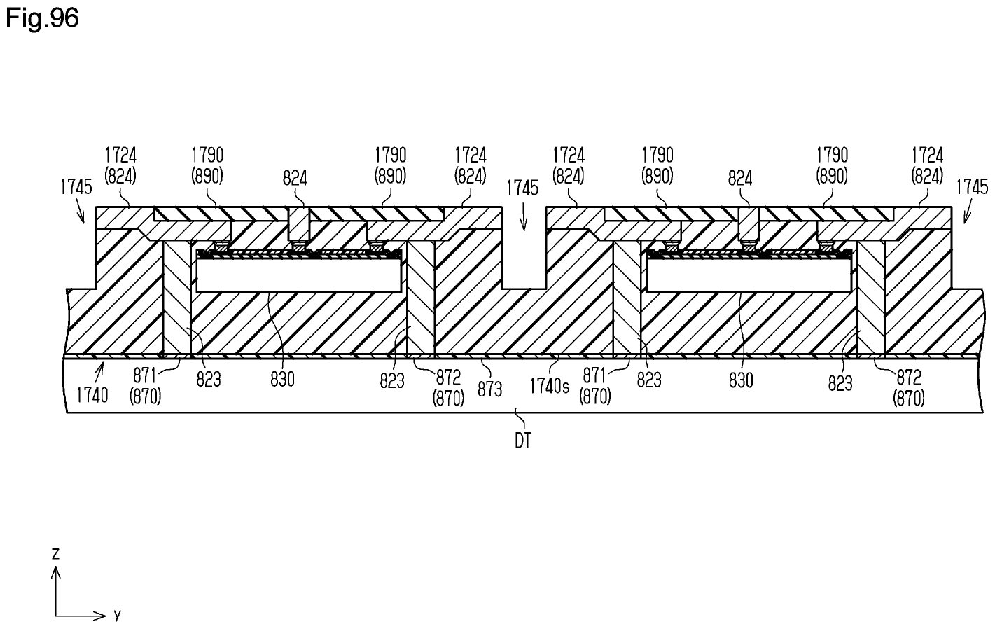

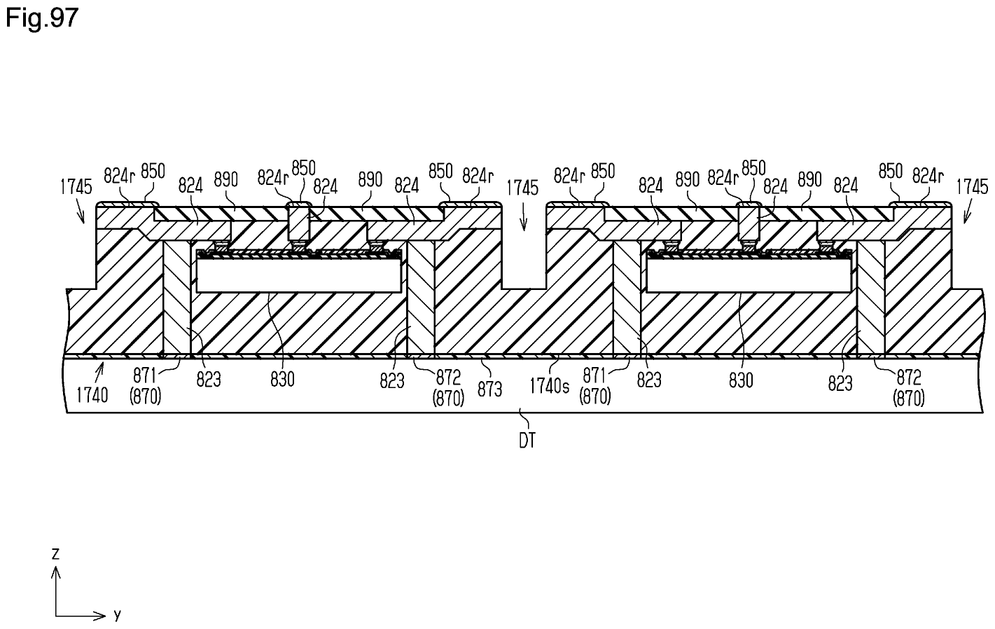

That is, the method for manufacturing the electronic component 801B includes a step of cutting the insulation layer 1790 and the wiring layer 1724 and half-cutting the resin layer 1740. More specifically, as shown in FIG. 96, the dicing tape DT is applied to the lower surface of the resin layer 1740. The insulation layer 1790 and the wiring layer 1724 are cut, and the resin layer 1740 is partially cut in the thickness-wise direction z (half cutting). The cutting of the insulation layer 1790 and the wiring layer 1724 and the half cutting of the resin layer 1740 are performed, for example, from the insulation layer 1790 toward the dicing tape DT along the cutting lines CL (single-dashed lines) shown in FIG. 95 using a dicing blade. In the cutting lines CL shown in FIG. 95, the width in a direction of the short sides corresponds to the thickness (width) of the dicing blade. As described above, the cutting of the insulation layer 1790 and the wiring layer 1724 forms the wiring layers 824 and the insulation member 890. The half cutting of the resin layer 1740 forms a separation groove 1745 in the resin layer 1740. That is, the method for manufacturing the electronic component 801B includes a cutting step. Moreover, the method for manufacturing the electronic component 801B includes a first cutting step.

The method for manufacturing the electronic component 801B includes a step of forming the outer electrodes 850 as shown in FIG. 97. The step of forming the outer electrodes 850 of the present embodiment is the same as the step of forming the outer electrodes 850 of the seventh embodiment.

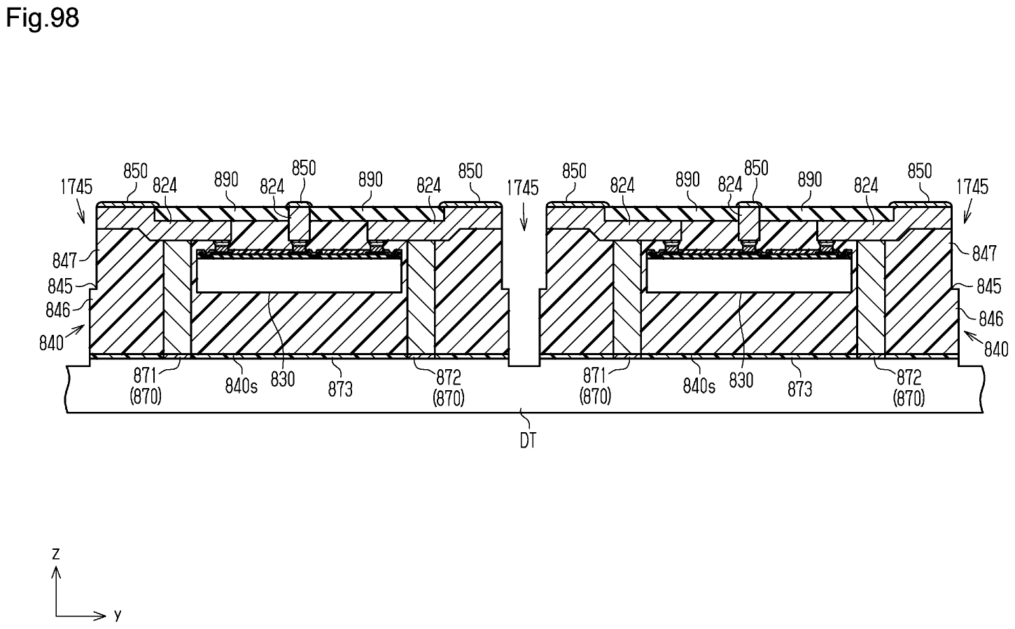

The method for manufacturing the electronic component 801B includes a step of separating into pieces singulated for each first functional element 830 as shown in FIG. 98. The step of separating into pieces singulated for each first functional element 830, in the present embodiment is the same as the step of separating into pieces singulated for each first functional element 830 in the seventh embodiment. That is, the method for manufacturing the electronic component 801B includes a cutting step. Moreover, the method for manufacturing the electronic component 801B includes a second cutting step.

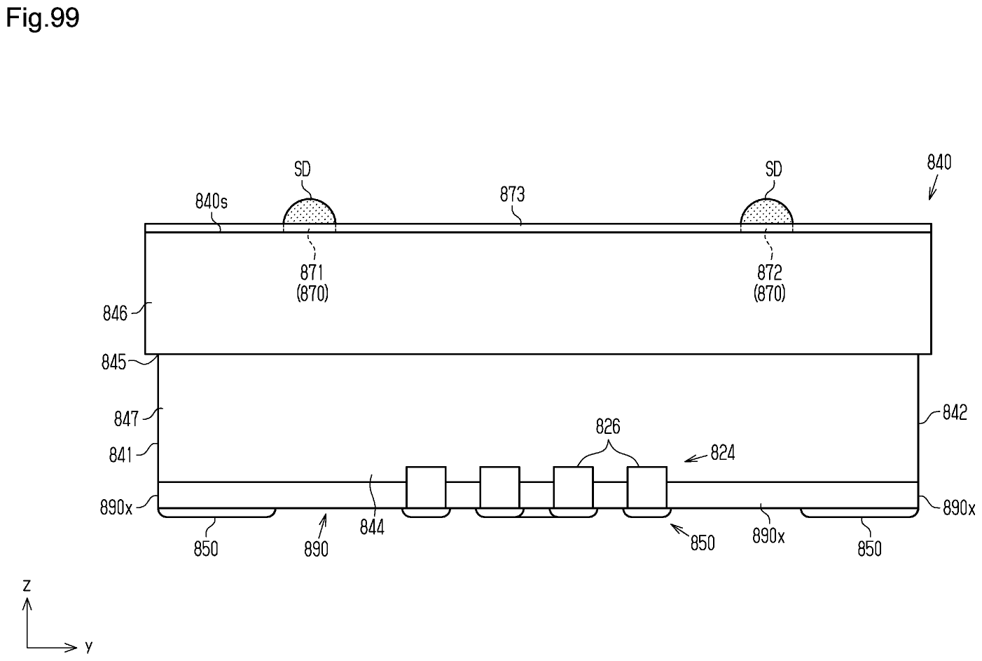

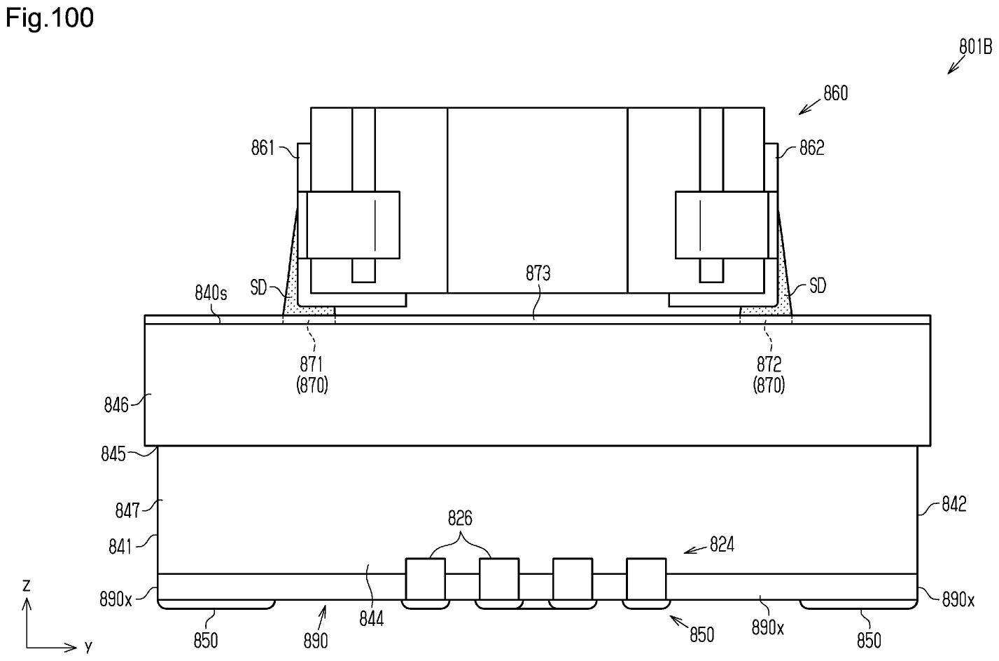

The method for manufacturing the electronic component 801B includes a step of mounting the second functional element 860 as shown in FIGS. 99 and 100. The step of mounting the second functional element 860 in the present embodiment is the same as the step of mounting the second functional element 860 in the seventh embodiment. That is, as shown in FIG. 99, the solder SD is formed on the first upper surface electrode 871 and the second upper surface electrode 872 of the upper surface wire 870. Subsequently, as shown in FIG. 100, the second functional element 860 is fixed to the solder SD. That is, the method for manufacturing the electronic component 801B includes a second functional element mounting step. The steps described above manufacture the electronic component 801B.

Advantages

The present embodiment has the following advantages in addition to the advantages of the seventh embodiment.

(2-1) The main surface wire 825 and the through wire 826 are integrally formed as the wiring layer 824. This configuration simplifies the step of forming the wiring layer 824 as compared to a configuration in which the main surface wire 825 and the through wire 826 are separately formed.

(2-2) The through wire 826 and the main surface wire 825 are formed to have the same thickness. In this configuration, the thickness of the insulation member 890 is decreased as compared to a configuration in which the through wire 826 is formed by a terminal pillar.

Ninth Embodiment

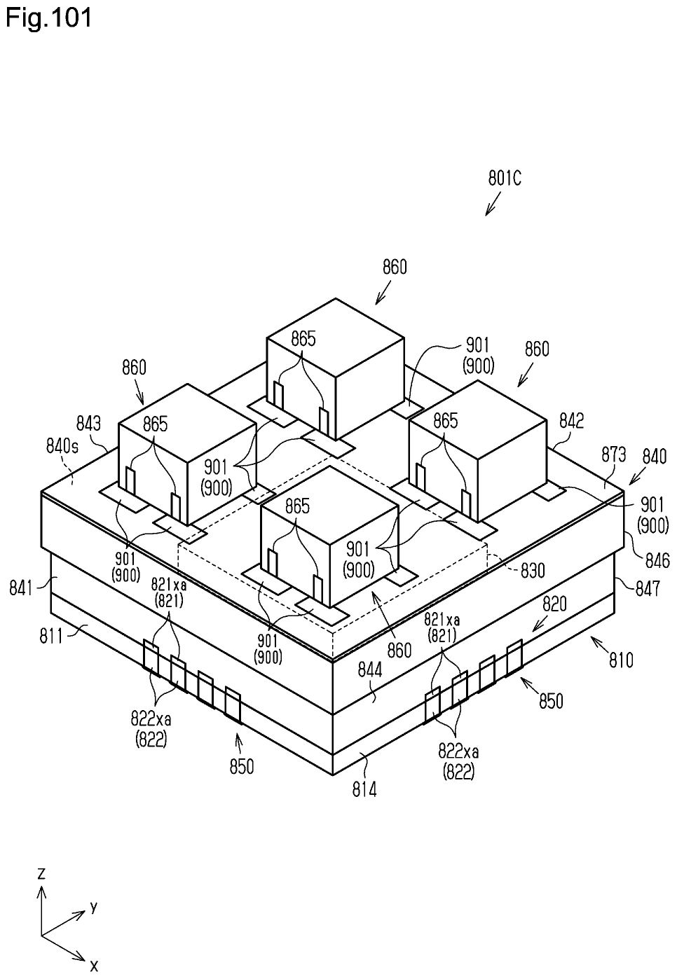

A ninth embodiment of an electronic component 801C according to the present disclosure will now be described with reference to FIGS. 101 to 105. The electronic component 801C of the present embodiment differs from the electronic component 801A of the seventh embodiment in the type of second functional element 860, the number of the second functional elements 860, the number of connection conductors 823, and the arrangement of the connection conductors 823. In the description below, the same reference signs are given to those elements that are the same as the electronic component 801A of the seventh embodiment. Such elements may not be described in detail. In FIG. 101, the second functional elements 860 are indicated by double-dashed lines for the sake of convenience.

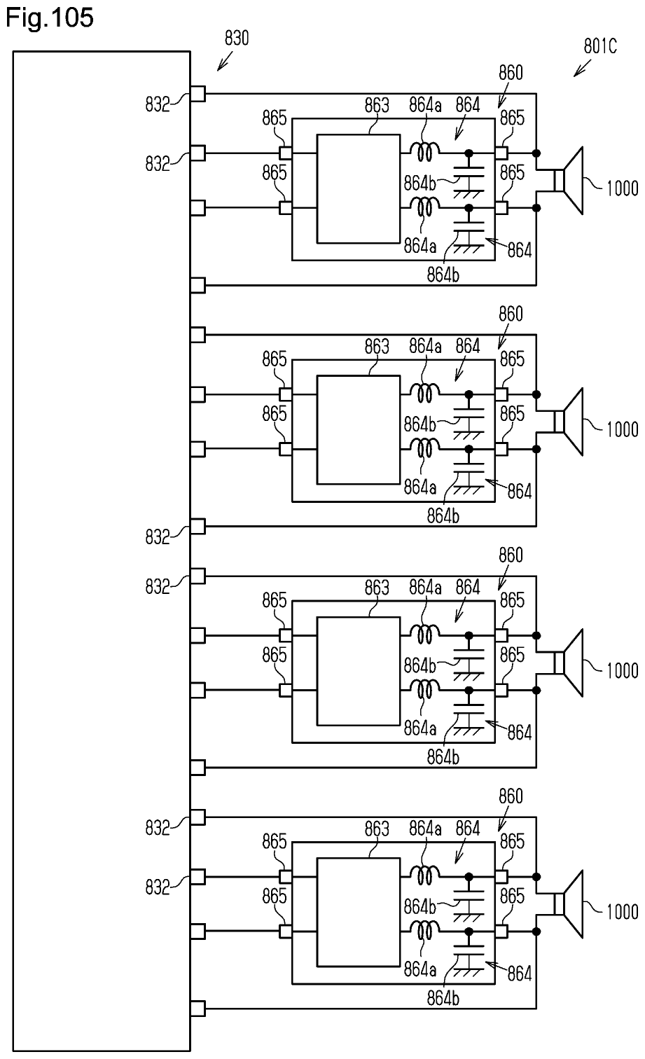

As shown in FIG. 101, the electronic component 801C of the present embodiment is configured to be an audio output device including the first functional element 830 and multiple (in the present embodiment, four) second functional elements 860. The audio output device is configured to amplify a weak audio signal and drive electroacoustic transducing elements 1000 (refer to FIG. 105) such as a speaker or headphones.

The second functional elements 860 are separated from each other in the first direction x and the second direction y. In the present embodiment, two second functional elements 860 are disposed on the resin main surface 840s close to the resin side surface 841 and are separated from each other the first direction x. Two second functional elements 860 are disposed on the resin main surface 840s close to the resin side surface 842 and are separated from each other in the first direction x.

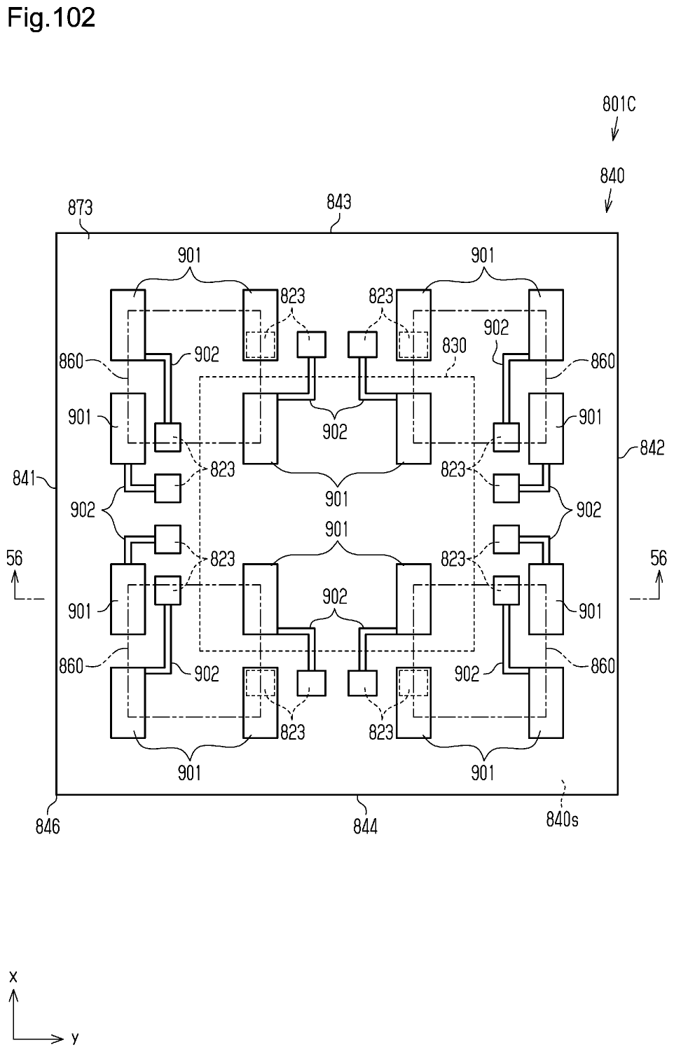

As shown in FIG. 102, an upper surface wire 900 is formed on the resin main surface 840s. The upper surface wire 900 includes upper surface electrodes 901 configured to be electrically connected to the second functional elements 860. In the present embodiment, four upper surface electrodes 901 are formed for each second functional element 860. The four upper surface electrodes 901 are separated from each other in the first direction x and the second direction y. Thus, in the present embodiment, the upper surface wire 900 includes sixteen upper surface electrodes 901.

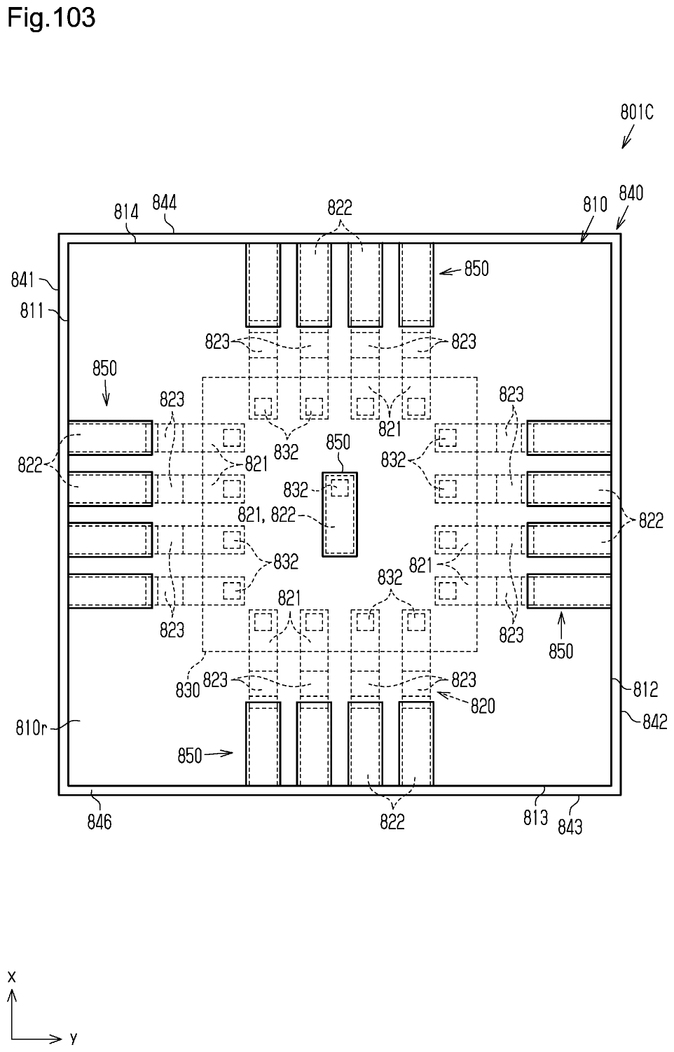

As shown in FIGS. 102 and 103, since the sixteen upper surface electrodes 901 and the sixteen main surface wires 821 are electrically connected by separate connection conductors 823, sixteen connection conductors 823 are provided. In other words, each main surface wire 821 is connected to a connection conductor 823.

As shown in FIG. 102, four of the connection conductors 823 overlap the upper surface electrodes 901 in the thickness-wise direction z. That is, the connection conductors 823 are in contact with the upper surface electrodes 901. Hence, the upper surface wire 900 includes twelve connection wires 902 separately connecting the twelve connection conductors 823 and the twelve upper surface electrodes 901 that do not overlap each other in the thickness-wise direction z. Thus, the first functional element 830 is electrically connected to the four second functional elements 860.

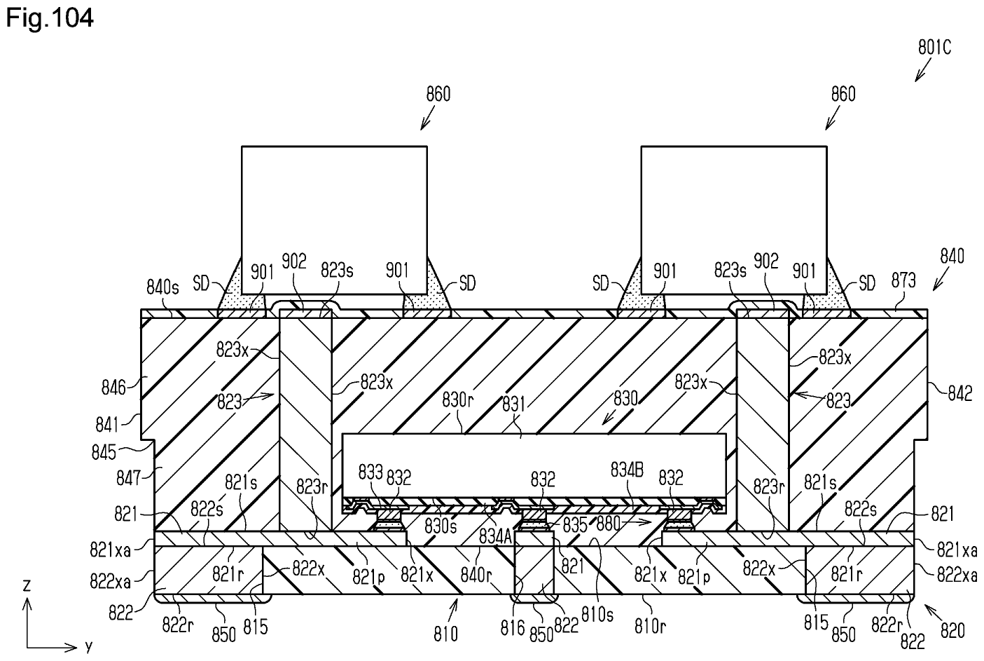

As shown in FIG. 104, the connection wires 902 are formed on the upper surface 823s of the connection conductors 823 that do not overlap the upper surface electrodes 901 in the thickness-wise direction z. That is, the connection wires 902 cover the upper surface 823 s of the connection conductors 823. The connection wires 902 are covered by the insulation film 873.

FIG. 105 schematically shows the circuit configuration of the electronic component 801C used as the audio output device. In the present embodiment, each second functional element 860 is electrically connected to the electroacoustic transducing element 1000 and amplifies an audio signal and outputs the signal to the electroacoustic transducing element 1000. The second functional element 860 includes a full-bridge output stage 863 and LC filters 864. The full-bridge output stage 863 amplifies and outputs an audio signal. The LC filters 864 remove noise from the audio signal, which is output from the output stage 863. In the present embodiment, since a balanced trans less (BTL) configuration is used, each second functional element 860 includes an output stage 863 and two LC filters 864 connected to the output stage 863. The use of the BLT configuration eliminates the need for output coupling capacitors and doubles the output of the electroacoustic transducing element 1000.

As shown in FIG. 105, each second functional element 860 has a packaged structure in which the output stage 863 and the two LC filters 864 are encapsulated by an encapsulation resin and includes four external electrodes 865. Among the four external electrodes 865, two external electrodes 865 are configured to be an input electrode that is electrically connected to the input side of one of the half-bridge circuits in the output stage 863 and an output electrode that is electrically connected to the output side of one of the two LC filters 864. The remaining two external electrodes 865 are configured to be an input electrode that is electrically connected to the input side of the other half-bridge circuit in the output stage 863 and an output electrode that is electrically connected to the output side of the other one of the two LC filters 864.

The output stage 863 includes two sets of two transistors that are connected in series, and the two sets are connected in parallel. One example of the transistor is an N-type metal—oxide—semiconductor field-effect transistor (MOSFET). In the output stage 863, two arms are connected in parallel and connected to a source electrode of an upper arm MOSFET and a drain electrode of a lower arm MOSFET.

The LC filters 864 each include an inductor 864a and a capacitor 864b that are connected in series. The inductor 864a has a first end connected to a node between the source electrode of the upper arm MOSFET and the drain electrode of the lower arm MOSFET. The inductor 864a has a second end connected to a first end of the capacitor 864b. The capacitor 864b has a second end connected ground. In addition, the second end of the inductor 864a and the first end of the capacitor 864b are connected to the electroacoustic transducing element 1000 by the external electrode 865.

The first functional element 830 is a control circuit element configured to control the second functional elements 860 and includes, for example, an LSI. The first functional element 830 controls the switching of each MOSFET between on and off in the output stage 863 of each second functional element 860. The first functional element 830 includes an upper arm drive circuit that controls the switching of the upper arm MOSFET, a lower arm drive circuit that controls the switching of the lower arm MOSFET, and a signal generation circuit that outputs a PWM signal to the upper arm drive circuit and the lower arm drive circuit for controlling each MOSEFT. That is, the electronic component 801C of the present embodiment is an audio output device that includes a class-D amplifier circuit.

The operation of the present embodiment will now be described.

Unlike the first functional element 830, the second functional elements 860 are not encapsulated by the encapsulation resin 840. In other words, the second functional elements 860 are mounted on the resin main surface 840s, which is located outside the encapsulation resin 840. Thus, the number of second functional elements 860 mounted on the resin main surface 840s is readily changed. The number of second functional elements 860 mounted on the resin main surface 840s is adjusted in accordance with the number of electroacoustic transducing elements 1000 electrically connected to the electronic component 801C.

The present embodiment has the following advantages in addition to the advantages of the seventh embodiment.

(3-1) The second functional element 860 includes a transistor as the output stage 863. In this configuration, the second functional element 860 is disposed outside the encapsulation resin 840. When the transistor is driven and generates heat, the heat is readily dissipated to the outside of the electronic component 801C. This limits interference of the heat of the transistor with heat generated by the driving of the first functional element 830, thereby avoiding concentration of the heats generated by the transistor and the first functional element 830.

In addition, since the second functional element 860 includes the output stage 863, the wire of the transistor through which a larger current flows is disposed in the second functional element 860. This reduces current that is supplied from the first functional element 830 to the output stage 863 of the second functional element 860. As a result, electromagnetic interference (EMI) noise is reduced in the inner electrodes 820, which connect the first functional element 830 and the second functional elements 860.

Modified Examples

The above-described embodiments exemplify, without any intention to limit, applicable forms of an electronic component and a method for manufacturing an electronic component according to the present disclosure. The electronic component and the method for manufacturing an electronic component according to the present disclosure may be applicable to forms differing from the above embodiments. In an example of such a form, the configuration of the embodiments is partially replaced, changed, or omitted, or a further configuration is added to the embodiments. The modified examples described below may be combined with one another as long as there is no technical inconsistency. For the sake of convenience, the following modified examples will be described based on the seventh embodiment. However, other embodiments may be used as long as there is no technical inconsistency.

In the seventh and ninth embodiments, the configuration of the main surface wires 821 may be changed in any manner. In an example, the main surface wires 821 may have a stacking structure such as that of the seed layer 824a and the plated layer 824b of the wiring layers 824 in the eighth embodiment. The wiring layers 824 of the eighth embodiment may have a stacking structure such as that of the metal layer 821a and the conductive layer 821b of the main surface wires 821 in the seventh embodiment.

In the seventh and ninth embodiments, the main surface wire 821 and the through wire 822 may be formed integrally in the same manner as the main surface wire 825 and the through wire 826 of the eighth embodiment.

In the eighth embodiment, the main surface wire 825 and the through wire 826 may be formed separately in the same manner as the main surface wires 821 and the through wires 822 of the seventh embodiment.

In the seventh and ninth embodiments, the width-wise dimension of the main surface wire 821 (dimension of the main surface wire 821 in a direction orthogonal to the direction in which the main surface wires 821 extends as viewed in the thickness-wise direction z) and the width-wise dimension of the through wire 822 (dimension of the through wire 822 in a direction in which the through wire 822 extends as viewed in the thickness-wise direction z) may be changed in any manner. In an example, the width-wise dimension of the main surface wire 821 may be greater than the width-wise dimension of the through wire 822. The width-wise dimension of the main surface wire 821 may be smaller than the width-wise dimension of the through wire 822.

In the ninth embodiment, the electronic component 801C may include the insulation member 890 of the electronic component 801B instead of the substrate 810. In this case, the wiring layers 824 are used instead of the main surface wires 821 and the through wires 822.

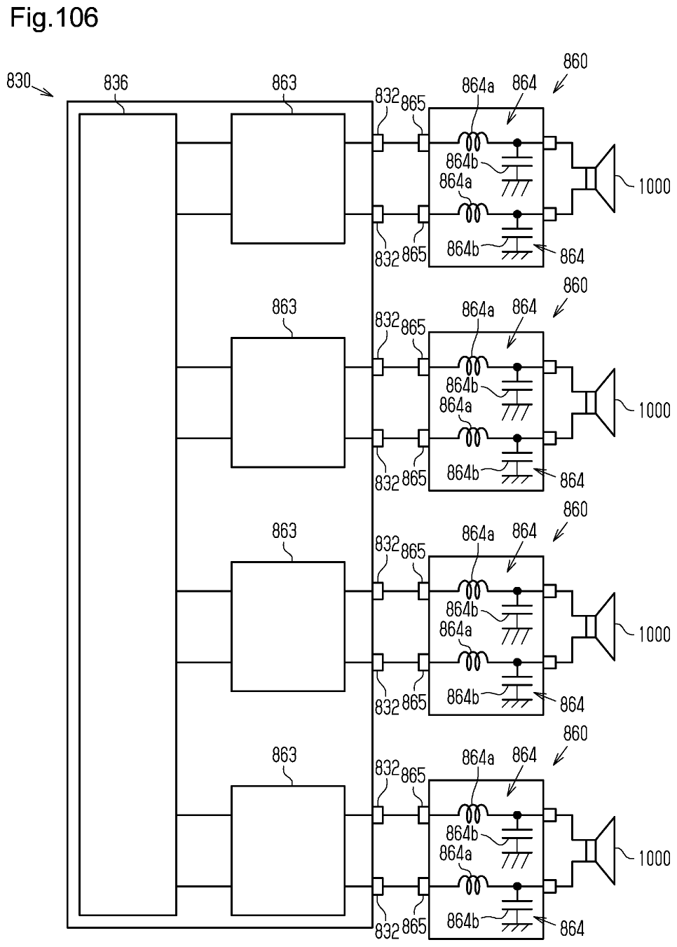

In the ninth embodiment, the configuration of the first functional element 830 and the configuration of the second functional elements 860 may be changed in any manner. In an example, as shown in FIG. 106, the first functional element 830 may include the output stages 863 of the second functional elements 860 of the ninth embodiment. The first functional element 830 includes a control circuit 836 that controls the output stages 863 of the second functional elements 860. The control circuit 836 includes, for example, an LSI. Since the first functional element 830 includes the output stages 863, the output stages 863 are omitted from the second functional elements 860. The second functional elements 860 each include the LC filters 864.

In the electronic component 801C, the first functional element 830 and the second functional elements 860 are electrically connected by the inner electrodes 820 and the upper surface wire 870. This shortens the conductive path between the first functional element 830 and the second functional elements 860 as compared to a configuration in which the second functional elements 860 are disposed separately from the encapsulation resin 840 of the electronic component 801C. As shown in FIG. 106, since the first functional element 830 includes the output stages 863, the conductive path between the first functional element 830 and the second functional elements 860 is short, so that an increase in EMI noise is limited even when a large current flows from the output stages 863 of the first functional element 830 to the second functional elements 860.

In each embodiment, the shape of the electronic components 801A, 801B, and 801C may be changed. In an example, the electronic component 801A has a configuration in which the steps 845 are omitted from the encapsulation resin 840. That is, the first resin part 846 and the second resin part 847 are not separated in the encapsulation resin 840. A method for manufacturing such an electronic component 801A includes a singulation step instead of the step of cutting the base member 1610 and cutting a half of the resin layer 1640. More specifically, after the singulation step, the step of forming the outer electrodes 850 is performed. The steps 845 may be omitted from the electronic component 801B of the eighth embodiment and the electronic component 801C of the ninth embodiment.

In the seventh and ninth embodiments, as viewed in the thickness-wise direction z, the shape of the back surface 822r of the through wires 822 exposed from the substrate 810 may be changed in any manner. The back surface 822r of the through wires 822 arranged separately from each other in the first direction x may be rectangular as viewed in the thickness-wise direction z so that the long sides extend in the second direction y and the short sides extend in the first direction x. The back surface 822r of the through wires 822 arranged separately from each other in the second direction y may be rectangular as viewed in the thickness-wise direction z so that the long sides extend in the first direction x and the short sides extend in the second direction y. The shape of the back surface 822r of the through wires 822 as viewed in the thickness-wise direction z is not limited to a rectangle and may be circular or elliptical.

In the eighth embodiment, as viewed in the thickness-wise direction z, the shape of the back surface 826r of the through wire 826 exposed from the insulation member 890 may be changed in any manner. The back surface 826r of the through wires 826 arranged separately from each other in the first direction x may be rectangular as viewed in the thickness-wise direction z so that the long sides extend in the second direction y and the short sides extend in the first direction x. The back surface 826r of the through wires 826 arranged separately from each other in the second direction y may be rectangular as viewed in the thickness-wise direction z so that the long sides extend in the first direction x and the short sides extend in the second direction y. The shape of the back surface 826r of the through wires 826 as viewed in the thickness-wise direction z is not limited to a rectangle and may be circular or elliptical.

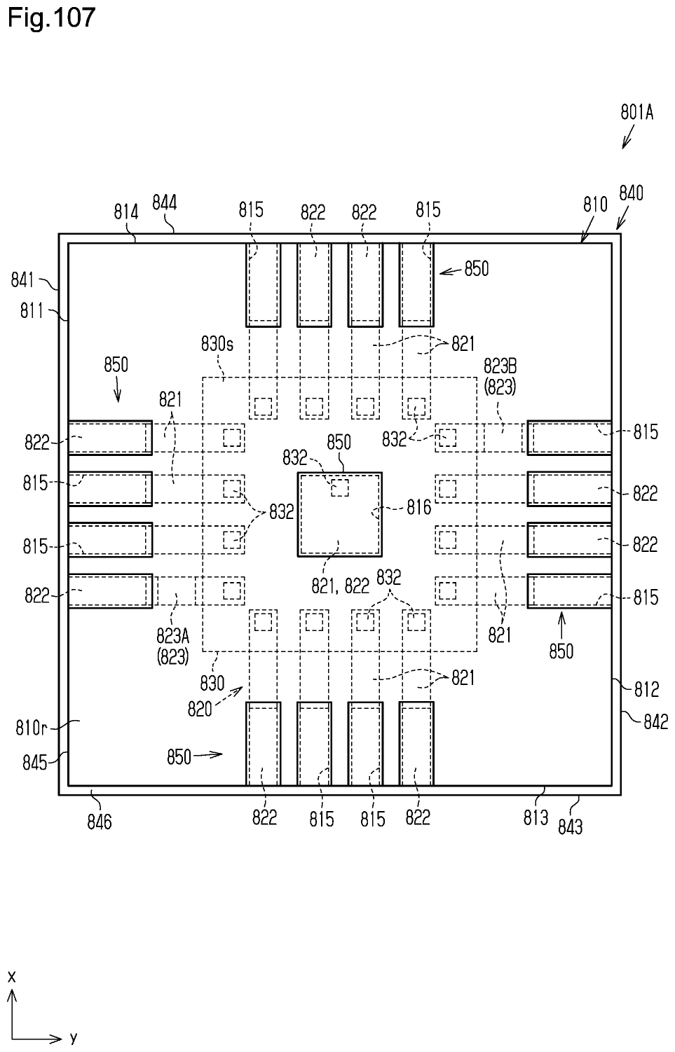

In each embodiment, the shape of the through holes 816 and 892 as viewed in the thickness-wise direction z and the shape of the through wires 822 and 826 disposed in the through holes 816 and 892 as viewed in the thickness-wise direction z (the shape of the outer electrodes 850 as viewed in the thickness-wise direction z) may be changed in any manner. In an example, as shown in FIG. 107, the shape of the through hole 816 as viewed in the thickness-wise direction z and the shape of the through wire 822 disposed in the through hole 816 as viewed in the thickness-wise direction z (the shape of the outer electrode 850 as viewed in the thickness-wise direction z) are each square. In the illustrated example, the dimension of the through hole 816 in the second direction y and the dimension of the through wire 822 disposed in the through hole 816 in the second direction y (dimension of the outer electrode 850 in the second direction y) are greater than the dimension of the through hole 816 in the second direction y and the dimension of the through wire 822 in the through hole 816 in the second direction y (dimension of the outer electrode 850 in the second direction y) in the seventh embodiment. This configuration facilitates heat dissipation from the first functional element 830 to the exterior of the electronic component 801A.

In each embodiment, the through wires 822 and 826 disposed in the through holes 816 and 892 do not have to be electrically connected to the electrode pads 832 of the first functional element 830 by the main surface wires 821. In this case, the outer electrodes 850 that cover the through wires 822 and 826 disposed in the through holes 816 and 892 may be omitted.

In each embodiment, the through holes 816 and 892 and the through wires 822 and 826 disposed in the through holes 816 and 892 may be omitted. Accordingly, the outer electrodes 850 that cover the through wires 822 and 826 disposed in the through holes 816 and 892 may also be omitted.

In each embodiment, the inner electrodes 820 are formed through electrolytic plating. However, there is no limit to such a configuration. For example, the main surface wires 821 of the inner electrodes 820 may be formed by a lead frame, and the connection conductors 823 may be formed by a metal post. In this case, the connection conductors 823 may be bonded to the wire main surface 821s of the main surface wires 821 by a conductive bonding material or may be bonded to the main surface wires 821 by welding such as ultrasonic welding.

In each embodiment, the outer electrodes 850 cover the back surfaces 822r and 826r of the through wires 822 and 826. However, there is no limit to such a configuration. For example, in the seventh and ninth embodiments, the outer electrodes 850 may be configured to cover the side surfaces 822x of the through wires 822 including the exposed side surface 822xa, which is exposed from the substrate side surfaces 811 to 814 of the substrate 810. The outer electrodes 850 may be configured to cover the main surface wires 821 including the wire side surface 821xa exposed from the resin side surfaces 841 to 844 of the encapsulation resin 840. In the eighth embodiment, the outer electrodes 850 may be configured to cover the side surfaces of the through wire 826 including side surfaces exposed from the insulation side surfaces 890x of the insulation member 890. The outer electrodes 850 may be configured to cover the main surface wires 825 including side surfaces exposed from the resin side surfaces 841 to 844 of the encapsulation resin 840.

In the seventh and ninth embodiments, the position of the connection conductors 823 with respect to the main surface wires 821 may be changed in any manner. In an example, the connection conductors 823 are disposed on the main surface wires 821 at a position overlapping the through wires 822 in the thickness-wise direction z.

In the eighth embodiment, the position of the connection conductors 823 with respect to the wiring layers 824 may be changed in any manner. In an example, the first connection conductor 823A is connected to the through wire 826 of the wiring layer 824. The second connection conductor 823B is connected to the through wire 826 of the wiring layer 824.

In the seventh and eighth embodiments, the positional relationship of the first connection conductor 823A and the second connection conductor 823B with the first functional element 830 may be changed in any manner. In an example, the first connection conductor 823A and the second connection conductor 823B may be located at one side of the first functional element 830 in the second direction y. In an example, the first connection conductor 823A and the second connection conductor 823B may be located at separate positions in the first direction x with respect to the first functional element 830. The first connection conductor 823A and the second connection conductor 823B may be located at one side of the first functional element 830 in the first direction x.

In each embodiment, the dimensions of the connection conductor 823 in the first direction x and the second direction y may be changed in any manner. In an example, in the seventh embodiment, the first connection conductor 823A is greater in the dimension in the first direction x than the main surface wire 821, which extends in the second direction y. Also, the second connection conductor 823B is greater in the dimension in the first direction x than the main surface wire 821, which extends in the second direction y.

In each embodiment, the number of main surface wires 821, through wires 822, and connection conductors 823 may be changed in any manner. Any number of main surface wires 821, through wires 822, and connection conductors 823 may be used as long as the first functional element 830 is electrically connected to the second functional element 860. For example, the number of main surface wires 821, through wires 822, and connection conductors 823 may each be one.

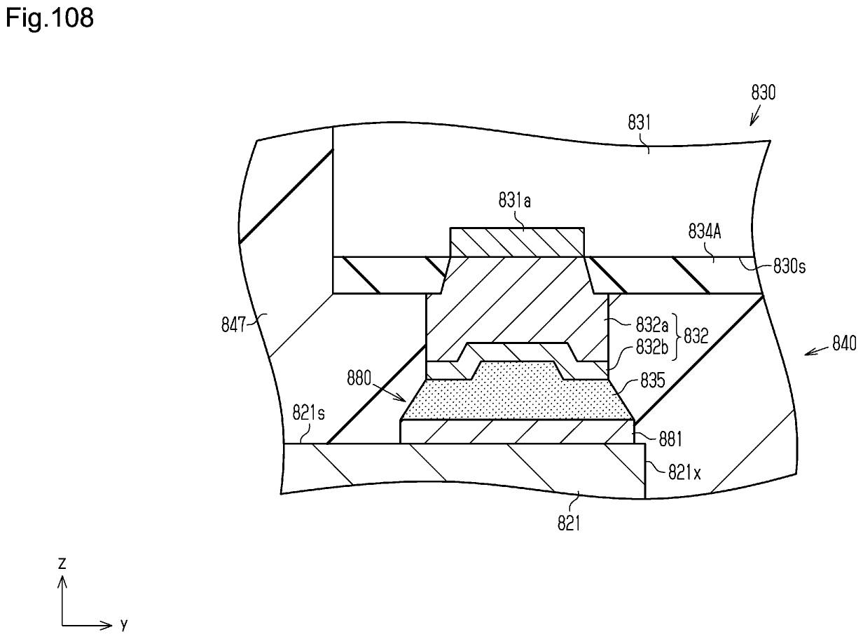

In each embodiment, the first functional element 830 may include terminals that may be changed in configuration. In an example, as shown in FIG. 108, the wire 833 may be omitted, and the electrode pad 832 may be disposed in the recess 831b of the element substrate 831 In this case, the electrode pad 832 is directly connected to the electrode 831a.

In each embodiment, the main surface wires 821 and the first functional element 830 are electrically connected by flip-chip-bonding. However, there is no limit to such a configuration. For example, the main surface wires 821 and the first functional element 830 may be electrically connected by a wire formed by wire bonding.

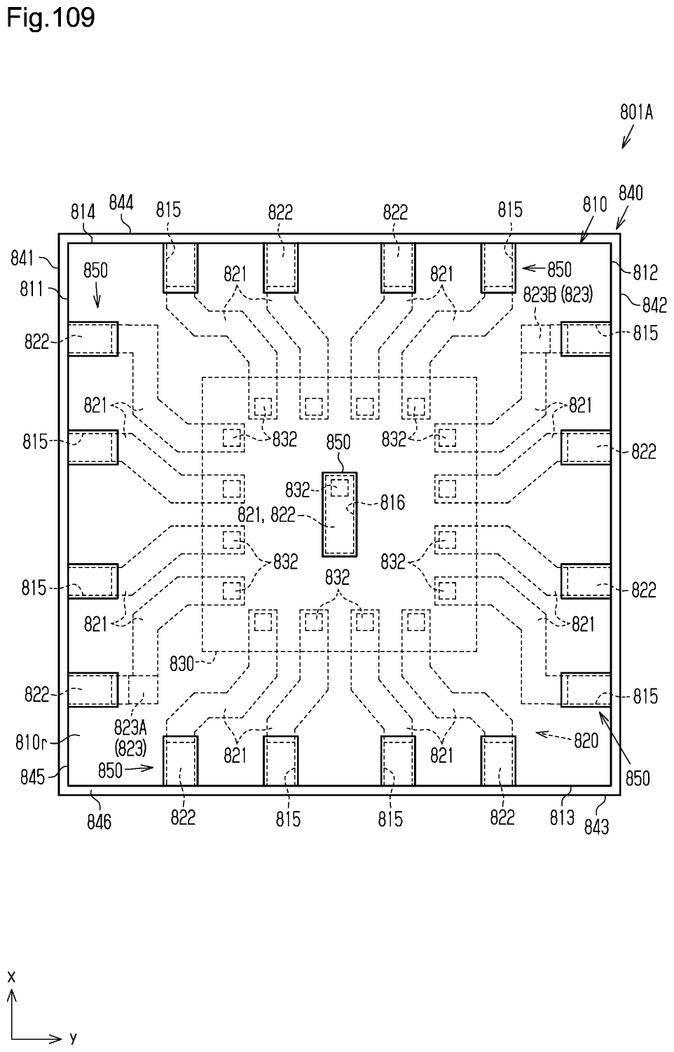

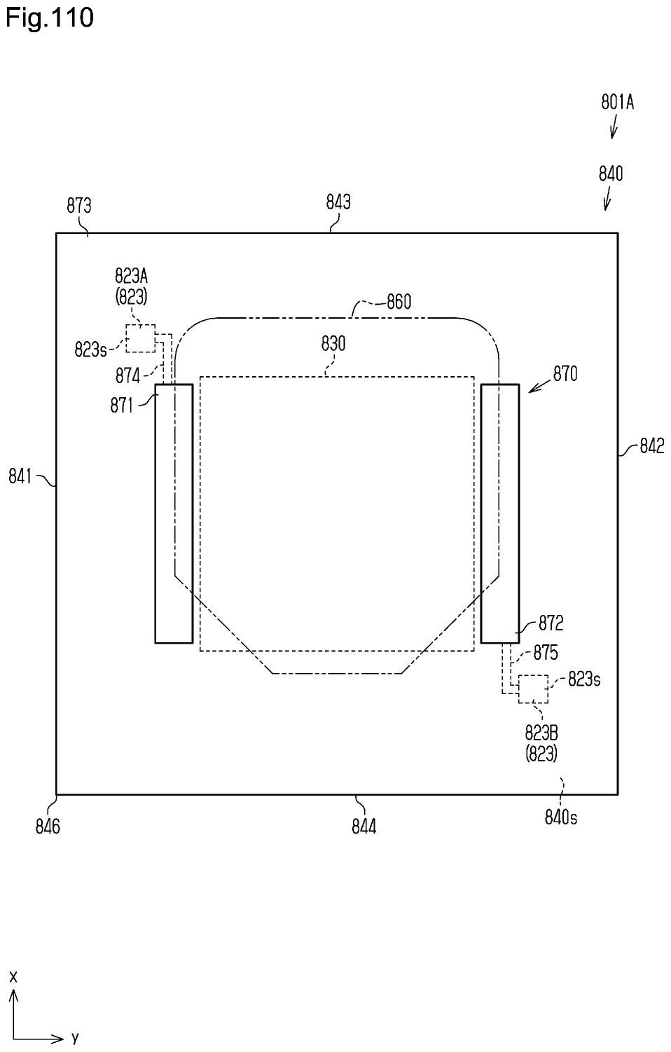

In each embodiment, the main surface wires 821 extend in the first direction x or the second direction y. There is no limit to such a configuration. For example, as shown in FIG. 109, the electronic component 801A may be configured so that the pitch between the through wires 822 (outer electrodes 850) arranged in the first direction x is greater than the pitch between the electrode pads 832 arranged in the first direction x and that the pitch between the through wires 822 (outer electrodes 850) arranged in the second direction y is greater than the pitch between the electrode pads 832 arranged in the second direction y. In this case, as shown in FIG. 110, as viewed in the thickness-wise direction z, the first connection conductor 823A and the second connection conductor 823B do not overlap the first upper surface electrode 871 and the second upper surface electrode 872 of the upper surface wire 870. Thus, in the illustrated example, the upper surface wire 870 includes a connection wire 874 that connects the first upper surface electrode 871 to the first connection conductor 823A and a connection wire 874 that connects the second upper surface electrode 872 to the second connection conductor 823B. In the illustrated example, the first upper surface electrode 871 and the connection wire 874 are formed integrally, and the second upper surface electrode 872 and a connection wire 875 are formed integrally. The connection wire 874 is disposed to cover the upper surface 823s of the first connection conductor 823A.

The connection wire 875 is disposed to cover the upper surface 823s of the second connection conductor 823B. The electronic component 801B of the eighth embodiment may be changed in the same manner.

In each embodiment, the main surface wire 821 does not have to include the inward part 821p. In this case, the connection conductor 823 is connected to a portion of the main surface wire 821 that overlaps the through wire 822 in the thickness-wise direction z.

In each embodiment, the upper surface wire 870 and the second functional element 860 are electrically connected by the solder SD. However, there is no limit to such a configuration. For example, the upper surface wire 870 and the second functional element 860 may be electrically connected by a wire formed by wire bonding.

In each embodiment, the upper surface wires 870 and 900 may be omitted from the electronic components 801A to 801C. In this case, the connection conductors 823 and the second functional element 860 are directly electrically connected. In an example, the upper surface 823s of the first connection conductor 823A exposed from the resin main surface 840s is connected to the first electrode 861 of the second functional element 860 by the solder SD, and the upper surface 823s of the second connection conductor 823B exposed from the resin main surface 840s is connected to the second electrode 862 of the second functional element 860 by the solder SD.

In each embodiment, the insulation film 873 may be omitted from the electronic components 801A to 801C.

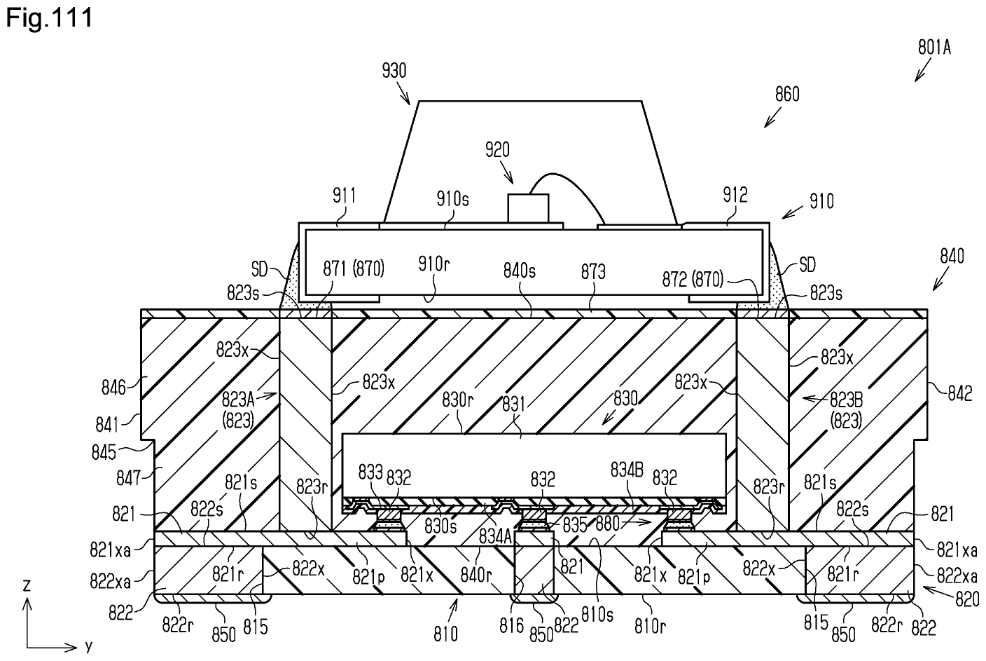

In each embodiment, the relationship between the first functional element 830 and the second functional element 860 may be changed in any manner. In an example, the second functional element 860 may be a drive element, and the first functional element 830 may be a control element that controls the driving of the second functional element 860. Alternatively, the second functional element 860 may be an optical element, and the first functional element 830 may be a control element that controls the optical mode of the second functional element 860. The optical element may be, for example, a light emitting diode. In this case, the first functional element 830, which is the control element, controls the supply of power to the optical element (second functional element 860). In an example, as shown in FIG. 111, the second functional element 860 includes a substrate 910 including a substrate main surface 910s and a substrate back surface 910r facing in opposite directions in the thickness-wise direction z, a light emitting diode 920 mounted on the substrate main surface 910s, and a transparent encapsulation resin 930 that encapsulates the light emitting diode 920. The substrate 910 is flat and rectangular so that the long sides extend in the second direction y and the short sides extend in the first direction x. A first electrode 911 and a second electrode 912 are disposed on opposite ends of the substrate 910 in the second direction y. The first electrode 911 forms an anode electrode. The second electrode 912 forms a cathode electrode. The first electrode 911 is connected to the first upper surface electrode 871. The second electrode 912 is connected to the second upper surface electrode 872. Thus, the light emitting diode 920 is electrically connected to the ISL, that is, the first functional element 830. The optical element may be a vertical cavity surface emitting laser (VCSEL).

In each embodiment, the electronic components 801A, 801B, and 801C may include multiple first functional elements 830. In this case, the first functional elements 830 may differ from each other in type (e.g., LSI, IC).

In the seventh and eighth embodiments, the size of the second functional element 860 may be changed in any manner. In an example, the second functional element 860 may be smaller in size than the first functional element 830. In the seventh and eighth embodiments, the second functional elements 860 may be mounted on the resin main surface 840s.

In each embodiment, the second functional elements may be omitted from the electronic components 801A, 801B, and 801C. That is, the electronic components 801A, 801B, and 801C may include the substrate 810 (insulation member 890), the main surface wires 821 (825), the first functional element 830 electrically connected to the main surface wires 821 (825), the connection conductors 823 electrically connected to the main surface wires 821 (825), the through wires 822 (826) electrically connected to the main surface wires 821 (825), and the encapsulation resin 840 that encapsulates the main surface wires 821 (825), the first functional element 830, and the connection conductors 823. The first functional element 830 and the substrate 810 (the insulation member 890) are disposed at opposite sides of the main surface wires 821 (825) in the thickness-wise direction z. The connection conductors 823 extend away from the substrate 810 (insulation member 890) in the thickness-wise direction z. The through wires 822 (826) extend away from the first functional element 830 in the thickness-wise direction z. In this case, the connection conductors 823 are exposed from the resin main surface 840s of the encapsulation resin 840 so as to be electrically connected to the second functional element 860. In the electronic components 801A, 801B, and 801C, the resin main surface 840s of the encapsulation resin 840 may include the upper surface wire 870.

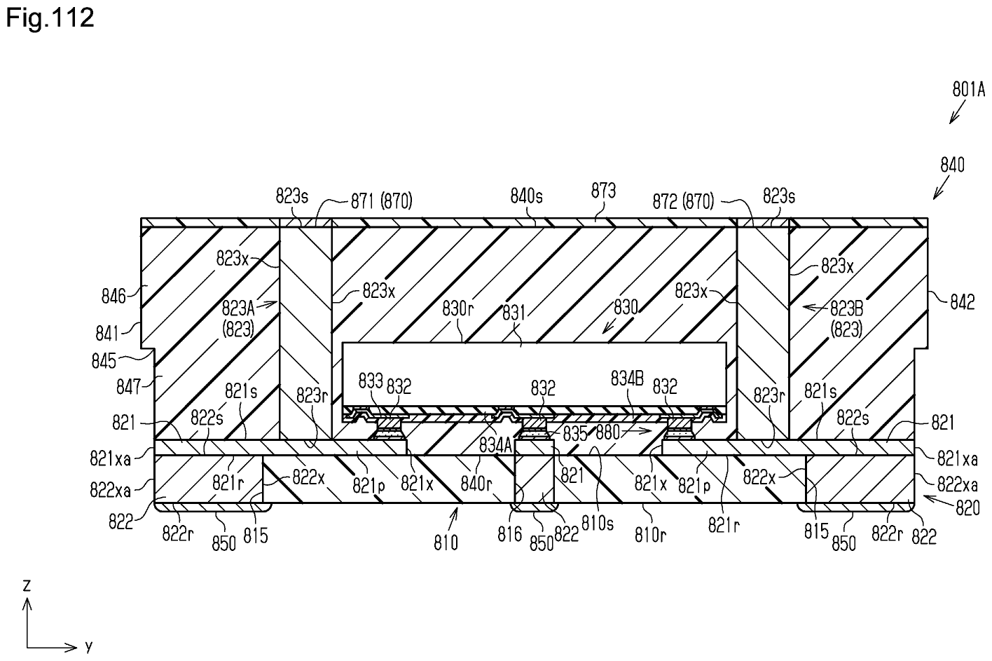

In an example, as shown in FIG. 112, the electronic component 801A does not include the second functional element 860. The upper surface wire 870 is formed on the resin main surface 840s of the encapsulation resin 840. With this configuration, the type of second functional element 860 may be changed in accordance with a circuit used with the electronic component 801A. Further, after the electronic component 801A is mounted on a wiring substrate (not shown), a suitable type of second functional element 860 for the circuit of the wiring substrate may be mounted on the upper surface wire 870. The electronic components 801B and 801C may be changed in the same manner.

A method for manufacturing such electronic components 801A and 801C that do not include the second functional element 860 includes the same steps as the method for manufacturing the electronic component 801A of the seventh embodiment from the step of forming the terminal pillars 1622 on the upper surface 1601 of the support substrate 1600 shown in FIG. 59 to the step of separating into pieces singulated for each first functional element 830 shown in FIG. 76. More specifically, the method for manufacturing the electronic components 801A and 801C that do not include the second functional element 860 includes the step of forming the through wires 822, the insulation layer forming step that forms the insulation layer (base member 1610), the main surface wire forming step that forms the main surface wire 1621, the conductor forming step that forms the connection conductors 1623, the first element mounting step that mounts the first functional element 830, the resin layer forming step that forms the resin layer 1640, and the cutting step that cuts the resin layer 1640.

A method for manufacturing the electronic component 801B that does not include the second functional element 860 includes the same steps as the method for manufacturing the electronic component 801B of the eighth embodiment from the step of preparing the support substrate 1700 shown in FIG. 81 to the step of separating into pieces singulated for each first functional element 830 shown in FIG. 98. More specifically, the method for manufacturing the electronic component 801B that do not include the second functional element 860 includes the insulation layer forming step that forms the insulation layer 1790, the first inner electrode forming step that forms the wiring layer 1724 including the main surface wire and the through wire, the second inner electrode forming step that forms the connection conductors 1723, the first element mounting step that mounts the first functional element 830, the resin layer forming step that forms the resin layer 1740, and the cutting step that cuts the resin layer 1740.

Clauses

The technical aspects that are understood from the embodiments and the modified examples will be described below.

1-1. A semiconductor device, including:

a substrate including a substrate main surface and a substrate back surface facing in opposite directions;

a wire portion including a conductive layer formed on the substrate main surface;

a bonding portion including a first plated layer formed on an upper surface of the wire portion and a first solder layer formed on an upper surface of the first plated layer;

a semiconductor element including an element main surface facing the substrate main surface, an element electrode formed on the element main surface, and a second plated layer formed on a lower surface of the element electrode and bonded to the first solder layer; and

an encapsulation resin covering the semiconductor element, in which

the bonding portion is larger than the element electrode as viewed in a thickness-wise direction that is perpendicular to the substrate main surface.

1-2. The semiconductor device according to clause 1-1, in which a cross section of the first solder layer that is perpendicular to the substrate main surface has an aspect ratio that is greater than or equal to 40 and less than or equal to 80.

1-3. The semiconductor device according to clause 1-1 or 1-2, in which a distance from the element electrode to an end of the bonding portion is greater than or equal to 4 μm and less than or equal to 10 μm.

1-4. The semiconductor device according to any one of clauses 1-1 to 1-3, in which a distance between an end of the conductive layer and an end of the bonding portion is less than or equal to 1 μm.

1-5. The semiconductor device according to any one of clauses 1-1 to 1-4, in which

the element electrode and the second solder layer are disposed on each end of a mount surface in a first direction that is parallel to the mount surface, and

the wire portion extends toward an outer side of the semiconductor element.

1-6. The semiconductor device according to clause 1-5, in which the element electrode is separated from an end of the bonding portion by a first distance in a direction toward an inner side of the semiconductor element, the element electrode is separated from an end of the bonding portion by a second distance in a direction toward an outer side of the semiconductor element, and the second distance is greater than the first distance.

1-7. The semiconductor device according to any one of clauses 1-1 to 1-6, in which the solder layer has a thickness that is less than or equal to a thickness of the first plated layer.

1-8. The semiconductor device according to any one of clauses 1-1 to 1-7, in which

the first solder layer has a thickness that is greater than or equal to 1 μm and less than or equal to 5 μm, and

the first plated layer has a thickness that is greater than or equal to 3 μm and less than or equal to 5 μm.

1-9. The semiconductor device according to any one of clauses 1-1 to 1-8, in which the conductive layer has a thickness that is greater than or equal to 15 μm and less than or equal to 20 μm.

1-10. The semiconductor device according to any one of clauses 1-1 to 1-9, in which the first solder layer and the second solder layer form a solder layer having a thickness that is greater than or equal to 10 μm and less than or equal to 15 μm.

1-11. The semiconductor device according to any one of clauses 1-1 to 1-10, in which

the conductive layer is formed from Cu, and

the first plated layer is formed from Ni.

1-12. The semiconductor device according to any one of clauses 1-1 to 1-11, in which

the element electrode includes a second plated layer, and

the second solder layer is formed on a lower surface of the second plated layer.

1-13. The semiconductor device according to clause 1-12, in which the second plated layer is formed from Ni.

1-14. The semiconductor device according to any one of clauses 1-1 to 1-13, further including a metal layer formed on a lower surface of the conductive layer.

1-15. The semiconductor device according to clause 1-14, in which the metal layer includes Ti.

1-16. The semiconductor device according to any one of clauses 1-1 to 1-15, in which

the substrate is formed from a resin,

the wire portion includes a main surface wire and a through wire,

the main surface wire includes the conductive layer, and

the through wire is disposed outside the semiconductor element as viewed in the thickness-wise direction, is connected to the main surface wire, and extends through the substrate in the thickness-wise direction.

1-17. The semiconductor device according to clause 1-16, further including an external connection terminal covering the through wire exposed on the substrate back surface.

1-18. The semiconductor device according to clause 1-17, in which the main surface wire and the through wire are exposed on a side surface of the substrate.

1-19. The semiconductor device according to clause 1-18, in which the external connection terminal covers the main surface wire and the through wire exposed on the side surface of the substrate.

1-20. The semiconductor device according to clause 1-16, in which the wire portion includes a columnar wire,

the columnar wire and the through wire are located at opposite sides of the main surface wire,

the columnar wire includes a side surface extending in the thickness-wise direction and exposed from the resin side surface.

1-21. The semiconductor device according to clause 1-20, in which

the encapsulation resin includes a first resin part located toward the substrate and a second resin part located toward a resin upper surface, and

as viewed in the thickness-wise direction, the second resin part is larger than the first resin part.

1-22. The semiconductor device according to clause 1-20 or 1-21, further including an external connection terminal covering the wire portion exposed from the substrate and the encapsulation resin.

1-23. The semiconductor device according to any one of clauses 1-1 to 1-15, in which

the substrate is formed from a resin,

the wire portion includes a main surface wire and a through wire,

the main surface wire includes the conductive layer, and

the through wire is disposed outside the semiconductor element as viewed in the thickness-wise direction, is connected to the main surface wire, and extends through the encapsulation resin in the thickness-wise direction.

1-24. The semiconductor device according to clause 1-23, further including an external connection terminal covering the through wire exposed on an upper surface of the encapsulation resin.

1-25. The semiconductor device according to any one of clauses 1-1 to 1-15, in which

the substrate is formed from a semiconductor material,

the wire portion includes a main surface wire and a through wire,

the main surface wire includes the conductive layer, and

the through wire is disposed outside the semiconductor element as viewed in the thickness-wise direction, is connected to the main surface wire, and extends through the substrate in the thickness-wise direction.

1-26. The semiconductor device according to clause 1-25, in which the substrate includes a first insulation layer disposed between the substrate main surface and the conductive layer and a second insulation layer disposed between the through wire disposed in a through hole and a wall surface defining the through hole.

1-27. The semiconductor device according to clause 1-25 or 1-26, in which

the through wire includes an upper surface facing toward the conductive layer, and

the upper surface is recessed inward from the through wire.

1-28. The semiconductor device according to any one of clauses 1-23 to 1-27, further including an external connection terminal covering the through wire exposed on the substrate back surface.

2-1. A semiconductor device, including:

an encapsulation resin including a first layer and a second layer, the first layer including a first main surface and a first back surface facing in opposite directions in a thickness-wise direction, the second layer including a second main surface and a second back surface facing in opposite directions in the thickness-wise direction, and the second back surface being in contact with the first main surface;

a wire being in contact with the first main surface and partially covered by the second layer; and

a semiconductor element including a lower surface facing the first main surface and pads disposed on the lower surface, in which at least one of the pads is bonded to the wire and covered by the second layer.

2-2. The semiconductor device according to clause 2-1, in which a distance between the first main surface and the second back surface is smaller than a distance between the second main surface and the second back surface.

2-3. The semiconductor device according to clause 2-2, in which the first layer contains a filler including an inorganic compound.

2-4. The semiconductor device according to clause 2-2 or 2-3, further including joint wires joined to the wire, in which

each of the joint wires extends from the wire to the first back surface and is partially covered by the first layer, and

each of the joint wires includes a bottom surface exposed on the first back surface.

2-5. The semiconductor device according to clause 2-4, further including terminals, in which the terminals separately cover the bottom surfaces of the joint wires.

2-6. The semiconductor device according to clause 2-5, in which each of the terminals includes metal layers stacked in the thickness-wise direction.

2-7. The semiconductor device according to clause 2-6, in which the metal layers have a composition including nickel and gold.

2-8. The semiconductor device according to clause 2-5, in which the terminals each include a solder ball.

2-9. The semiconductor device according to clause 2-6 or 2-7, in which

the first layer includes a side surface facing in a direction orthogonal to the thickness-wise direction and joined to the first main surface and the first back surface, and

the joint wires each include an end surface exposed on the side surface.

2-10. The semiconductor device according to clause 2-9, in which the terminals each include a bottom portion and a lateral portion joined to the bottom portion,

the bottom portion covers the bottom surface of one of the joint wires, and

the lateral portion covers the end surface of one of the joint wires.

2-11. The semiconductor device according to clause 2-6, further including a heat dissipating body, in which

the heat dissipating body includes a part embedded in the first layer in contact with the second back surface,

at least a portion of the heat dissipating body overlaps the semiconductor element as viewed in the thickness-wise direction.

2-12. The semiconductor device according to clause 2-11, in which

the heat dissipating body includes a base embedded in the first layer and a cover formed on the base and exposed on the first back surface,

the base has a thickness that is equal to a distance between the first main surface and the first back surface, and

the cover includes the metal layers.

2-13. The semiconductor device according to clause 12, in which

the heat dissipating body includes a bump projecting from the base toward the lower surface in the thickness-wise direction, and

one of the pads is bonded to the bump.

2-14. The semiconductor device according to clause 2-2 or 2-3, further including first joint wires and second joint wires joined to the wire,

each of the first joint wires extends from the wire to the first back surface and is partially covered by the first layer,

each of the first joint wires includes a bottom surface exposed on the first back surface,

each of the second joint wires extends from the wire to the second main surface and is partially covered by the second layer, and

each of the second joint wires includes a top surface exposed on the second main surface.

2-15. The semiconductor device according to clause 2-14, in which as viewed in the thickness-wise direction, a shortest distance from a center of the semiconductor element to one of the second joint wires is less than a shortest distance from the center of the semiconductor element to one of the first joint wires.

2-16. The semiconductor device according to clause 2-14 or 2-15, further including first terminals and second terminals, in which

the first terminals separately cover the bottom surfaces of the first joint wires,

the second terminals separately cover the top surfaces of the second joint wires.

2-17. The semiconductor device according to any one of clauses 2-2 to 2-16, in which as viewed in the thickness-wise direction, the wire is located at an inner side of a peripheral edge of the encapsulation resin.

3-1. An electronic component, including:

an insulation member having an electrically insulating property and including an insulation main surface and an insulation back surface facing in opposite directions in a thickness-wise direction;

a main surface wire formed on the insulation main surface and including a wire main surface facing in the same direction as the insulation main surface and a wire back surface facing the insulation main surface;

a first functional element electrically connected to the main surface wire, the first functional element and the insulation member being disposed at opposite sides of the main surface wire in the thickness-wise direction;

an encapsulation resin covering the main surface wire and the first functional element and including an element placement surface facing in the same direction as the insulation main surface;

a connection conductor electrically connected to the main surface wire, extending from the wire main surface to the element placement surface in the thickness-wise direction, and exposed from the element placement surface;

a through wire electrically connected to the main surface wire, extending from the wire back surface to the insulation back surface in the thickness-wise direction, and exposed from the insulation back surface; and

a second functional element mounted on the element placement surface and electrically connected to the connection conductor.

3-2. The electronic component according to clause 3-1, in which the second functional element is greater than the first functional element in dimension in the thickness-wise direction.

3-3. The electronic component according to clause 3-1 or 3-2, further including an upper surface wire formed on the element placement surface and electrically connected to the connection conductor, in which the second functional element is electrically connected to the connection conductor by the upper surface wire.

3-4. The electronic component according to clause 3-3, in which

the upper surface wire includes an upper surface electrode electrically connected to the second functional element, and

the electronic component further includes an insulation film, the insulation film covering the element placement surface and the upper surface wire excluding the upper surface electrode.

3-5. The electronic component according to any one of clauses 3-1 to 3-4, in which

the connection conductor is disposed to overlap the first functional element as viewed in a direction orthogonal to the thickness-wise direction, and

the second functional element is greater than the first functional element in a dimension in a direction orthogonal to the thickness-wise direction.

3-6. The electronic component according to any one of clauses 3-1 to 3-5, in which

the main surface wire includes an inward part extending to an inner side of the insulation main surface from the through wire in a planar direction of the insulation main surface, and

the first functional element is mounted on the inward part.

3-7. The electronic component according to clause 3-6, in which the connection conductor is connected to a portion of the inner part located between the first functional element and the through wire in a direction in which the inward part extends.

3-8. The electronic component according to clause 3-7, in which

the connection conductor includes multiple connection conductors, and

the connection conductors are separately located at opposite sides of the first functional element as viewed in the thickness-wise direction.

3-9. The electronic component according to any one of clauses 3-1 to 3-8, in which

the encapsulation resin includes
a resin side surface facing in a direction intersecting the thickness-wise direction, and
a step recessed inward from the resin side surface, and

the encapsulation resin is divided into a first resin part located toward the element placement surface from the step and a second resin part located toward the insulation member from the step in the thickness-wise direction.

3-10. The electronic component according to any one of clauses 3-1 to 3-9, in which the through wire is exposed from a side surface of the insulation member.

3-11. The electronic component according to clause 3-10, in which

the encapsulation resin includes a resin side surface facing in a direction intersecting the thickness-wise direction, and

the main surface wire is exposed from the resin side surface.

3-12. The electronic component according to any one of clauses 3-1 to 3-11, in which

the second functional element includes multiple second functional elements,

the main surface wire includes multiple main surface wires,

the connection conductor includes multiple connection conductors, and

the second functional elements are separately electrically connected to the first functional element by the main surface wires and the connection conductors.

3-13. The electronic component according to clause 3-12, in which

the second functional element includes multiple second functional elements,

the second functional elements each include multiple electrodes,

an upper surface wire is formed on the element placement surface, the upper surface wire including upper surface electrodes separately connected to the connection conductors, and

the electrodes are separately connected to the upper surface electrodes.

3-14. The electronic component according to any one of clauses 3-1 to 3-13, in which the first functional element includes a semiconductor element.

3-15. The electronic component according to any one of clauses 3-1 to 3-14, in which

the first functional element includes a control element, and

the second functional element includes a drive element driven by the control element.

3-16. The electronic component according to clause 3-14 or 3-15, in which the first functional element includes a large scale integration (LSI).

3-17. The electronic component according to clause 3-14, in which

the first functional element includes a switched-mode power supply LSI, and

the second functional element includes an inductor.

3-18. The electronic component according to clause 3-15 or 3-16, in which the second functional element includes an optical element.

3-19. The electronic component according to any one of clauses 3-12 to 3-16, in which

the second functional element includes a bridge-type output stage and an LC filter configured to remove noise from an output signal of the output stage, and

the first functional element includes an LSI configured to control the output stage.

3-20. The electronic component according to any one of clauses 3-12 to 3-14, in which

the first functional element includes a bridge-type output stage and an LSI configured to control the output stage, and

the second functional element includes an LC filter configured to remove noise from an output signal of the output stage.

3-21. An electronic component, including:

an insulation member having an electrically insulating property and including an insulation main surface and an insulation back surface facing in opposite directions in a thickness-wise direction;

a main surface wire formed on the insulation main surface and including a wire main surface facing in the same direction as the insulation main surface and a wire back surface facing the insulation main surface;

a through wire electrically connected to the main surface wire, extending from the wire back surface to the insulation back surface in the thickness-wise direction, and exposed from the insulation back surface;

a first functional element electrically connected to the main surface wire, the first functional element and the insulation member being disposed at opposite sides of the main surface wire in the thickness-wise direction;

an encapsulation resin covering the main surface wire and the first functional element and including an element placement surface facing in the same direction as the insulation main surface; and

a connection conductor electrically connected to the main surface wire, extending from the wire main surface to the element placement surface in the thickness-wise direction, and exposed from the element placement surface, in which the connection conductor is configured to be electrically connected to a second functional element mounted on the element placement surface.

3-22. A method for manufacturing an electronic component, the method including:

a step of forming through wires on a support substrate having an electrically insulating property;

an insulation layer forming step that forms an insulation layer including an insulation main surface and an insulation back surface facing in opposite directions in a thickness-wise direction so that the insulation layer fills a gap between the through wires on the support substrate and exposes the through wires from both the insulation main surface and the back surface;

a main surface wire forming step that forms a main surface wire including a wire main surface and a wire back surface facing in opposite directions in the thickness-wise direction on the insulation main surface so that the wire back surface is electrically connected to the through wires;

a conductor forming step that forms a connection conductor on the wire main surface;

a first element mounting step that mounts a first functional element on the wire main surface;

a resin layer forming step that forms a resin layer to cover the main surface wire, the connection conductor, and the first functional element; and

a cutting step that cuts the insulation layer, the resin layer, the main surface wire, and the through wires in the thickness-wise direction to form an insulation member including the through wires and an encapsulation resin covering the main surface wire, the connection conductor, and the first functional element, in which

in the resin layer forming step, the resin layer is formed so that the connection conductor is exposed from a surface of the resin layer located at a side opposite from the insulation member, and

the method further includes a second element mounting step that mounts a second functional element on a surface of the encapsulation resin located at a side opposite from the insulation member so as to be electrically connected to the connection conductor.

3-23. The method according to clause 3-22, in which in the main surface wire forming step, the main surface wire is formed through electrolytic plating.

3-24. The method according to clause 3-22 or 3-23, in which in the conductor forming step, the connection conductor is formed through electrolytic plating.

3-25. The method according to any one of clauses 3-22 to 3-24, further including a resin layer grinding step performed before the second element mounting step, in which the resin layer grinding step grinds the resin layer to reduce thickness of the resin layer.

3-26. The method according to clause 3-25, further including an upper surface wire forming step performed between the resin layer grinding step and the second element mounting step, in which the upper surface wire forming step forms an upper surface wire on a ground surface of the resin layer so as to be electrically connected to the connection conductor.

3-27. The method according to clause 3-26, further including an insulation film forming step performed between the resin layer grinding step and the second element mounting step, in which the insulation film forming step forms an insulation film that covers the ground surface of the resin layer excluding a portion of the ground surface exposing the connection conductor.

3-28. A method for manufacturing an electronic component, the method including:

an insulation layer forming step that forms an insulation layer including an insulation main surface and an insulation back surface facing in opposite directions in a thickness-wise direction;

a first inner electrode forming step that forms a through wire exposed from the insulation back surface and a main surface wire including a wire main surface and a wire back surface facing in opposite directions in the thickness-wise direction and formed on the insulation main surface so as to be electrically connected to the through wire on the wire back surface;

a second inner electrode forming step that forms a connection conductor formed on the wire main surface;

a first element mounting step that mounts a first functional element on the wire main surface;

a resin layer forming step that forms a resin layer that covers the main surface wire, the connection conductor, and the first functional element; and

a cutting step that cuts the insulation layer, the through wire, the wire main surface, and the resin layer in the thickness-wise direction to form an insulation member including the through wire an encapsulation resin covering the main surface wire, the connection conductor, and the first functional element, in which

in the resin layer forming step, the resin layer is formed so that the connection conductor is exposed from a surface of the resin layer located at a side opposite from the insulation member, and

the method further includes a second element mounting step that mounts a second functional element on a surface of the encapsulation resin located a side opposite from the insulation member so as to be electrically connected to the connection conductor.

3-29. The method according to clause 3-28, in which in the first inner electrode forming step, the through wire and the main surface wire are formed integrally.

3-30. The method according to clause 3-29, in which in the first inner electrode forming step, the through wire and the main surface wire are formed through electrolytic plating.

3-31. The method according to any one of clauses 3-28 to 3-30, in which in the second inner electrode forming step, the connection conductor is formed through electrolytic plating.

3-32. The method according to any one of clauses 3-28 to 3-31, further including a resin layer grinding step performed before the second element mounting step, in which the resin layer grinding step grinds the resin layer to reduce thickness of the resin layer.

3-33. The method according to clause 3-32, further including an upper surface wire forming step performed between the resin layer grinding step and the second element mounting step, in which the upper surface wire forming step forms an upper surface wire on a ground surface of the resin layer so as to be electrically connected to the connection conductor.

3-34. The method according to clause 3-33, further including an insulation film forming step performed between the resin layer grinding step and the second element mounting step, in which the insulation film forming step forms an insulation film that covers the ground surface of the resin layer excluding a portion of the ground surface exposing the connection conductor.

3-35. The method according to any one of clauses 3-22 to 3-34, in which in the cutting step, the main surface wire is exposed from a resin side surface of the encapsulation resin, and the through wire is exposed from a side surface of the insulation member.

3-36. The method according to clause 3-35, in which

the cutting step includes a first cutting step and a second cutting step,

the first cutting step cuts from a side of the insulation layer toward the resin layer with a dicing blade, so that the insulation layer is cut to form the insulation member and the resin layer is partially cut in the thickness-wise direction to form a separation groove, and

the second cutting step cuts the resin layer from the separation groove to form the encapsulation resin.

3-37. A method for manufacturing an electronic component, the method including:

a step of forming through wires on a support substrate having an electrically insulating property;

an insulation layer forming step that forms an insulation layer including an insulation main surface and an insulation back surface facing in opposite directions in a thickness-wise direction so that the insulation layer fills a gap between the through wires on the support substrate and exposes the through wires from both the insulation main surface and the back surface;

a main surface wire forming step that forms a main surface wire including a wire main surface and a wire back surface facing in opposite directions in the thickness-wise direction on the insulation main surface so that the wire back surface is electrically connected to the through wires;

a conductor forming step that forms a connection conductor on the wire main surface;

a first element mounting step that mounts a first functional element on the wire main surface;

a resin layer forming step that forms a resin layer to cover the main surface wire, the connection conductor, and the first functional element; and

a cutting step that cuts the insulation layer, the resin layer, the main surface wire, and the through wires in the thickness-wise direction to form an insulation member including the through wires and an encapsulation resin covering the main surface wire, the connection conductor, and the first functional element, in which

in the resin layer forming step, the resin layer is formed so that the connection conductor is exposed from a surface of the resin layer located at a side opposite from the insulation member, and

the encapsulation resin includes an element placement surface on which a second functional element is mounted,

the second functional element is electrically connected to the connection conductor, and

the element placement surface and the insulation layer are formed on opposite surfaces of the encapsulation resin in the thickness-wise direction.

3-38. A method for manufacturing an electronic component, the method including:

an insulation layer forming step that forms an insulation layer including an insulation main surface and an insulation back surface facing in opposite directions in a thickness-wise direction;

a first inner electrode forming step that forms a through wire exposed from the insulation back surface and a main surface wire including a wire main surface and a wire back surface facing in opposite directions in the thickness-wise direction and formed on the insulation main surface so as to be electrically connected to the through wire on the wire back surface;

a second inner electrode forming step that forms a connection conductor formed on the wire main surface;

a first element mounting step that mounts a first functional element on the wire main surface;

a resin layer forming step that forms a resin layer that covers the main surface wire, the connection conductor, and the first functional element; and

a cutting step that cuts the insulation layer, the through wire, the wire main surface, and the resin layer in the thickness-wise direction to form an insulation member including the through wire an encapsulation resin covering the main surface wire, the connection conductor, and the first functional element, in which

in the resin layer forming step, the resin layer is formed so that the connection conductor is exposed from a surface of the resin layer located at a side opposite from the insulation member, and

the encapsulation resin includes an element placement surface on which a second functional element is mounted,

the second functional element is electrically connected to the connection conductor, and

the element placement surface and the insulation layer are formed on opposite surfaces of the encapsulation resin in the thickness-wise direction.

### REFERENCE SIGNS LIST

A1, A2, A11 to A14) semiconductor device; 10) substrate; 20) wire portion; 21) main surface wire; 22) through wire; 23) first wire part; 24) second wire part; 27) columnar wire; 31) metal layer; 32) conductive layer; 40) bonding portion; 41) plated layer (first plated layer); 42) first solder layer; 45) solder layer; 50) semiconductor element; 55) element electrode; 56) second solder layer; 60) encapsulation resin; 70) external connection terminal; 71) first conductive film; 72) second conductive film; 101) substrate main surface; 102) substrate back surface; 105) through hole; 106) wall surface; 111) substrate main surface; 112) substrate back surface; 121) substrate main surface; 122) substrate back surface; 125) through hole; 135) through hole; 141) first insulation layer; 142) second insulation layer; 501) element main surface; 551) metal layer; 552) conductive layer; 605) through hole; A10, A11, A20, A30, A40) semiconductor device; 710) encapsulation resin; 711) first layer; 711A) first main surface; 711B) first back surface; 711C) side surface; 788) filler; 712) second layer; 712A) second main surface; 712B) second back surface; 721) wire; 789) base layer; 790) body layer; 722) joint wire; 722A) bottom surface; 722B) end surface; 723) first joint wire; 723 A) bottom surface; 723B) end surface; 724) second joint wire; 724A) top surface; 724B) side surface; 730) semiconductor element; 730A) lower surface; 731) pad; 739) bonding layer; 741) terminal; 791) bottom portion; 792) lateral portion; 742) first terminal; 743) second terminal; 750: heat dissipating body; 751) base; 752) cover; 753) bump; 793) base layer; 794) body layer; 780) base member; 781) insulation film; 782) separation layer; 783) columnar body; 784) first resin layer; 785) second resin layer; 786) metal layer; 787) tape; C) center; L1, L2) shortest distance; z) thickness-wise direction; x) first direction; y) second direction; 801A, 801B, 801C) electronic component; 810) substrate (insulation member); 810s) substrate main surface (insulation main surface); 810s) substrate back surface (insulation back surface); 811 to 814) substrate side surface (side surface of insulation member); 820) inner electrode; 821, 825) main surface wire; 821p) inward part; 821s) wire main surface; 821r) wire back surface; 822, 826) through wire; 822r) back surface (exposed back surface); 823) connection conductor; 823A) first connection conductor (connection conductor); 823B) second connection conductor (connection conductor); 824s) wire main surface; 824r) wire back surface; 830) first functional element; 840) encapsulation resin; 840s) resin main surface (element placement surface); 841 to 844) resin side surface; 845) step; 846) first resin part; 847) second resin part; 860) second functional element; 861) first electrode; 862) second electrode; 865) external electrode; 863) output stage; 864) LC filter; 870) upper surface wire; 871) first upper surface electrode (upper surface electrode); 872) second upper surface electrode (upper surface electrode); 873) insulation film; 890) insulation member; 890s) insulation main surface; 890r) insulation back surface; 890x) insulation side surface (side surface of insulation member); 900) upper surface wire; 901) upper surface electrode; 1600) support substrate; 1610) base member (insulation layer); 1611) upper surface (insulation main surface); 1612) lower surface (insulation back surface); 1621) main surface wire; 1623) connection conductor; 1640, 1740) resin layer; 1640s, 1740s) resin main surface (surface of resin layer opposite from insulation member); 1645, 1745) separation groove; 1700) support substrate; 1723) connection conductor; 1790) insulation layer; 1790s) insulation main surface; 1790r) insulation back surface; x) first direction; y) second direction; z) thickness-wise direction

1. A semiconductor device, comprising:
a substrate including a substrate main surface and a substrate back surface facing in opposite directions;
a wire portion including a conductive layer formed on the substrate main surface;
a bonding portion including a first plated layer formed on an upper surface of the wire portion and a first solder layer formed on an upper surface of the first plated layer;
a semiconductor element including an element main surface facing the substrate main surface, an element electrode formed on the element main surface, and a second plated layer formed on a lower surface of the element electrode and bonded to the first solder layer; and
an encapsulation resin covering the semiconductor element, wherein
the bonding portion is larger than the element electrode as viewed in a thickness-wise direction that is perpendicular to the substrate main surface.

2. The semiconductor device according to claim 1, wherein a cross section of the first solder layer that is perpendicular to the substrate main surface has an aspect ratio that is greater than or equal to 40 and less than or equal to 80.

3. The semiconductor device according to claim 1, wherein a distance from the element electrode to an end of the bonding portion is greater than or equal to 4 μm and less than or equal to 10 μm.

4. The semiconductor device according to claim 1, wherein a distance between an end of the conductive layer and an end of the bonding portion is less than or equal to 1 μm.

5. The semiconductor device according to claim 1, wherein
the element electrode and the second solder layer are disposed on each end of a mount surface in a first direction that is parallel to the mount surface, and
the wire portion extends toward an outer side of the semiconductor element.

6. The semiconductor device according to claim 5, wherein
the element electrode is separated from an end of the bonding portion by a first distance in a direction toward an inner side of the semiconductor element,
the element electrode is separated from an end of the bonding portion by a second distance in a direction toward an outer side of the semiconductor element, and
the second distance is greater than the first distance.

7. A semiconductor device, comprising:
an encapsulation resin including a first layer and a second layer, the first layer including a first main surface and a first back surface facing in opposite directions in a thickness-wise direction, the second layer including a second main surface and a second back surface facing in opposite directions in the thickness-wise direction, and the second back surface being in contact with the first main surface;
a wire being in contact with the first main surface and partially covered by the second layer; and
a semiconductor element including a lower surface facing the first main surface and pads disposed on the lower surface, wherein at least one of the pads is bonded to the wire and covered by the second layer.

8. The semiconductor device according to claim 7, wherein a distance between the first main surface and the second back surface is smaller than a distance between the second main surface and the second back surface.

9. The semiconductor device according to claim 8, wherein the first layer contains a filler including an inorganic compound.

10. The semiconductor device according to claim 8 or 9, further comprising joint wires joined to the wire, wherein
each of the joint wires extends from the wire to the first back surface and is partially covered by the first layer, and
each of the joint wires includes a bottom surface exposed on the first back surface.

11. The semiconductor device according to claim 10, further comprising terminals, wherein the terminals separately cover the bottom surfaces of the joint wires.

12. The semiconductor device according to claim 11, wherein each of the terminals includes metal layers stacked in the thickness-wise direction.

13. An electronic component, comprising:
an insulation member having an electrically insulating property and including an insulation main surface and an insulation back surface facing in opposite directions in a thickness-wise direction;
a main surface wire formed on the insulation main surface and including a wire main surface facing in the same direction as the insulation main surface and a wire back surface facing the insulation main surface;
a first functional element electrically connected to the main surface wire, the first functional element and the insulation member being disposed at opposite sides of the main surface wire in the thickness-wise direction;
an encapsulation resin covering the main surface wire and the first functional element and including an element placement surface facing in the same direction as the insulation main surface;
a connection conductor electrically connected to the main surface wire, extending from the wire main surface to the element placement surface in the thickness-wise direction, and exposed from the element placement surface;
a through wire electrically connected to the main surface wire, extending from the wire back surface to the insulation back surface in the thickness-wise direction, and exposed from the insulation back surface; and
a second functional element mounted on the element placement surface and electrically connected to the connection conductor.

14. The electronic component according to claim 13, wherein the second functional element is greater than the first functional element in dimension in the thickness-wise direction.

15. The electronic component according to claim 13, further comprising an upper surface wire formed on the element placement surface and electrically connected to the connection conductor, wherein the second functional element is electrically connected to the connection conductor by the upper surface wire.

16-20. (canceled)
